(19) United States
(12) Patent Application Publication
(10) Pub. No.: US 2023/0292615 A1
(43) Pub. Date: Sep. 14, 2023

(54) ORGANIC MOLECULES FOR OPTOELECTRONIC DEVICES

(71) Applicant: CYNORA GMBH, Bruchsal (DE)

(72) Inventors: Daniel ZINK, Graben-Neudorf (DE); Damien THIRION, Karlsdorf-Neuthard (DE); Stefan SEIFERMANN, Bühl (DE); Sebastian DÜCK, Heidelberg (DE); Ramin PASHAZADEH, Bruchsal (DE)

(21) Appl. No.: 18/006,143

(22) PCT Filed: Jul. 22, 2021
(86) PCT No.: PCT/EP2021/070474

§ 371 Date: Jan. 19, 2023

(30) Foreign Application Priority Data
Jul. 24, 2020 (EP) 20187620.8

(51) Int. Cl. H10K 85/60; C07F 5/02; C09K 11/06

(52) U.S. Cl. CPC H10K 85/658; C07F 5/027; C09K 11/06; C07B 2200/05; H10K 50/11

(57) ABSTRACT

The invention pertains to an organic molecule for use in optoelectronic devices. The organic molecule has a structure of Formula I:

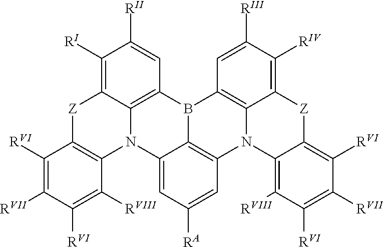

Formula I
wherein
R^{A} is a moiety represented by one of Formulas II, III, or IV:

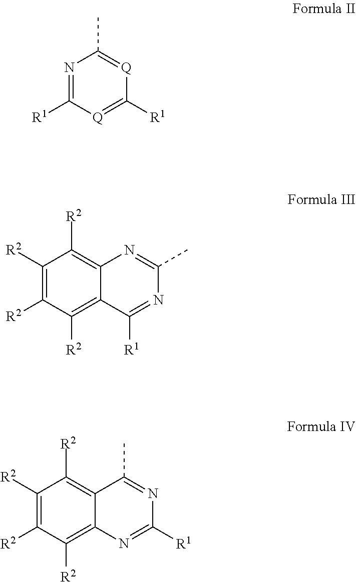

which is bonded to the structure of Formula I via the position marked by the dotted line; Q is at each occurrence independently selected from the group consisting of N and CR³; and
Z is at each occurrence independently from one another selected from the group consisting of a direct bond, CR⁴R⁵, C═CR⁴R⁵, C═O, C═NR⁴, NR⁴, O, SiR⁴R⁵, S, S(O) and S(O)₂.

### CROSS-REFERENCE TO RELATED APPLICATIONS

This application is a U S. National Phase Patent Application of International Patent Application Number PCT/EP2021/070474, filed on Jul. 22, 2021, which claims priority to European Patent Application Number 20187620.8, filed on Jul. 24, 2020, the entire contents of all of which are incorporated herein by reference.

The invention relates to light-emitting organic molecules and their use in organic light-emitting diodes (OLEDs) and in other optoelectronic devices.

### DESCRIPTION

The object of the present invention is to provide molecules which are suitable for use in optoelectronic devices.

This object is achieved by the invention which provides a new class of organic molecules.

Organic electroluminescent devices containing one or more light-emitting layers based on organics, such as, e.g., organic light emitting diodes (OLEDs), light emitting electrochemical cells (LECs) and light-emitting transistors, gain increasing importance. In particular, OLEDs are promising devices for electronic products such as screens, displays and illumination devices. In contrast to most electroluminescent devices essentially based on inorganics, organic electroluminescent devices based on organics are often rather flexible and producible in particularly thin layers. The OLED-based screens and displays already available today bear either good efficiencies and long lifetimes or good color purities and long lifetimes, but do not combine all three properties, i.e. good efficiency, long lifetime, and good color purity.

Thus, there is still an unmet technical need for organic electroluminescent devices which have a high quantum yield, a long lifetime, and a good color purity.

The color purity or color point of an OLED is typically provided by CIEx and CIEy coordinates, whereas the color gamut for the next generation display is provided by so-called BT-2020 and DCPI3 values. Generally, in order to achieve these color coordinates, top emitting devices are needed to adjust the color coordinates by changing the cavity. In order to achieve high efficiency in top emitting devices while targeting this color gamut, a narrow emission spectrum in bottom emitting devices is required.

The organic molecules according to the invention exhibit emission maxima in the sky blue, green or yellow spectral range. The organic molecules exhibit in particular emission maxima between 490 and 600 nm, more preferably between 500 and 560 nm, and even more preferably between 520 and 540 nm. Additionally, the molecules of the invention exhibit in particular a narrow emission—expressed by a small full width at half maximum (FWHM). The emission spectra of the organic molecules preferably show a full width at half maximum (FWHM) of less than or equal to 0.25 eV (≤0.25 eV), if not stated otherwise measured with 2% by weight of emitter in poly(methyl methacrylate) PMMA at room temperature. The photoluminescence quantum yields of the organic molecules according to the invention are, in particular, 10% or more.

The use of the molecules according to the invention in an optoelectronic device, for example, an organic light-emitting diode (OLED), leads to a narrow emission and high efficiency of the device. Corresponding OLEDs have a higher stability than OLEDs with known emitter materials and comparable color and/or by employing the molecules according to the invention in an OLED display, a more accurate reproduction of visible colors in nature, i.e. a higher resolution in the displayed image, is achieved. In particular, the molecules can be used in combination with an energy pump to achieve hyper-fluorescence or hyper-phosphorescence. In these cases, another species included in an organic electroluminescent device transfers energy to the organic molecules of the invention which then emit light.

The organic molecules according to the invention include or consist a structure of Formula I

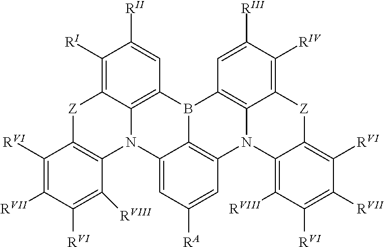

### Formula I

wherein
R^{A} is an acceptor moiety represented b one of Formulas II, III or IV:

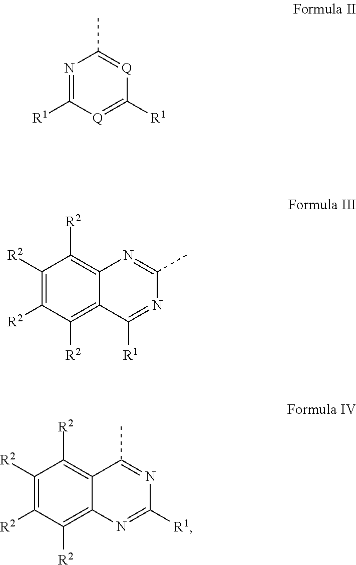

which is bonded to the structure of Formula I via the position marked by the dotted line.
Q is at each occurrence independently selected from the group consisting of N and CR³.
Z is at each occurrence independently from one another selected from the group consisting of a direct bond, CR⁴R⁵, C═CR⁴R⁵, C═O, C═NR⁴, NR⁴, O, SiR⁴R⁵, S, S(O) and S(O)₂.

R¹, R², and R³ are at each occurrence independently selected from the group consisting of:
hydrogen, deuterium, halogen, Me, ⁱPr, ^{t}Bu, CN, CF₃, SiMe₃, SiPh₃,
C₆-C₁₁-aryl,
wherein optionally one or more hydrogen atoms are independently substituted by C₁-C₅-alkyl, CN, CF₃ and Ph (=phenyl).
R^{I}, R^{II}, R^{III}, R^{IV}, R^{VI}, R^{VII}, and R^{VIII} are independently selected from the group consisting of:
hydrogen;
deuterium;
N(R⁶)₂;
OR⁶;
SR⁶;
Si(R⁶)₃;
B(OR⁶)₂;
OSO₂R⁶;
CF₃;
CN;
halogen;
C₁-C₄₀-alkyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₁-C₄₀-alkoxy,
which is optionally substituted with one or more substituents R⁶ and
wherein one or more non-adjacent CH₂-groups are optionally substituted by R⁶C═CR⁶, C≡C, Si(R′)₂, Ge(R⁶)₂, Sn(R⁶)₂, C═O, C═S, C═Se, C═NR⁶, P(═O)(R⁶), SO, SO₂, NR⁶, O, S or CONR⁶;
C₁-C₄-thioalkoxy,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S. C═Se, C═NR⁶, P(═O)(R⁶), SO, SO₂, NR⁶, O, S or CONR⁶;
C₂-C₄₀-alkenyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶). SO, SO₂, NR⁶, O, S or CONR⁶;
C₂-C₄₀-alkynyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S. C═Se, C═NR⁶, P(═O)(R⁶), SO, SO₂, NR⁶, O, S or CONR⁶;
C₆-C₆₀-aryl,
which is optionally substituted with one or more substituents R⁶; and
C₃-C₅₇-heteroaryl.
which is optionally substituted with one or more substituents R⁶.
R⁴, R⁵, and R⁶ are at each occurrence independently selected from the group consisting of: hydrogen, deuterium, OPh, SPh, CF₃, CN, F, Si(C₁-C₅-alkyl)₃, Si(Ph)₃;
C₁-C₅-alkyl,
wherein optionally one or more hydrogen atoms are independently substituted by deuterium, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
which is optionally substituted with one or more C₁-C₅-alkyl substituents;
C₃-C₁₇-heteroaryl,
which is optionally substituted with one or more C₁-C₅-alkyl substituents;
N(C₆-C₁₈-aryl)₂;
N(C₃-C₁₇-heteroaryl)₂; and
N(C₃-C₁₇-heteroaryl)(C₆-C₁₈-aryl);
wherein the substituents R^{I}, R^{II}, R^{III}, R^{IV}, R^{VI}, R^{VII}, and R^{VIII} independently from each other optionally form a mono- or polycyclic, aliphatic, aromatic and/or benzo-fused ring system with one or more adjacent substituents R^{I}, R^{II}, R^{III}, R^{IV}, R^{VI}, R^{VII} or R^{VIII}.

In one embodiment of the invention, the organic molecule includes or consists of a structure of Formula 1-1:

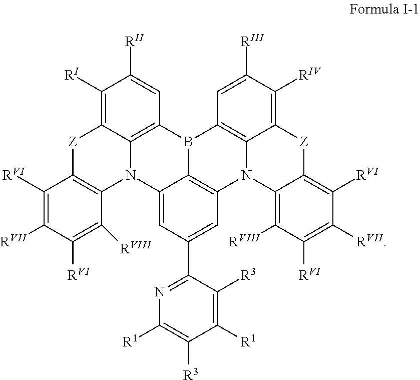

In another embodiment of the invention, the organic molecule includes or consists of a structure of Formula 1-1 and R³ is at each occurrence hydrogen.

In one embodiment of the invention, the organic molecule includes or consists of a structure of Formula 1-2:

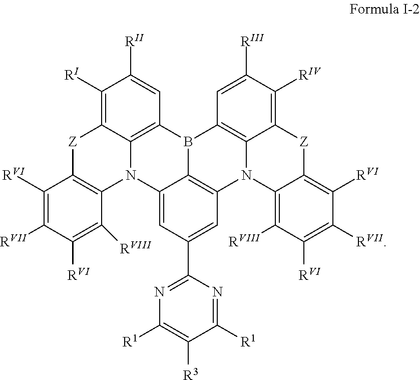

In another embodiment of the invention, the organic molecule includes or consists of a structure of Formula 1-2 wherein R³ is hydrogen.

In one embodiment of the invention, the organic molecule includes or consists of a structure of Formula 1-3:

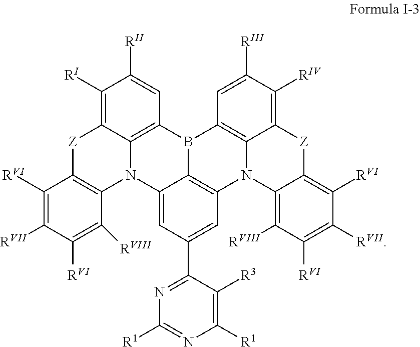

In another embodiment of the invention, the organic molecule includes or consists of a structure of Formula 1-3 wherein R³ is hydrogen.

In one embodiment of the invention, the organic molecule includes or consists of a structure of Formula 1-4:

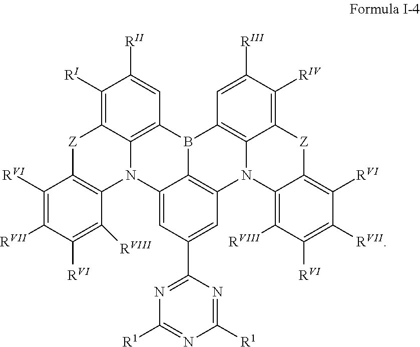

In a preferred embodiment of the invention, the organic molecule includes or consists of a structure of Formula 1-5:

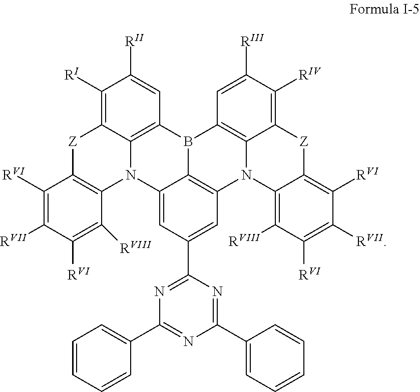

In one embodiment of the invention, the organic molecule includes or consists of a structure of Formula 1-6:

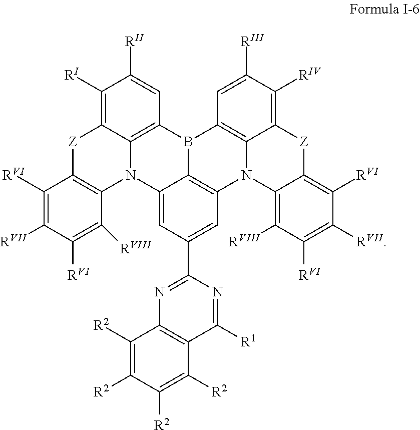

In another embodiment of the invention, the organic molecule includes or consists of a structure of Formula 1-6 wherein R² is at each occurrence hydrogen.

In one embodiment of the invention, the organic molecule includes or consists of a structure of Formula 1-7:

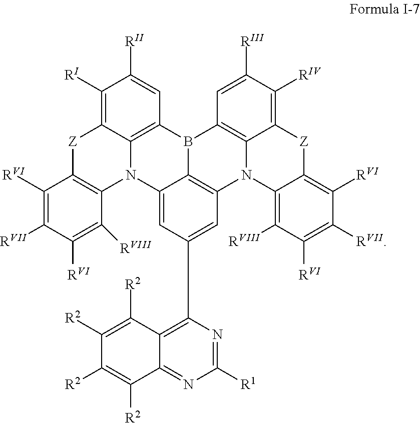

In another embodiment of the invention, the organic molecule includes or consists of a structure of Formula 1-7 wherein R² is at each occurrence hydrogen.

In a preferred embodiment of the invention, the organic molecule includes or consists of a structure of Formula Ia:

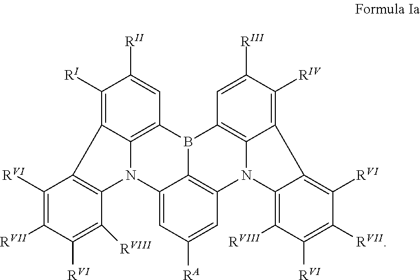

In one embodiment of the invention, the organic molecule includes or consists of a structure of Formula Ia-1:

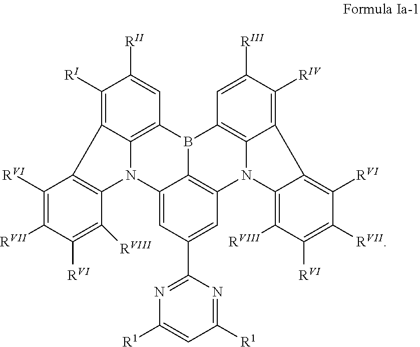

In one embodiment of the invention, the organic molecule includes or consists of a structure of Formula Ia-2:

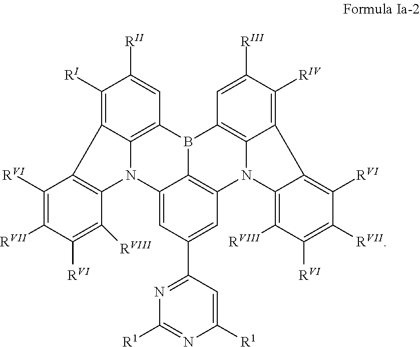

In one embodiment of the invention, the organic molecule includes or consists of a structure of Formula Ia-3:

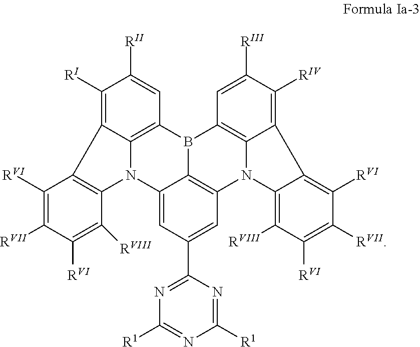

In one embodiment of the invention, the organic molecule includes or consists of a structure of Formula Ia-4:

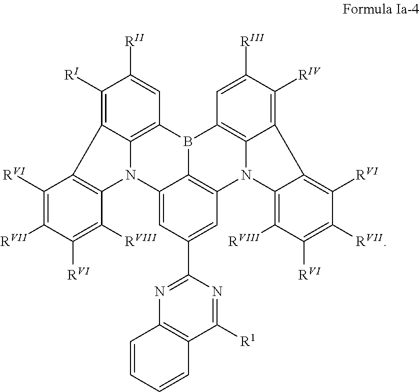

In one embodiment of the invention, the organic molecule includes or consists of a structure of Formula Ia-5:

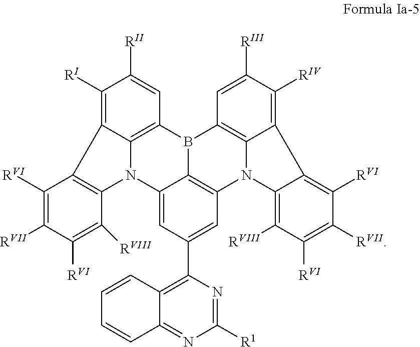

In a preferred embodiment of the invention, the organic molecule includes or consists of a structure of Formula Ib:

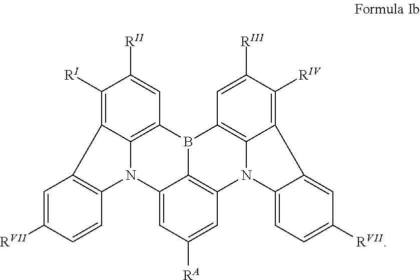

In an even more preferred embodiment of the invention, the organic molecule includes or consists of a structure of Formula Ib-1, Ib-2 or Ib-3:

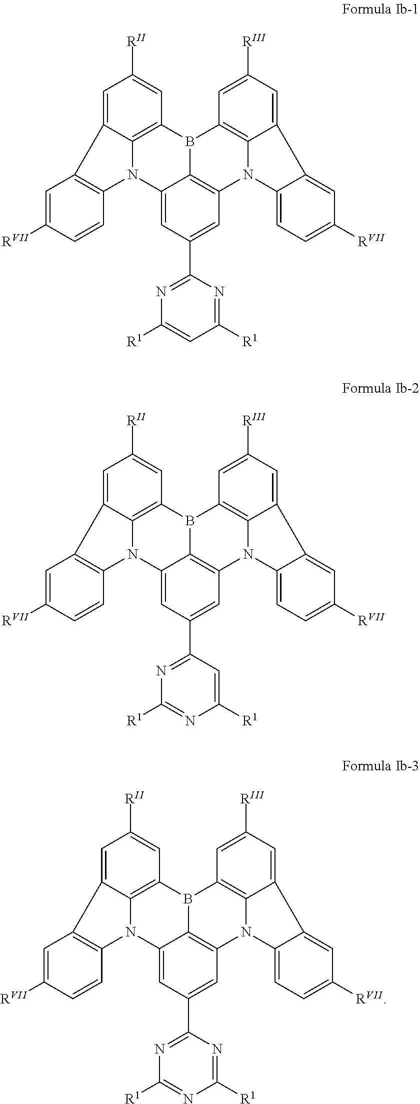

In a particularly preferred embodiment of the invention, the organic molecule includes or consists of a structure of Formula Ib-4, Ib-5 or Ib-6:

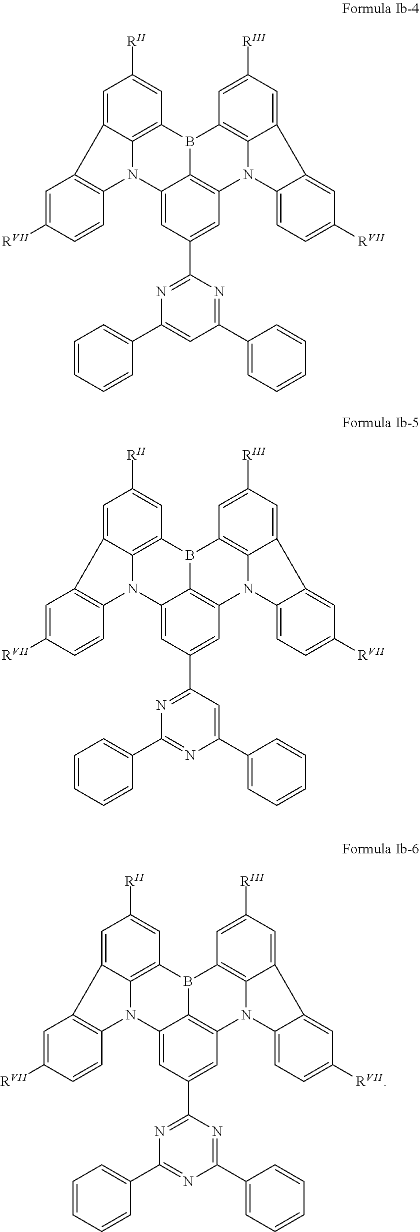

In another particularly preferred embodiment of the invention, the organic molecule includes or consists of a structure of Formula Ib-4-1, Ib-4-2, Ib-5-1, Ib-5-2, Ib-6-1, or Ib-6-2.

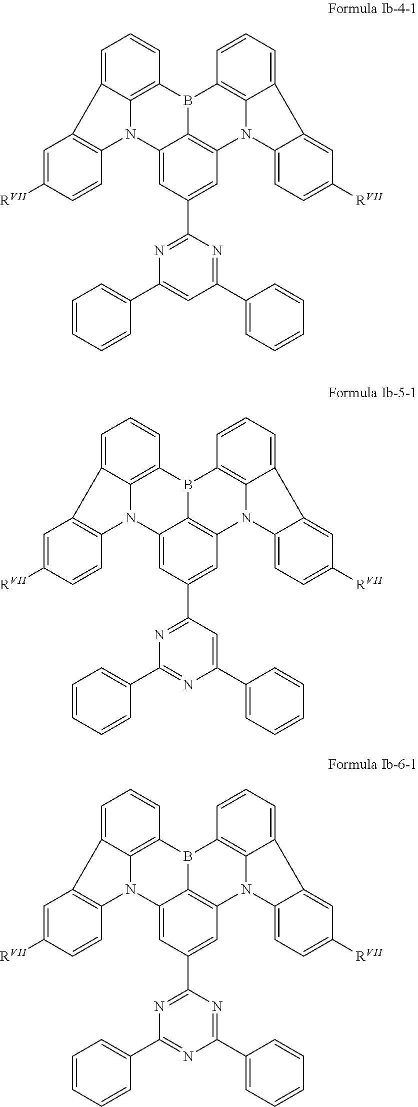

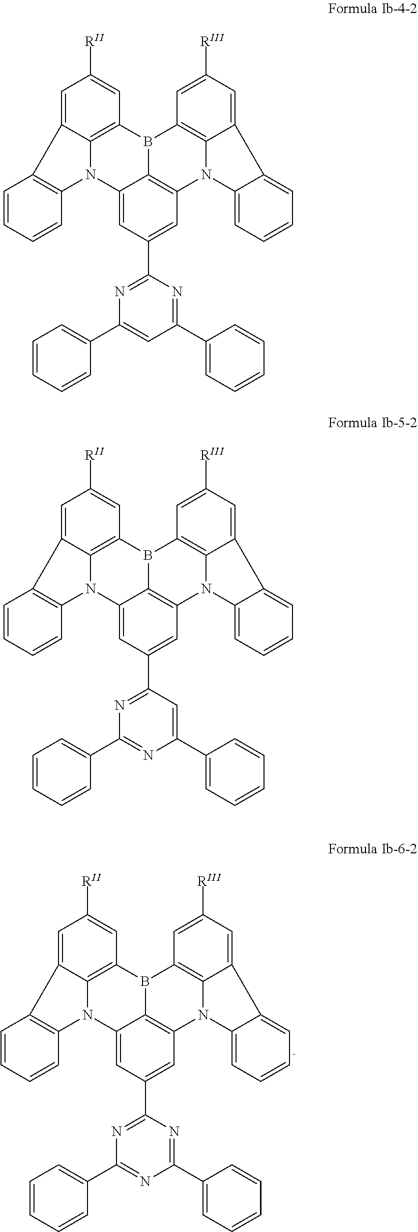

In another embodiment of the invention, the organic molecule includes or consists of a structure of Formula Ic:

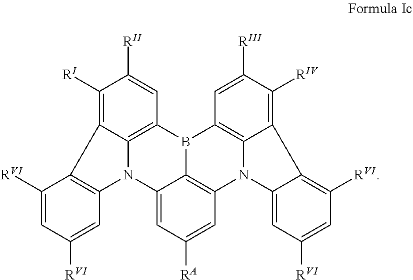

In another embodiment of the invention, the organic molecule includes or consists of a structure of Formula Id:

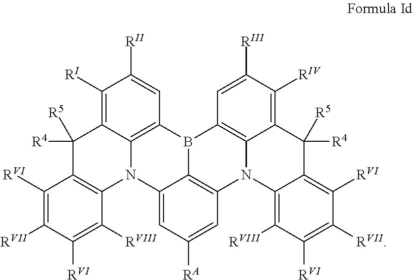

In another embodiment of the invention, the organic molecule includes or consists of a structure of Formula Ie:

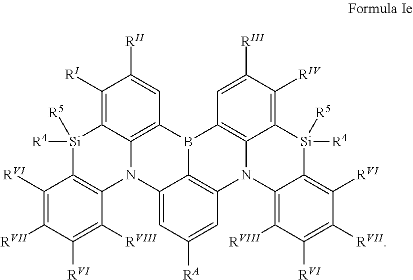

In another embodiment of the invention, the organic molecule includes or consists of a structure of Formula If:

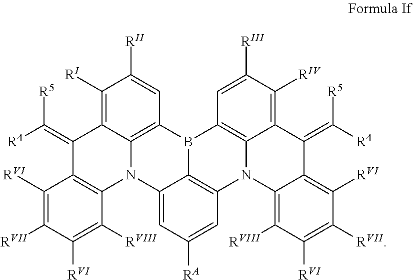

In another embodiment of the invention, the organic molecule includes or consists of a structure of Formula Ig:

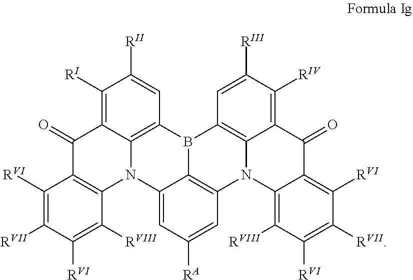

In another embodiment of the invention, the organic molecule includes or consists of a structure of Formula Ih:

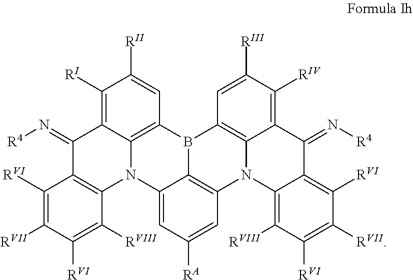

In another embodiment of the invention, the organic molecule includes or consists of a structure of Formula Ii:

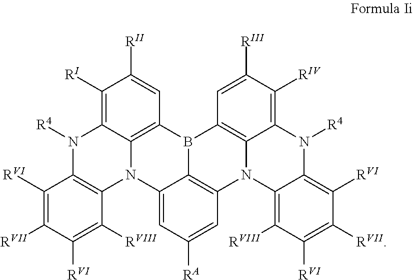

In another embodiment of the invention, the organic molecule includes or consists of a structure of Formula Ij:

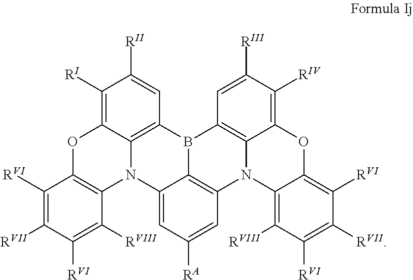

In another embodiment of the invention, the organic molecule includes or consists of a structure of Formula Ik:

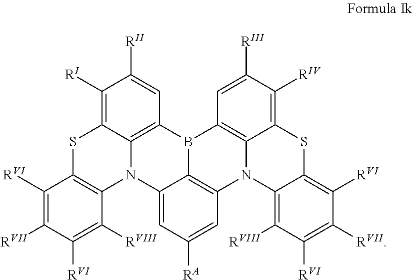

In another embodiment of the invention, the organic molecule includes or consists of a structure of Formula Im:

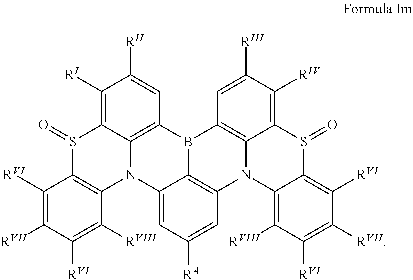

In another embodiment of the invention, the organic molecule includes or consists of a structure of Formula In:

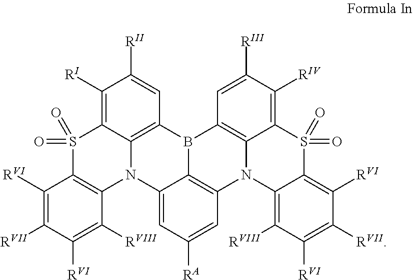

In a preferred embodiment of the invention, the organic molecule includes or consists of a structure of Formulas I, I-1, I-2, I-3, I-4, I-5, I-6, I-7, Ia, Ia-1, Ia-2, Ia-3, Ia-4, Ia-5, Ib, Ib-1, Ib-2, Ib-3, Ib-4, Ib-4-1, Ib-4-2, Ib-5, Ib-5-1, Ib-5-2, Ib-6, Ib-6-1, Ib-6-2, Ic, Id, Ie, If, Ig, Ih, Ii, Ij, Ik, Im, or In, wherein R^{I}, R^{II}, R^{III}, R^{IV}, R^{VI}, R^{VII}, and R^{VIII} are at each occurrence independently selected from the group consisting of: hydrogen, deuterium, halogen, CN, CF₃, SiMe₃, SiPh₃;
C₁-C₅-alkyl,
wherein one or more hydrogen atoms are optionally substituted by deuterium;
C₆-C₁₈-aryl,
wherein optionally one or more hydrogen atoms are independently substituted by C₁-C₅-alkyl, C₆-C₁₈-aryl, C₃-C₁₇-heteroaryl, CN or CFs;
C₃-C₁₅-heteroaryl,
wherein optionally one or more hydrogen atoms are independently substituted by C₁-C₅-alkyl, C₆-C₁₈-aryl, C₃-C₁₇-heteroaryl, CN or CF₃; and
N(Ph)₂.

In an even more preferred embodiment of the invention, the organic molecule includes or consists of a structures of Formulas I, I-1, I-2, I-3, I-4, I-5, I-6, I-7, Ia, Ia-1, Ia-2, Ia-3, Ia-4, Ia-5, Ib, Ib-1, Ib-2, Ib-3, Ib-4, Ib-4-1, Ib-4-2, Ib-5, Ib-5-1, Ib-5-2, Ib-6, Ib-6-1, Ib-6-2, Ic, Id, Ie, If, Ig, Ih, Ii, Ij, Ik, Im, or In, wherein R^{I}, R^{II}, R^{III}, R^{IV}, R^{VI}, R^{VII}, and R^{VIII} are at each occurrence independently selected from the group consisting of: hydrogen, deuterium, halogen, Me, ⁱPr, ^{t}Bu, CN, CF₃, SiMe₃, SiPh₃,
Ph, which is optionally substituted with one or more substituents independently selected from the group consisting of Me, ⁱPr, ^{t}Bu, CN, CF₃, and Ph, and
N(Ph)₂.

In a preferred embodiment of the invention, the organic molecule includes or consists of a structure of Formulas I, I-1, I-2, I-3, I-4, I-5, I-6, I-7, Ia, Ia-1, Ia-2, Ia-3, Ia-4, Ia-5, Ib, Ib-1, Ib-2, Ib-3, Ib-4, Ib-4-1, Ib-4-2, Ib-5, Ib-5-1, Ib-5-2, Ib-6, Ib-6-1, Ib-6-2, Ic, Id, Ie, If, Ig, Ih, Ii, Ij, Ik, Im, or In, wherein R⁴, R⁵, and R⁶ are at each occurrence independently selected from the group consisting of: hydrogen, deuterium, halogen. CN, CF₃, SiMe₃, SiPh₃;
C₁-C₅-alkyl,
wherein one or more hydrogen atoms are optionally substituted by deuterium;
C₆-C₁₆-aryl,
wherein optionally one or more hydrogen atoms are independently substituted by C₁-C₅-alkyl, C₅-C₁₆-aryl, C₃-C₁₇-heteroaryl, CN or CF₃;
C₃-C₁₅-heteroaryl,
wherein optionally one or more hydrogen atoms are independently substituted by C₁-C₅-alkyl, C₆-C₁₈-aryl, C₃-C₁₇-heteroaryl, CN or CF₃; and
N(Ph)₂.

In an even more preferred embodiment of the invention, the organic molecule includes or consists of a structure of Formulas I, I-1, I-2, I-3, I-4, I-5, I-6, I-7, Ia, Ia-1, Ia-2, Ia-3, Ia-4, Ia-5, Ib, Ib-1, Ib-2, Ib-3, Ib-4, Ib-4-1, Ib-4-2, Ib-5, Ib-5-1, Ib-5-2, Ib-6, Ib-6-1, Ib-6-2, Ic, Id, Ie, If, Ig, Ih, Ii, Ij, Ik, Im, or In, wherein R⁴, R⁵, and R⁶ are at each occurrence independently selected from the group consisting of: hydrogen, deuterium, halogen, Me, ⁱPr, ^{t}Bu, CN, CF₃, SiMe₃, SiPh₃,
Ph, which is optionally substituted with one or more substituents independently selected from the group consisting of Me, ⁱPr, ^{t}Bu, CN, CF₃, and Ph, and
N(Ph)₂.

In a preferred embodiment of the invention, the organic molecule includes or consists of a structure of Formulas I, I-1, I-2, I-3, I-4, I-5, I-6, I-7, Ia, Ia-1, Ia-2, Ia-3, Ia-4, Ia-5, Ib, Ib-1, Ib-2, Ib-3, Ic, Id, Ie, If, Ig, Ih, Ii, Ij, Ik, Im, or In, wherein R¹, R², and R³ are at each occurrence independently selected from the group consisting of: hydrogen, deuterium, Me, ⁱPr, ^{t}Bu, and
phenyl, which is optionally substituted with one or more substituents independently selected from the group consisting of Me, ⁱPr, ^{t}Bu, and Ph.

In another preferred embodiment of the invention, the organic molecule includes or consists of a structure of Formulas I, I-1, I-2, I-3, I-4, I-5, I-6, I-7, Ia, Ia-1, Ia-2, Ia-3, Ia-4, Ia-5, Ib, Ib-1, Ib-2, Ib-3, Ic, Id, Ie, If, Ig, Ih, Ii, Ij, Ik, Im, or In, wherein
R², and R³ are at each occurrence hydrogen; and wherein
R¹ is at each occurrence independently selected from the group consisting of: hydrogen, deuterium, Me, ⁱPr, ^{t}Bu, and
phenyl, which is optionally substituted with one or more substituents independently selected from the group consisting of Me, ⁱPr, ^{t}Bu, and Ph.

In another preferred embodiment of the invention, the organic molecule includes or consists of a structure of Formulas I, I-1, I-2, I-3, I-4, I-5, I-6, I-7, Ia, Ia-1, Ia-2, Ia-3, Ia-4, Ia-5, Ib, Ib-1, Ib-2, Ib-3, Ic, Id, Ie, If, Ig, Ih, Ii, Ij, Ik, Im, or In, wherein
R², and R³ are at each occurrence hydrogen; and wherein
R¹ is at each occurrence independently selected from the group consisting of: hydrogen and phenyl.

In another preferred embodiment of the invention, the organic molecule includes or consists of a structure of Formulas I, I-1, I-2, I-3, I-4, I-5, I-6, I-7, Ia, Ia-1, Ia-2, Ia-3, Ia-4, Ia-5, Ib, Ib-1, Ib-2, Ib-3, Ic, Id, Ie, If, Ig, Ih, Ii, Ij, Ik, Im, or In, wherein
R², and R³ are at each occurrence hydrogen; and wherein
R¹ is at each occurrence phenyl.

In another embodiment of the invention, the organic molecule includes or consists of a structure of Formulas I, I-1, I-2, I-3, I-4, I-5, I-6, I-7, Ia, Ia-1, Ia-2, Ia-3, Ia-4, Ia-5, Ib, Ib-1, Ib-2, Ib-3, Ic, Id, Ie, If, Ig, Ih, Ii, Ij, Ik, Im, or In, wherein
R¹, R², and R³ are at each occurrence hydrogen.

As used throughout the present application, the terms “aryl” and “aromatic” may be understood in the broadest sense as any mono-, bi- or polycyclic aromatic moieties. Accordingly, an aryl group contains 6 to 60 aromatic ring atoms, and a heteroaryl group contains 5 to 60 aromatic ring atoms, of which at least one is a heteroatom. Notwithstanding, throughout the application the number of aromatic ring atoms may be given as subscripted number in the definition of certain substituents. In particular, the heteroaromatic ring includes one to three heteroatoms. Again, the terms “heteroaryl” and “heteroaromatic” may be understood in the broadest sense as any mono-, bi- or polycyclic hetero-aromatic moieties that include at least one heteroatom. The heteroatoms may at each occurrence be the same or different and be individually selected from the group consisting of N, O and S. Accordingly, the term “arylene” refers to a divalent substituent that bears two binding sites to other molecular structures and thereby serving as a linker structure. In case, a group in the exemplary embodiments is defined differently from the definitions given here, for example, the number of aromatic ring atoms or number of heteroatoms differs from the given definition, the definition in the exemplary embodiments is to be applied. According to the invention, a condensed (annulated) aromatic or heteroaromatic polycycle is built of two or more single aromatic or heteroaromatic cycles, which formed the polycycle via a condensation reaction.

In particular, as used throughout the present application, examples of the term aryl group or heteroaryl group include groups which can be bound via any position of the aromatic or heteroaromatic group, derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthoimidazole, phenanthroimidazole, pyridoimidazole, pyrazinoimidazole, quinoxalinoimidazole, oxazole, benzoxazole, naphthooxazole, anthroxazol, phenanthroxazol, isoxazole, 1,2-thiazole, 1,3-thiazole, benzothiazole, pyridazine, benzopyridazine, pyrimidine, benzopyrimidine, 1,3,5-triazine, quinoxaline, pyrazine, phenazine, naphthyridine, carboline, benzocarboline, phenanthroline, 1,2,3-triazole, 1,2,4-triazole, benzotriazole, 1,2,3-oxadiazole, 1,2,4-oxadiazole, 1,2,5-oxadiazole, 1,2,3,4-tetrazine, purine, pteridine, indolizine and benzothiadiazole or combinations of the above mentioned groups.

As used throughout the present application, examples of the term cyclic group may be understood in the broadest sense as any mono-, bi- or polycyclic moieties.

As used above and herein, examples of the term alkyl group may be understood in the broadest sense as any linear, branched, or cyclic alkyl substituent. In particular, the term alkyl includes the substituents methyl (Me), ethyl (Et), n-propyl (ⁿPr), i-propyl (ⁱPr), cyclopropyl, n-butyl (ⁿBu), i-butyl (^{t}Bu), s-butyl (^{s}Bu), t-butyl (^{t}Bu), cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]-octyl, 2-(2,6-dimethyl)octyl, 3-(3,7-dimethyl)octyl, adamantyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl and 1-(n-decyl)-cyclohex-1-yl.

As used above and herein, examples of the term alkenyl include linear, branched, and cyclic alkenyl substituents. Examples of the term alkenyl group exemplarily includes the substituents ethenyl, propenyl, butenyl, pentenyl, cyclopentenyl, hexenyl, cyclohexenyl, heptenyl, cycloheptenyl, octenyl, cyclooctenyl or cyclooctadienyl.

As used above and herein, examples of the term alkynyl include linear, branched, and cyclic alkynyl substituents. Examples of the term alkynyl group exemplarily include ethynyl, propynyl, butynyl, pentynyl, hexynyl, heptynyl or octynyl.

As used above and herein, examples of the term alkoxy include linear, branched, and cyclic alkoxy substituents. The term alkoxy group exemplarily includes methoxy, ethoxy, n-propoxy, i-propoxy, n-butoxy, i-butoxy, s-butoxy, t-butoxy and 2-methylbutoxy.

As used above and herein, examples of the term thioalkoxy include linear, branched, and cyclic thioalkoxy substituents, in which the O of the exemplary alkoxy groups is replaced by S.

As used above and herein, the terms “halogen” and “halo” may be understood in the broadest sense as being preferably fluorine, chlorine, bromine or iodine.

Whenever hydrogen (H) is mentioned herein, it could also be replaced by deuterium at each occurrence.

It is understood that when a molecular fragment is described as being a substituent or otherwise attached to another moiety, its name may be written as if it were a fragment (e.g. naphthyl, dibenzofuryl) or as if it were the whole molecule (e.g. naphthalene, dibenzofuran). As used herein, these different ways of designating a substituent or attached fragment are considered to be equivalent.

In one embodiment, the organic molecules according to the invention have an excited state lifetime of not more than 250 μs, of not more than 150 μs, in particular of not more than 100 μs, more preferably of not more than 80 μs or not more than 60 μs, even more preferably of not more than 40 μs in a film of poly(methyl methacrylate) (PMMA) with 2% by weight of the organic molecule at room temperature.

In one embodiment of the invention, the organic molecules according to the invention represent thermally-activated delayed fluorescence (TADF) emitters, which exhibit a AEST value, which corresponds to the energy difference between the first excited singlet state (S1) and the first excited triplet state (T1), of less than 5000 cm⁻¹, preferably less than 3000 cm¹, more preferably less than 1500 cm¹, even more preferably less than 1000 cm¹ or even less than 500 cm¹.

In a further embodiment of the invention, the organic molecules according to the invention have an emission peak in the visible or nearest ultraviolet range, i.e., in the range of a wavelength of from 480 to 580 nm, with a full width at half maximum of less than 0.30 eV, preferably less than 0.28 eV, more preferably less than 0.25 eV, even more preferably less than 0.23 eV or even less than 0.20 eV in a film of poly(methyl methacrylate) (PMMA) with 2% by weight of the organic molecule at room temperature.

Orbital and excited state energies can be determined either by means of experimental methods or by calculations employing quantum-chemical methods, in particular density functional theory calculations. The energy of the highest occupied molecular orbital E^{HOMO} is determined by methods known to the person skilled in the art from cyclic voltammetry measurements with an accuracy of 0.1 eV. The energy of the lowest unoccupied molecular orbital E^{LUMO} is determined as the onset of the absorption spectrum.

The onset of an absorption spectrum is determined by computing the intersection of the tangent to the absorption spectrum with the x-axis. The tangent to the absorption spectrum is set at the low-energy side of the absorption band and at the point at half maximum of the maximum intensity of the absorption spectrum.

The energy of the first excited triplet state T1 is determined from the onset of the emission spectrum at low temperature, typically at 77 K. For host compounds, where the first excited singlet state and the lowest triplet state are energetically separated by >0.4 eV, the phosphorescence is usually visible in a steady-state spectrum in 2-Me-THF. The triplet energy can thus be determined as the onset of the phosphorescence spectrum. For TADF emitter molecules, the energy of the first excited triplet state T1 is determined from the onset of the delayed emission spectrum at 77 K, if not otherwise stated measured in a film of PMMA with 2% by weight of emitter. For both, host and emitter compounds, the energy of the first excited singlet state S1 is determined from the onset of the emission spectrum (measured as follows: emitters: concentration of 2% by weight in a film of PMMA; hosts: neat film).

The onset of an emission spectrum is determined by computing the intersection of the tangent to the emission spectrum with the x-axis. The tangent to the emission spectrum is set at the high-energy side of the emission band and at the point at half maximum of the maximum intensity of the emission spectrum.

A further aspect of the invention relates to the use of an organic molecule according to the invention as a luminescent emitter or as an absorber, and/or as a host material and/or as an electron transport material, and/or as a hole injection material, and/or as a hole blocking material in an optoelectronic device.

The optoelectronic device may be understood in the broadest sense as any device based on organic materials that is suitable for emitting light in the visible or nearest ultraviolet (UV) range. i.e., in the range of a wavelength of from 380 to 800 nm. More preferably, the optoelectronic device may be able to emit light in the visible range, i.e., of from 400 to 800 nm.

In the context of such use, the optoelectronic device is more particularly selected from the group consisting of:
organic light-emitting diodes (OLEDs),
light-emitting electrochemical cells,
OLED sensors, in particular in gas and vapor sensors not hermetically shielded to the outside,
organic diodes,
organic solar cells,
organic transistors,
organic field-effect transistors,
organic lasers, and
down-conversion elements.

A light-emitting electrochemical cell includes three layers, namely a cathode, an anode, and an active layer, which contains the organic molecule according to the invention.

In a preferred embodiment in the context of such use, the optoelectronic device is a device selected from the group consisting of an organic light emitting diode (OLED), a light emitting electrochemical cell (LEC), an organic laser, and a light-emitting transistor.

In one embodiment, the light-emitting layer of an organic light-emitting diode includes the organic molecules according to the invention.

In one embodiment, the light-emitting layer of an organic light-emitting diode includes not only the organic molecules according to the invention but also a host material whose triplet (T1) and singlet (S1) energy levels are energetically higher than the triplet (T1) and singlet (S1) energy levels of the organic molecule.

A further aspect of the invention relates to a composition including or consisting of:
(a) the organic molecule of the invention, in particular in the form of an emitter and/or a host, and
(b) one or more emitter and/or host materials: which differ from the organic molecule of the invention, and
(c) optionally, one or more dyes and/or one or more solvents.

In a further embodiment of the invention: the composition has a photoluminescence quantum yield (PLQY) of more than 10%, preferably more than 20%, more preferably more than 40%, even more preferably more than 60% or even more than 70% at room temperature.

Compositions with at Least One Further Emitter

One embodiment of the invention relates to a composition including or consisting of:
(i) 1-50% by weight, preferably 5-40% by weight, in particular 10-30% by weight, of the organic molecule according to the invention.
(ii) 5-98% by weight, preferably 30-93.9% by weight, in particular 40-88% by weight, of one host compound H;
(iii) 1-30% by weight, in particular 1-20% by weight, preferably 1-5% by weight, of at least one further emitter molecule F with a structure differing from the structure of the molecules according to the invention; and
(iv) optionally 0-94% by weight, preferably 0.1-65% by weight, in particular 1-50% by weight, of at least one further host compound D with a structure differing from the structure of the molecules according to the invention, and
(v) optionally 0-94% by weight: preferably 0-65% by weight: in particular 0-50% by weight, of a solvent.

The components or the compositions are chosen such that the sum of the weight of the components add up to 100%.

In a further embodiment of the invention: the composition has an emission peak in the visible or nearest ultraviolet range. i.e., in the range of a wavelength of from 380 to 800 nm.

In one embodiment of the invention, the at least one further emitter molecule F is a purely organic emitter.

In one embodiment of the invention, the at least one further emitter molecule F is a purely organic TADF emitter. Purely organic TADF emitters are known from the state of the art, e.g. Wong and Zysman-Colman (“Purely Organic Thermally Activated Delayed Fluorescence Materials for Organic Light-Emitting Diodes.”, Adv. Mater. 2017 June; 29(22)).

In one embodiment of the invention, the at least one further emitter molecule F is a fluorescence emitter, in particular a blue, a green, a yellow or a red fluorescence emitter.

In one embodiment of the invention, the at least one further emitter molecule F is a fluorescence emitter, in particular a red, a yellow or a green fluorescence emitter.

In a further embodiment of the invention, the composition, containing the at least one further emitter molecule F shows an emission peak in the visible or nearest ultraviolet range, i.e., in the range of a wavelength of from 380 to 800 nm, with a full width at half maximum of less than 0.30 eV, in particular less than 0.25 eV, preferably less than 0.22 eV, more preferably less than 0.19 eV or even less than 0.17 eV at room temperature, with a lower limit of 0.05 eV.

### Composition Wherein the at Least One Further Emitter Molecule F is a Green Fluorescence Emitter

In a further embodiment of the invention: the at least one further emitter molecule F is a fluorescence emitter, in particular a green fluorescence emitter.

In one embodiment: the at least one further emitter molecule F is a fluorescence emitter selected from the following groups:

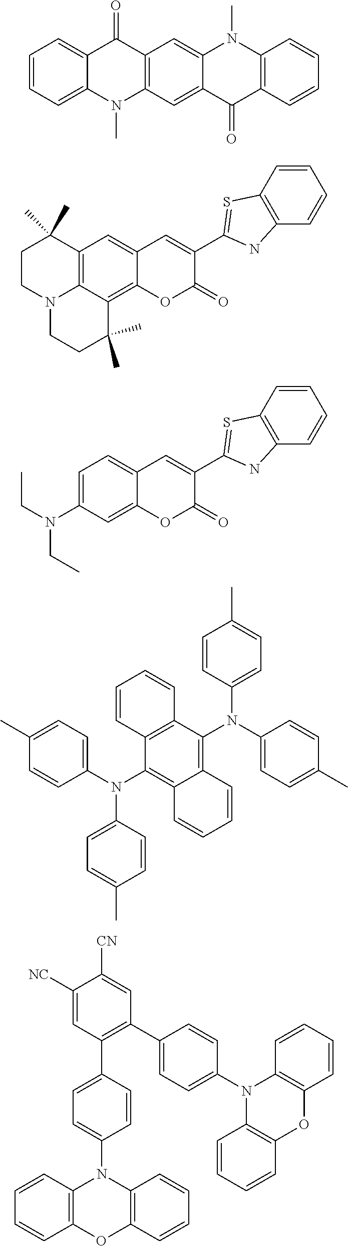

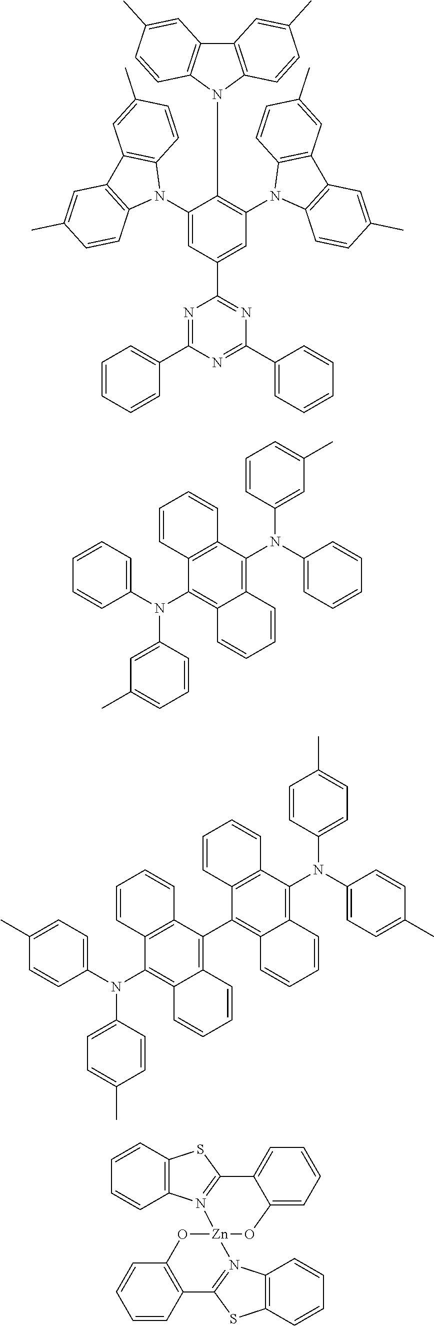

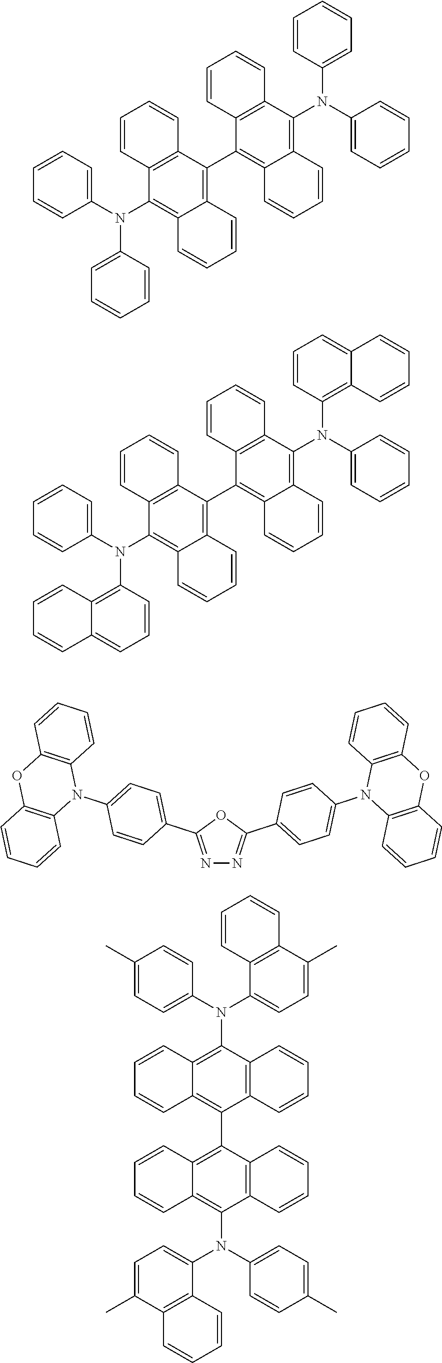

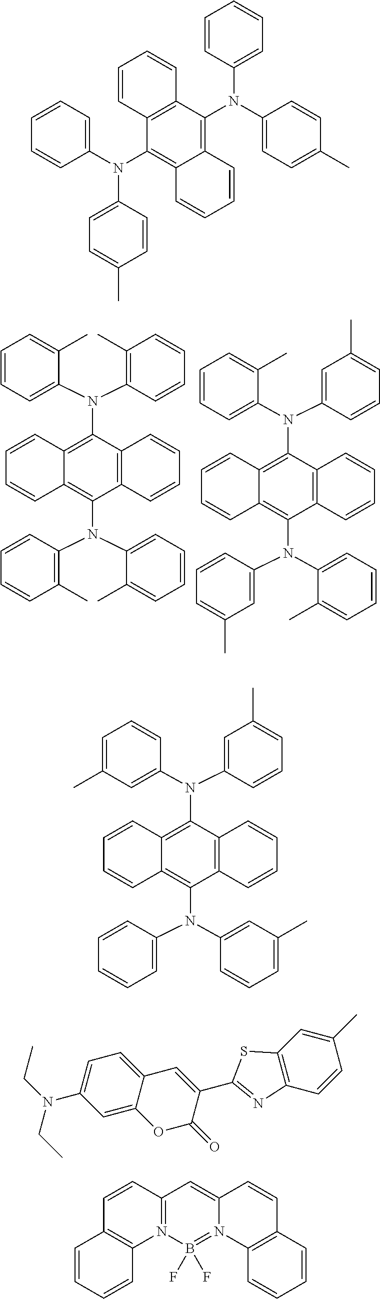

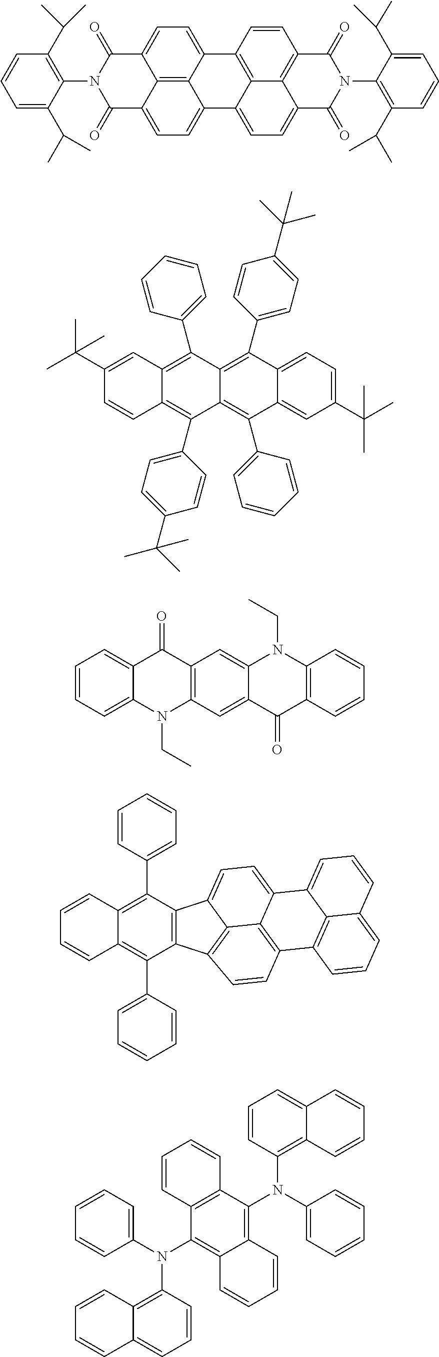

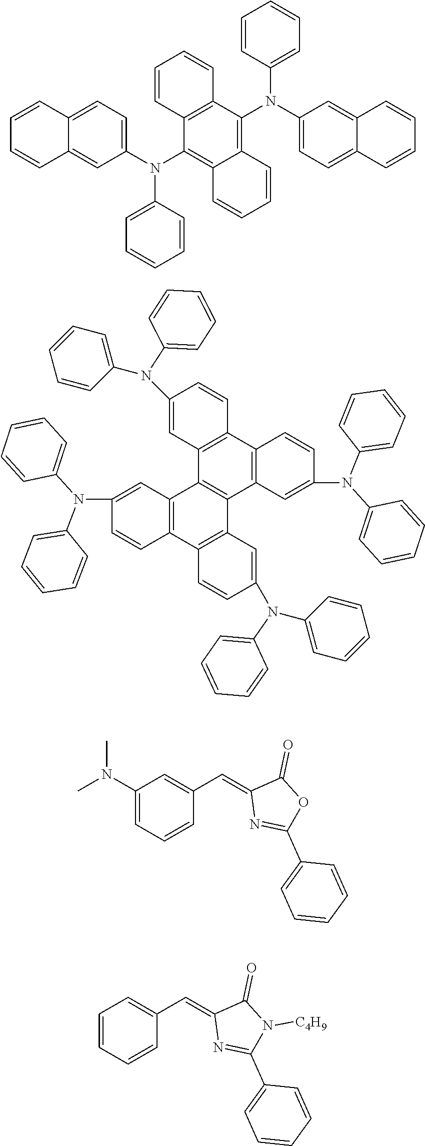

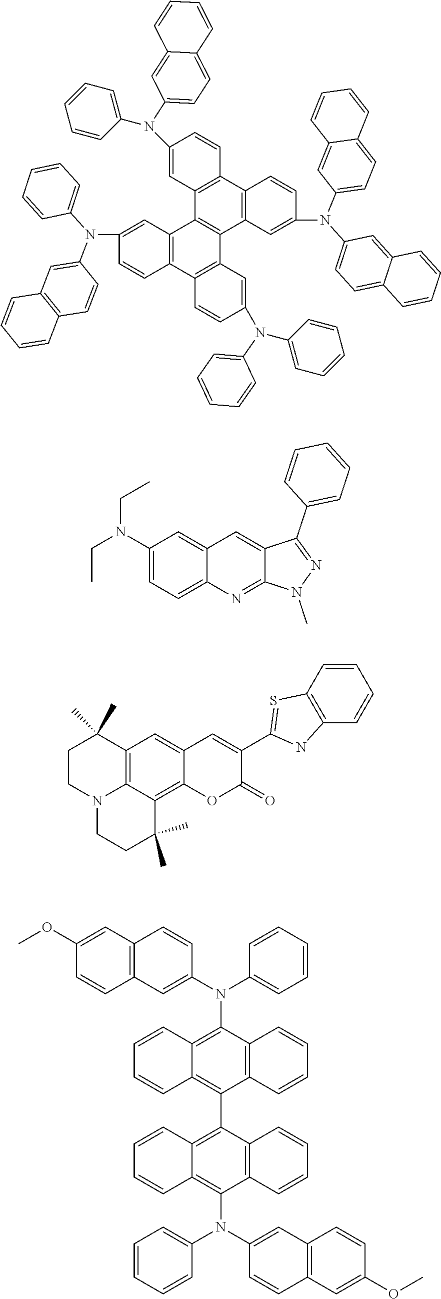

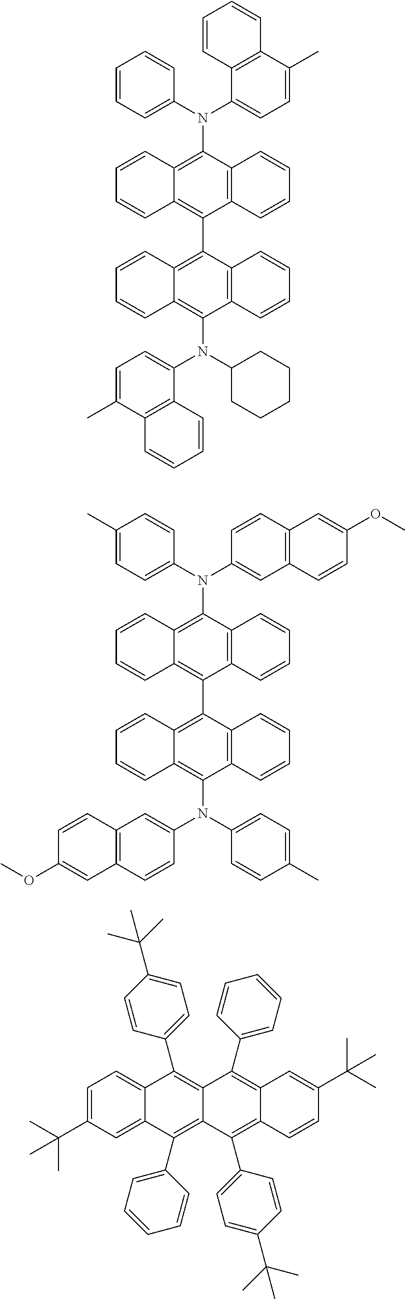

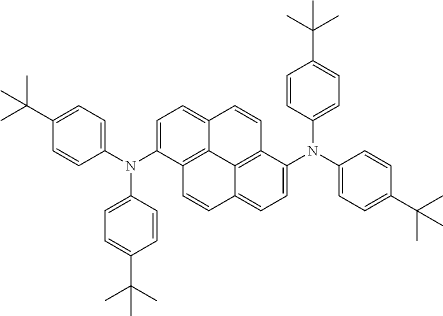 [SMILES: CC(C)(C)c1ccc(N(c2ccc(C(C)(C)C)cc2)c2ccc3ccc4c(N(c5ccc(C(C)(C)C)cc5)c5ccc(C(C)(C)C)cc5)ccc5ccc2c3c54)cc1]

In a further embodiment of the invention, the composition has an emission peak in the visible or nearest ultraviolet range, i.e., in the range of a wavelength of from 380 to 800 nm, in particular between 485 nm and 590 nm, preferably between 505 nm and 565 nm, even more preferably between 515 nm and 545 nm.

### Composition Wherein the at Least One Further Emitter Molecule F is a Red Fluorescence Emitter

In a further embodiment of the invention, the at least one further emitter molecule F is a fluorescence emitter, in particular a red fluorescence emitter.

In one embodiment, the at least one further emitter molecule F is a fluorescence emitter selected from the following groups:

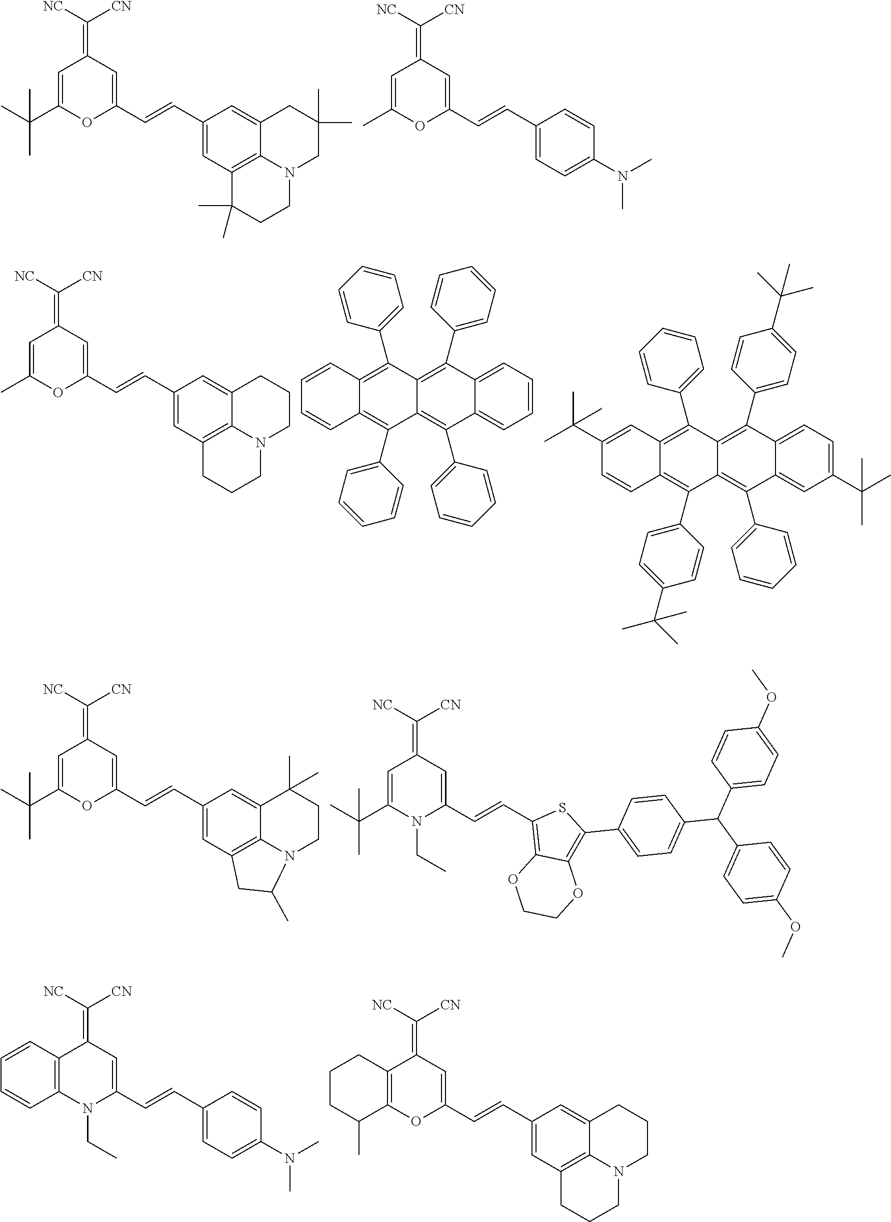

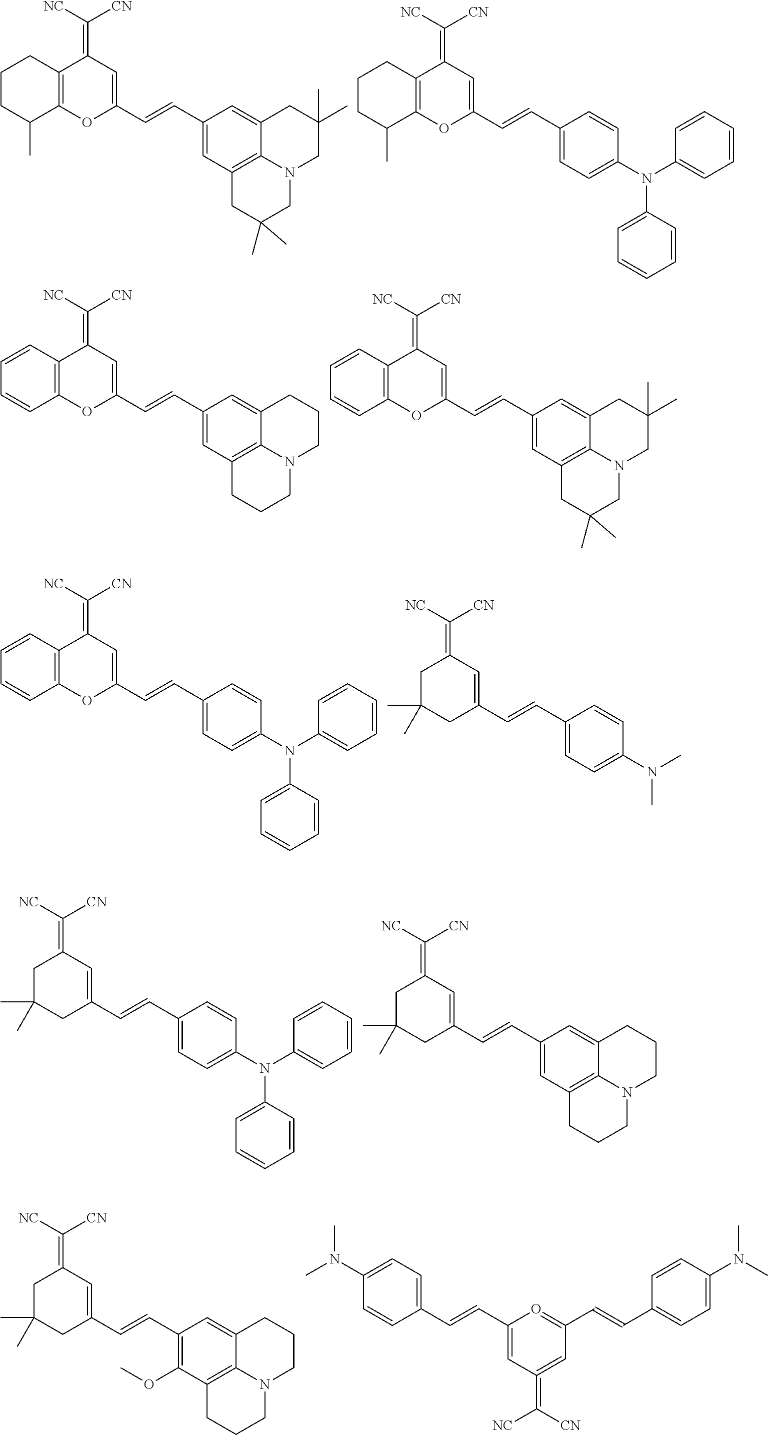

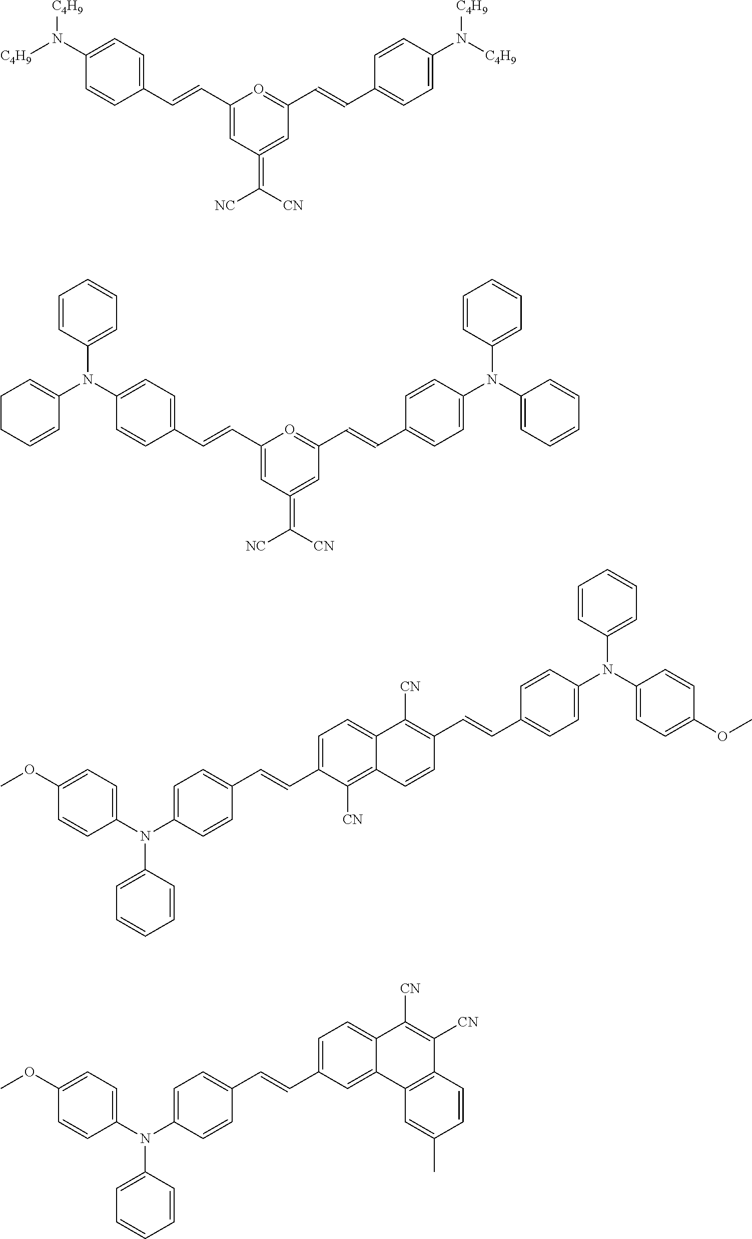

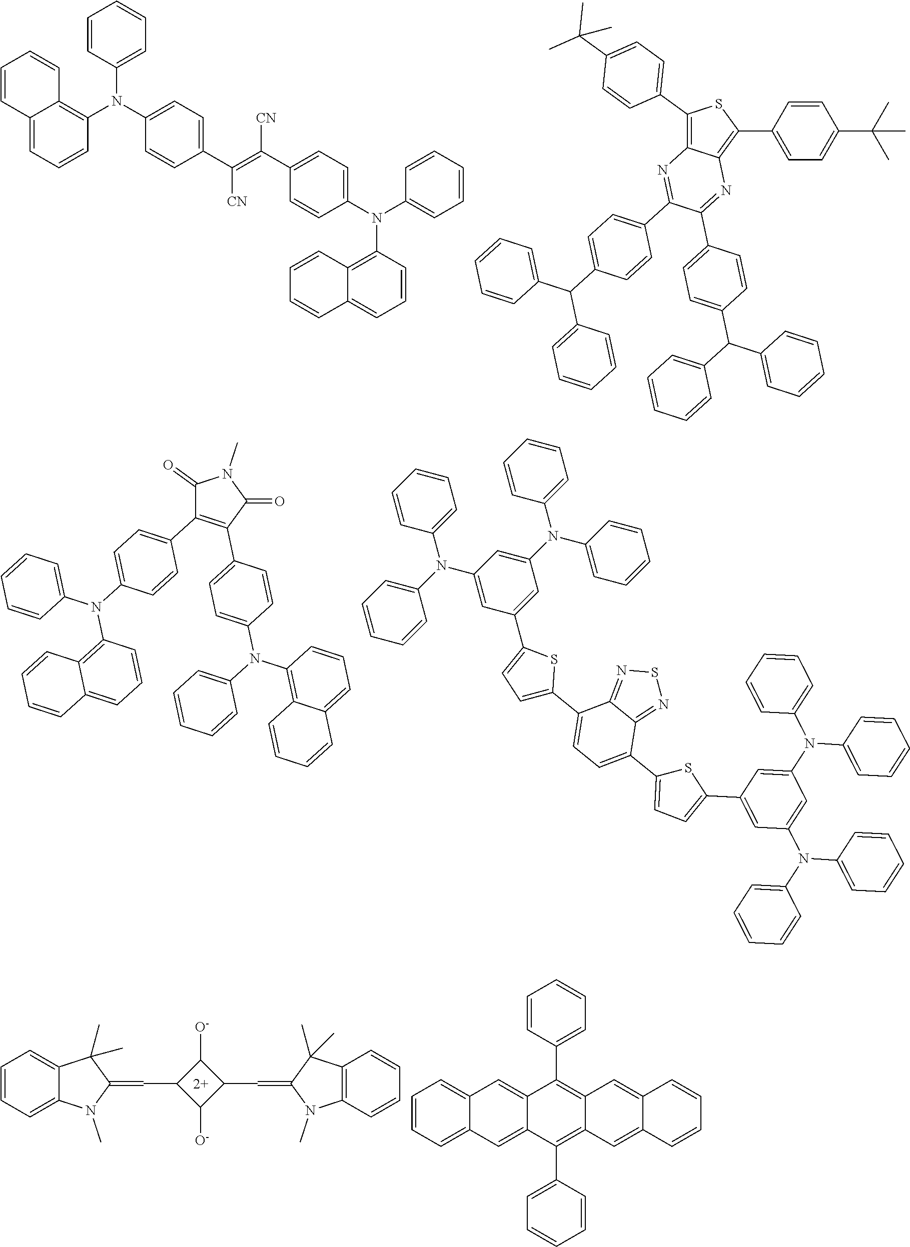

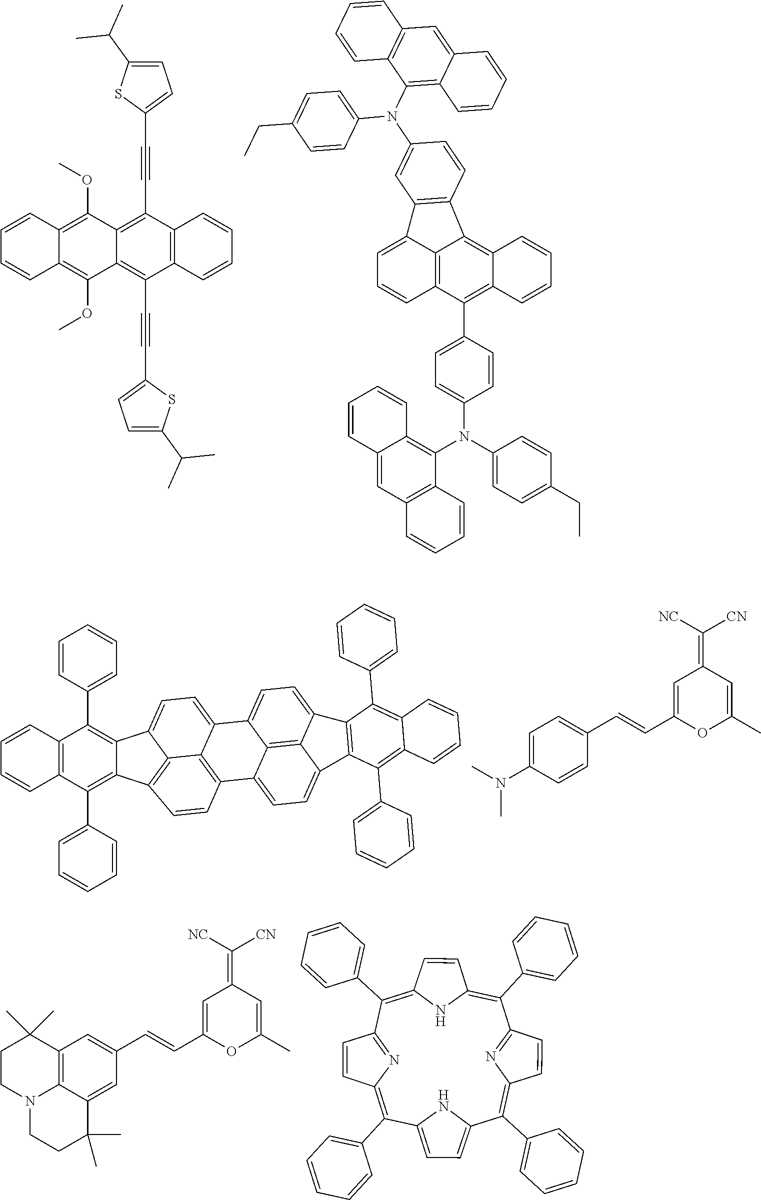

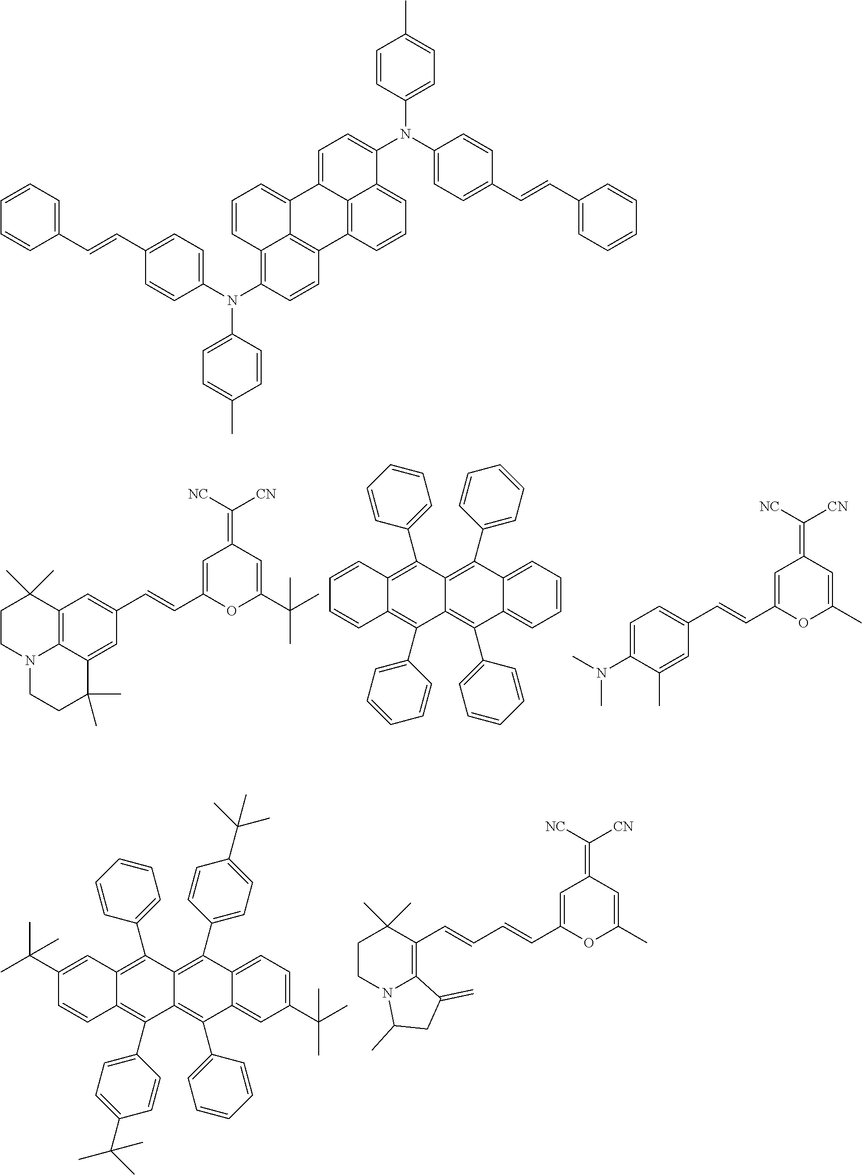

In a further embodiment of the invention, the composition has an emission peak in the visible or nearest ultraviolet range, i.e., in the range of a wavelength of from 380 to 800 nm, in particular between 590 nm and 690 nm, preferably between 610 nm and 665 nm, even more preferably between 620 nm and 640 nm.

### Light-Emitting Layer EML

In one embodiment, the light-emitting layer EML of an organic light-emitting diode of the invention includes (or essentially consists of) a composition including or consisting of:
(i) 1-50% by weight, preferably 5-40% by weight, in particular 10-30% by weight, of one or more organic molecules according to the invention;
(ii) 5-99% by weight, preferably 30-94.9% by weight, in particular 40-89% by weight, of at least one host compound H; and
(iii) optionally 0-94% by weight, preferably 0.1-65% by weight, in particular 1-50% by weight, of at least one further host compound D with a structure differing from the structure of the molecules according to the invention; and
(iv) optionally 0-94% by weight, preferably 0-65% by weight, in particular 0-50% by weight, of a solvent; and
(v) optionally 0-30% by weight, in particular 0-20% by weight, preferably 0-5% by weight, of at least one further emitter molecule F with a structure differing from the structure of the molecules according to the invention.

Preferably, energy can be transferred from the host compound H to the one or more organic molecules of the invention, in particular transferred from the first excited triplet state T1(H) of the host compound H to the first excited triplet state T1(E) of the one or more organic molecules according to the invention and/or from the first excited singlet state S1(H) of the host compound H to the first excited singlet state S1(E) of the one or more organic molecules according to the invention.

In one embodiment, the host compound H has a highest occupied molecular orbital HOMO(H) having an energy E^{HOMO}(H) in the range of from −5 eV to −6.5 eV and one organic molecule according to the invention E has a highest occupied molecular orbital HOMO(E) having an energy E^{HOMO}(E), wherein E^{HOMO}(H)>E^{HOMO}(E).

In a further embodiment, the host compound H has a lowest unoccupied molecular orbital LUMO(H) having an energy E^{LUMO}(H) and the one organic molecule according to the invention E has a lowest unoccupied molecular orbital LUMO(E) having an energy E^{LUMO}(E), wherein E^{LUMO}(H)>E^{LUMO}(E).

### Light-Emitting Layer EML Including at Least One Further Host Compound D

In a further embodiment, the light-emitting layer EML of an organic light-emitting diode of the invention includes (or essentially consists of) a composition including or consisting of:
(i) 1-50% by weight, preferably 5-40% by weight, in particular 10-30% by weight, of one organic molecule according to the invention;
(ii) 5-99% by weight, preferably 30-94.9% by weight, in particular 40-89% by weight, of one host compound H. and
(iii) 0-94% by weight, preferably 0.1-65% by weight, in particular 1-50% by weight, of at least one further host compound D with a structure differing from the structure of the molecules according to the invention; and
(iv) optionally 0-94% by weight, preferably 0-65% by weight, in particular 0-50% by weight, of a solvent; and
(v) optionally 0-30% by weight, in particular 0-20% by weight: preferably 0-5% by weight, of at least one further emitter molecule F with a structure differing from the structure of the molecules according to the invention.

In one embodiment of the organic light-emitting diode of the invention, the host compound H has a highest occupied molecular orbital HOMO(H) having an energy E^{HOMO}(H) in the range of from −5 eV to −6.5 eV and the at least one further host compound D has a highest occupied molecular orbital HOMO(D) having an energy E^{HOMO}(D), wherein E^{HOMO}(H)>E^{HOMO}(D). The relation E^{HOMO}(H)>E^{HOMO}(D) favors an efficient hole transport.

In a further embodiment, the host compound H has a lowest unoccupied molecular orbital LUMO(H) having an energy E^{LUMO}(H) and the at least one further host compound D has a lowest unoccupied molecular orbital LUMO(D) having an energy E^{LUMO}(D), wherein E^{LUMO}(H)>E^{LUMO}(D). The relation E^{LUMO}(H)>E^{LUMO}(D) favors an efficient electron transport.

In one embodiment of the organic light-emitting diode of the invention, the host compound H has a highest occupied molecular orbital HOMO(H) having an energy E^{HOMO}(H) and a lowest unoccupied molecular orbital LUMO(H) having an energy E^{LUMO}(H), and
the at least one further host compound D has a highest occupied molecular orbital HOMO(D) having an energy E^{HOMO}(D) and a lowest unoccupied molecular orbital LUMO(D) having an energy E^{LUMO}(D),
the organic molecule E of the invention has a highest occupied molecular orbital HOMO(E) having an energy E^{HOMO}(E) and a lowest unoccupied molecular orbital LUMO(E) having an energy E^{LUMO}(E).
wherein
E^{HOMO}(H)>E^{HOMO}(D) and the difference between the energy level of the highest occupied molecular orbital HOMO(E) of the organic molecule according to the invention (E^{HOMO}(E)) and the energy level of the highest occupied molecular orbital HOMO(H) of the host compound H (E^{HOMO}(H)) is between 0.5 eV and 0.5 eV, more preferably between −0.3 eV and 0.3 eV, even more preferably between −0.2 eV and 0.2 eV or even between −0.1 eV and 0.1 eV; and
E^{LUMO}(H)>E^{LUMO}(D) and the difference between the energy level of the lowest unoccupied molecular orbital LUMO(E) of the organic molecule according to the invention (E^{LUMO}(E)) and the lowest unoccupied molecular orbital LUMO(D) of the at least one further host compound D (E^{LUMO}(D)) is between −0.5 eV and 0.5 eV, more preferably between −0.3 eV and 0.3 eV, even more preferably between −0.2 eV and 0.2 eV or even between −0.1 eV and 0.1 eV.

### Light-Emitting Layer EML Including at Least One Further Emitter Molecule F

In a further embodiment, the light-emitting layer EML includes (or (essentially) consists of) a composition including or consisting of:
(i) 1-50% by weight, preferably 5-40% by weight, in particular 10-30% by weight, of one organic molecule according to the invention;
(ii) 5-98% by weight, preferably 30-93.9% by weight, in particular 40-88% by weight, of one host compound H;
(iii) 1-30% by weight, in particular 1-20% by weight, preferably 1-5% by weight, of at least one further emitter molecule F with a structure differing from the structure of the molecules according to the invention; and
(iv) optionally 0-94% by weight, preferably 0.1-65% by weight, in particular 1-50% by weight, of at least one further host compound D with a structure differing from the structure of the molecules according to the invention, and
(v) optionally 0-94% by weight: preferably 0-65% by weight: in particular 0-50% by weight, of a solvent.

In a further embodiment, the light-emitting layer EML includes (or (essentially) consists of) a composition as described in Compositions with at least one further emitter, with the at least one further emitter molecule F as defined in Composition wherein the at least one further emitter molecule F is a green fluorescence emitter.

In a further embodiment, the light-emitting layer EML includes (or (essentially) consists of) a composition as described in Compositions with at least one further emitter, with the at least one further emitter molecule F as defined in Composition wherein the at least one further emitter molecule F is a red fluorescence emitter.

In one embodiment of the light-emitting layer EML including at least one further emitter molecule F, energy can be transferred from the one or more organic molecules of the invention E to the at least one further emitter molecule F, in particular transferred from the first excited singlet state S1(E) of one or more organic molecules of the invention E to the first excited singlet state S1(F) of the at least one further emitter molecule F.

In one embodiment: the first excited singlet state S1(H) of one host compound H of the light-emitting layer is higher in energy than the first excited singlet state S1(E) of the one or more organic molecules of the invention E: S1(H)>S1(E), and the first excited singlet state S1(H) of one host compound H is higher in energy than the first excited singlet state S1(F) of the at least one emitter molecule F: S1(H)>S1(F).

In one embodiment, the first excited triplet state T1(H) of one host compound H is higher in energy than the first excited triplet state T1(E) of the one or more organic molecules of the invention E: T1(H)>T1(E), and the first excited triplet state T1(H) of one host compound H is higher in energy than the first excited triplet state T1(F) of the at least one emitter molecule F: T1(H)>T1(F).

In one embodiment, the first excited singlet state S1(E) of the one or more organic molecules of the invention E is higher in energy than the first excited singlet state S1(F) of the at least one emitter molecule F: S1(E)>S1(F).

In one embodiment, the first excited triplet state T1(E) of the one or more organic molecules E of the invention is higher in energy than the first excited singlet state T1(F) of the at least one emitter molecule F. T1(E)>T1(F).

In one embodiment, the first excited triplet state T1(E) of the one or more organic molecules E of the invention is higher in energy than the first excited singlet state T1(F) of the at least one emitter molecule F: T1(E)>T1(F), wherein the absolute value of the energy difference between T1(E) and T1(F) is larger than 0.3 eV, preferably larger than 0.4 eV, or even larger than 0.5 eV.

In one embodiment, the host compound H has a highest occupied molecular orbital HOMO(H) having an energy E^{HOMO}(H) and a lowest unoccupied molecular orbital LUMO(H) having an energy E^{LUMO}(H), and
the one organic molecule according to the invention E has a highest occupied molecular orbital HOMO(E) having an energy E^{HOMO}(E) and a lowest unoccupied molecular orbital LUMO(E) having an energy E^{LUMO}(E).
the at least one further emitter molecule F has a highest occupied molecular orbital HOMO(F) having an energy E^{HOMO}(F) and a lowest unoccupied molecular orbital LUMO(E) having an energy E^{LUMO}(F),
wherein
E^{HOMO}(H)>E^{HOMO}(E) and the difference between the energy level of the highest occupied molecular orbital HOMO(F) of the at least one further emitter molecule (E^{MOMO}(F)) and the energy level of the highest occupied molecular orbital HOMO(H) of the host compound H (E^{HOMO}(H)) is between 0.5 eV and 0.5 eV, more preferably between −0.3 eV and 0.3 eV, even more preferably between −0.2 eV and 0.2 eV or even between −0.1 eV and 0.1 eV; and
E^{LUMO}(H)>E^{LUMO}(E) and the difference between the energy level of the lowest unoccupied molecular orbital LUMO(F) of the at least one further emitter molecule (E^{LUMO}(F)) and the lowest unoccupied molecular orbital LUMO(E) of the one organic molecule according to the invention (E^{LUMO}(E)) is between −0.5 eV and 0.5 eV, more preferably between −0.3 eV and 0.3 eV, even more preferably between −0.2 eV and 0.2 eV or even between −0.1 eV and 0.1 eV.

### Optoelectronic Devices

In a further aspect, the invention relates to an optoelectronic device including an organic molecule or a composition as described herein, more particularly in the form of a device selected from the group consisting of organic light-emitting diode (OLED), light-emitting electrochemical cell. OLED sensor (particularly gas and vapor sensors not hermetically externally shielded), organic diode, organic solar cell, organic transistor, organic field-effect transistor, organic laser and down-conversion element.

In a preferred embodiment, the optoelectronic device is a device selected from the group consisting of an organic light emitting diode (OLED), a light emitting electrochemical cell (LEC), and a light-emitting transistor.

In one embodiment of the optoelectronic device of the invention, the organic molecule according to the invention is used as emission material in a light-emitting layer EML.

In one embodiment of the optoelectronic device of the invention, the light-emitting layer EML consists of the composition according to the invention described herein.

When the optoelectronic device is an OLED, it may, for example, exhibit the following layer structure:
1. substrate
2. anode layer A
3. hole injection layer, HIL
4. hole transport layer, HTL
5. electron blocking layer, EBL
6. emitting layer, EML
7. hole blocking layer, HBL
8. electron transport layer, ETL
9. electron injection layer, EIL
10. cathode layer, C
wherein the OLED includes each layer only optionally, different layers may be merged and the OLED may include more than one layer of each layer type defined above.

Furthermore, the optoelectronic device may optionally include one or more protective layers protecting the device from damaging exposure to harmful species in the environment including, for example, moisture, vapor and/or gases.

In one embodiment of the invention, the optoelectronic device is an OLED, which exhibits the following inverted layer structure:

1. substrate
2. cathode layer, C
3. electron injection layer, EIL
4. electron transport layer, ETL
5. hole blocking layer, HBL
6. emitting layer, EML
7. electron blocking layer, EBL
8. hole transport layer, HTL
9. hole injection layer, HIL
10. anode layer, A,
wherein the OLED with an inverted layer structure includes each layer only optionally, different layers may be merged together into, e.g., one or more layers, and the OLED may include more than one layer of each layer types defined above.

In one embodiment of the invention, the optoelectronic device is an OLED, which may exhibit stacked architecture. In this architecture, contrary to the typical arrangement, where the OLEDs are placed side by side, the individual units are stacked on top of each other. Blended light may be generated with OLEDs exhibiting a stacked architecture, in particular white light may be generated by stacking blue, green and red OLEDs. Furthermore, the OLED exhibiting a stacked architecture may optionally include a charge generation layer (CGL), which is typically located between two OLED subunits and typically consists of an n-doped layer and a p-doped layer with the n-doped layer of one CGL being typically located closer to the anode layer.

In one embodiment of the invention, the optoelectronic device is an OLED, which includes two or more emission layers between anode and cathode. In particular, this so-called tandem OLED includes three emission layers, wherein one emission layer emits red light, one emission layer emits green light and one emission layer emits blue light, and optionally may include further layers such as charge generation layers, blocking or transporting layers between the individual emission layers. In a further embodiment, the emission layers are adjacently stacked. In a further embodiment, the tandem OLED includes a charge generation layer between each two emission layers. In addition, adjacent emission layers or emission layers separated by a charge generation layer may be merged.

The substrate may be formed by any material or composition of materials. Most frequently, glass slides are used as substrates. Alternatively, thin metal layers (e.g., copper, gold, silver or aluminum films) or plastic films or slides may be used. This may allow a higher degree of flexibility. The anode layer A is mostly composed of materials allowing to obtain an (essentially) transparent film. As at least one of the two electrodes should be (essentially) transparent in order to allow light emission from the OLED, either the anode layer A or the cathode layer C is transparent. Preferably, the anode layer A includes a large content or even consists of transparent conductive oxides (TCOs). Such anode layer A may, for example, include indium tin oxide, aluminum zinc oxide, fluorine doped tin oxide, indium zinc oxide, PbO, SnO, zirconium oxide, molybdenum oxide, vanadium oxide, wolfram oxide, graphite, doped Si, doped Ge, doped GaAs, doped polyaniline, doped polypyrrol and/or doped polythiophene.

Preferably, the anode layer A (essentially) consists of indium tin oxide (ITO) (e.g., (InO3)0.9(SnO2)0.1). The roughness of the anode layer A caused by the transparent conductive oxides (TCOs) may be compensated by using a hole injection layer (HIL). Further, the HIL may facilitate the injection of quasi charge carriers (i.e., holes) in that the transport of the quasi charge carriers from the TCO to the hole transport layer (HTL) is facilitated. The hole injection layer (HIL) may include poly-3,4-ethylenedioxy thiophene (PEDOT), polystyrene sulfonate (PSS), MoO₂, V₂O₅, CuPC or CuI, in particular a mixture of PEDOT and PSS. The hole injection layer (HIL) may also prevent the diffusion of metals from the anode layer A into the hole transport layer (HTL). The HIL may, for example, include PEDOT:PSS (poly-3,4-ethylenedioxy thiophene: polystyrene sulfonate), PEDOT (poly-3,4-ethylenedioxy thiophene), mMTDATA (4,4′,4″-tris[phenyl(m-tolyl)amino]triphenylamine), Spiro-TAD (2,2′,7,7′-tetrakis(n,n-diphenylamino)-9,9′-spirobifluorene), DNTPD (N1,N1′-(biphenyl-4,4′-diyl)bis(N1-phenyl-N4,N4-di-m-tolylbenzene-1,4-diamine), NPB (N,N′-nis-(1-naphthalenyl)-N,N′-bis-phenyl-(1,1′-biphenyl)-4,4′-diamine), NPNPB (N,N′-diphenyl-N,N′-di-[4-(N,N-diphenyl-amino)phenyl]benzidine), MeO-TPD (N,N,N′,N′-tetrakis(4-methoxyphenyl)benzidine), HAT-CN (1,4,5,8,9,11-hexaazatriphenylen-hexacarbonitrile) and/or Spiro-NPD (N,N′-diphenyl-N,N′-bis-(1-naphthyl)-9,9′-spirobifluorene-2,7-diamine).

Adjacent to the anode layer A or hole injection layer (HIL), typically a hole transport layer (HTL) is located. Herein, any hole transport compound may be used. Exemplarily, electron-rich heteroaromatic compounds such as triarylamines and/or carbazoles may be used as hole transport compound. The HTL may decrease the energy barrier between the anode layer A and the light-emitting layer EML. The hole transport layer (HTL) may also be an electron blocking layer (EBL). Preferably, hole transport compounds bear comparably high energy levels of their triplet states T1. Exemplarily the hole transport layer (HTL) may include a star-shaped heterocycle such as tris(4-carbazoyl-9-ylphenyl)amine (TCTA), poly-TPD (poly(4-butylphenyl-diphenyl-amine)). [alpha]-NPD (poly(4-butylphenyl-diphenyl-amine)), TAPC (4,4′-cyclohexyliden-bis[N,N-bis(4-methylphenyl)benzenamine]), 2-TNATA (4,4′,4″-tris[2-naphthyl(phenyl)amino]triphenylamine), Spiro-TAD, DNTPD, NPB, NPNPB, MeO-TPD, HAT-CN and/or TrisPcz (9,9′-diphenyl-6-(9-phenyl-9H-carbazol-3-yl)-9H,9′H-3,3′-bicarbazole). In addition, the HTL may include a p-doped layer, which may be composed of an inorganic or organic dopant in an organic hole-transporting matrix. Transition metal oxides such as vanadium oxide, molybdenum oxide or tungsten oxide may, for example, be used as the inorganic dopant. Tetrafluorotetracyanoquinodimethane (F4-TCNQ), copper-pentafluorobenzoate (Cu(I)pFBz) or transition metal complexes may, for example, be used as the organic dopant.

The EBL may, for example, include mCP (1,3-bis(carbazol-9-yl)benzene). TCTA, 2-TNATA, mCBP (3,3-di(9H-carbazol-9-yl)biphenyl), tris-Pcz, CzSi (9-(4-tert-butylphenyl)-3,6-bis(triphenylsilyl)-9H-carbazole), and/or DCB (N,N′-dicarbazolyl-1,4-dimethylbenzene).

Adjacent to the hole transport layer (HTL), typically, the light-emitting layer EML is located. The light-emitting layer EML includes at least one light emitting molecule. Particularly, the EML includes at least one light emitting molecule according to the invention. Typically, the EML additionally includes one or more host material. Exemplarily, the host material is selected from CBP (4,4′-Bis-(N-carbazolyl)-biphenyl), mCP, mCBP Sif87 (dibenzo[b,d]thiophen-2-yltriphenylsilane), CzSi, Sif88 (dibenzo[b,d]thiophen-2-yl)diphenylsilane), DPEPO (bis[2-(diphenylphosphino)phenyl]ether oxide), 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, 9-[3,5-bis(2-dibenzothiophenyl)phenyl]-9H-carbazole, T2T (2,4,6-tris(biphenyl-3-yl)-1,3,5-triazine). T3T (2,4,6-tris(triphenyl-3-yl)-1,3,5-triazine) and/or TST (2,4,6-tris(9,9′-spirobifluorene-2-yl)-1,3,5-triazine). The host material typically should be selected to exhibit first triplet (T1) and first singlet (S1) energy levels, which are energetically higher than the first triplet (T1) and first singlet (S1) energy levels of the organic molecule.

In one embodiment of the invention, the EML includes a so-called mixed-host system with at least one hole-dominant host and one electron-dominant host. In a particular embodiment, the EML includes exactly one light emitting molecule species according to the invention and a mixed-host system including T2T as the electron-dominant host and a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole as the hole-dominant host. In a further embodiment the EML includes 50-80% by weight, preferably 60-75% by weight of a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole, 10-45% by weight, preferably 15-30% by weight of T2T and 5-40% by weight, preferably 10-30% by weight of light emitting molecule according to the invention.

Adjacent to the light-emitting layer EML, an electron transport layer (ETL) may be located. Herein, any electron transporter may be used. Exemplarily, electron-poor compounds such as, e.g., benzimidazoles, pyridines, triazoles, oxadiazoles (e.g., 1,3,4-oxadiazole), phosphinoxides and sulfone, may be used. An electron transporter may also be a star-shaped heterocycle such as 1,3,5-tri(1-phenyl-1H-benzo[d]imidazol-2-yl)phenyl (TPBi). The ETL may include NBphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphinoxide), BPyTP2 (2,7-di(2,2′-bipyridin-5-yl)triphenyle), Sif87 (dibenzo[b,d]thiophen-2-yltriphenylsilane), Sif88 (dibenzo[b,d]thiophen-2-yl)diphenylsilane), BmPyPhB (1,3-bis[3,5-di(pyridin-3-yl)phenyl]benzene) and/or BTB (4,4′-bis-[2-(4,6-diphenyl-1,3,5-triazinyl)]-1,1′-biphenyl). Optionally, the ETL may be doped with materials such as Liq. The electron transport layer (ETL) may also block holes or a hole blocking layer (HBL) is introduced.

The HBL may, for example, include BCP (2,9-dimethyl-4,7-diphenyl-1,10-phenanthroline=Bathocuproine), BAlq (bis(8-hydroxy-2-methylquinoline)-(4-phenylphenoxy)aluminum), NBphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphinoxide), T2T (2,4,6-tris(biphenyl-3-yl)-1,3,5-triazine), T3T (2,4,6-tris(triphenyl-3-yl)-1,3,5-triazine), TST (2,4,6-tris(9,9′-spirobifluorene-2-yl)-1,3,5-triazine), and/or TCB/TCP (1,3,5-tris(N-carbazolyl)benzol/1,3,5-tris(carbazol)-9-yl) benzene).

A cathode layer C may be located adjacent to the electron transport layer (ETL). For example, the cathode layer C may include or may consist of a metal (e.g., Al, Au, Ag, Pt, Cu. Zn, Ni, Fe, Pb, LiF, Ca, Ba, Mg, In, W, or Pd) or a metal alloy. For practical reasons, the cathode layer may also consist of (essentially) non-transparent metals such as Mg, Ca or Al. Alternatively or additionally, the cathode layer C may also include graphite and/or carbon nanotubes (CNTs). Alternatively, the cathode layer C may also consist of nanoscalic silver wires.

An OLED may further, optionally, include a protection layer between the electron transport layer (ETL) and the cathode layer C (which may be designated as electron injection layer (EIL)). This layer may include lithium fluoride, cesium fluoride, silver, Liq (8-hydroxyquinolinolatolithium), Li₂O, BaF₂, MgO and/or NaF.

Optionally, also the electron transport layer (ETL) and/or a hole blocking layer (HBL) may include one or more host compounds.

In order to modify the emission spectrum and/or the absorption spectrum of the light-emitting layer EML further, the light-emitting layer EML may further include one or more additional emitter molecules F. Such an emitter molecule F may be any emitter molecule known in the art. Preferably such an emitter molecule F is a molecule with a structure differing from the structure of the molecules according to the invention. The emitter molecule F may optionally be a TADF emitter. Alternatively, the emitter molecule F may optionally be a fluorescent and/or phosphorescent emitter molecule which is able to shift the emission spectrum and/or the absorption spectrum of the light-emitting layer EML. For example, the triplet and/or singlet excitons may be transferred from the emitter molecule according to the invention to the emitter molecule F before relaxing to the ground state S0 by emitting light typically red-shifted in comparison to the light emitted by emitter molecule E. Optionally, the emitter molecule F may also provoke two-photon effects (i.e., the absorption of two photons of half the energy of the absorption maximum).

Optionally, an optoelectronic device (e.g., an OLED) may, for example, be an essentially white optoelectronic device. Exemplarily such white optoelectronic device may include at least one (deep) blue emitter molecule and one or more emitter molecules emitting green and/or red light. Then, there may also optionally be energy transmittance between two or more molecules as described above.

As used herein, if not defined more specifically in the particular context, the designation of the colors of emitted and/or absorbed light is as follows:
violet: wavelength range of >380-420 nm;
deep blue, wavelength range of >420-480 nm;
sky blue: wavelength range of >480-500 nm;
green: wavelength range of >500-560 nm;
yellow: wavelength range of >560-580 nm;
orange: wavelength range of >580-620 nm;
red: wavelength range of >620-800 nm.

With respect to emitter molecules, such colors refer to the emission maximum. Therefore, exemplarily, a deep blue emitter has an emission maximum in the range of from >420 to 480 nm, a sky-blue emitter has an emission maximum in the range of from >480 to 500 nm, a green emitter has an emission maximum in a range of from >500 to 560 nm, and a red emitter has an emission maximum in a range of from >620 to 800 nm.

A further embodiment of the present invention relates to an OLED, which emits light with CIEx and CIEy color coordinates close to the CIEx (=0.170) and CIEy (=0.797) color coordinates of the primary color green (CIEx=0.170 and CIEy=0.797) as defined by ITU-R Recommendation BT.2020 (Rec. 2020) and thus is suited for the use in Ultra High Definition (UHD) displays, e g. UHD-TVs. In this context, the term “close to” refers to the ranges of CIEx and CIEy coordinates provided at the end of this paragraph. In commercial applications, typically top-emitting (top-electrode is transparent) devices are used, whereas test devices as used throughout the present application represent bottom-emitting devices (bottom-electrode and substrate are transparent). Accordingly, a further aspect of the present invention relates to an OLED, whose emission exhibits a CIEx color coordinate of between 0.15 and 0.45, preferably between 0.15 and 0.35, more preferably between 0.15 and 0.30 or even more preferably between 0.15 and 0.25 or even between 0.15 and 0.20 and/or a CIEy color coordinate of between 0.60 and 0.92, preferably between 0.65 and 0.90, more preferably between 0.70 and 0.88 or even more preferably between 0.75 and 0.86 or even between 0.79 and 0.84.

A further embodiment of the present invention relates to an OLED, which emits light with CIEx and CIEy color coordinates close to the CIEx (=0.708) and CIEy (=0.292) color coordinates of the primary color red (CIEx=0.708 and CIEy=0.292) as defined by ITU-R Recommendation BT.2020 (Rec. 2020) and thus is suited for the use in Ultra High Definition (UHD) displays. e.g. UHD-TVs. In this context, the term “close to” refers to the ranges of CIEx and CIEy coordinates provided at the end of this paragraph. In commercial applications, typically top-emitting (top-electrode is transparent) devices are used, whereas test devices as used throughout the present application represent bottom-emitting devices (bottom-electrode and substrate are transparent). Accordingly, a further aspect of the present invention relates to an OLED, whose emission exhibits a CIEx color coordinate of between 0.60 and 0.88, preferably between 0.61 and 0.83: more preferably between 0.63 and 0.78 or even more preferably between 0.66 and 0.76 or even between 0.68 and 0.73 and/or a CIEy color coordinate of between 0.25 and 0.70, preferably between 0.26 and 0.55, more preferably between 0.27 and 0.45 or even more preferably between 0.28 and 0.40 or even between 0.29 and 0.35.

Accordingly, a further aspect of the present invention relates to an OLED, which exhibits an external quantum efficiency at 14500 cd/m² of more than 10%, more preferably of more than 13%, more preferably of more than 15%, even more preferably of more than 17% or even more than 20% and/or exhibits an emission maximum between 495 nm and 580 nm, preferably between 500 nm and 560 nm, more preferably between 510 nm and 550 nm, even more preferably between 515 nm and 540 nm and/or exhibits a LT97 value at 14500 cd/m² of more than 100 h, preferably more than 250 h, more preferably more than 500 h, even more preferably more than 750 h or even more than 1000 h.

The optoelectronic device, in particular the OLED according to the present invention can be manufactured by any means of vapor deposition and/or liquid processing. Accordingly, at least one layer is
prepared by means of a sublimation process,
prepared by means of an organic vapor phase deposition process,
prepared by means of a carrier gas sublimation process,
solution processed or
printed.

The methods used to manufacture the optoelectronic device, in particular the OLED according to the present invention are known in the art. The different layers are individually and successively deposited on a suitable substrate by means of subsequent deposition processes. The individual layers may be deposited using the same or differing deposition methods.

Vapor deposition processes exemplarily include thermal (co)evaporation, chemical vapor deposition and physical vapor deposition. For active matrix OLED display, an AMOLED backplane is used as substrate. The individual layer may be processed from solutions or dispersions employing adequate solvents. Solution deposition processes exemplarily include spin coating, dip coating and jet printing. Liquid processing may optionally be carried out in an inert atmosphere (e.g., in a nitrogen atmosphere) and the solvent may optionally be completely or partially removed by means known in the state of the art.

### EXAMPLES

### General Synthesis Scheme

The general synthesis scheme provides a synthesis scheme for organic molecules according to the invention wherein R^{I}, R^{IV}, R^{VI} and R^{VIII} are all hydrogen and Z is a direct bond:

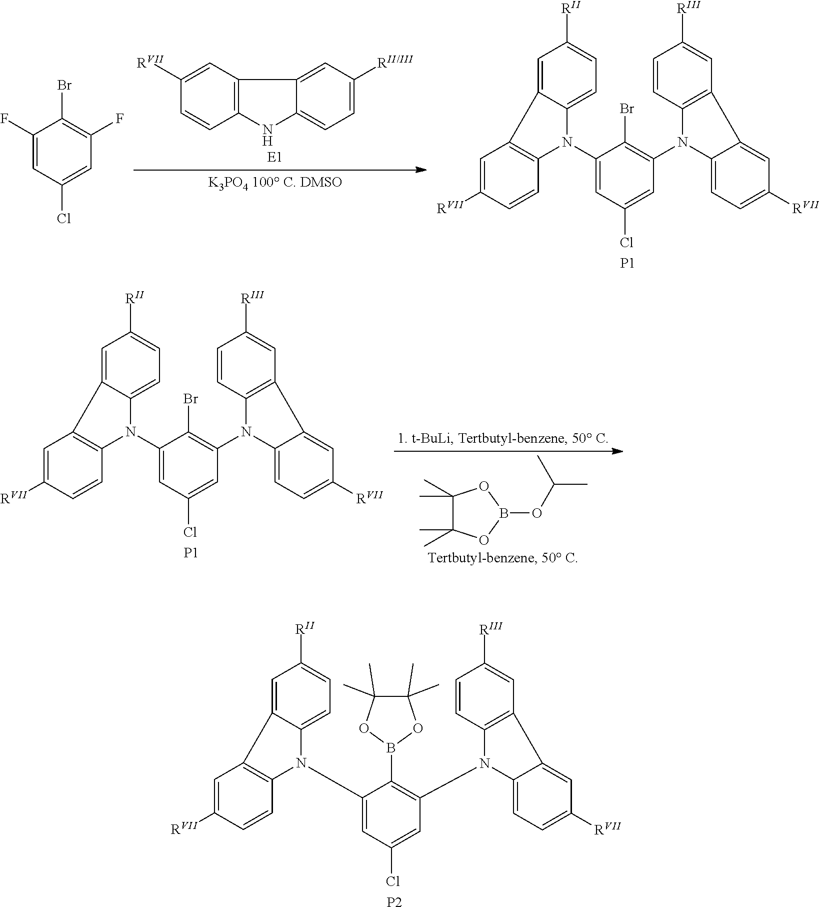

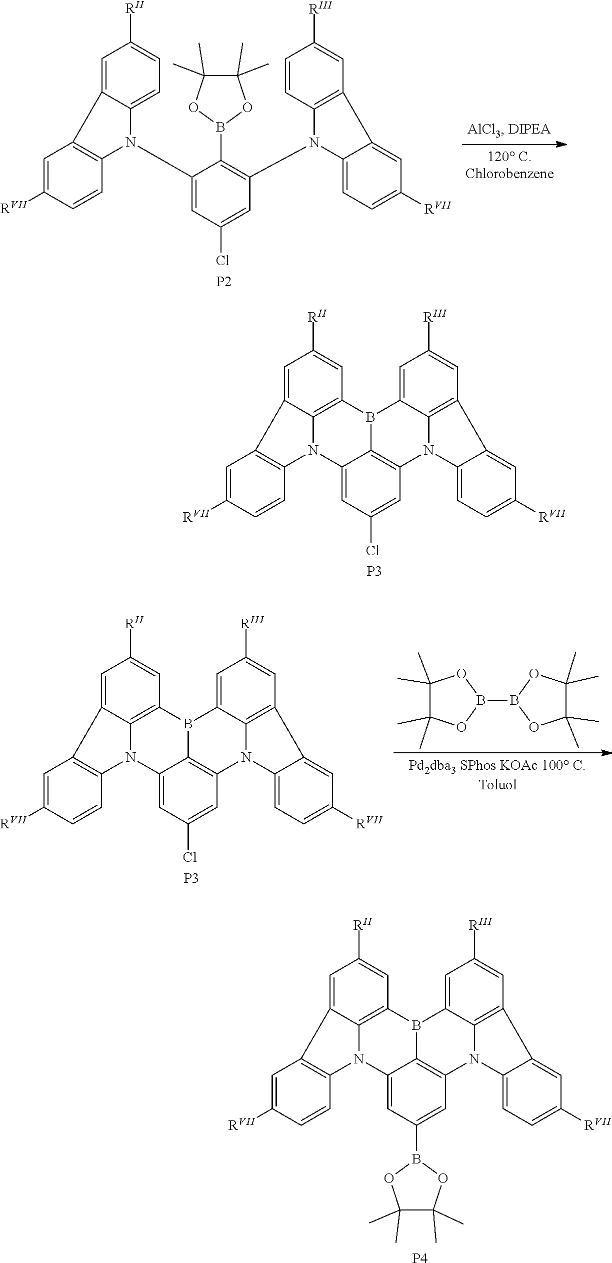

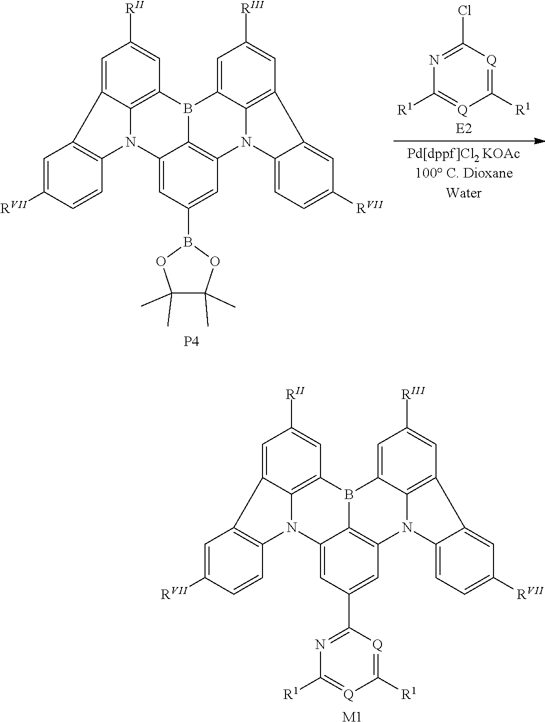

### General Procedure for Synthesis:

Under N2 atmosphere, a two-necked flask was charged with 4-Bromo-1-chloro-3,5-difluorobenzene [883546-16-5] (1.00 equiv.), a carbazole derivative E1 (2.00 equiv.), and Potassium phosphate tribasic [7778-53-2] (4.00 equiv.). Dry DMSO was added and the resulting suspension degassed for 10 min. Subsequently, the mixture was heated at 100° C. overnight. After cooling down to room temperature (rt), the reaction mixture was poured into ice/water. The precipitate was filtered and washed with water and ethanol and subsequently dried under high vacuum. The crude product was purified with MPLC or recrystallization to obtain the corresponding product P1 as a solid.

A two-necked flask was flame-dried under vacuum, allowed to cool down to rt under vacuum, backfilled with N2 and subsequently charged with the aryl chloride P1 (1.00 equiv.). At 0° C., a 1.7 M solution of tert-butyllithium in pentane [594-19-4] (2.00 equiv.) was added with a syringe and the resulting mixture was stirred at 50° C. until completion of the lithiation (monitored by quenching with DMF and subsequent TLC). At 50° C., 2-isopropoxy-4,4,5,5-tetramethyl-1,3,2-dioxaborolane [61676-62-8] (2.00 equiv.) was added with a syringe and the mixture was stirred at 50° C. until completion of the reaction (monitored by quenching with DMF and subsequent TLC). Water and ethyl acetate were added, the phases were separated, and the organic layer was dried over MgSO₄, filtered and concentrated. The crude product was purified by recrystallization or MPLC to obtain the corresponding boronic ester P2 as a solid.

Under N2 atmosphere, a two-necked flask was charged with the boronic ester P2 (1.00 equiv.). Dry chlorobenzene was added, followed by aluminum chloride [7446-70-0] (10.0 equiv.) and N,N-diisopropylethylamine (DIPEA) [7087-68-5] (15.0 equiv.). The resulting mixture was heated at 120° C. until completion of the reaction (monitored with TLC). After cooling down to rt, the reaction was carefully quenched with water. Subsequently, dichloromethane was added, the phases were separated, and the aqueous layer was extracted with dichloromethane. The combined organic layers were dried over MgSO₄, filtered and concentrated. The residue was purified by recrystallization or MPLC, yielding the desired material P3, as a solid.

Under N2 atmosphere, a two-necked flask was charged with P3 (1.00 equiv.), bis(pinacolato)diboron [73183-34-3] (1.20 equiv.), Pd₂(dba)₃ [51364-51-3] (0.06 equiv.). S-Phos [657408-07-6] (0.12 equiv.) and potassium acetate [127-08-2] (3.00 equiv.). Dry toluene (10 mL/mmol of P3) was added and the resulting mixture was degassed for 10 min. Subsequently, the mixture was heated at 100° C. overnight. After cooling down to room temperature (rt), dichloromethane and water were added, the phases were separated, the aqueous layer was extracted with dichloromethane and the combined organic layers were dried over MgSO₄, filtered and concentrated. The crude product was purified with MPLC or recrystallization to obtain the corresponding product P4 as a solid.

Under N2 atmosphere, a two-necked flask was charged with P4 (1.00 equiv.), a heteroaryl chloride E2, E3 or E4 (1.2 equiv.), Pd[dppf]Cl₂ [72287-26-4] (0.05 equiv.) and potassium acetate [127-08-2] (3.00 equiv.). A 10:1 dioxane:water mixture (22 mL/mmol of P4) was added and the resulting mixture was degassed for 10 min. Subsequently, the mixture was heated at 100° C. overnight. After cooling down to room temperature (rt), the mixture was poured into water. The crushed-out solid was filtered off and rinsed with ethanol. The crude product was purified with MPLC or recrystallization to obtain the corresponding product M1, M2 or M3 as a solid.

### Cyclic Voltammetry

Cyclic voltammograms were measured from solutions having concentration of 10⁻³ mol/L of the organic molecules in dichloromethane or a suitable solvent and a suitable supporting electrolyte (e.g. 0.1 mol/L of tetrabutylammonium hexafluorophosphate). The measurements were conducted at room temperature under nitrogen atmosphere with a three-electrode assembly (Working and counter electrodes: Pt wire, reference electrode: Pt wire) and calibrated using FeCp₂/FeCp₂⁺ as internal standard. The HOMO data was corrected using ferrocene as internal standard against a saturated calomel electrode (SCE).

### Density Functional Theory Calculation

Molecular structures were optimized employing the BP86 functional and the resolution of identity approach (RI). Excitation energies were calculated using the (BP86) optimized structures employing Time-Dependent DFT (TD-DFT) methods. Orbital and excited state energies were calculated with the B3LYP functional. Def2-SVP basis sets (and an m4-grid for numerical integration were used. The Turbomole program package was used for all calculations.

### Photophysical Measurements

Sample pretreatment: Spin-coating

Apparatus. Spin150, SPS euro.

The sample concentration was 10 mg/ml, dissolved in a suitable solvent.

Program: 1) 3 s at 400 U/min; 2) 20 sat 1000 U/min at 1000 Upm/s, 3) 10 s at 4000 U/min at 1000 Upm/s. After coating, the films were tried at 70° C. for 1 min.

Photoluminescence Spectroscopy and TCSPC (Time-Correlated Single-Photon Counting)

Steady-state emission spectroscopy was measured by a Horiba Scientific, Modell FluoroMax-4 equipped with a 150 W Xenon-Arc lamp, excitation- and emissions monochromators and a Hamamatsu R928 photomultiplier and a time-correlated single-photon counting option. Emissions and excitation spectra were corrected using standard correction fits.

Excited state lifetimes were determined employing the same system using the TCSPC method with FM-2013 equipment and a Horiba Yvon TCSPC hub.

### Excitation Sources:

NanoLED 370 (wavelength: 371 nm, pulse duration: 1.1 ns)

NanoLED 290 (wavelength: 294 nm, pulse duration: <1 ns)

SpectraLED 310 (wavelength: 314 nm)

SpectraLED 355 (wavelength: 355 nm).

Data analysis (exponential fit) was done using the software suite DataStation and DAS6 analysis software. The fit was specified using the chi-squared-test.

### Photoluminescence Quantum Yield Measurements

For photoluminescence quantum yield (PLQY) measurements an Absolute PL Quantum Yield Measurement C9920-03G system (Hamamatsu Photonics) was used. Quantum yields and CIE coordinates were determined using the software U6039-05 version 3.6.0.

Emission maxima were given in nm, quantum yields Φ in % and CIE coordinates as x,y values.

### PLQY was Determined Using the Following Protocol:

Quality assurance: Anthracene in ethanol (known concentration) was used as reference

Excitation wavelength: the absorption maximum of the organic molecule was determined and the molecule was excited using this wavelength

Measurement

Quantum yields were measured for sample of solutions or films under nitrogen atmosphere. The yield was calculated using the equation:

$${Φ}_{PL} = \frac{{n}_{photon} , emited}{{n}_{photon} , absorbed} = \frac{\int \frac{λ}{hc} [ {Int}_{emitted}^{sample} ( λ ) - {Int}_{absorbed}^{sample} ( λ ) ] d λ}{\int \frac{λ}{hc} [ {Int}_{emitted}^{reference} ( λ ) - {Int}_{absorbed}^{reference} ( λ ) ] d λ}$$

wherein nₚₕₒₜₒₙ denotes the photon count and Int. denotes the intensity.

### HPLC-MS

HPLC-MS analysis was performed on an HPLC by Agilent (1100 series) with MS-detector (Thermo LTQ XL).

A typical HPLC method was as follows: a reverse phase column 4.6 mm×150 mm, particle size 3.5 μm from Agilent (ZORBAX Eclipse Plus 95A C18, 4.6×150 mm, 3.5 μm HPLC column) was used in the HPLC. The HPLC-MS measurements were performed at room temperature (rt) with the following gradients

| Flow rate | Time | | | |
|---|---|---|---|---|
| [ml/min] | [min] | A[%] | B[%] | C[%] |
| 2.5 | 0 | 40 | 50 | 10 |
| 2.5 | 5 | 40 | 50 | 10 |
| 2.5 | 25 | 10 | 20 | 70 |
| 2.5 | 35 | 10 | 20 | 70 |
| 2.5 | 35.01 | 40 | 50 | 10 |
| 2.5 | 40.01 | 40 | 50 | 10 |
| 2.5 | 41.01 | 40 | 50 | 10 |

and using the following solvent mixtures:

| | | |
|---|---|---|
| Solvent A: | H2O (90%) | MeCN (10%) |
| Solvent B: | H2O (10%) | MeCN (90%) |
| Solvent C: | THF (50%) | MeCN (50%) |

An injection volume of 5 μL from a solution with a concentration of 0.5 mg/mL of the analyte was taken for the measurements.

Ionization of the probe was performed using an APCI (atmospheric pressure chemical ionization) source either in positive (APCI +) or negative (APCI −) ionization mode.

### Production and Characterization of Optoelectronic Devices

Optoelectronic devices, such as OLED devices, including organic molecules according to the invention can be produced via vacuum-deposition methods. If a layer contains more than one compound, the weight-percentage of one or more compounds was given in %. The total weight-percentage values amount to 100%, thus if a value was not given, the fraction of this compound equals to the difference between the given values and 100%.

The (not fully optimized) OLEDs were characterized using standard methods and measuring electroluminescence spectra, the external quantum efficiency (in %) in dependency on the intensity, calculated using the light detected by the photodiode, and the current. The OLED device lifetime was extracted from the change of the luminance during operation at constant current density. The LT50 value corresponds to the time, where the measured luminance decreased to 50% of the initial luminance, analogously LT80 corresponds to the time point, at which the measured luminance decreased to 80% of the initial luminance, and LT 95 corresponds to the time point, at which the measured luminance decreased to 95% of the initial luminance etc.

Accelerated lifetime measurements were performed (e.g. applying increased current densities). Exemplarily LT80 values at 500 cd/m² were determined using the following equation:

$$LT 80 ( 500 \frac{c d}{{m}^{2}} ) = LT 80 ( {L}_{0} ) {( \frac{{L}_{0}}{500 \frac{c d}{{m}^{2}}} )}^{1.6}$$

wherein L₀ denotes the initial luminance at the applied current density.

The values correspond to the average of several pixels (typically two to eight), the standard deviation between these pixels was given.

### Example 1

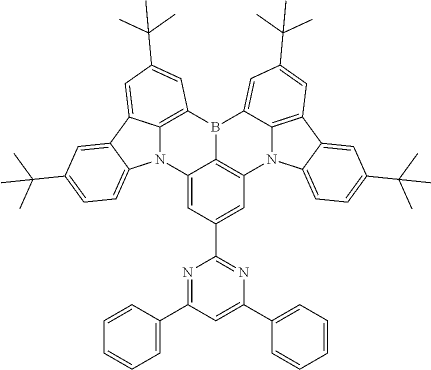 [SMILES: CC(C)(C)c1ccc2c(c1)c1cc(C(C)(C)C)cc3c1n2-c1cc(-c2nc(-c4ccccc4)cc(-c4ccccc4)n2)cc2c1B3c1cc(C(C)(C)C)cc3c4cc(C(C)(C)C)ccc4n-2c13]

Example 1 was synthesized according to the general procedure for synthesis, wherein 3,6-di-tert-butyl-carbazole and 2-chloro-4,6-diphenylpyrimidine were used as reactants E1 and E2, respectively.

Additional Examples of Organic Molecules of the Invention

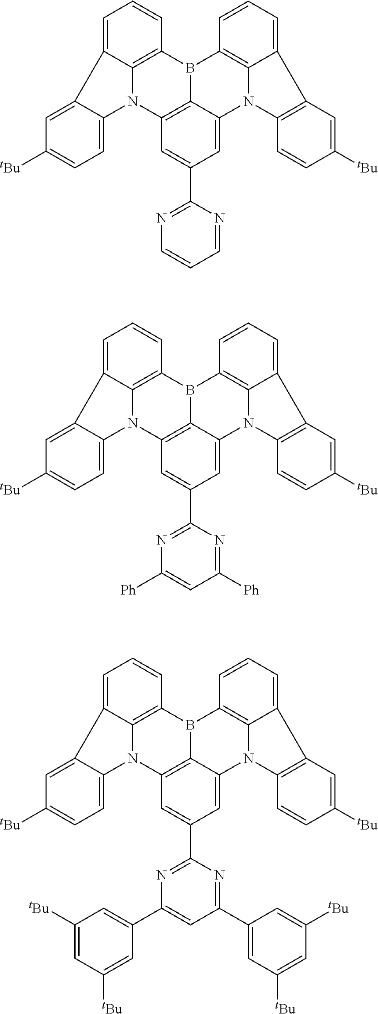 [SMILES: CC(C)(C)c1ccc2c(c1)c1cccc3c1n2-c1cc(-c2ncccn2)cc2c1B3c1cccc3c4cc(C(C)(C)C)ccc4n-2c13 ; CC(C)(C)c1ccc2c(c1)c1cccc3c1n2-c1cc(-c2nc(-c4ccccc4)cc(-c4ccccc4)n2)cc2c1B3c1cccc3c4cc(C(C)(C)C)ccc4n-2c13 ; CC(C)(C)c1cc(-c2cc(-c3cc(C(C)(C)C)cc(C(C)(C)C)c3)nc(-c3cc4c5c(c3)-n3c6ccc(C(C)(C)C)cc6c6cccc(c63)B5c3cccc5c6cc(C(C)(C)C)ccc6n-4c35)n2)cc(C(C)(C)C)c1]

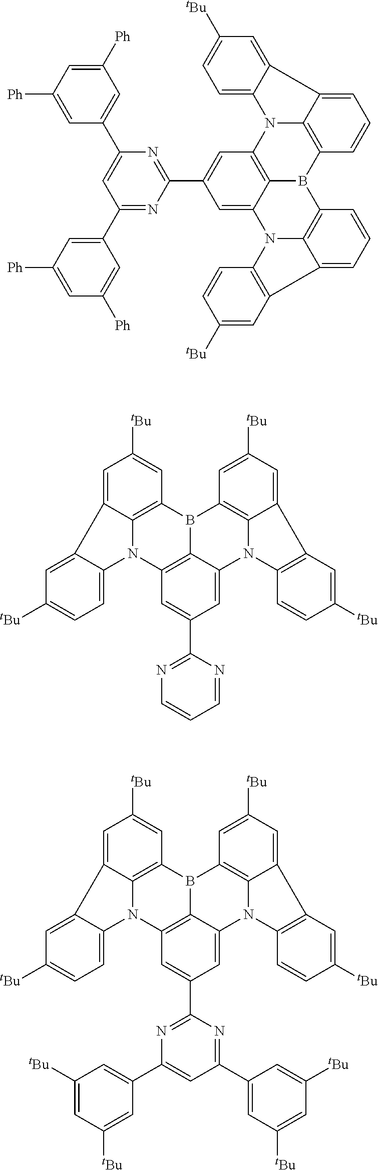 [SMILES: CC(C)(C)c1ccc2c(c1)c1cccc3c1n2-c1cc(-c2nc(-c4cc(-c5ccccc5)cc(-c5ccccc5)c4)cc(-c4cc(-c5ccccc5)cc(-c5ccccc5)c4)n2)cc2c1B3c1cccc3c4cc(C(C)(C)C)ccc4n-2c13 ; CC(C)(C)c1ccc2c(c1)c1cc(C(C)(C)C)cc3c1n2-c1cc(-c2ncccn2)cc2c1B3c1cc(C(C)(C)C)cc3c4cc(C(C)(C)C)ccc4n-2c13 ; CC(C)(C)c1cc(-c2cc(-c3cc(C(C)(C)C)cc(C(C)(C)C)c3)nc(-c3cc4c5c(c3)-n3c6ccc(C(C)(C)C)cc6c6cc(C(C)(C)C)cc(c63)B5c3cc(C(C)(C)C)cc5c6cc(C(C)(C)C)ccc6n-4c35)n2)cc(C(C)(C)C)c1]

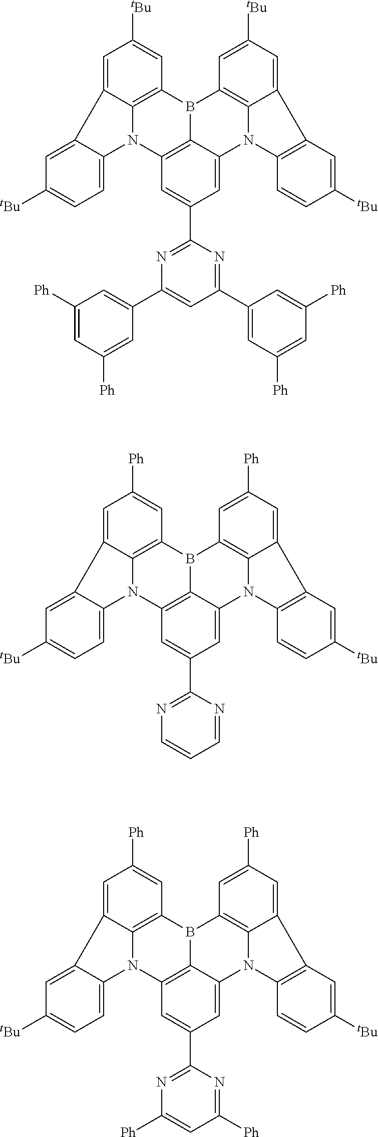 [SMILES: CC(C)(C)c1ccc2c(c1)c1cc(C(C)(C)C)cc3c1n2-c1cc(-c2nc(-c4cc(-c5ccccc5)cc(-c5ccccc5)c4)cc(-c4cc(-c5ccccc5)cc(-c5ccccc5)c4)n2)cc2c1B3c1cc(C(C)(C)C)cc3c4cc(C(C)(C)C)ccc4n-2c13 ; CC(C)(C)c1ccc2c(c1)c1cc(-c3ccccc3)cc3c1n2-c1cc(-c2ncccn2)cc2c1B3c1cc(-c3ccccc3)cc3c4cc(C(C)(C)C)ccc4n-2c13 ; CC(C)(C)c1ccc2c(c1)c1cc(-c3ccccc3)cc3c1n2-c1cc(-c2nc(-c4ccccc4)cc(-c4ccccc4)n2)cc2c1B3c1cc(-c3ccccc3)cc3c4cc(C(C)(C)C)ccc4n-2c13]

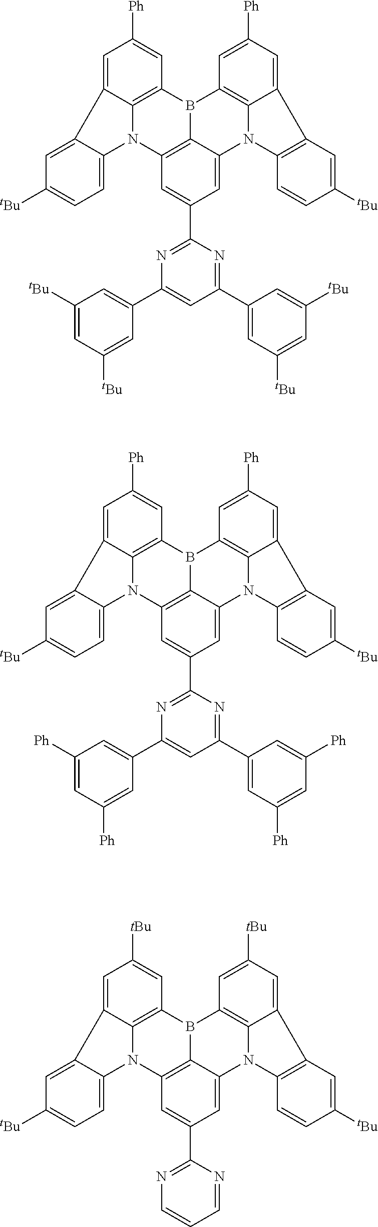 [SMILES: CC(C)(C)c1cc(-c2cc(-c3cc(C(C)(C)C)cc(C(C)(C)C)c3)nc(-c3cc4c5c(c3)-n3c6ccc(C(C)(C)C)cc6c6cc(-c7ccccc7)cc(c63)B5c3cc(-c5ccccc5)cc5c6cc(C(C)(C)C)ccc6n-4c35)n2)cc(C(C)(C)C)c1 ; CC(C)(C)c1ccc2c(c1)c1cc(-c3ccccc3)cc3c1n2-c1cc(-c2nc(-c4cc(-c5ccccc5)cc(-c5ccccc5)c4)cc(-c4cc(-c5ccccc5)cc(-c5ccccc5)c4)n2)cc2c1B3c1cc(-c3ccccc3)cc3c4cc(C(C)(C)C)ccc4n-2c13 ; CC(C)(C)c1ccc2c(c1)c1cc(C(C)(C)C)cc3c1n2-c1cc(-c2ncccn2)cc2c1B3c1cc(C(C)(C)C)cc3c4cc(C(C)(C)C)ccc4n-2c13]

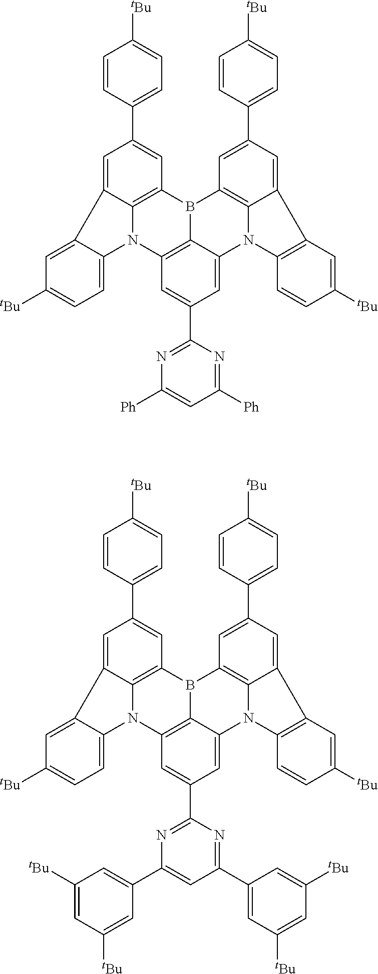 [SMILES: CC(C)(C)c1ccc(-c2cc3c4c(c2)c2cc(C(C)(C)C)ccc2n4-c2cc(-c4nc(-c5ccccc5)cc(-c5ccccc5)n4)cc4c2B3c2cc(-c3ccc(C(C)(C)C)cc3)cc3c5cc(C(C)(C)C)ccc5n-4c23)cc1 ; CC(C)(C)c1ccc(-c2cc3c4c(c2)c2cc(C(C)(C)C)ccc2n4-c2cc(-c4nc(-c5cc(C(C)(C)C)cc(C(C)(C)C)c5)cc(-c5cc(C(C)(C)C)cc(C(C)(C)C)c5)n4)cc4c2B3c2cc(-c3ccc(C(C)(C)C)cc3)cc3c5cc(C(C)(C)C)ccc5n-4c23)cc1]

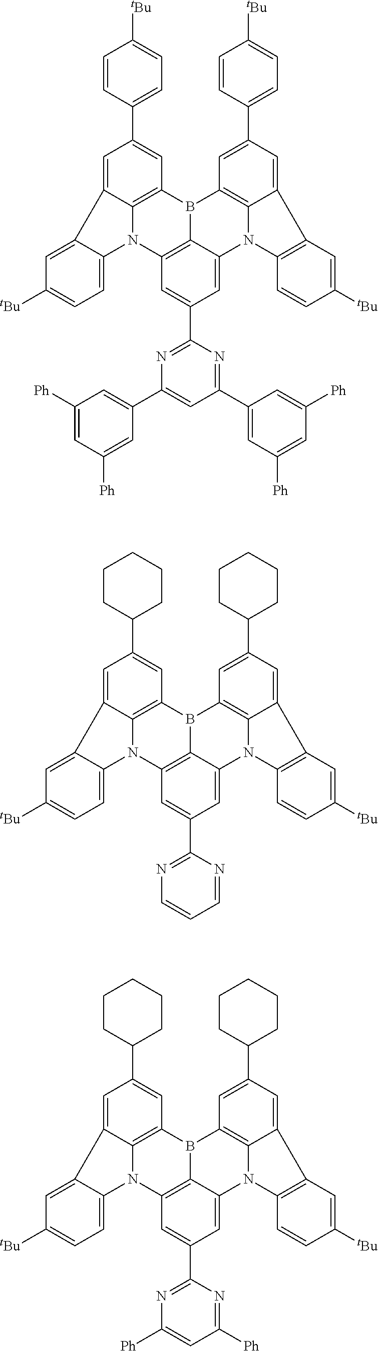 [SMILES: CC(C)(C)c1ccc(-c2cc3c4c(c2)c2cc(C(C)(C)C)ccc2n4-c2cc(-c4nc(-c5cc(-c6ccccc6)cc(-c6ccccc6)c5)cc(-c5cc(-c6ccccc6)cc(-c6ccccc6)c5)n4)cc4c2B3c2cc(-c3ccc(C(C)(C)C)cc3)cc3c5cc(C(C)(C)C)ccc5n-4c23)cc1 ; CC(C)(C)c1ccc2c(c1)c1cc(C3CCCCC3)cc3c1n2-c1cc(-c2ncccn2)cc2c1B3c1cc(C3CCCCC3)cc3c4cc(C(C)(C)C)ccc4n-2c13 ; CC(C)(C)c1ccc2c(c1)c1cc(C3CCCCC3)cc3c1n2-c1cc(-c2nc(-c4ccccc4)cc(-c4ccccc4)n2)cc2c1B3c1cc(C3CCCCC3)cc3c4cc(C(C)(C)C)ccc4n-2c13]

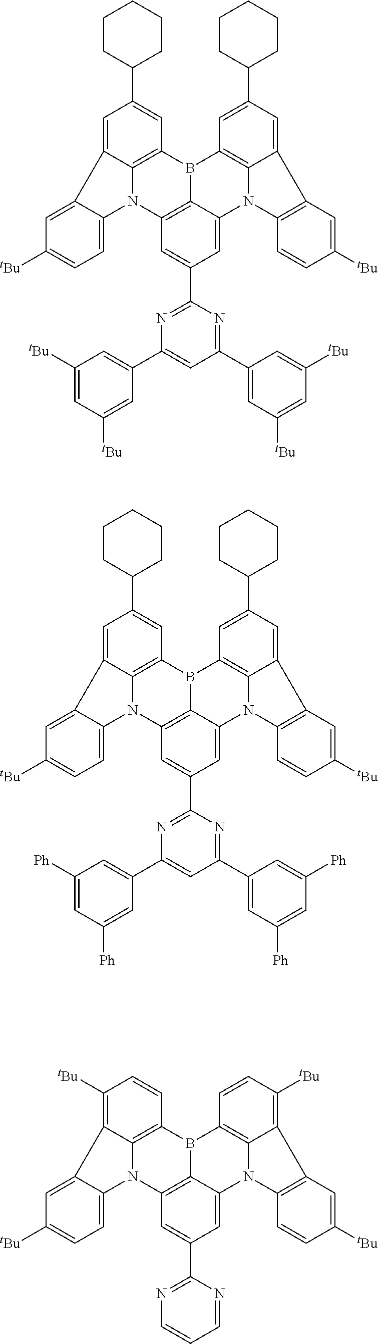 [SMILES: CC(C)(C)c1cc(-c2cc(-c3cc(C(C)(C)C)cc(C(C)(C)C)c3)nc(-c3cc4c5c(c3)-n3c6ccc(C(C)(C)C)cc6c6cc(C7CCCCC7)cc(c63)B5c3cc(C5CCCCC5)cc5c6cc(C(C)(C)C)ccc6n-4c35)n2)cc(C(C)(C)C)c1 ; CC(C)(C)c1ccc2c(c1)c1cc(C3CCCCC3)cc3c1n2-c1cc(-c2nc(-c4cc(-c5ccccc5)cc(-c5ccccc5)c4)cc(-c4cc(-c5ccccc5)cc(-c5ccccc5)c4)n2)cc2c1B3c1cc(C3CCCCC3)cc3c4cc(C(C)(C)C)ccc4n-2c13 ; CC(C)(C)c1ccc2c(c1)c1c(C(C)(C)C)ccc3c1n2-c1cc(-c2ncccn2)cc2c1B3c1ccc(C(C)(C)C)c3c4cc(C(C)(C)C)ccc4n-2c13]

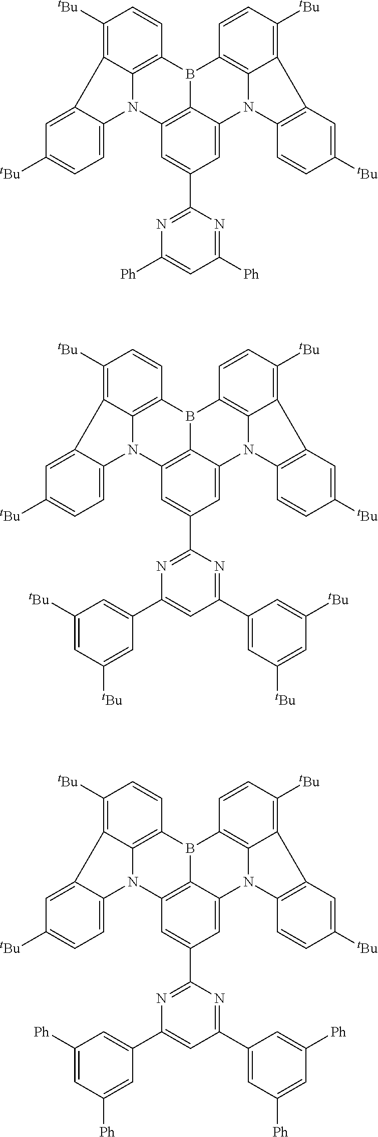 [SMILES: CC(C)(C)c1ccc2c(c1)c1c(C(C)(C)C)ccc3c1n2-c1cc(-c2nc(-c4ccccc4)cc(-c4ccccc4)n2)cc2c1B3c1ccc(C(C)(C)C)c3c4cc(C(C)(C)C)ccc4n-2c13 ; CC(C)(C)c1cc(-c2cc(-c3cc(C(C)(C)C)cc(C(C)(C)C)c3)nc(-c3cc4c5c(c3)-n3c6ccc(C(C)(C)C)cc6c6c(C(C)(C)C)ccc(c63)B5c3ccc(C(C)(C)C)c5c6cc(C(C)(C)C)ccc6n-4c35)n2)cc(C(C)(C)C)c1 ; CC(C)(C)c1ccc2c(c1)c1c(C(C)(C)C)ccc3c1n2-c1cc(-c2nc(-c4cc(-c5ccccc5)cc(-c5ccccc5)c4)cc(-c4cc(-c5ccccc5)cc(-c5ccccc5)c4)n2)cc2c1B3c1ccc(C(C)(C)C)c3c4cc(C(C)(C)C)ccc4n-2c13]

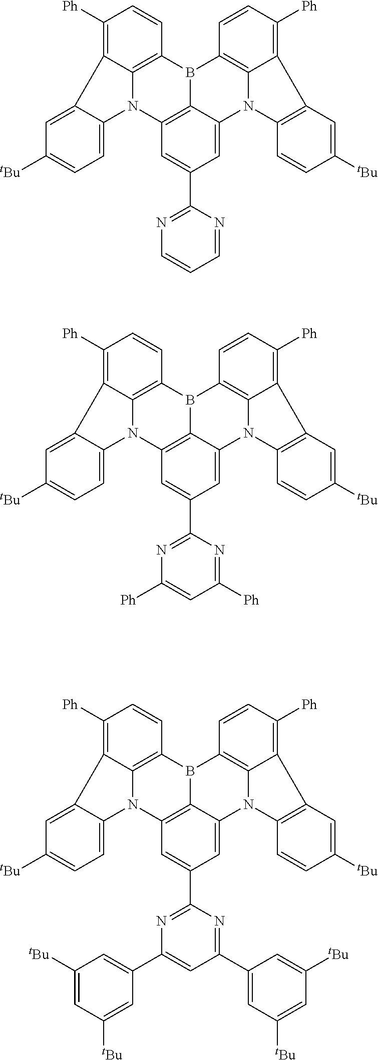 [SMILES: CC(C)(C)c1ccc2c(c1)c1c(-c3ccccc3)ccc3c1n2-c1cc(-c2ncccn2)cc2c1B3c1ccc(-c3ccccc3)c3c4cc(C(C)(C)C)ccc4n-2c13 ; CC(C)(C)c1ccc2c(c1)c1c(-c3ccccc3)ccc3c1n2-c1cc(-c2nc(-c4ccccc4)cc(-c4ccccc4)n2)cc2c1B3c1ccc(-c3ccccc3)c3c4cc(C(C)(C)C)ccc4n-2c13 ; CC(C)(C)c1cc(-c2cc(-c3cc(C(C)(C)C)cc(C(C)(C)C)c3)nc(-c3cc4c5c(c3)-n3c6ccc(C(C)(C)C)cc6c6c(-c7ccccc7)ccc(c63)B5c3ccc(-c5ccccc5)c5c6cc(C(C)(C)C)ccc6n-4c35)n2)cc(C(C)(C)C)c1]

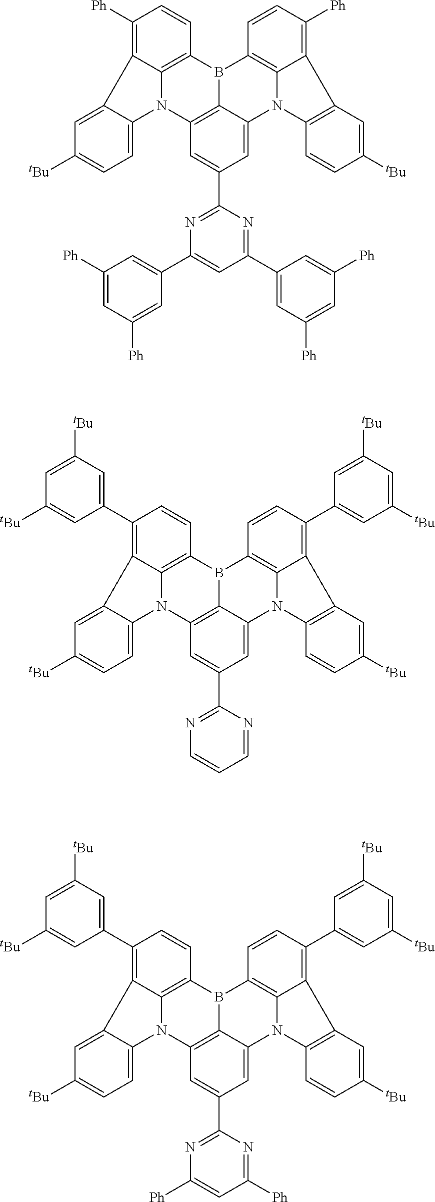 [SMILES: CC(C)(C)c1ccc2c(c1)c1c(-c3ccccc3)ccc3c1n2-c1cc(-c2nc(-c4cc(-c5ccccc5)cc(-c5ccccc5)c4)cc(-c4cc(-c5ccccc5)cc(-c5ccccc5)c4)n2)cc2c1B3c1ccc(-c3ccccc3)c3c4cc(C(C)(C)C)ccc4n-2c13 ; CC(C)(C)c1cc(-c2ccc3c4c2c2cc(C(C)(C)C)ccc2n4-c2cc(-c4ncccn4)cc4c2B3c2ccc(-c3cc(C(C)(C)C)cc(C(C)(C)C)c3)c3c5cc(C(C)(C)C)ccc5n-4c23)cc(C(C)(C)C)c1 ; CC(C)(C)c1cc(-c2ccc3c4c2c2cc(C(C)(C)C)ccc2n4-c2cc(-c4nc(-c5ccccc5)cc(-c5ccccc5)n4)cc4c2B3c2ccc(-c3cc(C(C)(C)C)cc(C(C)(C)C)c3)c3c5cc(C(C)(C)C)ccc5n-4c23)cc(C(C)(C)C)c1]

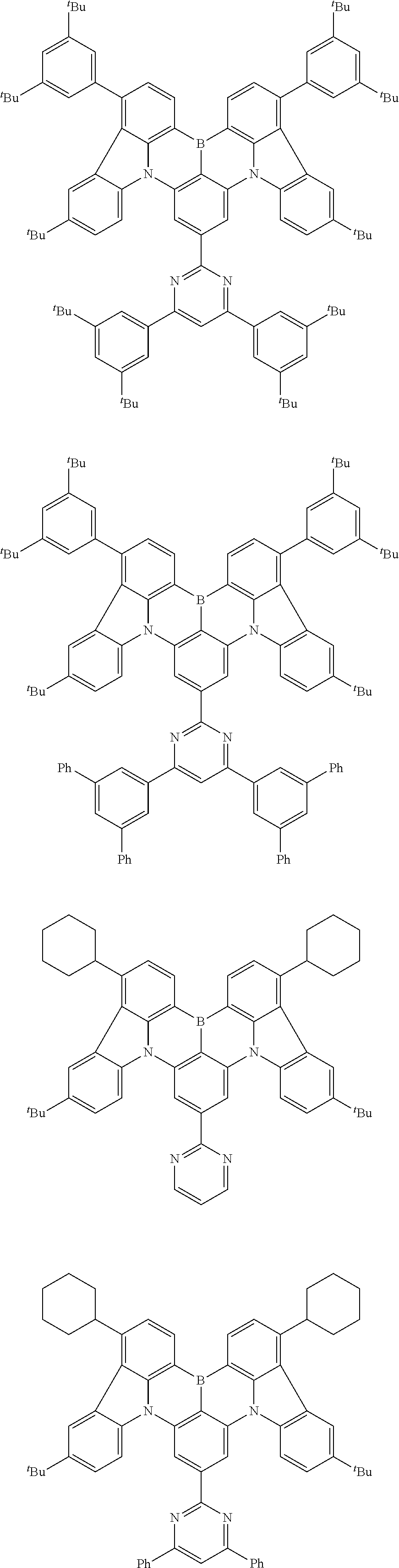

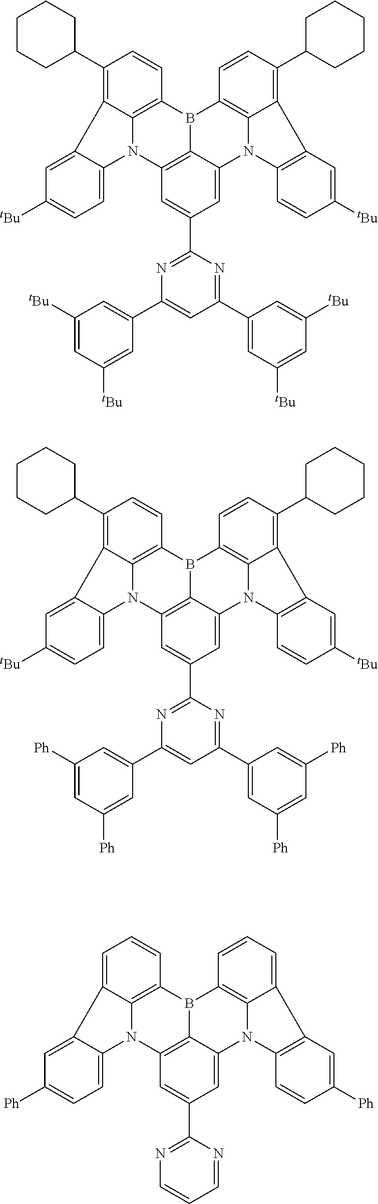 [SMILES: CC(C)(C)c1cc(-c2cc(-c3cc(C(C)(C)C)cc(C(C)(C)C)c3)nc(-c3cc4c5c(c3)-n3c6ccc(C(C)(C)C)cc6c6c(C7CCCCC7)ccc(c63)B5c3ccc(C5CCCCC5)c5c6cc(C(C)(C)C)ccc6n-4c35)n2)cc(C(C)(C)C)c1 ; CC(C)(C)c1ccc2c(c1)c1c(C3CCCCC3)ccc3c1n2-c1cc(-c2nc(-c4cc(-c5ccccc5)cc(-c5ccccc5)c4)cc(-c4cc(-c5ccccc5)cc(-c5ccccc5)c4)n2)cc2c1B3c1ccc(C3CCCCC3)c3c4cc(C(C)(C)C)ccc4n-2c13 ; c1ccc(-c2ccc3c(c2)c2cccc4c2n3-c2cc(-c3ncccn3)cc3c2B4c2cccc4c5cc(-c6ccccc6)ccc5n-3c24)cc1]

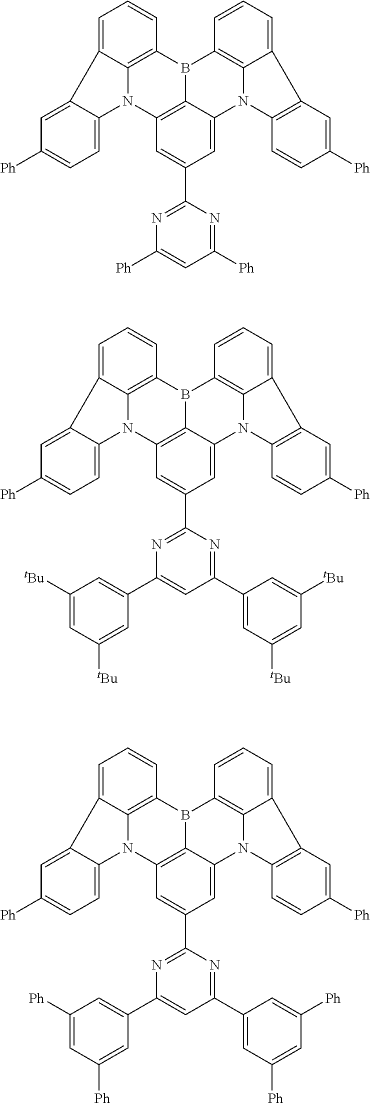 [SMILES: c1ccc(-c2ccc3c(c2)c2cccc4c2n3-c2cc(-c3nc(-c5ccccc5)cc(-c5ccccc5)n3)cc3c2B4c2cccc4c5cc(-c6ccccc6)ccc5n-3c24)cc1 ; CC(C)(C)c1cc(-c2cc(-c3cc(C(C)(C)C)cc(C(C)(C)C)c3)nc(-c3cc4c5c(c3)-n3c6ccc(-c7ccccc7)cc6c6cccc(c63)B5c3cccc5c6cc(-c7ccccc7)ccc6n-4c35)n2)cc(C(C)(C)C)c1 ; c1ccc(-c2cc(-c3ccccc3)cc(-c3cc(-c4cc(-c5ccccc5)cc(-c5ccccc5)c4)nc(-c4cc5c6c(c4)-n4c7ccc(-c8ccccc8)cc7c7cccc(c74)B6c4cccc6c7cc(-c8ccccc8)ccc7n-5c46)n3)c2)cc1]

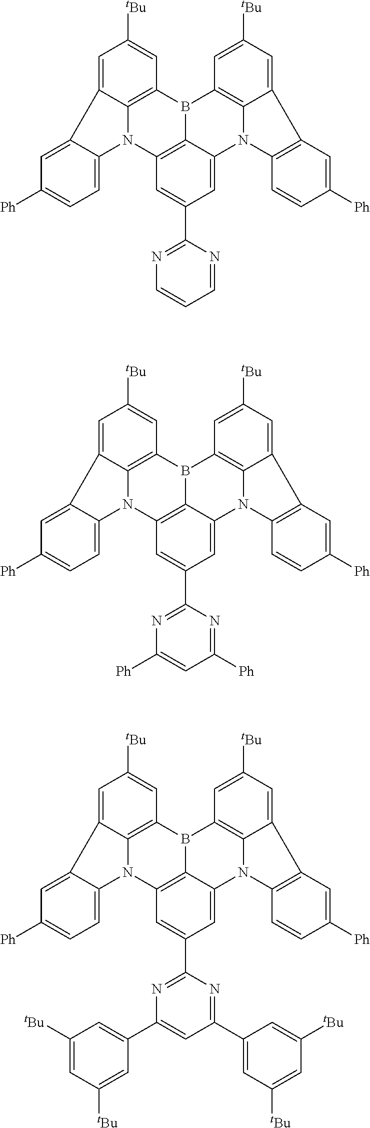 [SMILES: CC(C)(C)c1cc2c3c(c1)c1cc(-c4ccccc4)ccc1n3-c1cc(-c3ncccn3)cc3c1B2c1cc(C(C)(C)C)cc2c4cc(-c5ccccc5)ccc4n-3c12 ; CC(C)(C)c1cc2c3c(c1)c1cc(-c4ccccc4)ccc1n3-c1cc(-c3nc(-c4ccccc4)cc(-c4ccccc4)n3)cc3c1B2c1cc(C(C)(C)C)cc2c4cc(-c5ccccc5)ccc4n-3c12 ; CC(C)(C)c1cc(-c2cc(-c3cc(C(C)(C)C)cc(C(C)(C)C)c3)nc(-c3cc4c5c(c3)-n3c6ccc(-c7ccccc7)cc6c6cc(C(C)(C)C)cc(c63)B5c3cc(C(C)(C)C)cc5c6cc(-c7ccccc7)ccc6n-4c35)n2)cc(C(C)(C)C)c1]

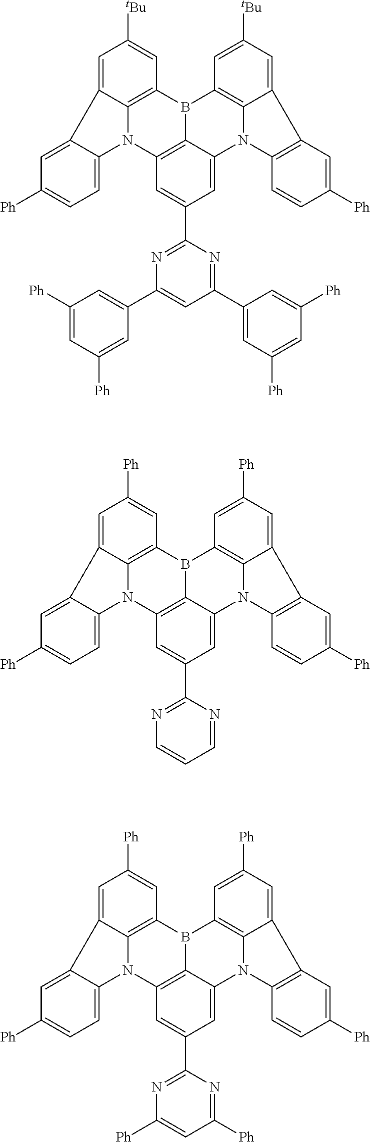 [SMILES: CC(C)(C)c1cc2c3c(c1)c1cc(-c4ccccc4)ccc1n3-c1cc(-c3nc(-c4cc(-c5ccccc5)cc(-c5ccccc5)c4)cc(-c4cc(-c5ccccc5)cc(-c5ccccc5)c4)n3)cc3c1B2c1cc(C(C)(C)C)cc2c4cc(-c5ccccc5)ccc4n-3c12 ; c1ccc(-c2ccc3c(c2)c2cc(-c4ccccc4)cc4c2n3-c2cc(-c3ncccn3)cc3c2B4c2cc(-c4ccccc4)cc4c5cc(-c6ccccc6)ccc5n-3c24)cc1 ; c1ccc(-c2ccc3c(c2)c2cc(-c4ccccc4)cc4c2n3-c2cc(-c3nc(-c5ccccc5)cc(-c5ccccc5)n3)cc3c2B4c2cc(-c4ccccc4)cc4c5cc(-c6ccccc6)ccc5n-3c24)cc1]

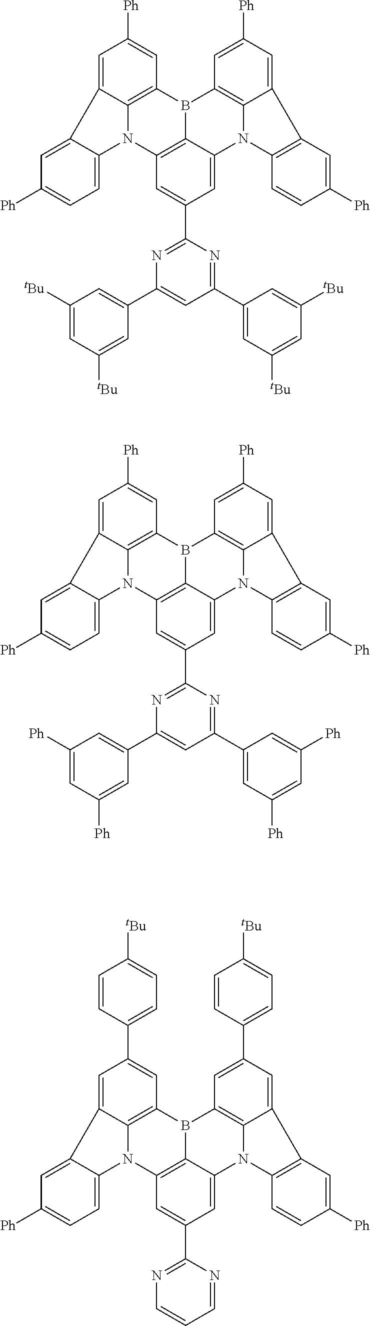 [SMILES: CC(C)(C)c1cc(-c2cc(-c3cc(C(C)(C)C)cc(C(C)(C)C)c3)nc(-c3cc4c5c(c3)-n3c6ccc(-c7ccccc7)cc6c6cc(-c7ccccc7)cc(c63)B5c3cc(-c5ccccc5)cc5c6cc(-c7ccccc7)ccc6n-4c35)n2)cc(C(C)(C)C)c1 ; c1ccc(-c2cc(-c3ccccc3)cc(-c3cc(-c4cc(-c5ccccc5)cc(-c5ccccc5)c4)nc(-c4cc5c6c(c4)-n4c7ccc(-c8ccccc8)cc7c7cc(-c8ccccc8)cc(c74)B6c4cc(-c6ccccc6)cc6c7cc(-c8ccccc8)ccc7n-5c46)n3)c2)cc1 ; CC(C)(C)c1ccc(-c2cc3c4c(c2)c2cc(-c5ccccc5)ccc2n4-c2cc(-c4ncccn4)cc4c2B3c2cc(-c3ccc(C(C)(C)C)cc3)cc3c5cc(-c6ccccc6)ccc5n-4c23)cc1]

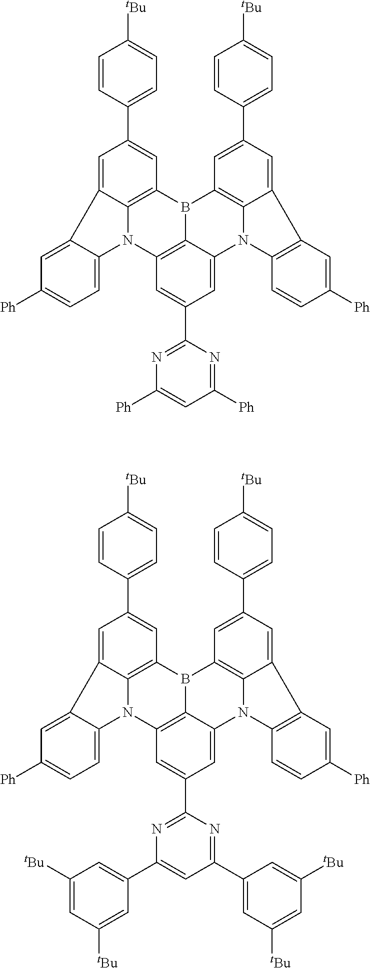 [SMILES: CC(C)(C)c1ccc(-c2cc3c4c(c2)c2cc(-c5ccccc5)ccc2n4-c2cc(-c4nc(-c5ccccc5)cc(-c5ccccc5)n4)cc4c2B3c2cc(-c3ccc(C(C)(C)C)cc3)cc3c5cc(-c6ccccc6)ccc5n-4c23)cc1 ; CC(C)(C)c1ccc(-c2cc3c4c(c2)c2cc(-c5ccccc5)ccc2n4-c2cc(-c4nc(-c5cc(C(C)(C)C)cc(C(C)(C)C)c5)cc(-c5cc(C(C)(C)C)cc(C(C)(C)C)c5)n4)cc4c2B3c2cc(-c3ccc(C(C)(C)C)cc3)cc3c5cc(-c6ccccc6)ccc5n-4c23)cc1]

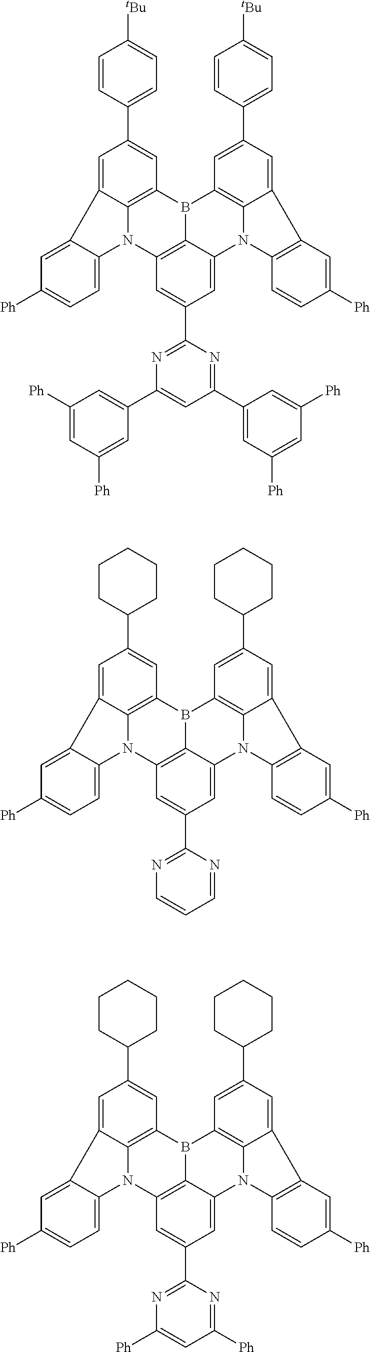 [SMILES: CC(C)(C)c1ccc(-c2cc3c4c(c2)c2cc(-c5ccccc5)ccc2n4-c2cc(-c4nc(-c5cc(-c6ccccc6)cc(-c6ccccc6)c5)cc(-c5cc(-c6ccccc6)cc(-c6ccccc6)c5)n4)cc4c2B3c2cc(-c3ccc(C(C)(C)C)cc3)cc3c5cc(-c6ccccc6)ccc5n-4c23)cc1 ; c1ccc(-c2ccc3c(c2)c2cc(C4CCCCC4)cc4c2n3-c2cc(-c3ncccn3)cc3c2B4c2cc(C4CCCCC4)cc4c5cc(-c6ccccc6)ccc5n-3c24)cc1 ; c1ccc(-c2ccc3c(c2)c2cc(C4CCCCC4)cc4c2n3-c2cc(-c3nc(-c5ccccc5)cc(-c5ccccc5)n3)cc3c2B4c2cc(C4CCCCC4)cc4c5cc(-c6ccccc6)ccc5n-3c24)cc1]

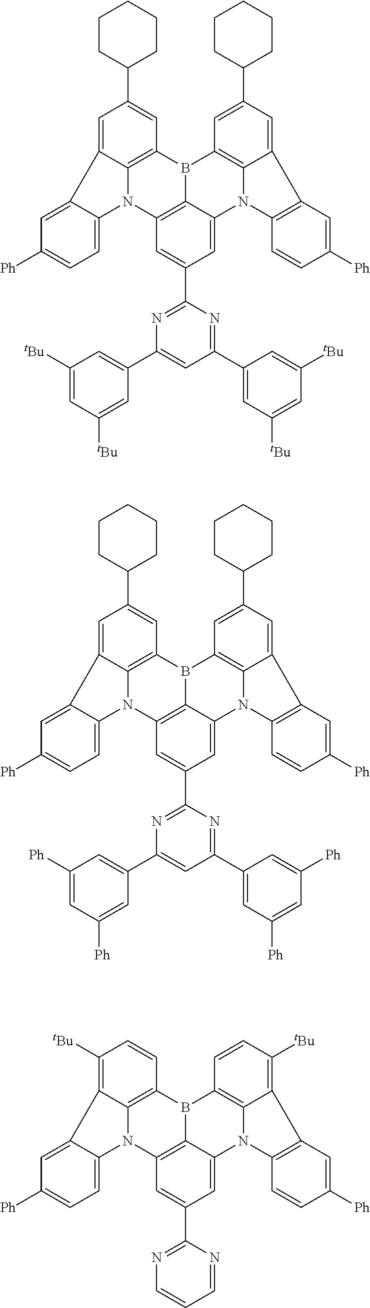 [SMILES: CC(C)(C)c1cc(-c2cc(-c3cc(C(C)(C)C)cc(C(C)(C)C)c3)nc(-c3cc4c5c(c3)-n3c6ccc(-c7ccccc7)cc6c6cc(C7CCCCC7)cc(c63)B5c3cc(C5CCCCC5)cc5c6cc(-c7ccccc7)ccc6n-4c35)n2)cc(C(C)(C)C)c1 ; c1ccc(-c2cc(-c3ccccc3)cc(-c3cc(-c4cc(-c5ccccc5)cc(-c5ccccc5)c4)nc(-c4cc5c6c(c4)-n4c7ccc(-c8ccccc8)cc7c7cc(C8CCCCC8)cc(c74)B6c4cc(C6CCCCC6)cc6c7cc(-c8ccccc8)ccc7n-5c46)n3)c2)cc1 ; CC(C)(C)c1ccc2c3c1c1cc(-c4ccccc4)ccc1n3-c1cc(-c3ncccn3)cc3c1B2c1ccc(C(C)(C)C)c2c4cc(-c5ccccc5)ccc4n-3c12]

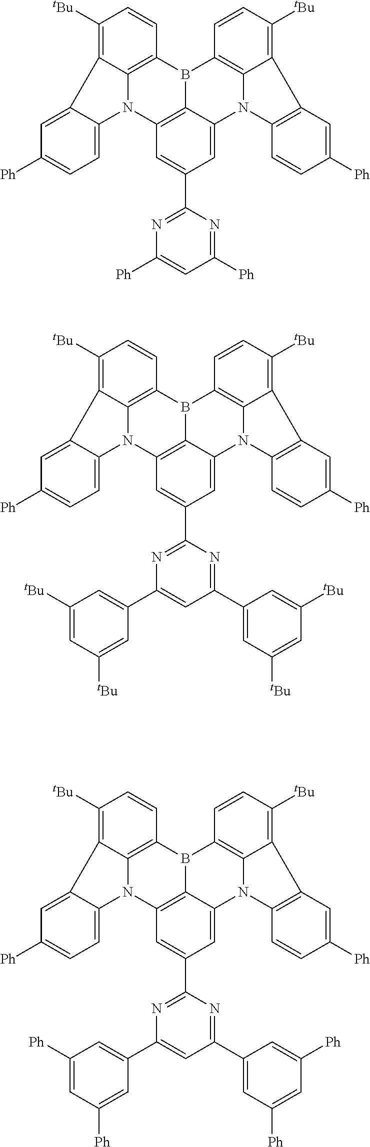 [SMILES: CC(C)(C)c1ccc2c3c1c1cc(-c4ccccc4)ccc1n3-c1cc(-c3nc(-c4ccccc4)cc(-c4ccccc4)n3)cc3c1B2c1ccc(C(C)(C)C)c2c4cc(-c5ccccc5)ccc4n-3c12 ; CC(C)(C)c1cc(-c2cc(-c3cc(C(C)(C)C)cc(C(C)(C)C)c3)nc(-c3cc4c5c(c3)-n3c6ccc(-c7ccccc7)cc6c6c(C(C)(C)C)ccc(c63)B5c3ccc(C(C)(C)C)c5c6cc(-c7ccccc7)ccc6n-4c35)n2)cc(C(C)(C)C)c1 ; CC(C)(C)c1ccc2c3c1c1cc(-c4ccccc4)ccc1n3-c1cc(-c3nc(-c4cc(-c5ccccc5)cc(-c5ccccc5)c4)cc(-c4cc(-c5ccccc5)cc(-c5ccccc5)c4)n3)cc3c1B2c1ccc(C(C)(C)C)c2c4cc(-c5ccccc5)ccc4n-3c12]

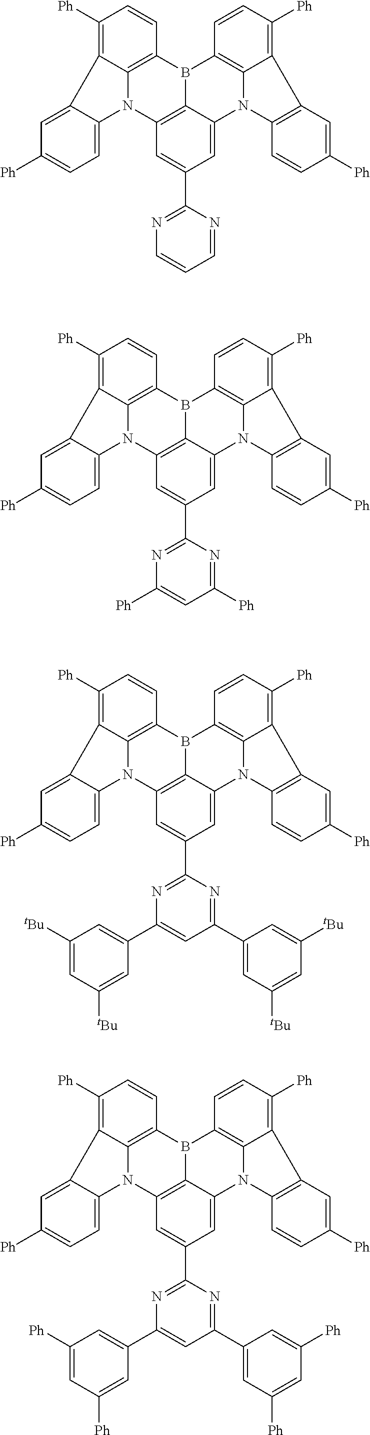

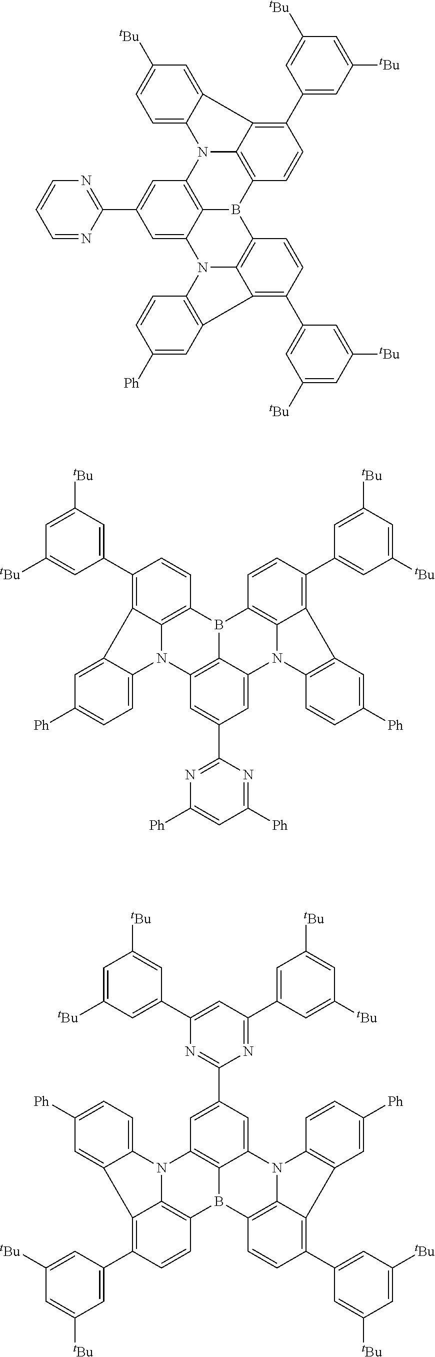

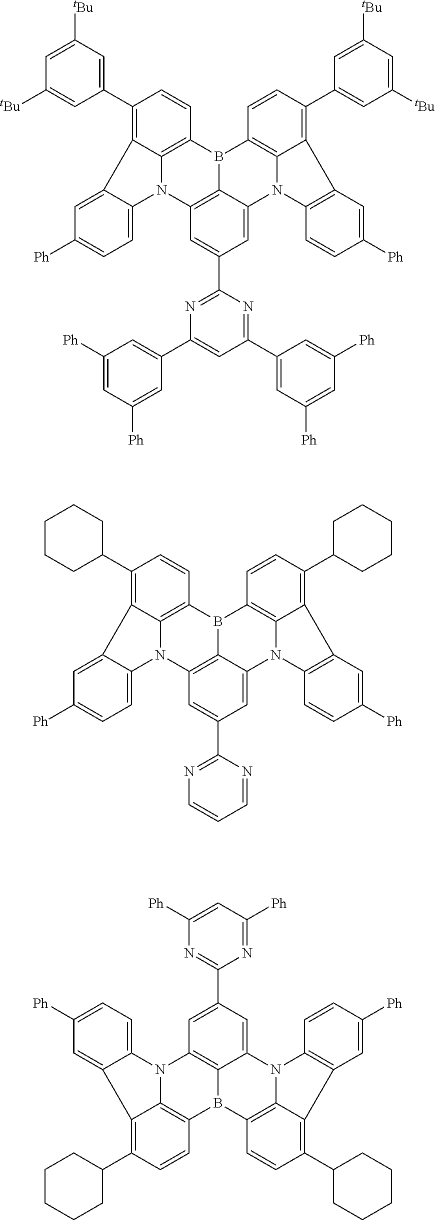 [SMILES: CC(C)(C)c1cc(-c2ccc3c4c2c2cc(-c5ccccc5)ccc2n4-c2cc(-c4nc(-c5cc(-c6ccccc6)cc(-c6ccccc6)c5)cc(-c5cc(-c6ccccc6)cc(-c6ccccc6)c5)n4)cc4c2B3c2ccc(-c3cc(C(C)(C)C)cc(C(C)(C)C)c3)c3c5cc(-c6ccccc6)ccc5n-4c23)cc(C(C)(C)C)c1 ; c1ccc(-c2ccc3c(c2)c2c(C4CCCCC4)ccc4c2n3-c2cc(-c3ncccn3)cc3c2B4c2ccc(C4CCCCC4)c4c5cc(-c6ccccc6)ccc5n-3c24)cc1 ; c1ccc(-c2ccc3c(c2)c2c(C4CCCCC4)ccc4c2n3-c2cc(-c3nc(-c5ccccc5)cc(-c5ccccc5)n3)cc3c2B4c2ccc(C4CCCCC4)c4c5cc(-c6ccccc6)ccc5n-3c24)cc1]

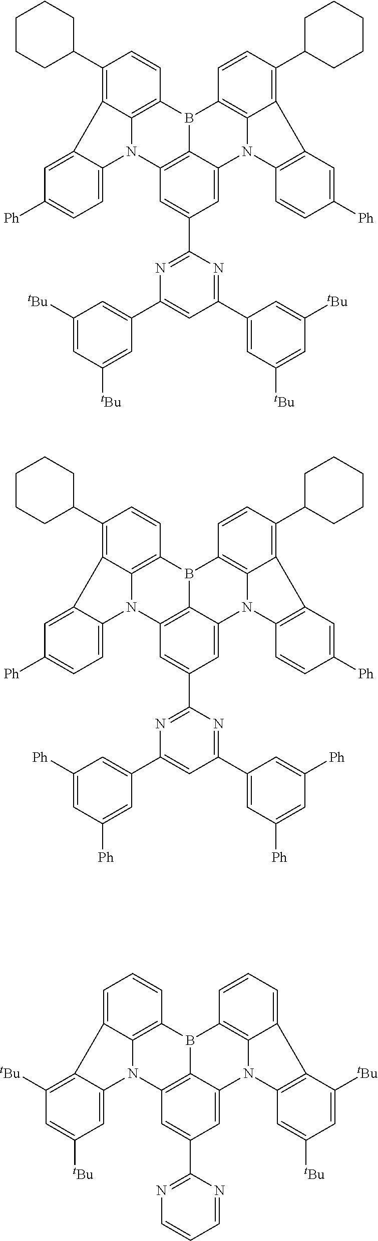 [SMILES: CC(C)(C)c1cc(-c2cc(-c3cc(C(C)(C)C)cc(C(C)(C)C)c3)nc(-c3cc4c5c(c3)-n3c6ccc(-c7ccccc7)cc6c6c(C7CCCCC7)ccc(c63)B5c3ccc(C5CCCCC5)c5c6cc(-c7ccccc7)ccc6n-4c35)n2)cc(C(C)(C)C)c1 ; c1ccc(-c2cc(-c3ccccc3)cc(-c3cc(-c4cc(-c5ccccc5)cc(-c5ccccc5)c4)nc(-c4cc5c6c(c4)-n4c7ccc(-c8ccccc8)cc7c7c(C8CCCCC8)ccc(c74)B6c4ccc(C6CCCCC6)c6c7cc(-c8ccccc8)ccc7n-5c46)n3)c2)cc1 ; CC(C)(C)c1cc(C(C)(C)C)c2c3cccc4c3n(c2c1)-c1cc(-c2ncccn2)cc2c1B4c1cccc3c4c(C(C)(C)C)cc(C(C)(C)C)cc4n-2c13]

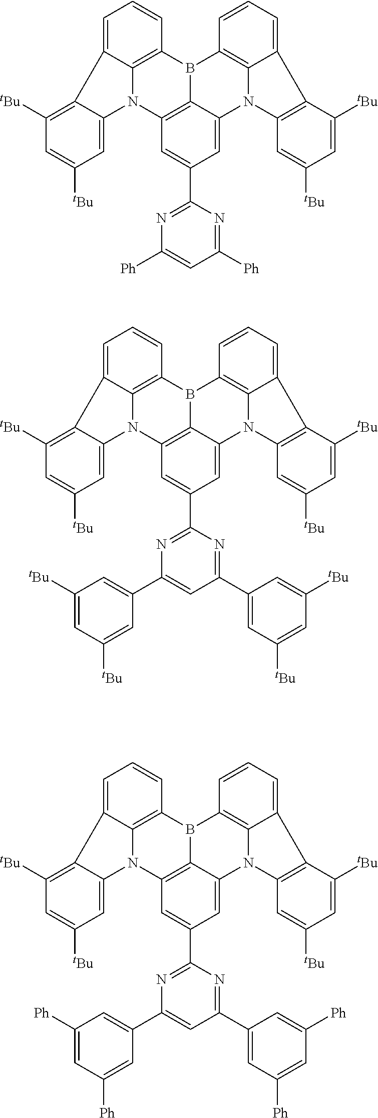 [SMILES: CC(C)(C)c1cc(C(C)(C)C)c2c3cccc4c3n(c2c1)-c1cc(-c2nc(-c3ccccc3)cc(-c3ccccc3)n2)cc2c1B4c1cccc3c4c(C(C)(C)C)cc(C(C)(C)C)cc4n-2c13 ; CC(C)(C)c1cc(-c2cc(-c3cc(C(C)(C)C)cc(C(C)(C)C)c3)nc(-c3cc4c5c(c3)-n3c6cc(C(C)(C)C)cc(C(C)(C)C)c6c6cccc(c63)B5c3cccc5c6c(C(C)(C)C)cc(C(C)(C)C)cc6n-4c35)n2)cc(C(C)(C)C)c1 ; CC(C)(C)c1cc(C(C)(C)C)c2c3cccc4c3n(c2c1)-c1cc(-c2nc(-c3cc(-c5ccccc5)cc(-c5ccccc5)c3)cc(-c3cc(-c5ccccc5)cc(-c5ccccc5)c3)n2)cc2c1B4c1cccc3c4c(C(C)(C)C)cc(C(C)(C)C)cc4n-2c13]

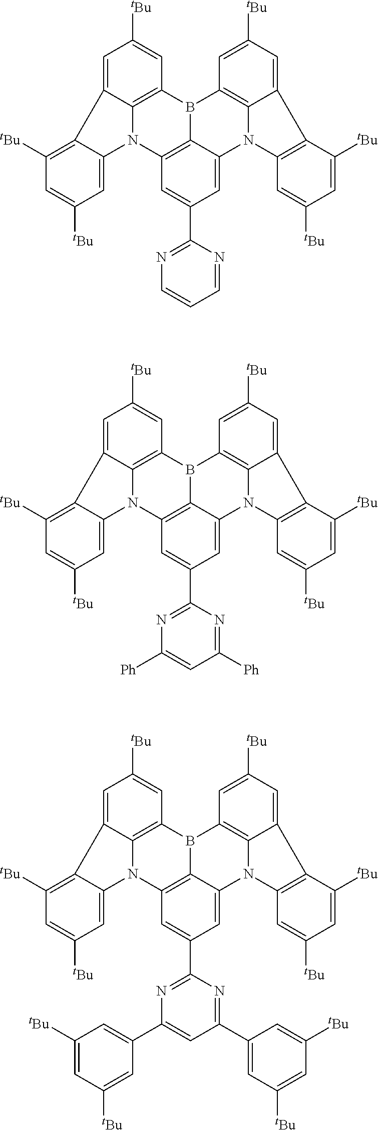 [SMILES: CC(C)(C)c1cc2c3c(c1)c1c(C(C)(C)C)cc(C(C)(C)C)cc1n3-c1cc(-c3ncccn3)cc3c1B2c1cc(C(C)(C)C)cc2c4c(C(C)(C)C)cc(C(C)(C)C)cc4n-3c12 ; CC(C)(C)c1cc2c3c(c1)c1c(C(C)(C)C)cc(C(C)(C)C)cc1n3-c1cc(-c3nc(-c4ccccc4)cc(-c4ccccc4)n3)cc3c1B2c1cc(C(C)(C)C)cc2c4c(C(C)(C)C)cc(C(C)(C)C)cc4n-3c12 ; CC(C)(C)c1cc(-c2cc(-c3cc(C(C)(C)C)cc(C(C)(C)C)c3)nc(-c3cc4c5c(c3)-n3c6cc(C(C)(C)C)cc(C(C)(C)C)c6c6cc(C(C)(C)C)cc(c63)B5c3cc(C(C)(C)C)cc5c6c(C(C)(C)C)cc(C(C)(C)C)cc6n-4c35)n2)cc(C(C)(C)C)c1]

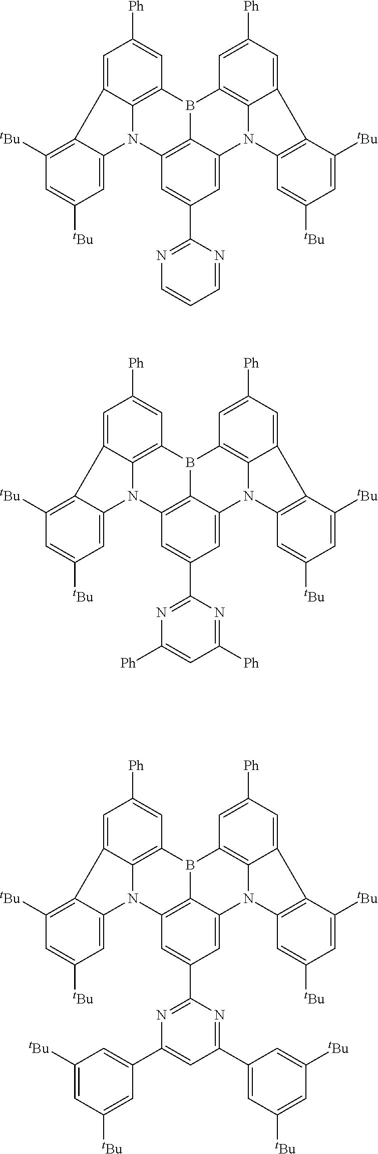 [SMILES: CC(C)(C)c1cc(C(C)(C)C)c2c3cc(-c4ccccc4)cc4c3n(c2c1)-c1cc(-c2ncccn2)cc2c1B4c1cc(-c3ccccc3)cc3c4c(C(C)(C)C)cc(C(C)(C)C)cc4n-2c13 ; CC(C)(C)c1cc(C(C)(C)C)c2c3cc(-c4ccccc4)cc4c3n(c2c1)-c1cc(-c2nc(-c3ccccc3)cc(-c3ccccc3)n2)cc2c1B4c1cc(-c3ccccc3)cc3c4c(C(C)(C)C)cc(C(C)(C)C)cc4n-2c13 ; CC(C)(C)c1cc(-c2cc(-c3cc(C(C)(C)C)cc(C(C)(C)C)c3)nc(-c3cc4c5c(c3)-n3c6cc(C(C)(C)C)cc(C(C)(C)C)c6c6cc(-c7ccccc7)cc(c63)B5c3cc(-c5ccccc5)cc5c6c(C(C)(C)C)cc(C(C)(C)C)cc6n-4c35)n2)cc(C(C)(C)C)c1]

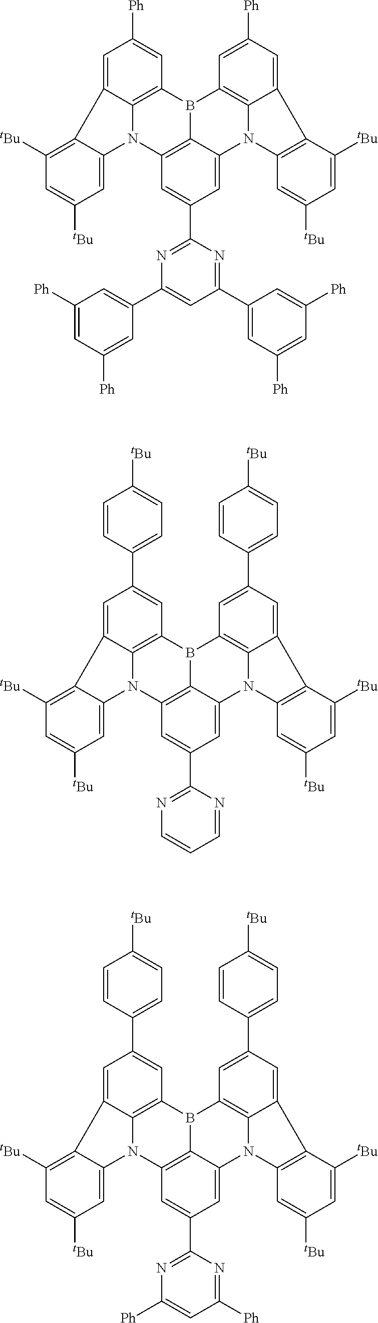

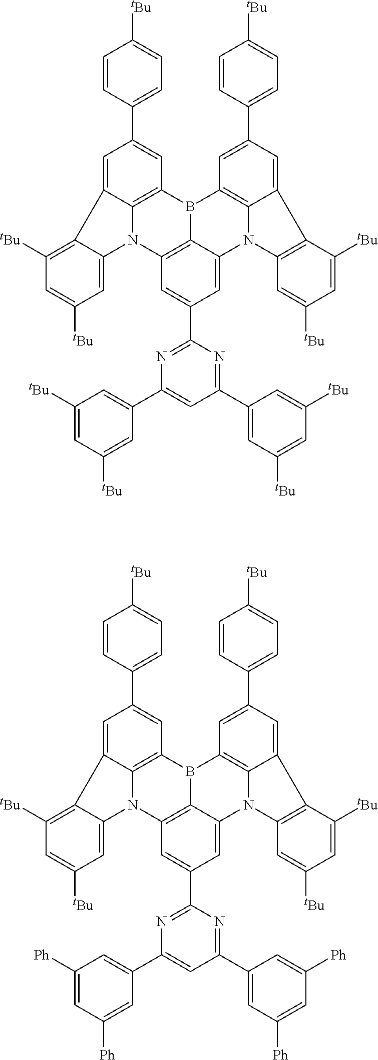 [SMILES: CC(C)(C)c1ccc(-c2cc3c4c(c2)c2c(C(C)(C)C)cc(C(C)(C)C)cc2n4-c2cc(-c4nc(-c5cc(C(C)(C)C)cc(C(C)(C)C)c5)cc(-c5cc(C(C)(C)C)cc(C(C)(C)C)c5)n4)cc4c2B3c2cc(-c3ccc(C(C)(C)C)cc3)cc3c5c(C(C)(C)C)cc(C(C)(C)C)cc5n-4c23)cc1 ; CC(C)(C)c1ccc(-c2cc3c4c(c2)c2c(C(C)(C)C)cc(C(C)(C)C)cc2n4-c2cc(-c4nc(-c5cc(-c6ccccc6)cc(-c6ccccc6)c5)cc(-c5cc(-c6ccccc6)cc(-c6ccccc6)c5)n4)cc4c2B3c2cc(-c3ccc(C(C)(C)C)cc3)cc3c5c(C(C)(C)C)cc(C(C)(C)C)cc5n-4c23)cc1]

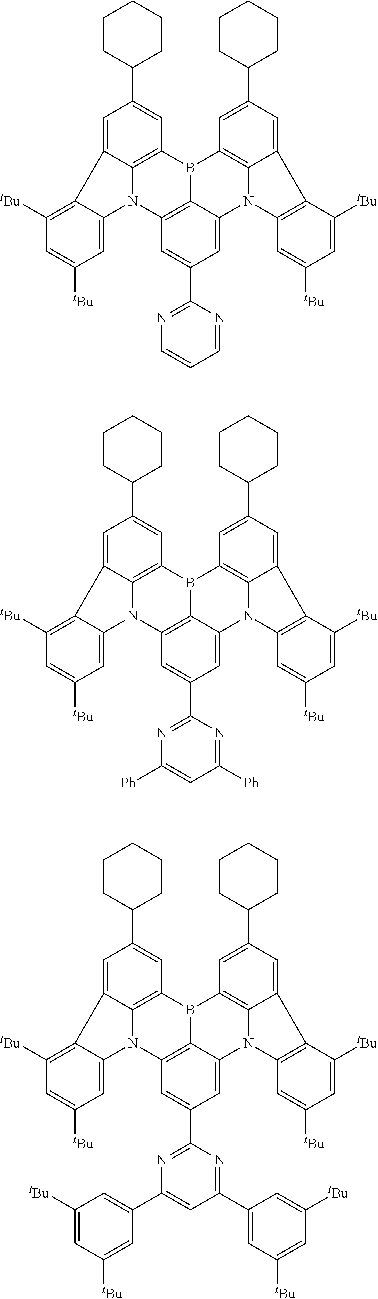 [SMILES: CC(C)(C)c1cc(C(C)(C)C)c2c3cc(C4CCCCC4)cc4c3n(c2c1)-c1cc(-c2ncccn2)cc2c1B4c1cc(C3CCCCC3)cc3c4c(C(C)(C)C)cc(C(C)(C)C)cc4n-2c13 ; CC(C)(C)c1cc(C(C)(C)C)c2c3cc(C4CCCCC4)cc4c3n(c2c1)-c1cc(-c2nc(-c3ccccc3)cc(-c3ccccc3)n2)cc2c1B4c1cc(C3CCCCC3)cc3c4c(C(C)(C)C)cc(C(C)(C)C)cc4n-2c13 ; CC(C)(C)c1cc(-c2cc(-c3cc(C(C)(C)C)cc(C(C)(C)C)c3)nc(-c3cc4c5c(c3)-n3c6cc(C(C)(C)C)cc(C(C)(C)C)c6c6cc(C7CCCCC7)cc(c63)B5c3cc(C5CCCCC5)cc5c6c(C(C)(C)C)cc(C(C)(C)C)cc6n-4c35)n2)cc(C(C)(C)C)c1]

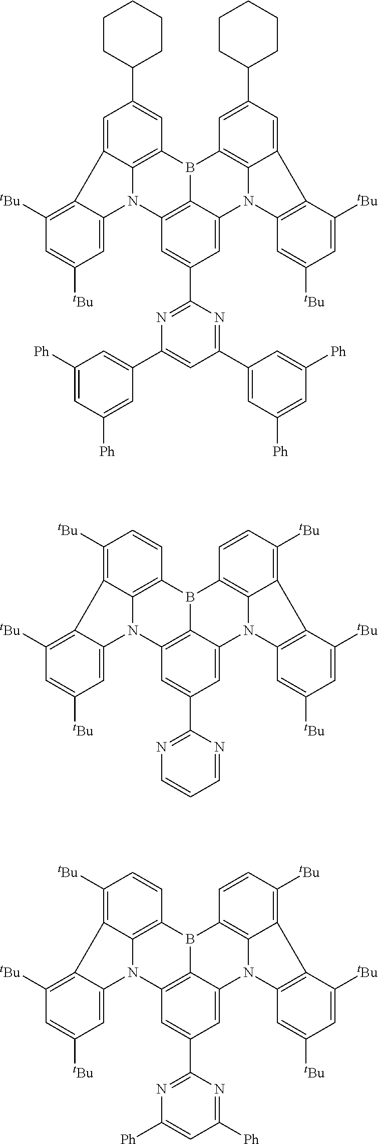 [SMILES: CC(C)(C)c1cc(C(C)(C)C)c2c3cc(C4CCCCC4)cc4c3n(c2c1)-c1cc(-c2nc(-c3cc(-c5ccccc5)cc(-c5ccccc5)c3)cc(-c3cc(-c5ccccc5)cc(-c5ccccc5)c3)n2)cc2c1B4c1cc(C3CCCCC3)cc3c4c(C(C)(C)C)cc(C(C)(C)C)cc4n-2c13 ; CC(C)(C)c1cc(C(C)(C)C)c2c3c(C(C)(C)C)ccc4c3n(c2c1)-c1cc(-c2ncccn2)cc2c1B4c1ccc(C(C)(C)C)c3c4c(C(C)(C)C)cc(C(C)(C)C)cc4n-2c13 ; CC(C)(C)c1cc(C(C)(C)C)c2c3c(C(C)(C)C)ccc4c3n(c2c1)-c1cc(-c2nc(-c3ccccc3)cc(-c3ccccc3)n2)cc2c1B4c1ccc(C(C)(C)C)c3c4c(C(C)(C)C)cc(C(C)(C)C)cc4n-2c13]

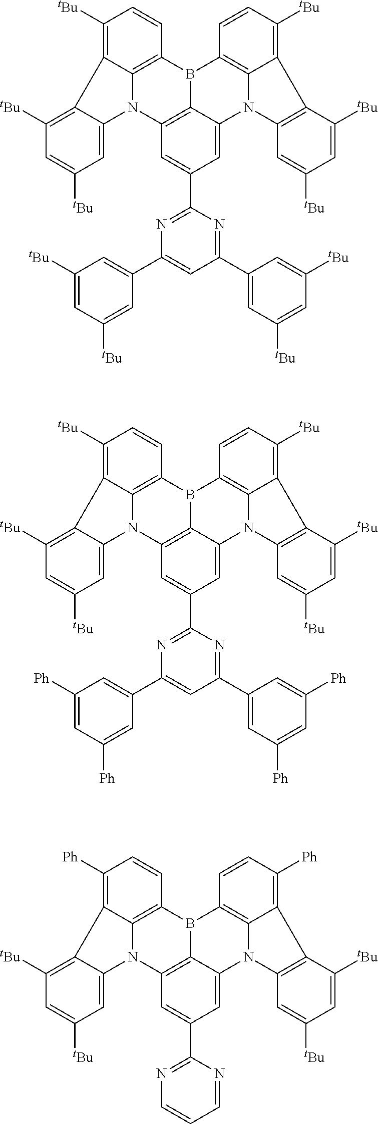

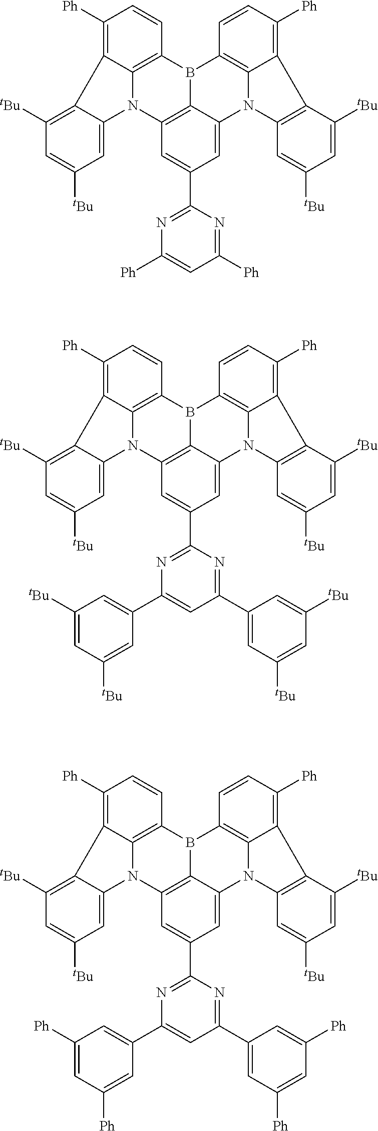

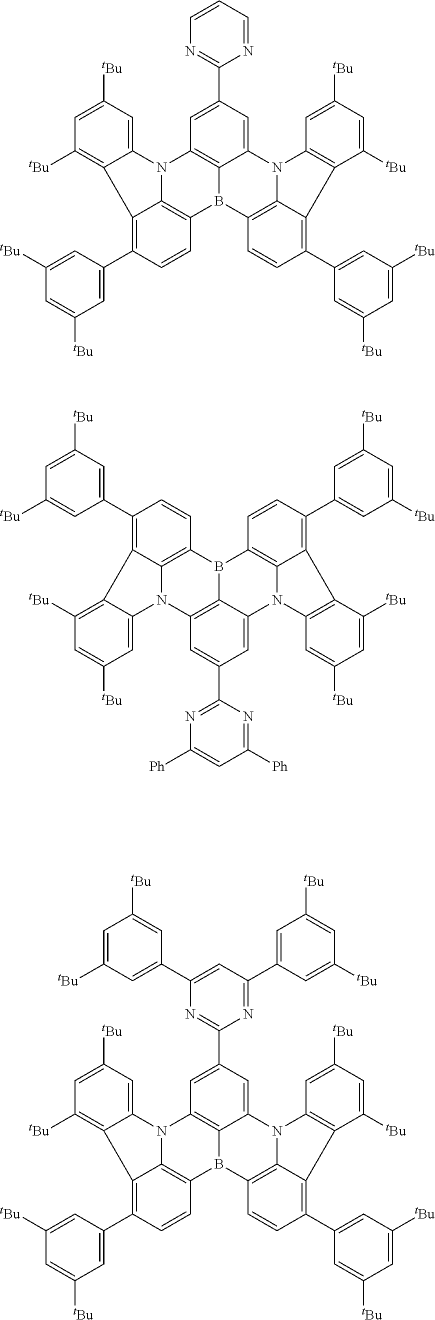

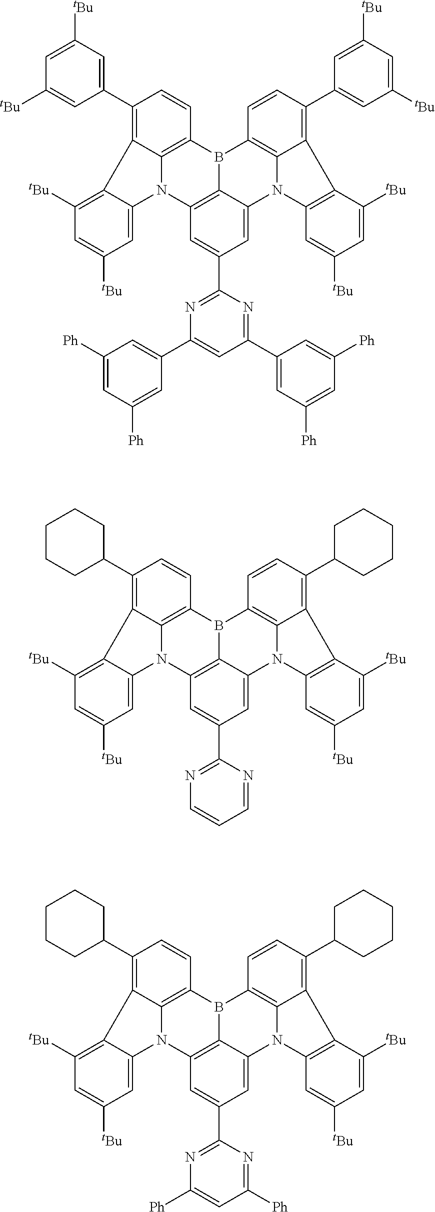

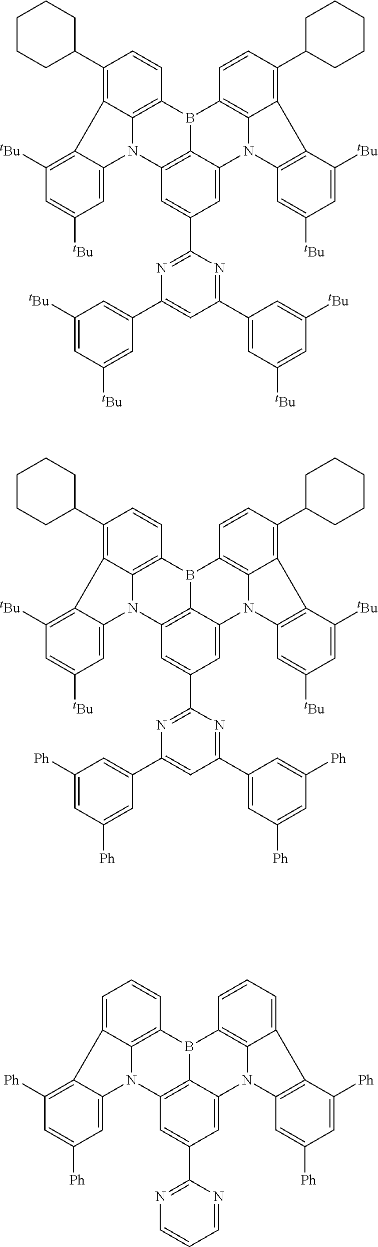 [SMILES: CC(C)(C)c1cc(-c2cc(-c3cc(C(C)(C)C)cc(C(C)(C)C)c3)nc(-c3cc4c5c(c3)-n3c6cc(C(C)(C)C)cc(C(C)(C)C)c6c6c(C7CCCCC7)ccc(c63)B5c3ccc(C5CCCCC5)c5c6c(C(C)(C)C)cc(C(C)(C)C)cc6n-4c35)n2)cc(C(C)(C)C)c1 ; CC(C)(C)c1cc(C(C)(C)C)c2c3c(C4CCCCC4)ccc4c3n(c2c1)-c1cc(-c2nc(-c3cc(-c5ccccc5)cc(-c5ccccc5)c3)cc(-c3cc(-c5ccccc5)cc(-c5ccccc5)c3)n2)cc2c1B4c1ccc(C3CCCCC3)c3c4c(C(C)(C)C)cc(C(C)(C)C)cc4n-2c13 ; c1ccc(-c2cc(-c3ccccc3)c3c4cccc5c4n(c3c2)-c2cc(-c3ncccn3)cc3c2B5c2cccc4c5c(-c6ccccc6)cc(-c6ccccc6)cc5n-3c24)cc1]

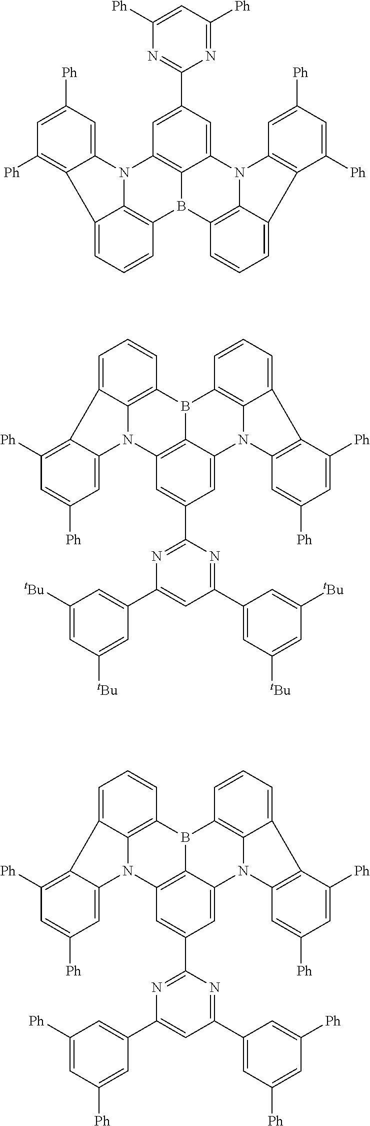 [SMILES: c1ccc(-c2cc(-c3ccccc3)c3c4cccc5c4n(c3c2)-c2cc(-c3nc(-c4ccccc4)cc(-c4ccccc4)n3)cc3c2B5c2cccc4c5c(-c6ccccc6)cc(-c6ccccc6)cc5n-3c24)cc1 ; CC(C)(C)c1cc(-c2cc(-c3cc(C(C)(C)C)cc(C(C)(C)C)c3)nc(-c3cc4c5c(c3)-n3c6cc(-c7ccccc7)cc(-c7ccccc7)c6c6cccc(c63)B5c3cccc5c6c(-c7ccccc7)cc(-c7ccccc7)cc6n-4c35)n2)cc(C(C)(C)C)c1 ; c1ccc(-c2cc(-c3ccccc3)cc(-c3cc(-c4cc(-c5ccccc5)cc(-c5ccccc5)c4)nc(-c4cc5c6c(c4)-n4c7cc(-c8ccccc8)cc(-c8ccccc8)c7c7cccc(c74)B6c4cccc6c7c(-c8ccccc8)cc(-c8ccccc8)cc7n-5c46)n3)c2)cc1]

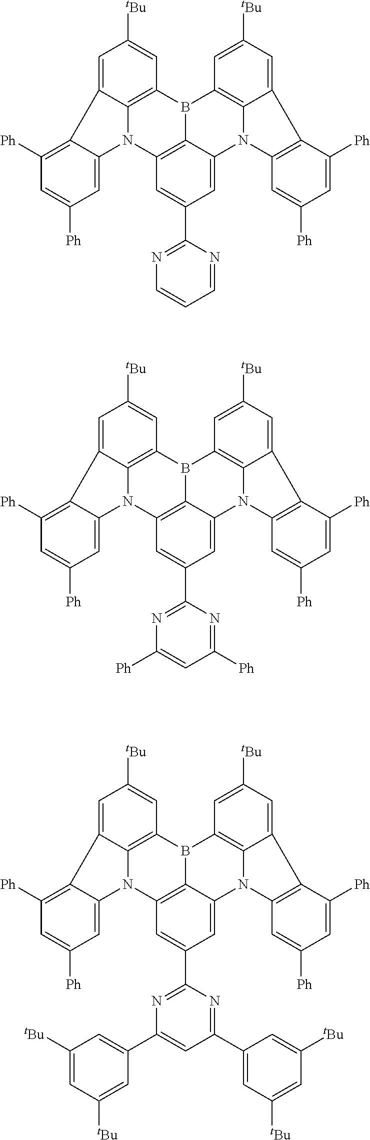 [SMILES: CC(C)(C)c1cc2c3c(c1)c1c(-c4ccccc4)cc(-c4ccccc4)cc1n3-c1cc(-c3ncccn3)cc3c1B2c1cc(C(C)(C)C)cc2c4c(-c5ccccc5)cc(-c5ccccc5)cc4n-3c12 ; CC(C)(C)c1cc2c3c(c1)c1c(-c4ccccc4)cc(-c4ccccc4)cc1n3-c1cc(-c3nc(-c4ccccc4)cc(-c4ccccc4)n3)cc3c1B2c1cc(C(C)(C)C)cc2c4c(-c5ccccc5)cc(-c5ccccc5)cc4n-3c12 ; CC(C)(C)c1cc(-c2cc(-c3cc(C(C)(C)C)cc(C(C)(C)C)c3)nc(-c3cc4c5c(c3)-n3c6cc(-c7ccccc7)cc(-c7ccccc7)c6c6cc(C(C)(C)C)cc(c63)B5c3cc(C(C)(C)C)cc5c6c(-c7ccccc7)cc(-c7ccccc7)cc6n-4c35)n2)cc(C(C)(C)C)c1]

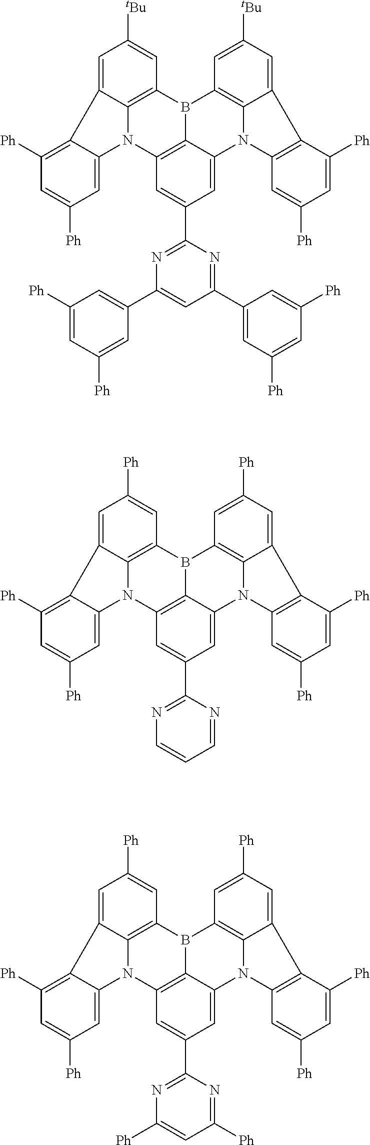 [SMILES: CC(C)(C)c1cc2c3c(c1)c1c(-c4ccccc4)cc(-c4ccccc4)cc1n3-c1cc(-c3nc(-c4cc(-c5ccccc5)cc(-c5ccccc5)c4)cc(-c4cc(-c5ccccc5)cc(-c5ccccc5)c4)n3)cc3c1B2c1cc(C(C)(C)C)cc2c4c(-c5ccccc5)cc(-c5ccccc5)cc4n-3c12 ; c1ccc(-c2cc3c4c(c2)c2c(-c5ccccc5)cc(-c5ccccc5)cc2n4-c2cc(-c4ncccn4)cc4c2B3c2cc(-c3ccccc3)cc3c5c(-c6ccccc6)cc(-c6ccccc6)cc5n-4c23)cc1 ; c1ccc(-c2cc3c4c(c2)c2c(-c5ccccc5)cc(-c5ccccc5)cc2n4-c2cc(-c4nc(-c5ccccc5)cc(-c5ccccc5)n4)cc4c2B3c2cc(-c3ccccc3)cc3c5c(-c6ccccc6)cc(-c6ccccc6)cc5n-4c23)cc1]

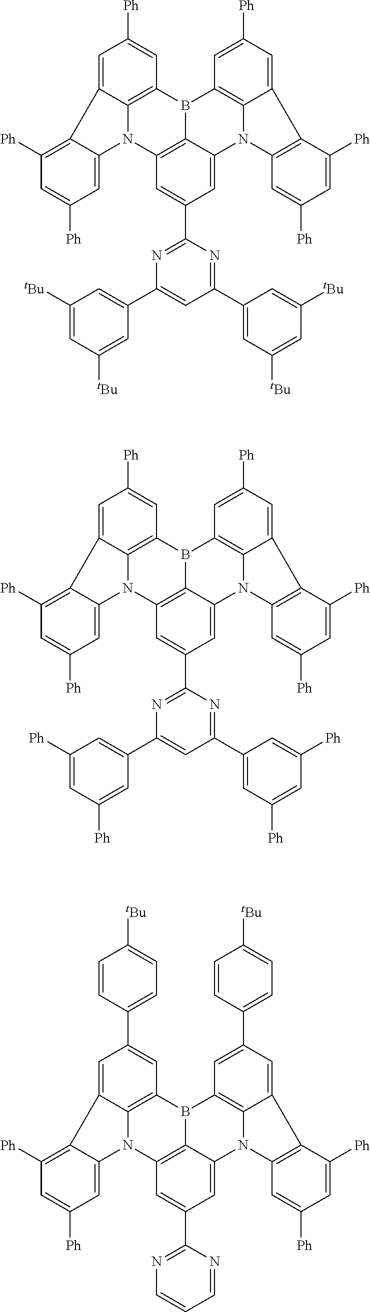

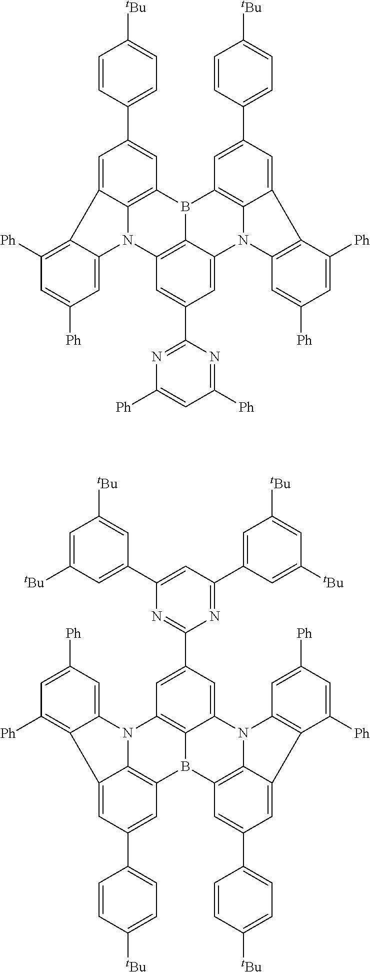 [SMILES: CC(C)(C)c1ccc(-c2cc3c4c(c2)c2c(-c5ccccc5)cc(-c5ccccc5)cc2n4-c2cc(-c4nc(-c5ccccc5)cc(-c5ccccc5)n4)cc4c2B3c2cc(-c3ccc(C(C)(C)C)cc3)cc3c5c(-c6ccccc6)cc(-c6ccccc6)cc5n-4c23)cc1 ; CC(C)(C)c1ccc(-c2cc3c4c(c2)c2c(-c5ccccc5)cc(-c5ccccc5)cc2n4-c2cc(-c4nc(-c5cc(C(C)(C)C)cc(C(C)(C)C)c5)cc(-c5cc(C(C)(C)C)cc(C(C)(C)C)c5)n4)cc4c2B3c2cc(-c3ccc(C(C)(C)C)cc3)cc3c5c(-c6ccccc6)cc(-c6ccccc6)cc5n-4c23)cc1]

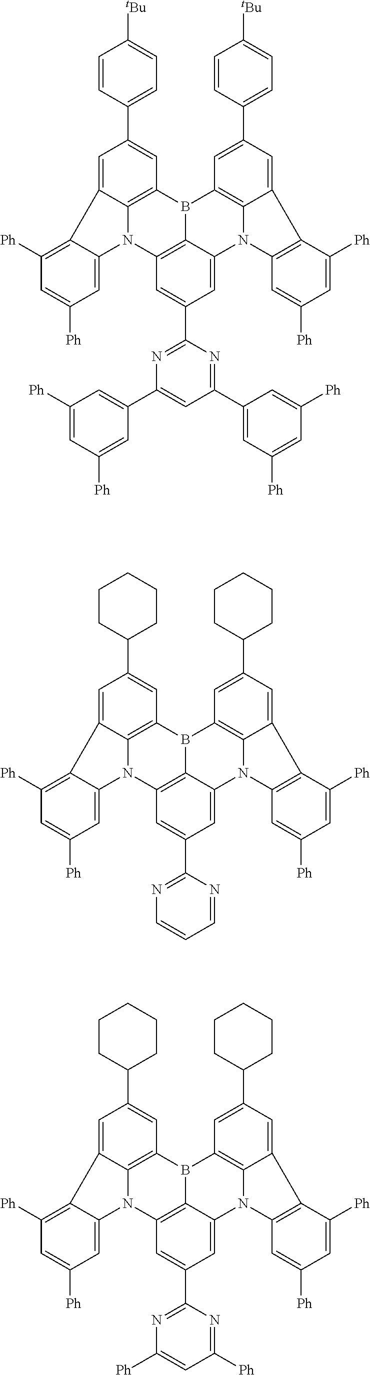

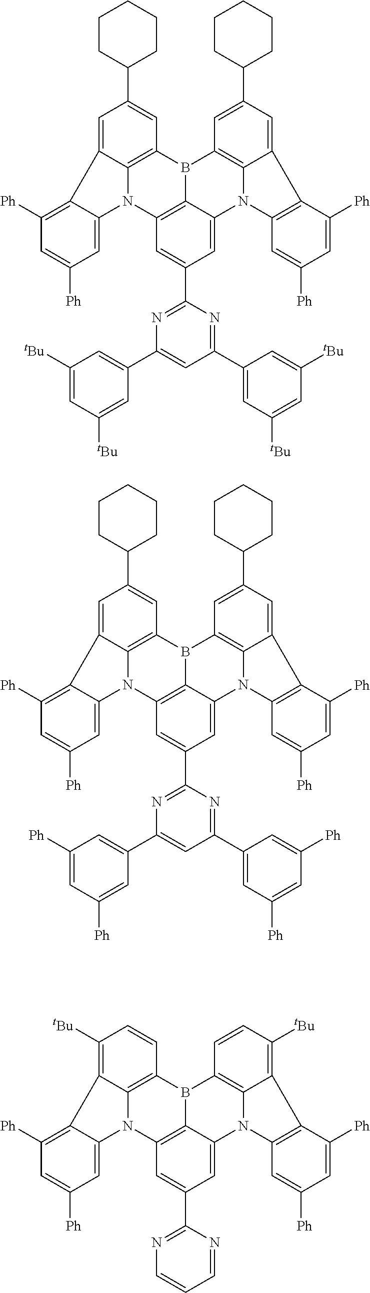

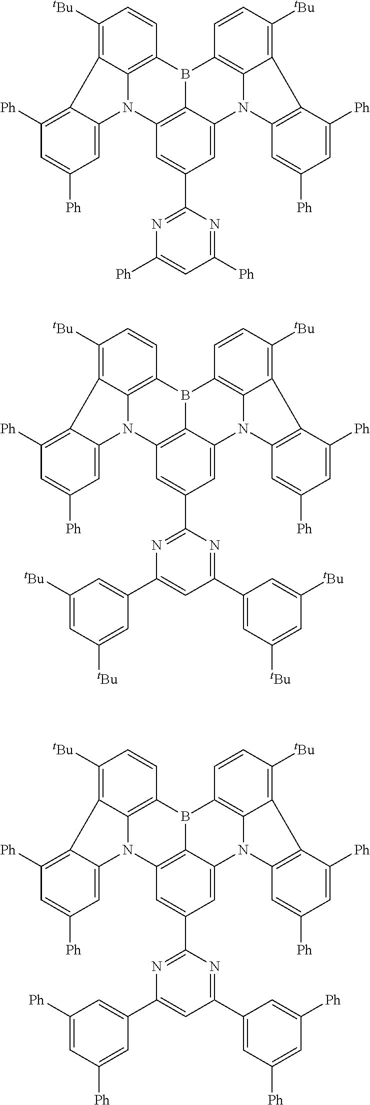

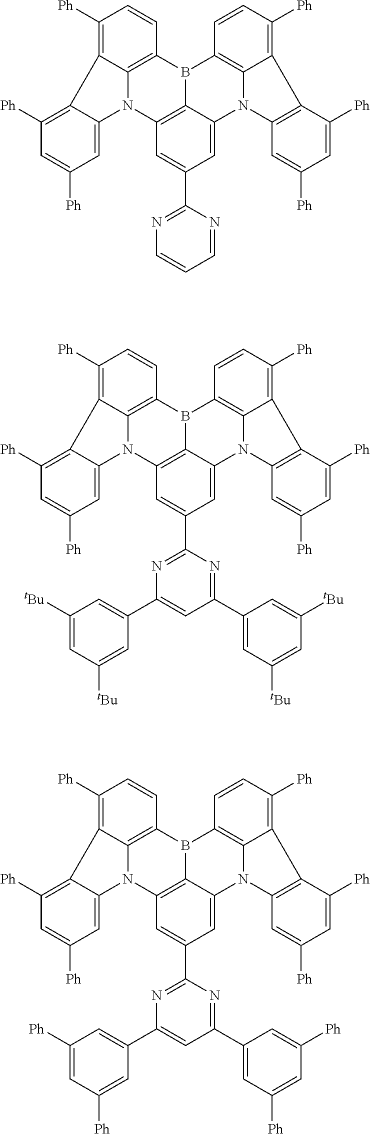

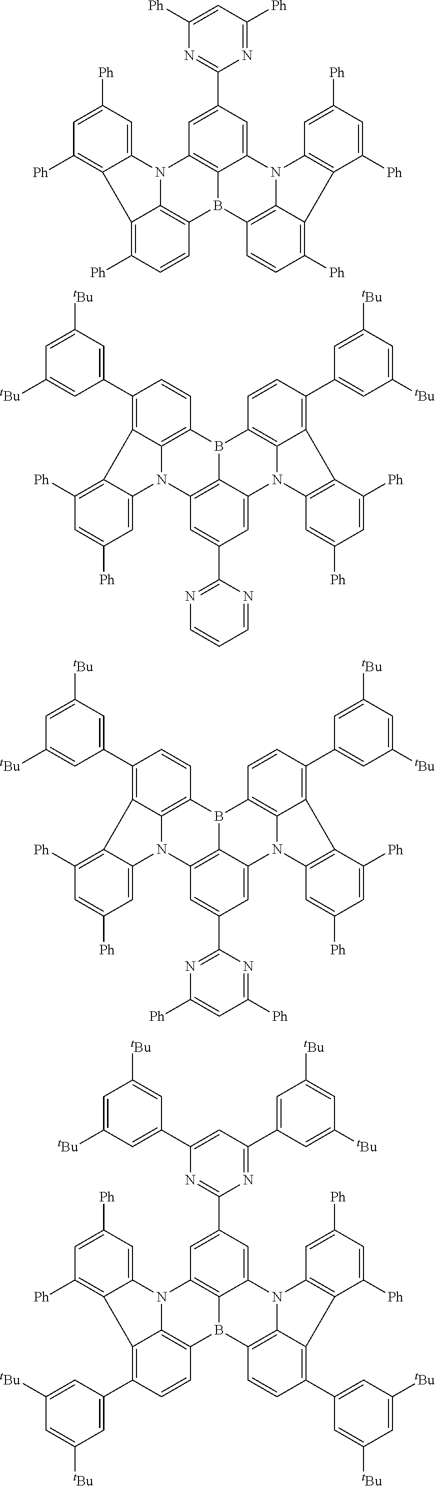

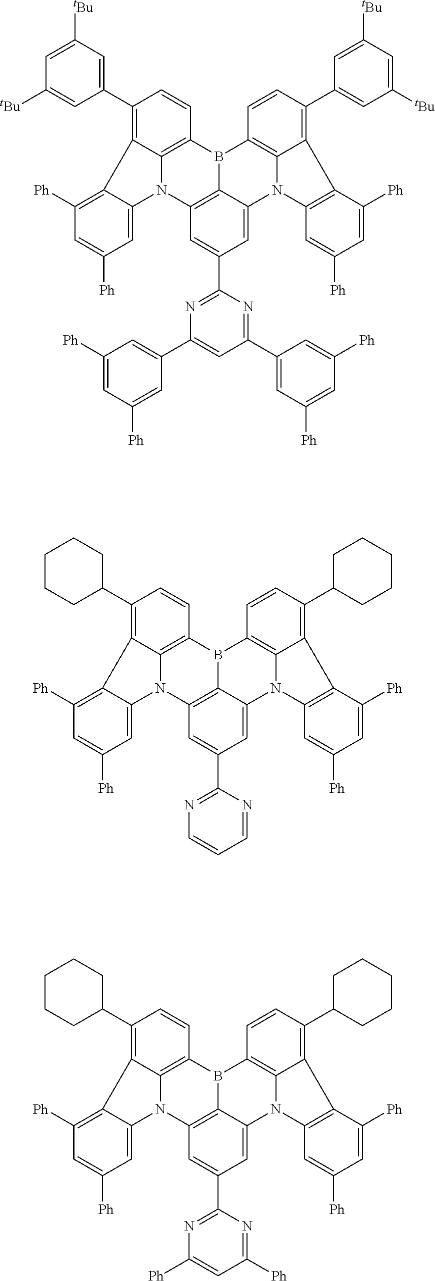

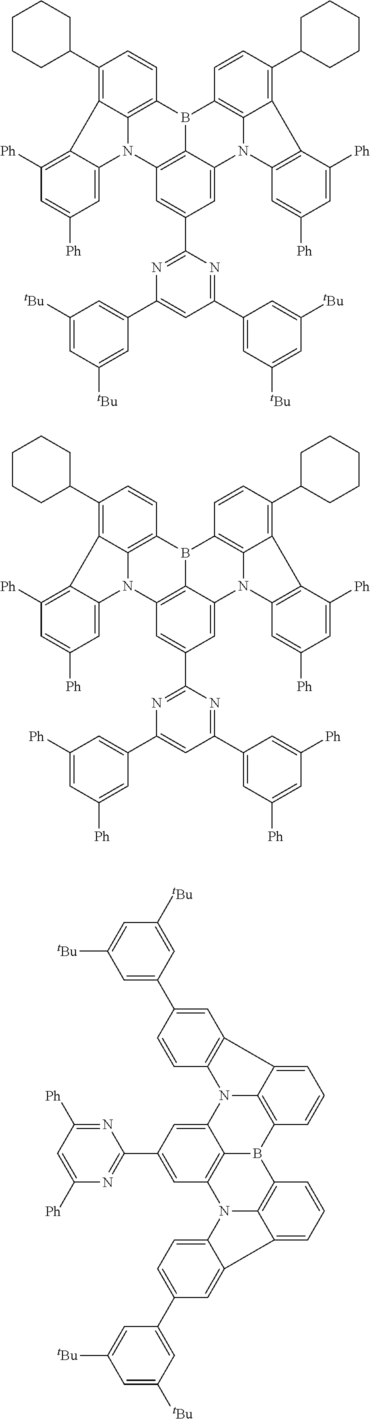

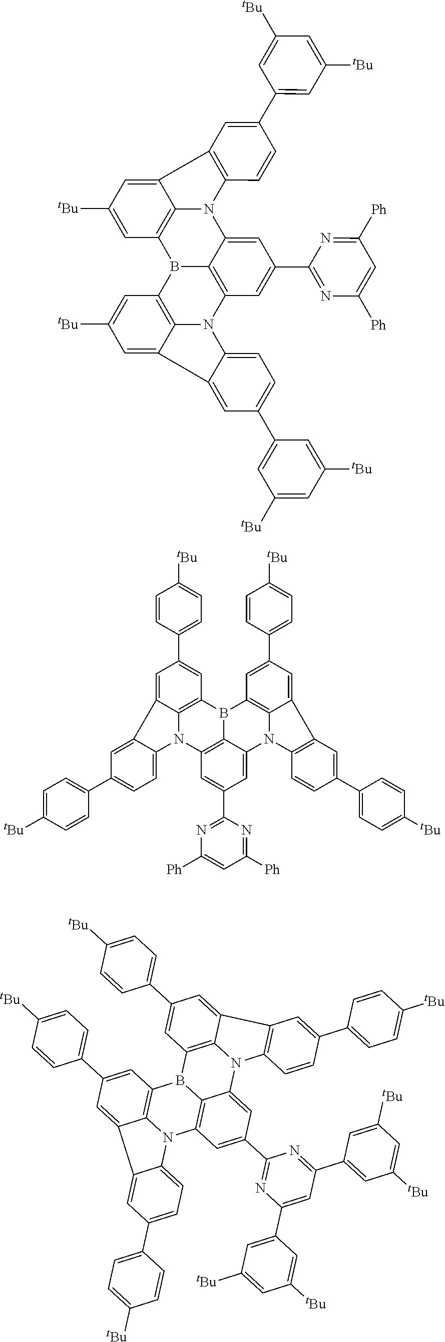

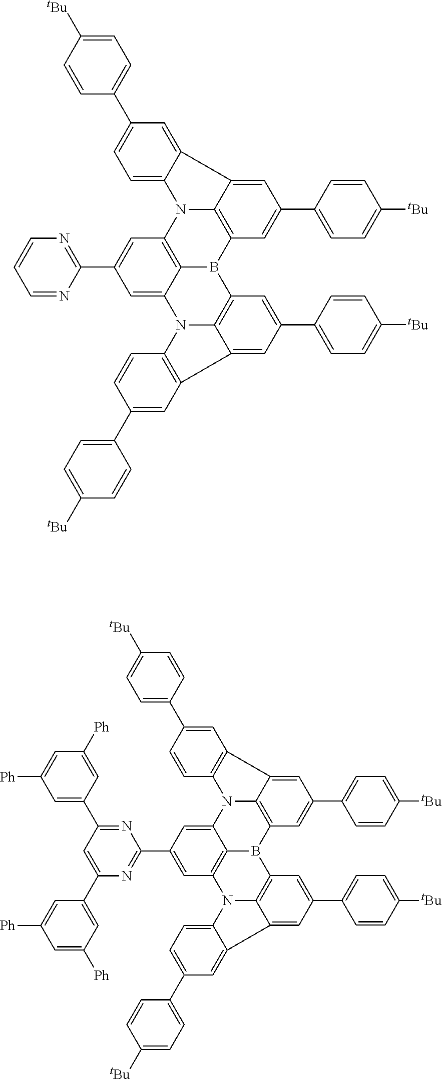 [SMILES: CC(C)(C)c1ccc(-c2ccc3c(c2)c2cc(-c4ccc(C(C)(C)C)cc4)cc4c2n3-c2cc(-c3ncccn3)cc3c2B4c2cc(-c4ccc(C(C)(C)C)cc4)cc4c5cc(-c6ccc(C(C)(C)C)cc6)ccc5n-3c24)cc1 ; CC(C)(C)c1ccc(-c2ccc3c(c2)c2cc(-c4ccc(C(C)(C)C)cc4)cc4c2n3-c2cc(-c3nc(-c5cc(-c6ccccc6)cc(-c6ccccc6)c5)cc(-c5cc(-c6ccccc6)cc(-c6ccccc6)c5)n3)cc3c2B4c2cc(-c4ccc(C(C)(C)C)cc4)cc4c5cc(-c6ccc(C(C)(C)C)cc6)ccc5n-3c24)cc1]

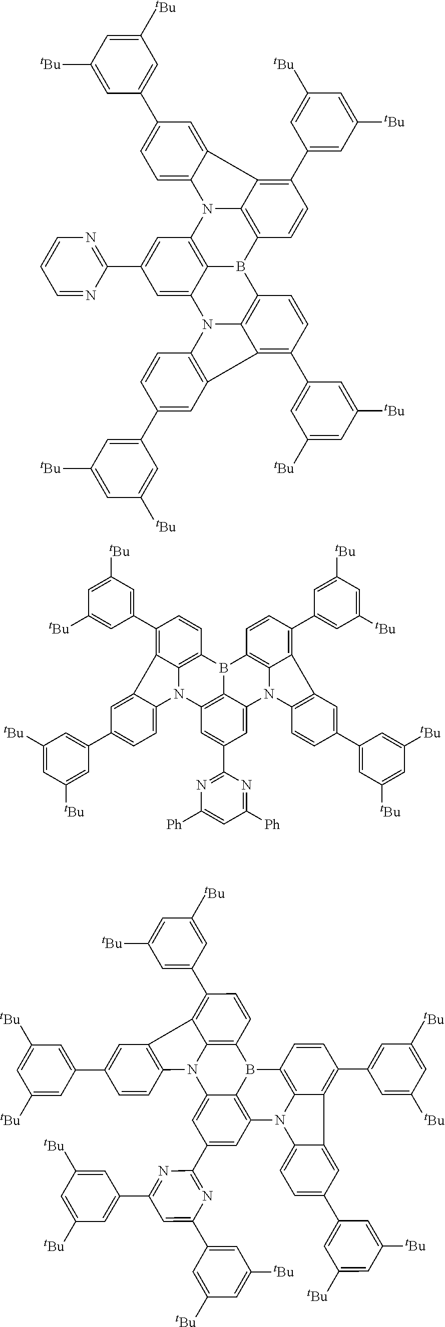

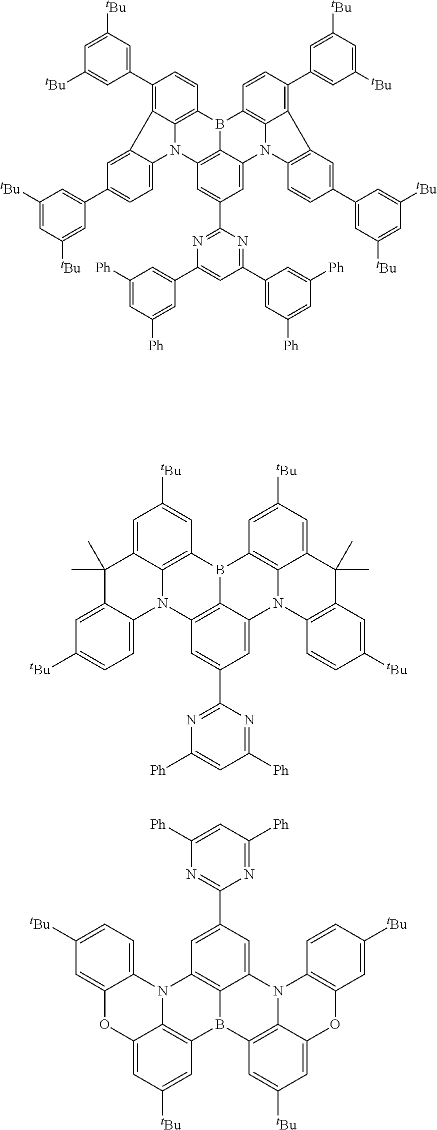

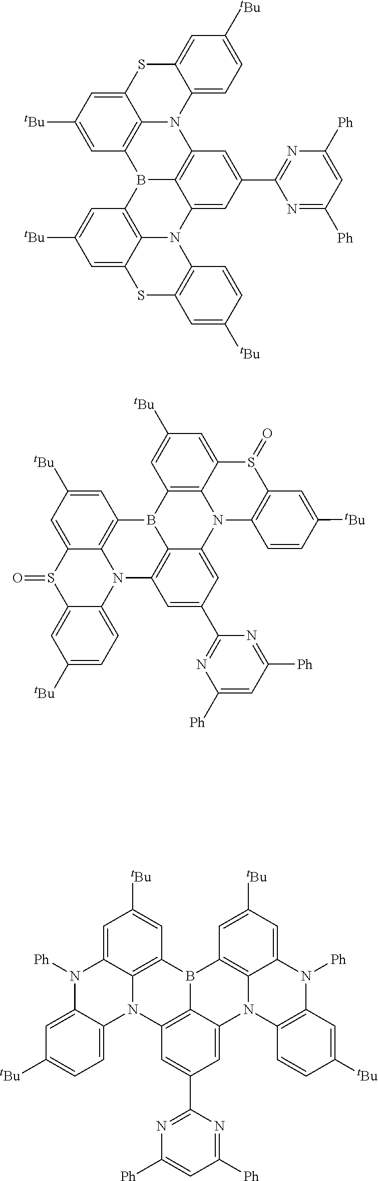 [SMILES: CC(C)(C)c1ccc2c(c1)Sc1cc(C(C)(C)C)cc3c1N2c1cc(-c2nc(-c4ccccc4)cc(-c4ccccc4)n2)cc2c1B3c1cc(C(C)(C)C)cc3c1N2c1ccc(C(C)(C)C)cc1S3 ; CC(C)(C)c1ccc2c(c1)S(=O)c1cc(C(C)(C)C)cc3c1N2c1cc(-c2nc(-c4ccccc4)cc(-c4ccccc4)n2)cc2c1B3c1cc(C(C)(C)C)cc3c1N2c1ccc(C(C)(C)C)cc1S3=O ; CC(C)(C)c1ccc2c(c1)N(c1ccccc1)c1cc(C(C)(C)C)cc3c1N2c1cc(-c2nc(-c4ccccc4)cc(-c4ccccc4)n2)cc2c1B3c1cc(C(C)(C)C)cc3c1N2c1ccc(C(C)(C)C)cc1N3c1ccccc1]

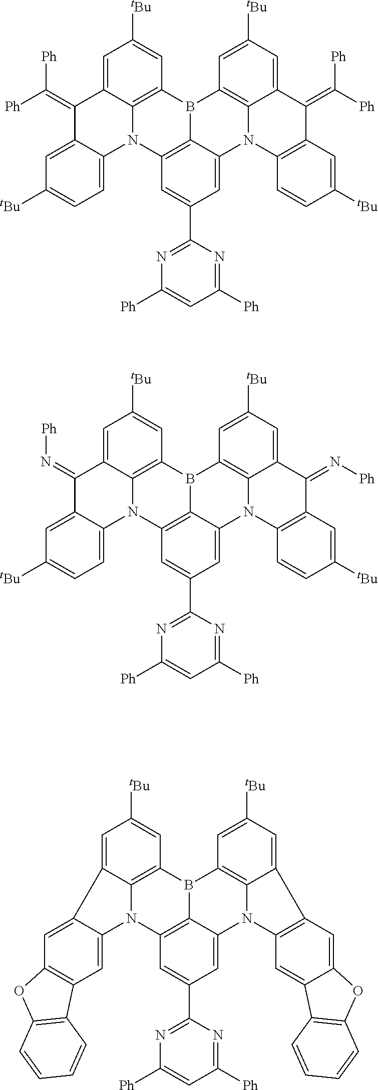 [SMILES: CC(C)(C)c1ccc2c(c1)C(=C(c1ccccc1)c1ccccc1)c1cc(C(C)(C)C)cc3c1N2c1cc(-c2nc(-c4ccccc4)cc(-c4ccccc4)n2)cc2c1B3c1cc(C(C)(C)C)cc3c1N2c1ccc(C(C)(C)C)cc1C3=C(c1ccccc1)c1ccccc1 ; CC(C)(C)c1ccc2c(c1)/c(=N/c1ccccc1)c1cc(C(C)(C)C)cc3c1n2-c1cc(-c2nc(-c4ccccc4)cc(-c4ccccc4)n2)cc2c1B3c1cc(C(C)(C)C)cc3/c(=N/c4ccccc4)c4cc(C(C)(C)C)ccc4n-2c13 ; CC(C)(C)c1cc2c3c(c1)c1cc4oc5ccccc5c4cc1n3-c1cc(-c3nc(-c4ccccc4)cc(-c4ccccc4)n3)cc3c1B2c1cc(C(C)(C)C)cc2c4cc5oc6ccccc6c5cc4n-3c12]

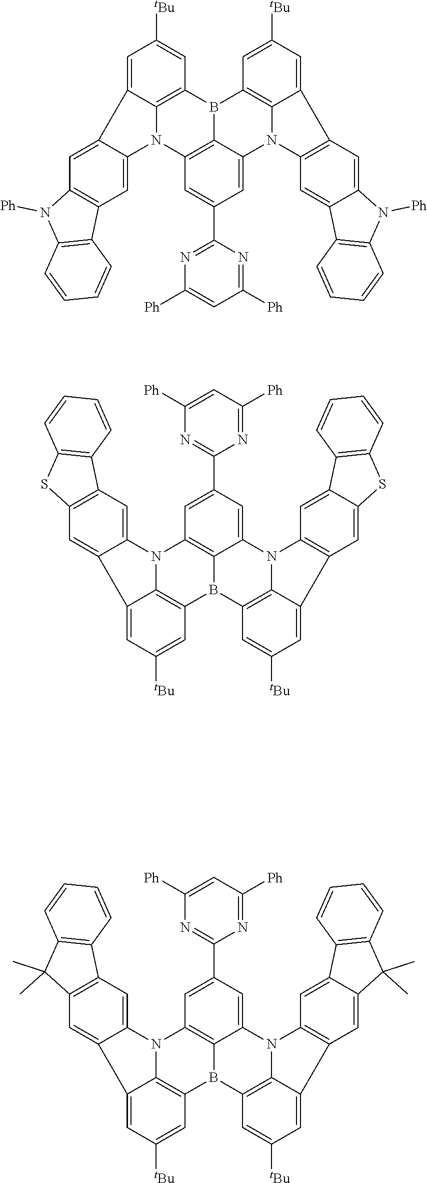

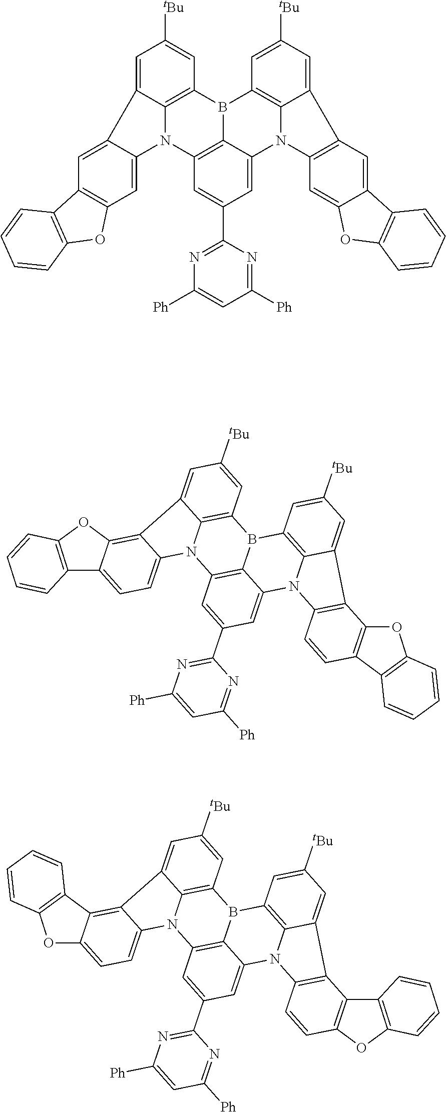 [SMILES: CC(C)(C)c1cc2c3c(c1)c1cc4c(cc1n3-c1cc(-c3nc(-c5ccccc5)cc(-c5ccccc5)n3)cc3c1B2c1cc(C(C)(C)C)cc2c5cc6c(cc5n-3c12)oc1ccccc16)oc1ccccc14 ; CC(C)(C)c1cc2c3c(c1)c1c4oc5ccccc5c4ccc1n3-c1cc(-c3nc(-c4ccccc4)cc(-c4ccccc4)n3)cc3c1B2c1cc(C(C)(C)C)cc2c4c5oc6ccccc6c5ccc4n-3c12 ; CC(C)(C)c1cc2c3c(c1)c1c4c(ccc1n3-c1cc(-c3nc(-c5ccccc5)cc(-c5ccccc5)n3)cc3c1B2c1cc(C(C)(C)C)cc2c5c6c(ccc5n-3c12)oc1ccccc16)oc1ccccc14]

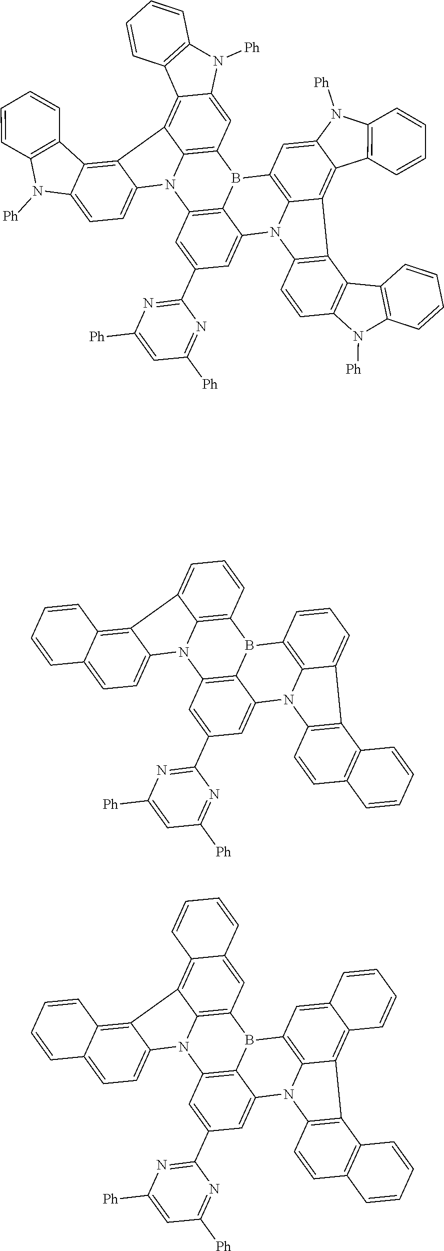

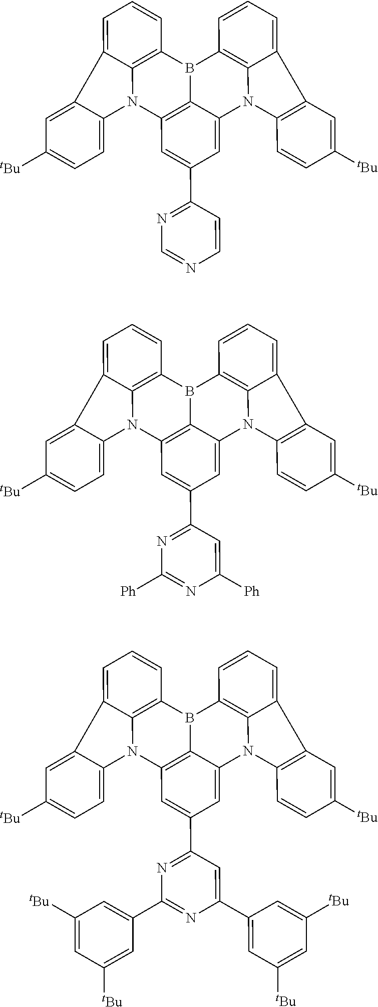 [SMILES: CC(C)(C)c1ccc2c(c1)c1cccc3c1n2-c1cc(-c2ccncn2)cc2c1B3c1cccc3c4cc(C(C)(C)C)ccc4n-2c13 ; CC(C)(C)c1ccc2c(c1)c1cccc3c1n2-c1cc(-c2cc(-c4ccccc4)nc(-c4ccccc4)n2)cc2c1B3c1cccc3c4cc(C(C)(C)C)ccc4n-2c13 ; CC(C)(C)c1cc(-c2cc(-c3cc4c5c(c3)-n3c6ccc(C(C)(C)C)cc6c6cccc(c63)B5c3cccc5c6cc(C(C)(C)C)ccc6n-4c35)nc(-c3cc(C(C)(C)C)cc(C(C)(C)C)c3)n2)cc(C(C)(C)C)c1]

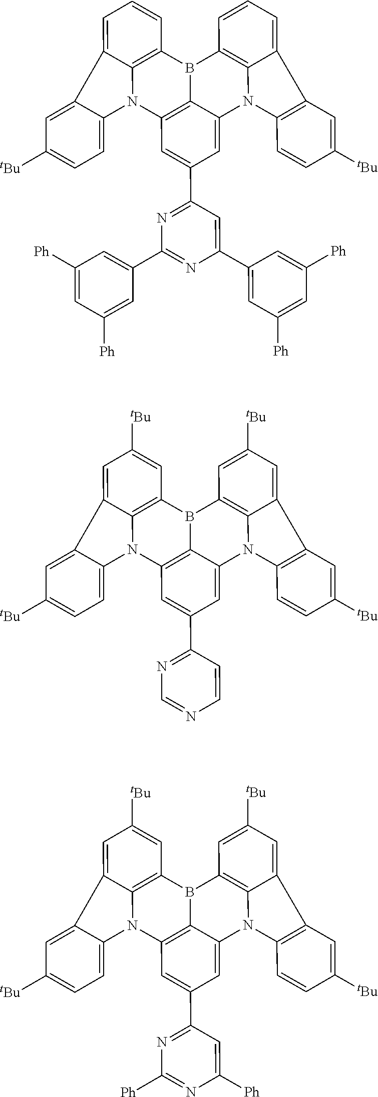 [SMILES: CC(C)(C)c1ccc2c(c1)c1cccc3c1n2-c1cc(-c2cc(-c4cc(-c5ccccc5)cc(-c5ccccc5)c4)nc(-c4cc(-c5ccccc5)cc(-c5ccccc5)c4)n2)cc2c1B3c1cccc3c4cc(C(C)(C)C)ccc4n-2c13 ; CC(C)(C)c1ccc2c(c1)c1cc(C(C)(C)C)cc3c1n2-c1cc(-c2ccncn2)cc2c1B3c1cc(C(C)(C)C)cc3c4cc(C(C)(C)C)ccc4n-2c13 ; CC(C)(C)c1ccc2c(c1)c1cc(C(C)(C)C)cc3c1n2-c1cc(-c2cc(-c4ccccc4)nc(-c4ccccc4)n2)cc2c1B3c1cc(C(C)(C)C)cc3c4cc(C(C)(C)C)ccc4n-2c13]

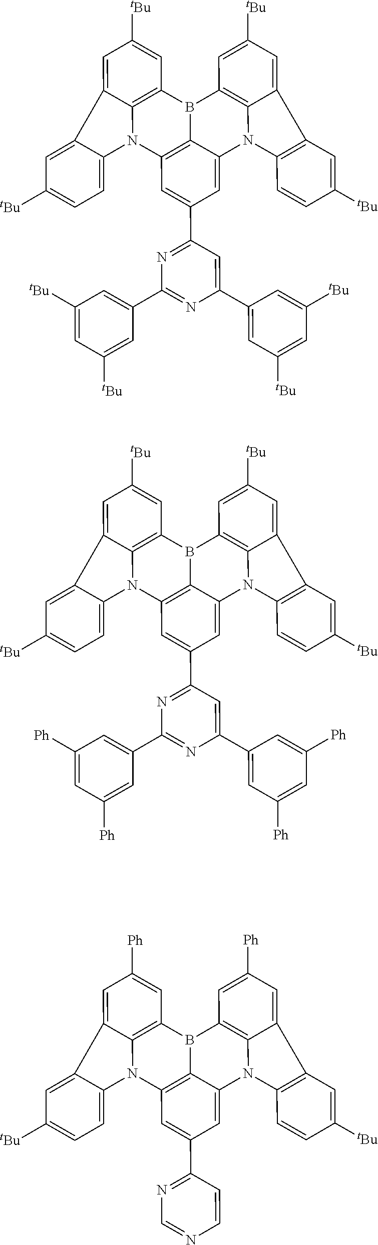 [SMILES: CC(C)(C)c1cc(-c2cc(-c3cc4c5c(c3)-n3c6ccc(C(C)(C)C)cc6c6cc(C(C)(C)C)cc(c63)B5c3cc(C(C)(C)C)cc5c6cc(C(C)(C)C)ccc6n-4c35)nc(-c3cc(C(C)(C)C)cc(C(C)(C)C)c3)n2)cc(C(C)(C)C)c1 ; CC(C)(C)c1ccc2c(c1)c1cc(C(C)(C)C)cc3c1n2-c1cc(-c2cc(-c4cc(-c5ccccc5)cc(-c5ccccc5)c4)nc(-c4cc(-c5ccccc5)cc(-c5ccccc5)c4)n2)cc2c1B3c1cc(C(C)(C)C)cc3c4cc(C(C)(C)C)ccc4n-2c13 ; CC(C)(C)c1ccc2c(c1)c1cc(-c3ccccc3)cc3c1n2-c1cc(-c2ccncn2)cc2c1B3c1cc(-c3ccccc3)cc3c4cc(C(C)(C)C)ccc4n-2c13]

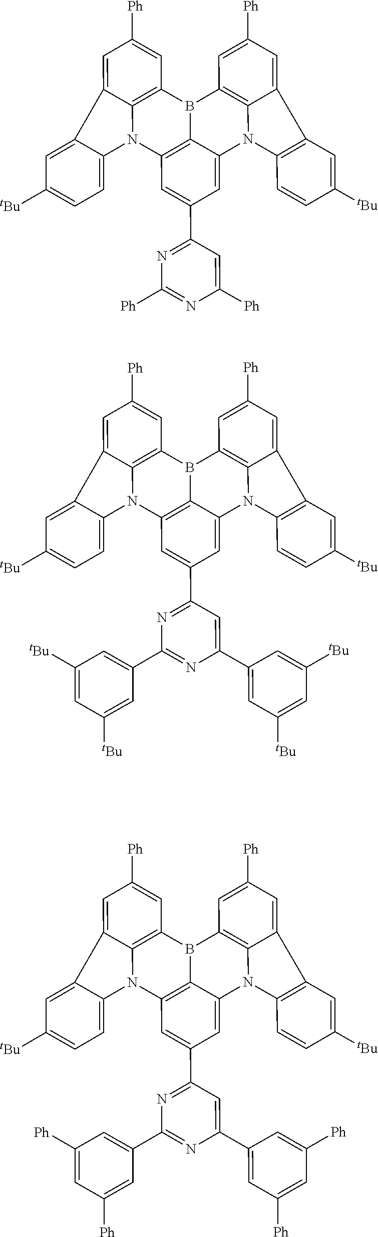 [SMILES: CC(C)(C)c1ccc2c(c1)c1cc(-c3ccccc3)cc3c1n2-c1cc(-c2cc(-c4ccccc4)nc(-c4ccccc4)n2)cc2c1B3c1cc(-c3ccccc3)cc3c4cc(C(C)(C)C)ccc4n-2c13 ; CC(C)(C)c1cc(-c2cc(-c3cc4c5c(c3)-n3c6ccc(C(C)(C)C)cc6c6cc(-c7ccccc7)cc(c63)B5c3cc(-c5ccccc5)cc5c6cc(C(C)(C)C)ccc6n-4c35)nc(-c3cc(C(C)(C)C)cc(C(C)(C)C)c3)n2)cc(C(C)(C)C)c1 ; CC(C)(C)c1ccc2c(c1)c1cc(-c3ccccc3)cc3c1n2-c1cc(-c2cc(-c4cc(-c5ccccc5)cc(-c5ccccc5)c4)nc(-c4cc(-c5ccccc5)cc(-c5ccccc5)c4)n2)cc2c1B3c1cc(-c3ccccc3)cc3c4cc(C(C)(C)C)ccc4n-2c13]

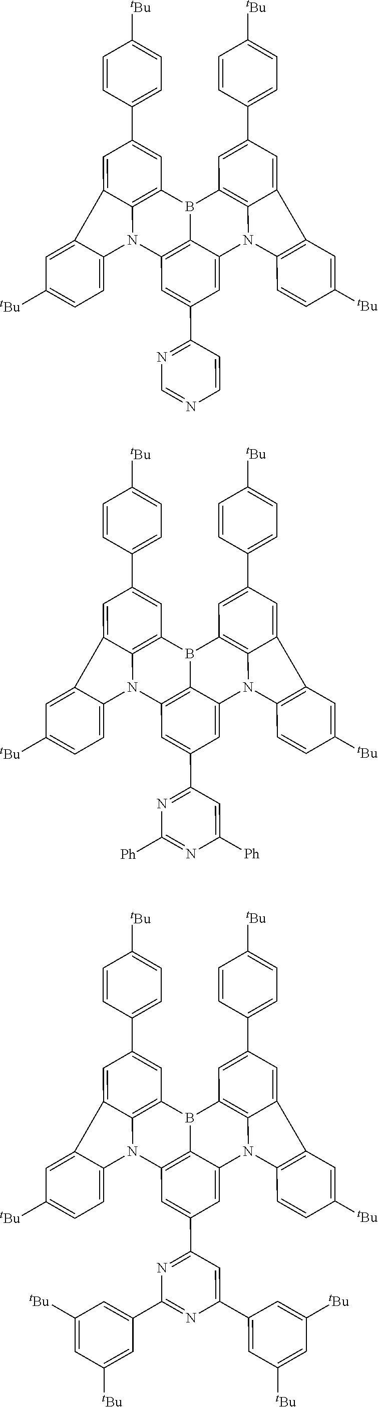 [SMILES: CC(C)(C)c1ccc(-c2cc3c4c(c2)c2cc(C(C)(C)C)ccc2n4-c2cc(-c4ccncn4)cc4c2B3c2cc(-c3ccc(C(C)(C)C)cc3)cc3c5cc(C(C)(C)C)ccc5n-4c23)cc1 ; CC(C)(C)c1ccc(-c2cc3c4c(c2)c2cc(C(C)(C)C)ccc2n4-c2cc(-c4cc(-c5ccccc5)nc(-c5ccccc5)n4)cc4c2B3c2cc(-c3ccc(C(C)(C)C)cc3)cc3c5cc(C(C)(C)C)ccc5n-4c23)cc1 ; CC(C)(C)c1ccc(-c2cc3c4c(c2)c2cc(C(C)(C)C)ccc2n4-c2cc(-c4cc(-c5cc(C(C)(C)C)cc(C(C)(C)C)c5)nc(-c5cc(C(C)(C)C)cc(C(C)(C)C)c5)n4)cc4c2B3c2cc(-c3ccc(C(C)(C)C)cc3)cc3c5cc(C(C)(C)C)ccc5n-4c23)cc1]

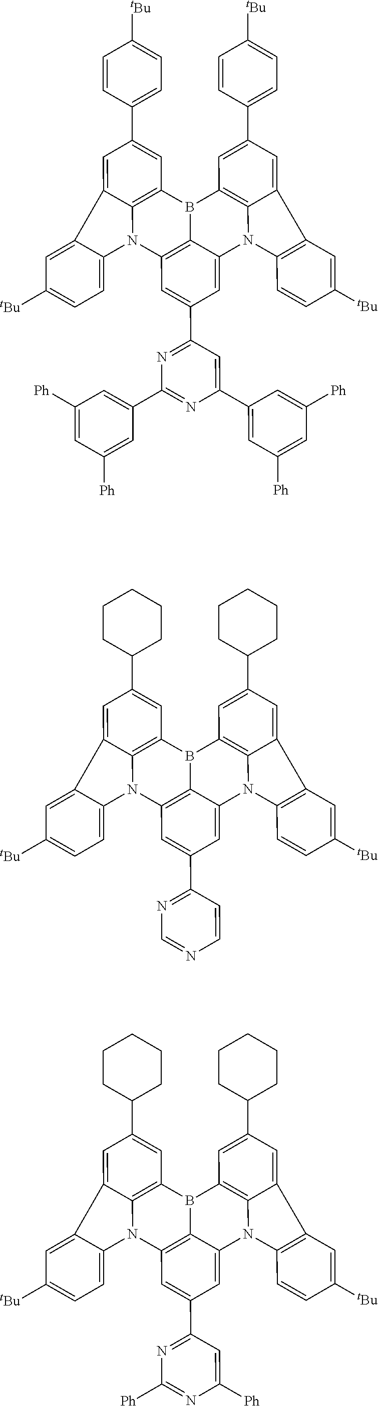 [SMILES: CC(C)(C)c1ccc(-c2cc3c4c(c2)c2cc(C(C)(C)C)ccc2n4-c2cc(-c4cc(-c5cc(-c6ccccc6)cc(-c6ccccc6)c5)nc(-c5cc(-c6ccccc6)cc(-c6ccccc6)c5)n4)cc4c2B3c2cc(-c3ccc(C(C)(C)C)cc3)cc3c5cc(C(C)(C)C)ccc5n-4c23)cc1 ; CC(C)(C)c1ccc2c(c1)c1cc(C3CCCCC3)cc3c1n2-c1cc(-c2ccncn2)cc2c1B3c1cc(C3CCCCC3)cc3c4cc(C(C)(C)C)ccc4n-2c13 ; CC(C)(C)c1ccc2c(c1)c1cc(C3CCCCC3)cc3c1n2-c1cc(-c2cc(-c4ccccc4)nc(-c4ccccc4)n2)cc2c1B3c1cc(C3CCCCC3)cc3c4cc(C(C)(C)C)ccc4n-2c13]

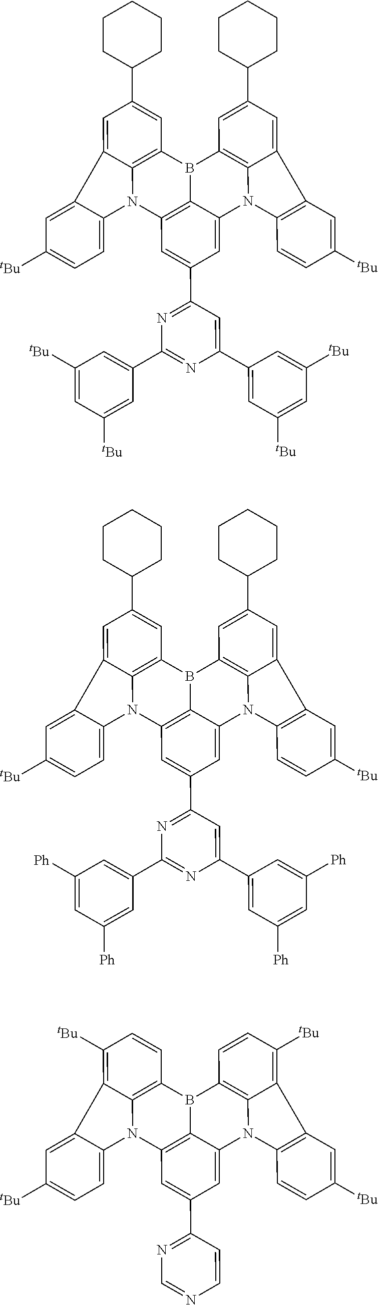 [SMILES: CC(C)(C)c1cc(-c2cc(-c3cc4c5c(c3)-n3c6ccc(C(C)(C)C)cc6c6cc(C7CCCCC7)cc(c63)B5c3cc(C5CCCCC5)cc5c6cc(C(C)(C)C)ccc6n-4c35)nc(-c3cc(C(C)(C)C)cc(C(C)(C)C)c3)n2)cc(C(C)(C)C)c1 ; CC(C)(C)c1ccc2c(c1)c1cc(C3CCCCC3)cc3c1n2-c1cc(-c2cc(-c4cc(-c5ccccc5)cc(-c5ccccc5)c4)nc(-c4cc(-c5ccccc5)cc(-c5ccccc5)c4)n2)cc2c1B3c1cc(C3CCCCC3)cc3c4cc(C(C)(C)C)ccc4n-2c13 ; CC(C)(C)c1ccc2c(c1)c1c(C(C)(C)C)ccc3c1n2-c1cc(-c2ccncn2)cc2c1B3c1ccc(C(C)(C)C)c3c4cc(C(C)(C)C)ccc4n-2c13]

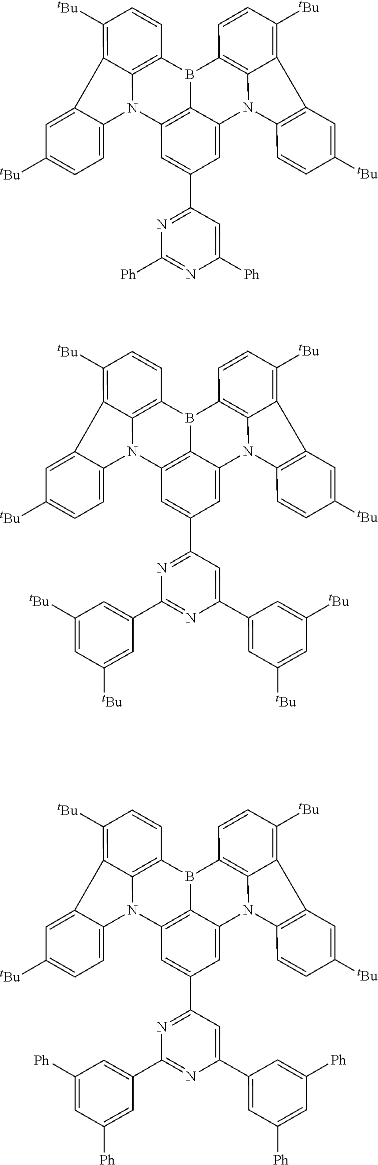 [SMILES: CC(C)(C)c1ccc2c(c1)c1c(C(C)(C)C)ccc3c1n2-c1cc(-c2cc(-c4ccccc4)nc(-c4ccccc4)n2)cc2c1B3c1ccc(C(C)(C)C)c3c4cc(C(C)(C)C)ccc4n-2c13 ; CC(C)(C)c1cc(-c2cc(-c3cc4c5c(c3)-n3c6ccc(C(C)(C)C)cc6c6c(C(C)(C)C)ccc(c63)B5c3ccc(C(C)(C)C)c5c6cc(C(C)(C)C)ccc6n-4c35)nc(-c3cc(C(C)(C)C)cc(C(C)(C)C)c3)n2)cc(C(C)(C)C)c1 ; CC(C)(C)c1ccc2c(c1)c1c(C(C)(C)C)ccc3c1n2-c1cc(-c2cc(-c4cc(-c5ccccc5)cc(-c5ccccc5)c4)nc(-c4cc(-c5ccccc5)cc(-c5ccccc5)c4)n2)cc2c1B3c1ccc(C(C)(C)C)c3c4cc(C(C)(C)C)ccc4n-2c13]

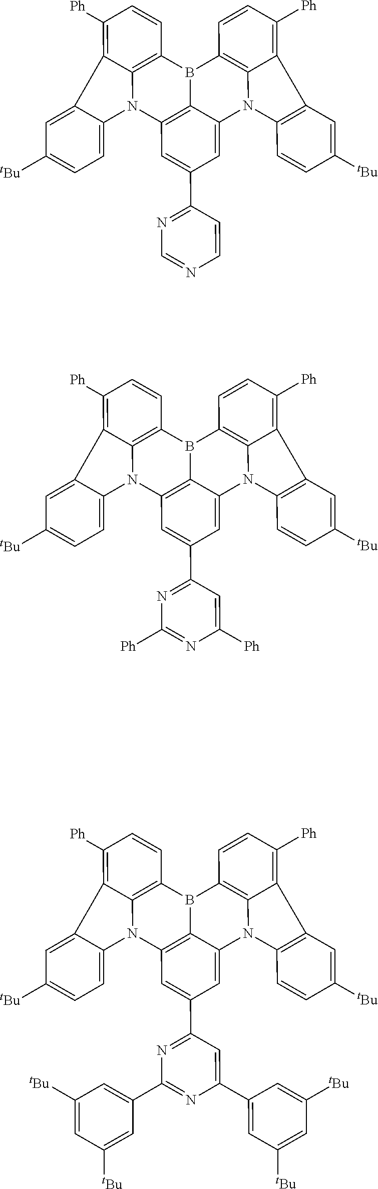 [SMILES: CC(C)(C)c1ccc2c(c1)c1c(-c3ccccc3)ccc3c1n2-c1cc(-c2ccncn2)cc2c1B3c1ccc(-c3ccccc3)c3c4cc(C(C)(C)C)ccc4n-2c13 ; CC(C)(C)c1ccc2c(c1)c1c(-c3ccccc3)ccc3c1n2-c1cc(-c2cc(-c4ccccc4)nc(-c4ccccc4)n2)cc2c1B3c1ccc(-c3ccccc3)c3c4cc(C(C)(C)C)ccc4n-2c13 ; CC(C)(C)c1cc(-c2cc(-c3cc4c5c(c3)-n3c6ccc(C(C)(C)C)cc6c6c(-c7ccccc7)ccc(c63)B5c3ccc(-c5ccccc5)c5c6cc(C(C)(C)C)ccc6n-4c35)nc(-c3cc(C(C)(C)C)cc(C(C)(C)C)c3)n2)cc(C(C)(C)C)c1]

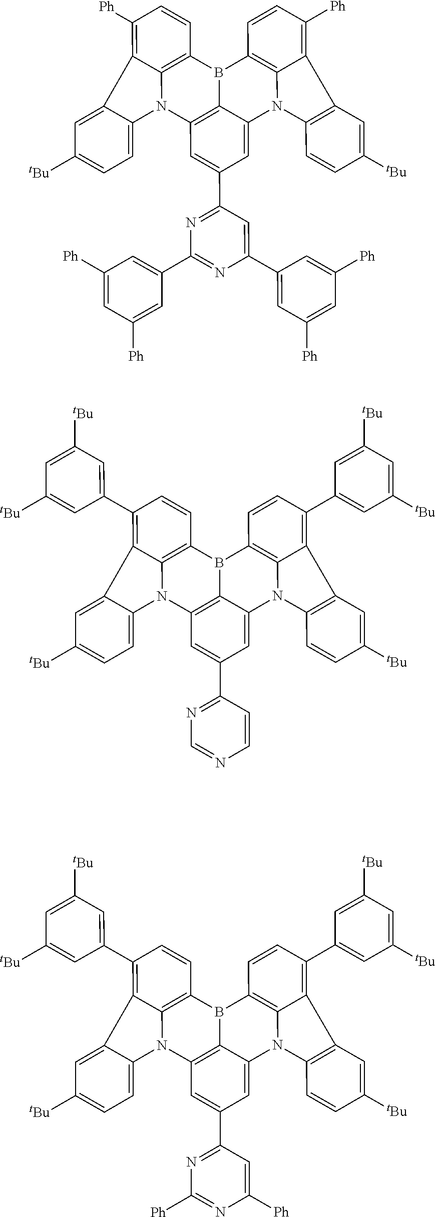 [SMILES: CC(C)(C)c1ccc2c(c1)c1c(-c3ccccc3)ccc3c1n2-c1cc(-c2cc(-c4cc(-c5ccccc5)cc(-c5ccccc5)c4)nc(-c4cc(-c5ccccc5)cc(-c5ccccc5)c4)n2)cc2c1B3c1ccc(-c3ccccc3)c3c4cc(C(C)(C)C)ccc4n-2c13 ; CC(C)(C)c1cc(-c2ccc3c4c2c2cc(C(C)(C)C)ccc2n4-c2cc(-c4ccncn4)cc4c2B3c2ccc(-c3cc(C(C)(C)C)cc(C(C)(C)C)c3)c3c5cc(C(C)(C)C)ccc5n-4c23)cc(C(C)(C)C)c1 ; CC(C)(C)c1cc(-c2ccc3c4c2c2cc(C(C)(C)C)ccc2n4-c2cc(-c4cc(-c5ccccc5)nc(-c5ccccc5)n4)cc4c2B3c2ccc(-c3cc(C(C)(C)C)cc(C(C)(C)C)c3)c3c5cc(C(C)(C)C)ccc5n-4c23)cc(C(C)(C)C)c1]

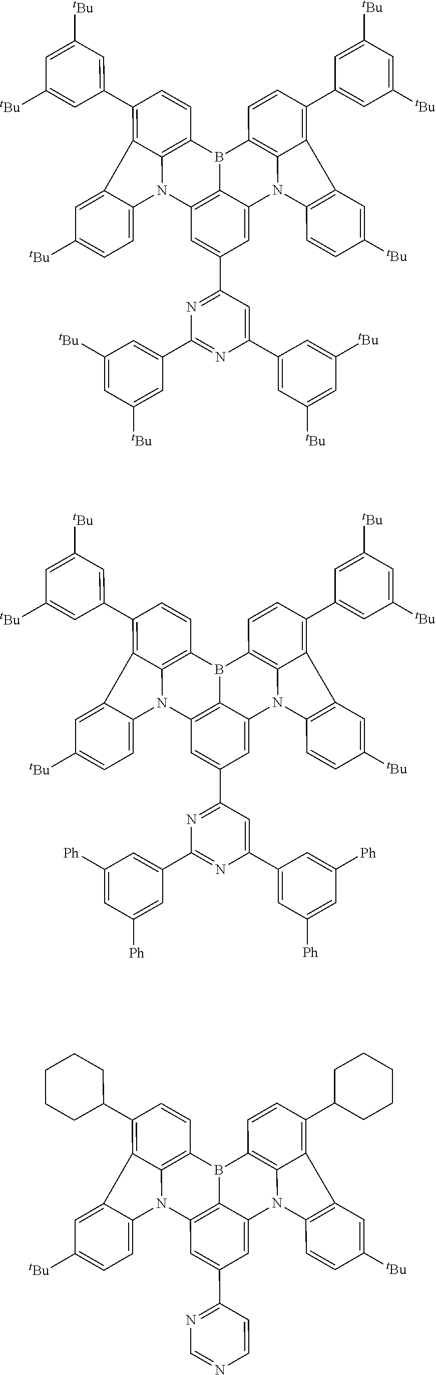

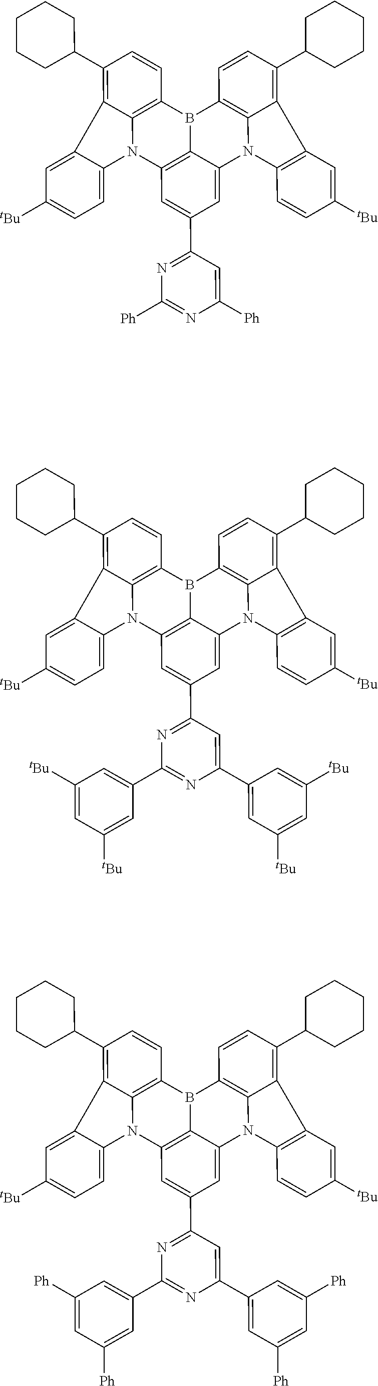 [SMILES: CC(C)(C)c1ccc2c(c1)c1c(C3CCCCC3)ccc3c1n2-c1cc(-c2cc(-c4ccccc4)nc(-c4ccccc4)n2)cc2c1B3c1ccc(C3CCCCC3)c3c4cc(C(C)(C)C)ccc4n-2c13 ; CC(C)(C)c1cc(-c2cc(-c3cc4c5c(c3)-n3c6ccc(C(C)(C)C)cc6c6c(C7CCCCC7)ccc(c63)B5c3ccc(C5CCCCC5)c5c6cc(C(C)(C)C)ccc6n-4c35)nc(-c3cc(C(C)(C)C)cc(C(C)(C)C)c3)n2)cc(C(C)(C)C)c1 ; CC(C)(C)c1ccc2c(c1)c1c(C3CCCCC3)ccc3c1n2-c1cc(-c2cc(-c4cc(-c5ccccc5)cc(-c5ccccc5)c4)nc(-c4cc(-c5ccccc5)cc(-c5ccccc5)c4)n2)cc2c1B3c1ccc(C3CCCCC3)c3c4cc(C(C)(C)C)ccc4n-2c13]

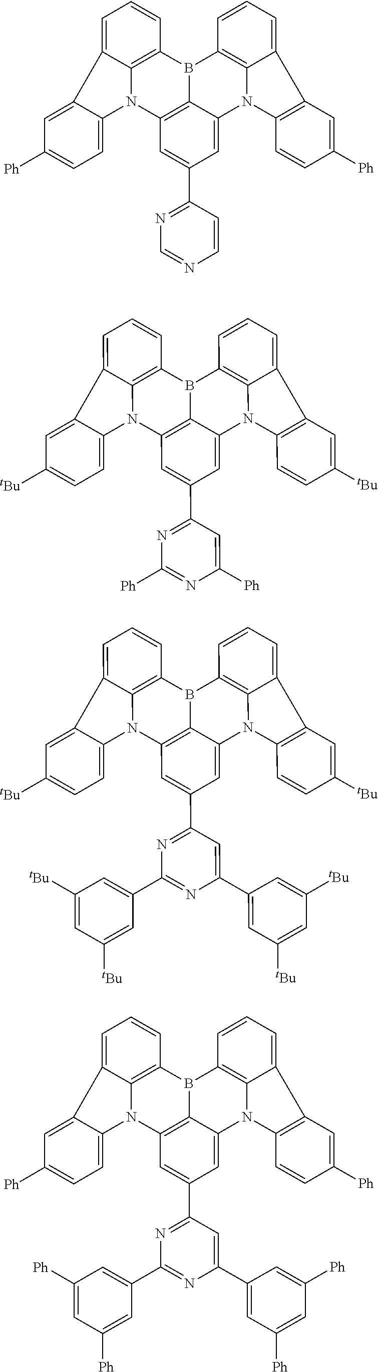

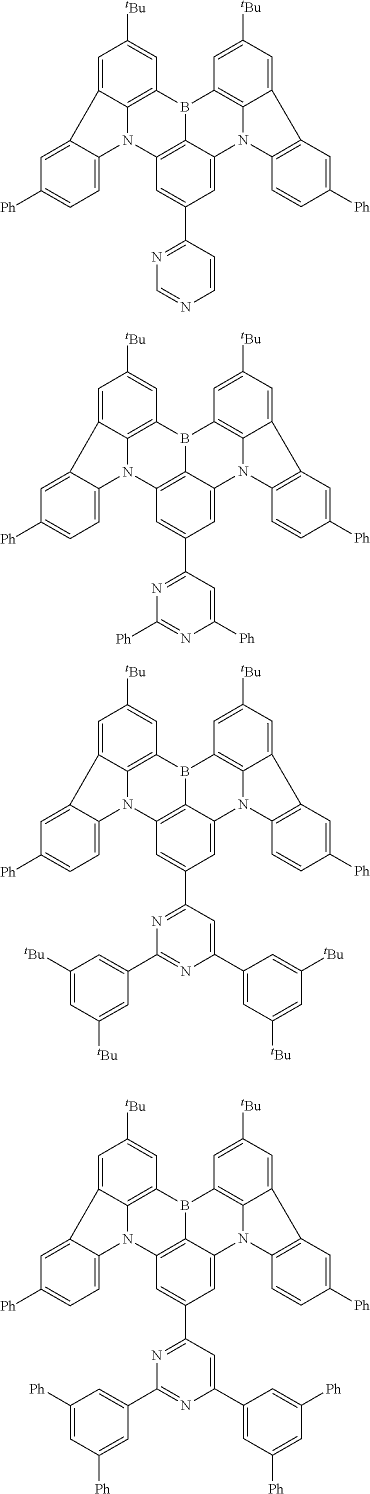

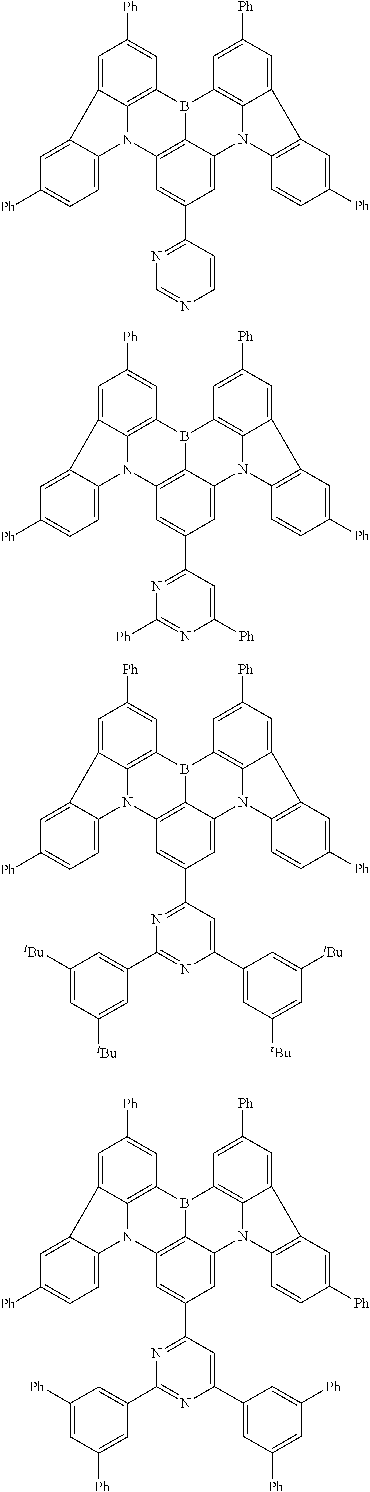

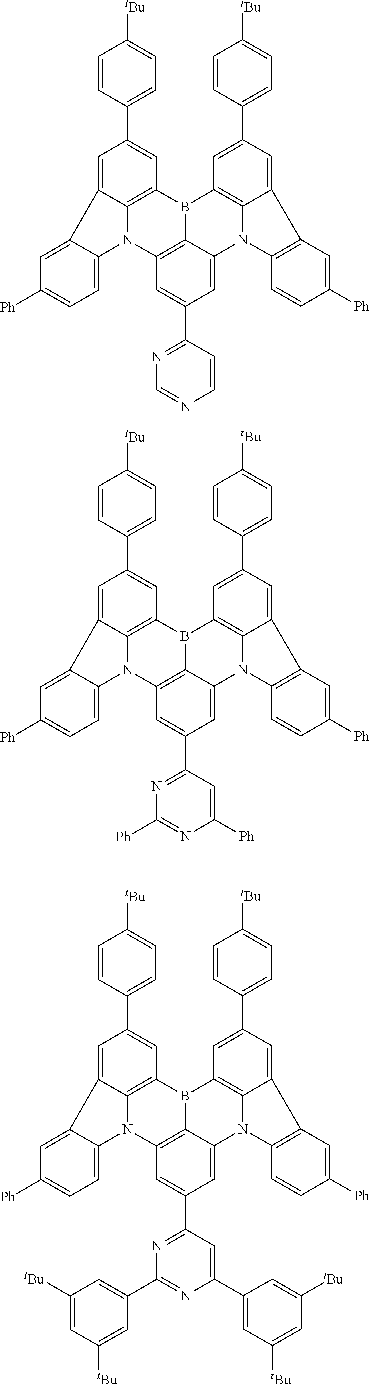 [SMILES: CC(C)(C)c1ccc(-c2cc3c4c(c2)c2cc(-c5ccccc5)ccc2n4-c2cc(-c4ccncn4)cc4c2B3c2cc(-c3ccc(C(C)(C)C)cc3)cc3c5cc(-c6ccccc6)ccc5n-4c23)cc1 ; CC(C)(C)c1ccc(-c2cc3c4c(c2)c2cc(-c5ccccc5)ccc2n4-c2cc(-c4cc(-c5ccccc5)nc(-c5ccccc5)n4)cc4c2B3c2cc(-c3ccc(C(C)(C)C)cc3)cc3c5cc(-c6ccccc6)ccc5n-4c23)cc1 ; CC(C)(C)c1ccc(-c2cc3c4c(c2)c2cc(-c5ccccc5)ccc2n4-c2cc(-c4cc(-c5cc(C(C)(C)C)cc(C(C)(C)C)c5)nc(-c5cc(C(C)(C)C)cc(C(C)(C)C)c5)n4)cc4c2B3c2cc(-c3ccc(C(C)(C)C)cc3)cc3c5cc(-c6ccccc6)ccc5n-4c23)cc1]

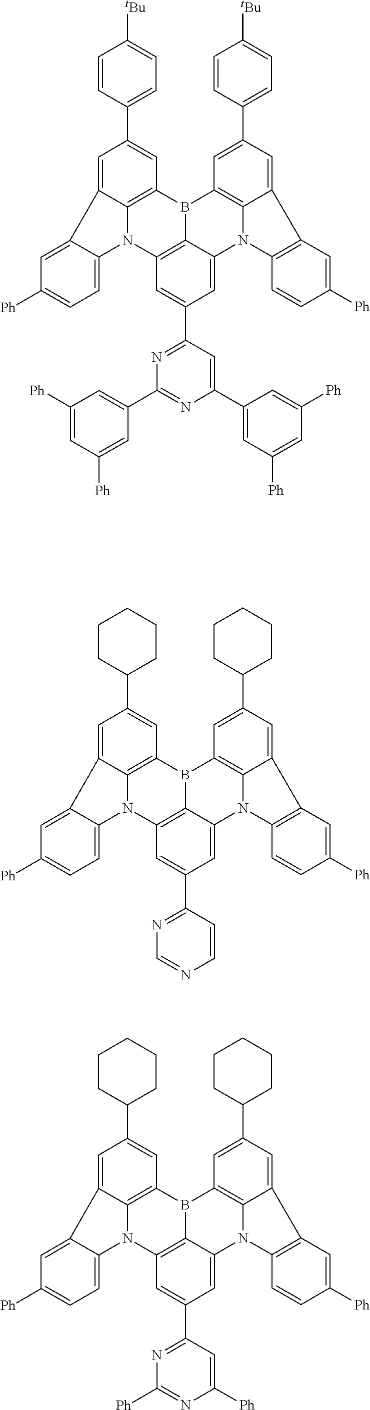 [SMILES: CC(C)(C)c1ccc(-c2cc3c4c(c2)c2cc(-c5ccccc5)ccc2n4-c2cc(-c4cc(-c5cc(-c6ccccc6)cc(-c6ccccc6)c5)nc(-c5cc(-c6ccccc6)cc(-c6ccccc6)c5)n4)cc4c2B3c2cc(-c3ccc(C(C)(C)C)cc3)cc3c5cc(-c6ccccc6)ccc5n-4c23)cc1 ; c1ccc(-c2ccc3c(c2)c2cc(C4CCCCC4)cc4c2n3-c2cc(-c3ccncn3)cc3c2B4c2cc(C4CCCCC4)cc4c5cc(-c6ccccc6)ccc5n-3c24)cc1 ; c1ccc(-c2ccc3c(c2)c2cc(C4CCCCC4)cc4c2n3-c2cc(-c3cc(-c5ccccc5)nc(-c5ccccc5)n3)cc3c2B4c2cc(C4CCCCC4)cc4c5cc(-c6ccccc6)ccc5n-3c24)cc1]

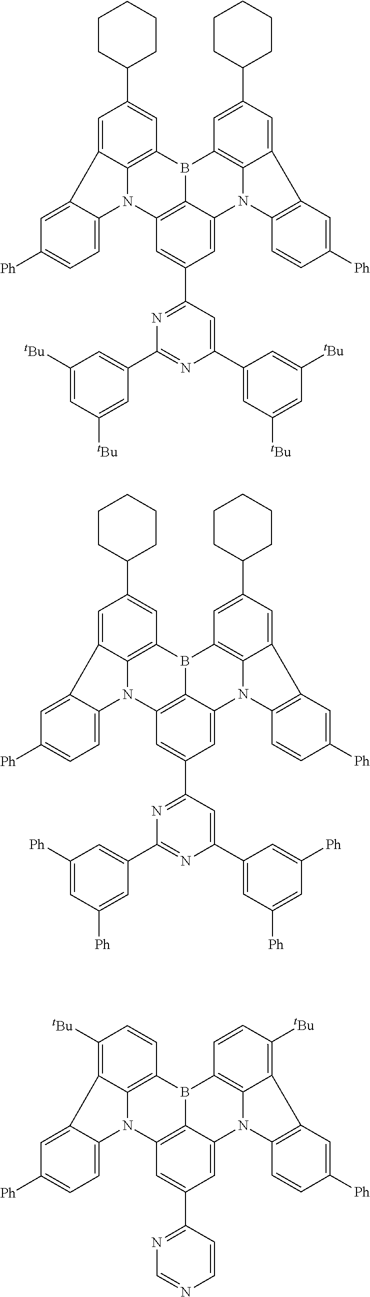 [SMILES: CC(C)(C)c1cc(-c2cc(-c3cc4c5c(c3)-n3c6ccc(-c7ccccc7)cc6c6cc(C7CCCCC7)cc(c63)B5c3cc(C5CCCCC5)cc5c6cc(-c7ccccc7)ccc6n-4c35)nc(-c3cc(C(C)(C)C)cc(C(C)(C)C)c3)n2)cc(C(C)(C)C)c1 ; c1ccc(-c2cc(-c3ccccc3)cc(-c3cc(-c4cc5c6c(c4)-n4c7ccc(-c8ccccc8)cc7c7cc(C8CCCCC8)cc(c74)B6c4cc(C6CCCCC6)cc6c7cc(-c8ccccc8)ccc7n-5c46)nc(-c4cc(-c5ccccc5)cc(-c5ccccc5)c4)n3)c2)cc1 ; CC(C)(C)c1ccc2c3c1c1cc(-c4ccccc4)ccc1n3-c1cc(-c3ccncn3)cc3c1B2c1ccc(C(C)(C)C)c2c4cc(-c5ccccc5)ccc4n-3c12]

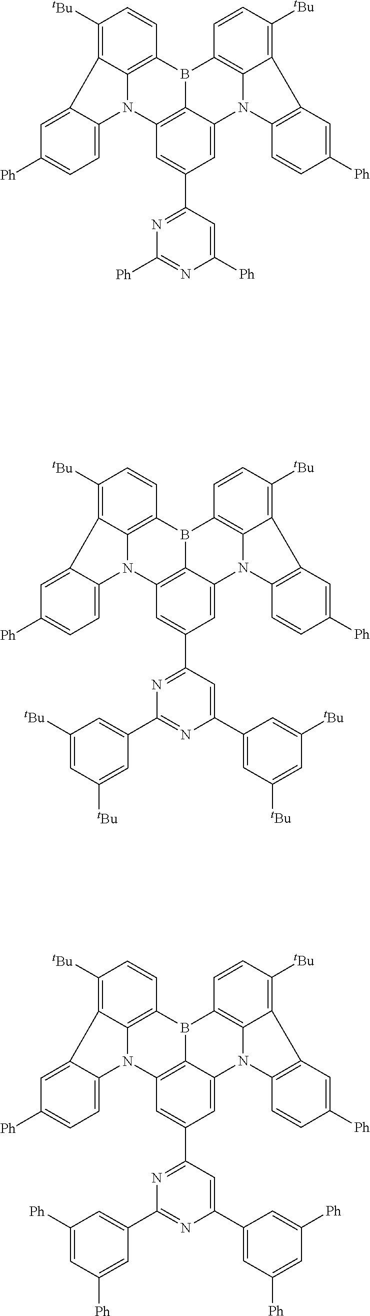 [SMILES: CC(C)(C)c1ccc2c3c1c1cc(-c4ccccc4)ccc1n3-c1cc(-c3cc(-c4ccccc4)nc(-c4ccccc4)n3)cc3c1B2c1ccc(C(C)(C)C)c2c4cc(-c5ccccc5)ccc4n-3c12 ; CC(C)(C)c1cc(-c2cc(-c3cc4c5c(c3)-n3c6ccc(-c7ccccc7)cc6c6c(C(C)(C)C)ccc(c63)B5c3ccc(C(C)(C)C)c5c6cc(-c7ccccc7)ccc6n-4c35)nc(-c3cc(C(C)(C)C)cc(C(C)(C)C)c3)n2)cc(C(C)(C)C)c1 ; CC(C)(C)c1ccc2c3c1c1cc(-c4ccccc4)ccc1n3-c1cc(-c3cc(-c4cc(-c5ccccc5)cc(-c5ccccc5)c4)nc(-c4cc(-c5ccccc5)cc(-c5ccccc5)c4)n3)cc3c1B2c1ccc(C(C)(C)C)c2c4cc(-c5ccccc5)ccc4n-3c12]

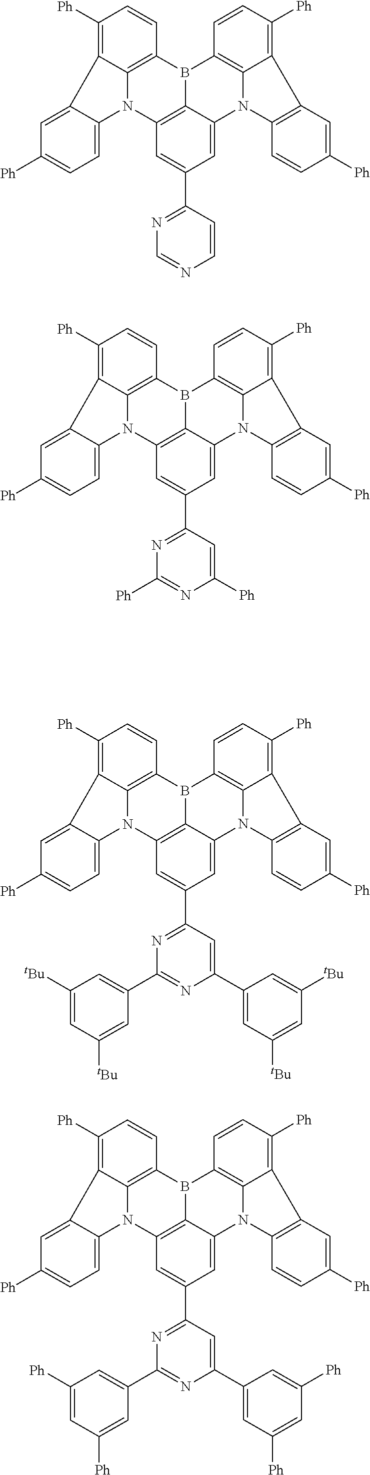

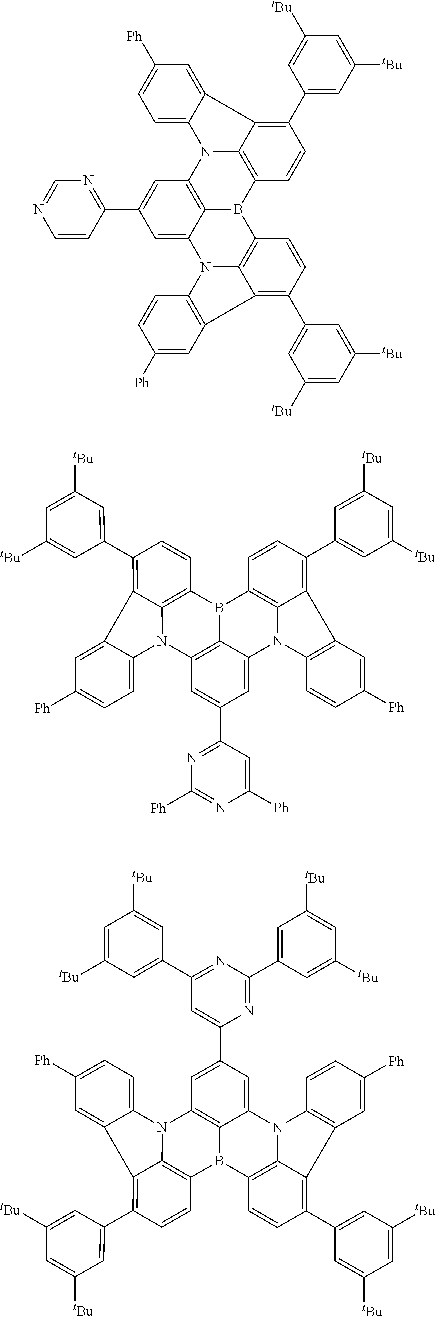

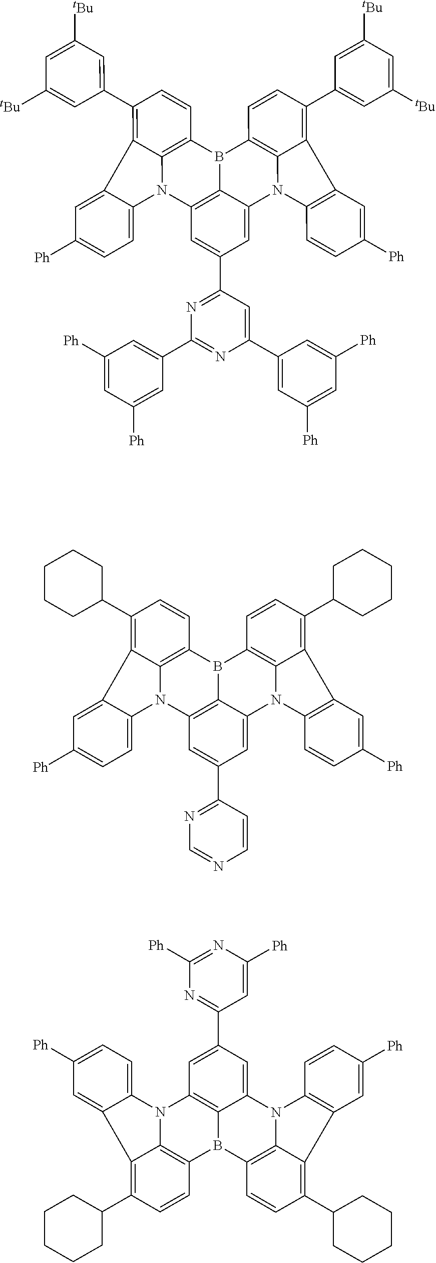 [SMILES: CC(C)(C)c1cc(-c2ccc3c4c2c2cc(-c5ccccc5)ccc2n4-c2cc(-c4cc(-c5cc(-c6ccccc6)cc(-c6ccccc6)c5)nc(-c5cc(-c6ccccc6)cc(-c6ccccc6)c5)n4)cc4c2B3c2ccc(-c3cc(C(C)(C)C)cc(C(C)(C)C)c3)c3c5cc(-c6ccccc6)ccc5n-4c23)cc(C(C)(C)C)c1 ; c1ccc(-c2ccc3c(c2)c2c(C4CCCCC4)ccc4c2n3-c2cc(-c3ccncn3)cc3c2B4c2ccc(C4CCCCC4)c4c5cc(-c6ccccc6)ccc5n-3c24)cc1 ; c1ccc(-c2ccc3c(c2)c2c(C4CCCCC4)ccc4c2n3-c2cc(-c3cc(-c5ccccc5)nc(-c5ccccc5)n3)cc3c2B4c2ccc(C4CCCCC4)c4c5cc(-c6ccccc6)ccc5n-3c24)cc1]

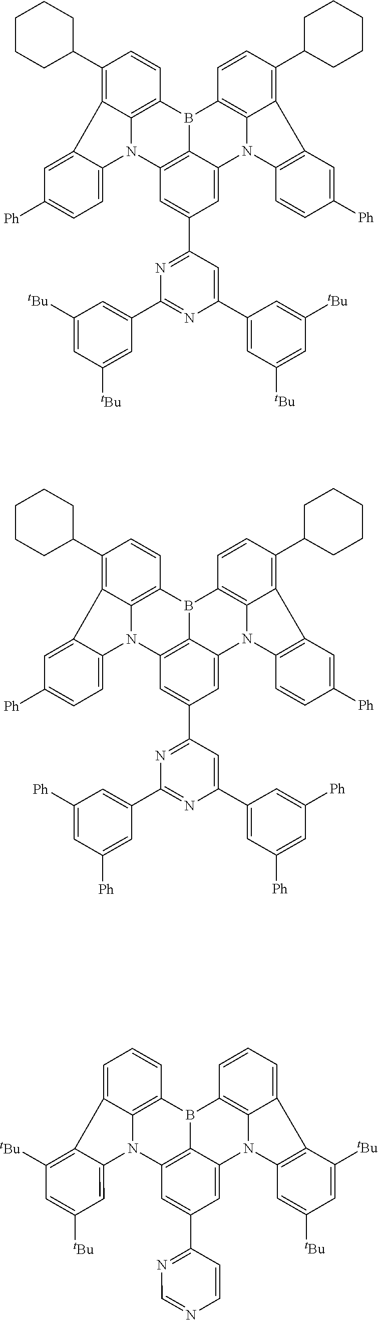 [SMILES: CC(C)(C)c1cc(-c2cc(-c3cc4c5c(c3)-n3c6ccc(-c7ccccc7)cc6c6c(C7CCCCC7)ccc(c63)B5c3ccc(C5CCCCC5)c5c6cc(-c7ccccc7)ccc6n-4c35)nc(-c3cc(C(C)(C)C)cc(C(C)(C)C)c3)n2)cc(C(C)(C)C)c1 ; c1ccc(-c2cc(-c3ccccc3)cc(-c3cc(-c4cc5c6c(c4)-n4c7ccc(-c8ccccc8)cc7c7c(C8CCCCC8)ccc(c74)B6c4ccc(C6CCCCC6)c6c7cc(-c8ccccc8)ccc7n-5c46)nc(-c4cc(-c5ccccc5)cc(-c5ccccc5)c4)n3)c2)cc1 ; CC(C)(C)c1cc(C(C)(C)C)c2c3cccc4c3n(c2c1)-c1cc(-c2ccncn2)cc2c1B4c1cccc3c4c(C(C)(C)C)cc(C(C)(C)C)cc4n-2c13]

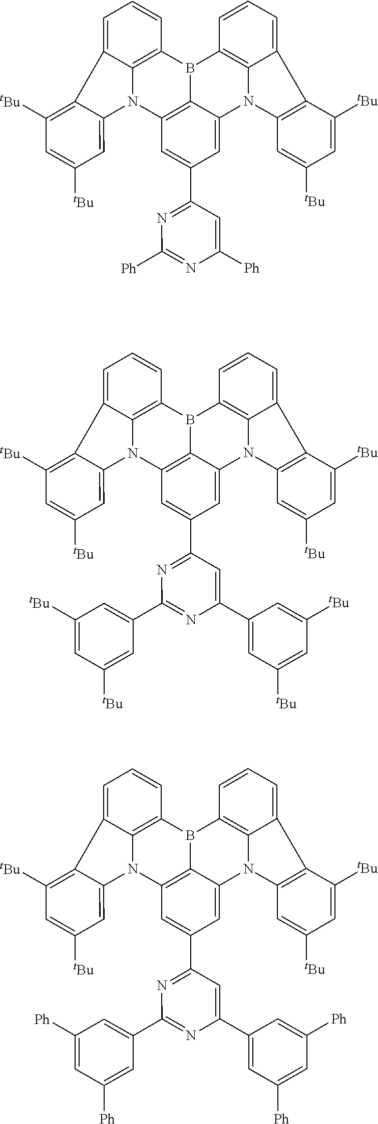 [SMILES: CC(C)(C)c1cc(C(C)(C)C)c2c3cccc4c3n(c2c1)-c1cc(-c2cc(-c3ccccc3)nc(-c3ccccc3)n2)cc2c1B4c1cccc3c4c(C(C)(C)C)cc(C(C)(C)C)cc4n-2c13 ; CC(C)(C)c1cc(-c2cc(-c3cc4c5c(c3)-n3c6cc(C(C)(C)C)cc(C(C)(C)C)c6c6cccc(c63)B5c3cccc5c6c(C(C)(C)C)cc(C(C)(C)C)cc6n-4c35)nc(-c3cc(C(C)(C)C)cc(C(C)(C)C)c3)n2)cc(C(C)(C)C)c1 ; CC(C)(C)c1cc(C(C)(C)C)c2c3cccc4c3n(c2c1)-c1cc(-c2cc(-c3cc(-c5ccccc5)cc(-c5ccccc5)c3)nc(-c3cc(-c5ccccc5)cc(-c5ccccc5)c3)n2)cc2c1B4c1cccc3c4c(C(C)(C)C)cc(C(C)(C)C)cc4n-2c13]

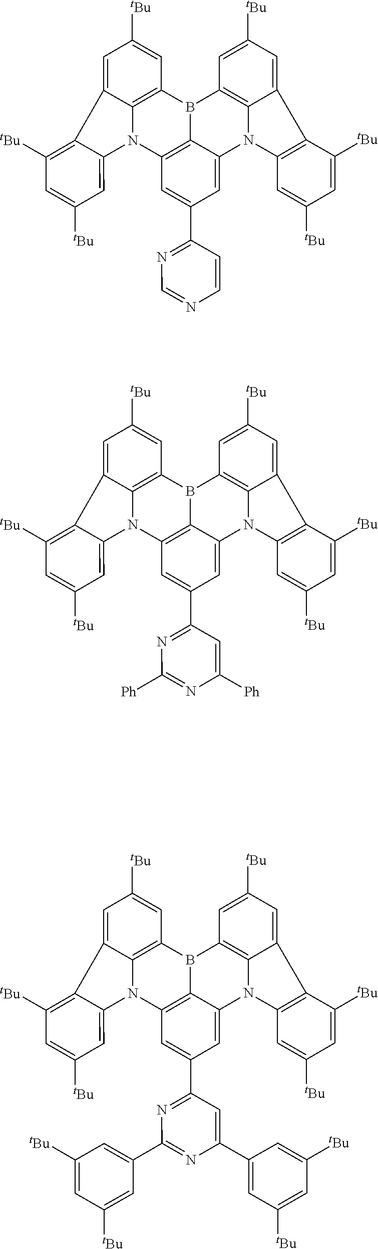 [SMILES: CC(C)(C)c1cc2c3c(c1)c1c(C(C)(C)C)cc(C(C)(C)C)cc1n3-c1cc(-c3ccncn3)cc3c1B2c1cc(C(C)(C)C)cc2c4c(C(C)(C)C)cc(C(C)(C)C)cc4n-3c12 ; CC(C)(C)c1cc2c3c(c1)c1c(C(C)(C)C)cc(C(C)(C)C)cc1n3-c1cc(-c3cc(-c4ccccc4)nc(-c4ccccc4)n3)cc3c1B2c1cc(C(C)(C)C)cc2c4c(C(C)(C)C)cc(C(C)(C)C)cc4n-3c12 ; CC(C)(C)c1cc(-c2cc(-c3cc4c5c(c3)-n3c6cc(C(C)(C)C)cc(C(C)(C)C)c6c6cc(C(C)(C)C)cc(c63)B5c3cc(C(C)(C)C)cc5c6c(C(C)(C)C)cc(C(C)(C)C)cc6n-4c35)nc(-c3cc(C(C)(C)C)cc(C(C)(C)C)c3)n2)cc(C(C)(C)C)c1]

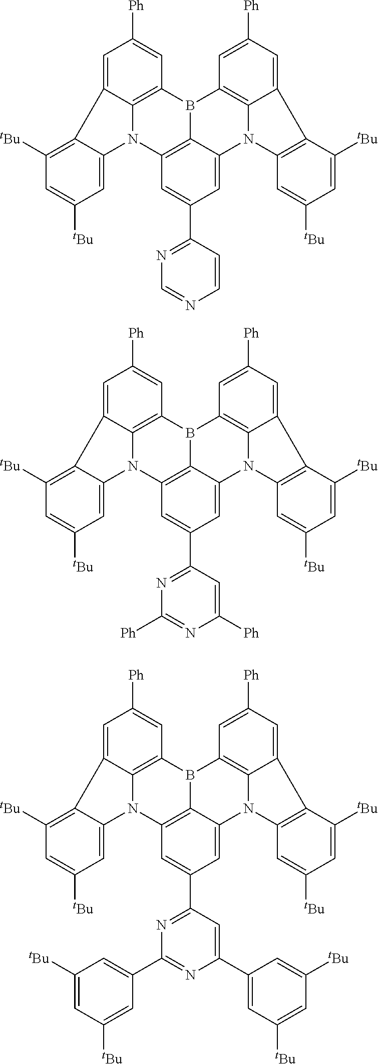

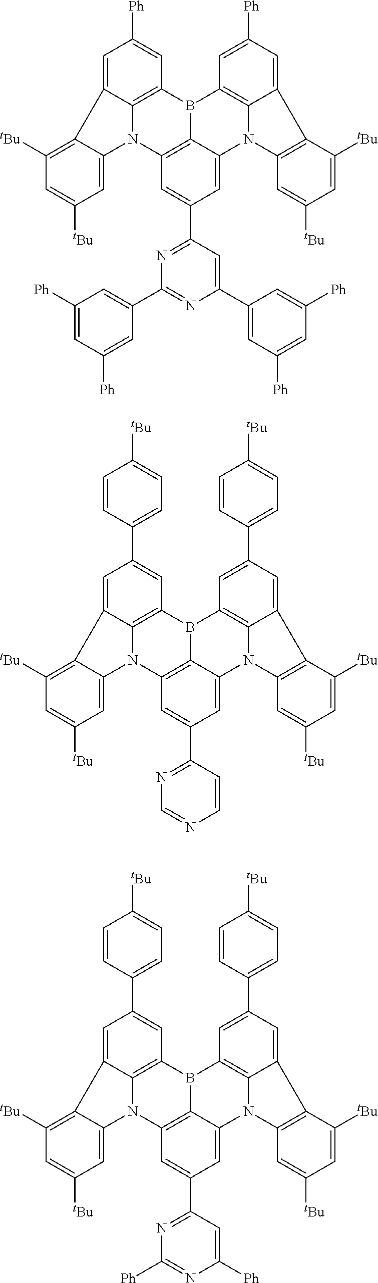

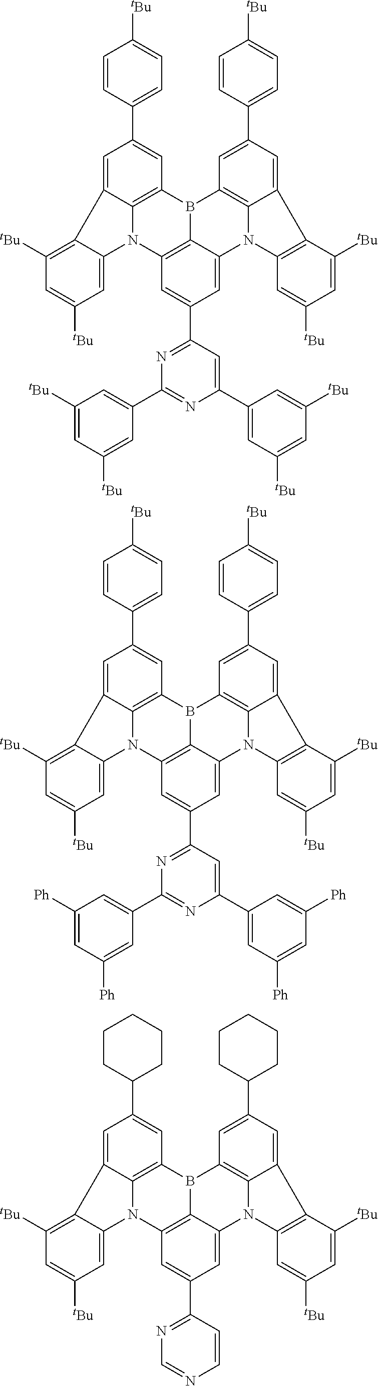

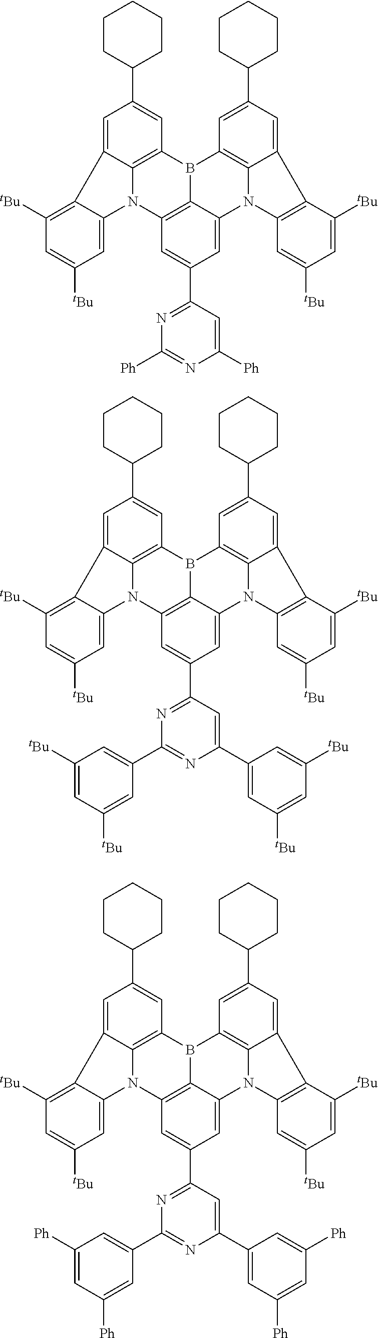

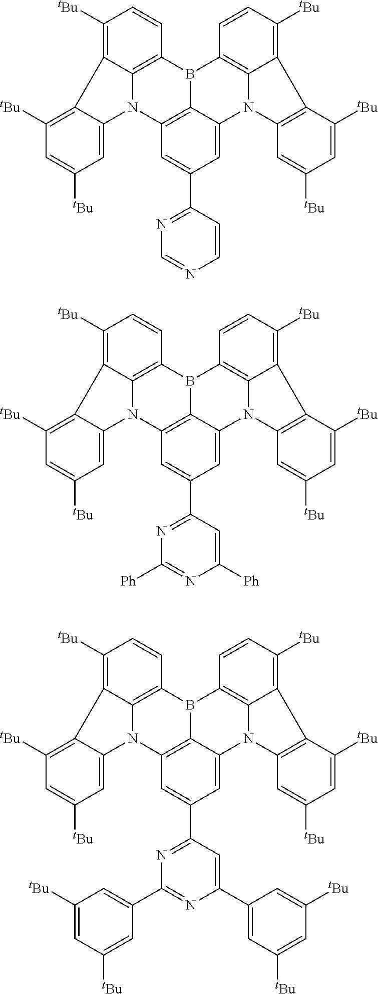 [SMILES: CC(C)(C)c1cc(C(C)(C)C)c2c3c(C(C)(C)C)ccc4c3n(c2c1)-c1cc(-c2ccncn2)cc2c1B4c1ccc(C(C)(C)C)c3c4c(C(C)(C)C)cc(C(C)(C)C)cc4n-2c13 ; CC(C)(C)c1cc(C(C)(C)C)c2c3c(C(C)(C)C)ccc4c3n(c2c1)-c1cc(-c2cc(-c3ccccc3)nc(-c3ccccc3)n2)cc2c1B4c1ccc(C(C)(C)C)c3c4c(C(C)(C)C)cc(C(C)(C)C)cc4n-2c13 ; CC(C)(C)c1cc(-c2cc(-c3cc4c5c(c3)-n3c6cc(C(C)(C)C)cc(C(C)(C)C)c6c6c(C(C)(C)C)ccc(c63)B5c3ccc(C(C)(C)C)c5c6c(C(C)(C)C)cc(C(C)(C)C)cc6n-4c35)nc(-c3cc(C(C)(C)C)cc(C(C)(C)C)c3)n2)cc(C(C)(C)C)c1]

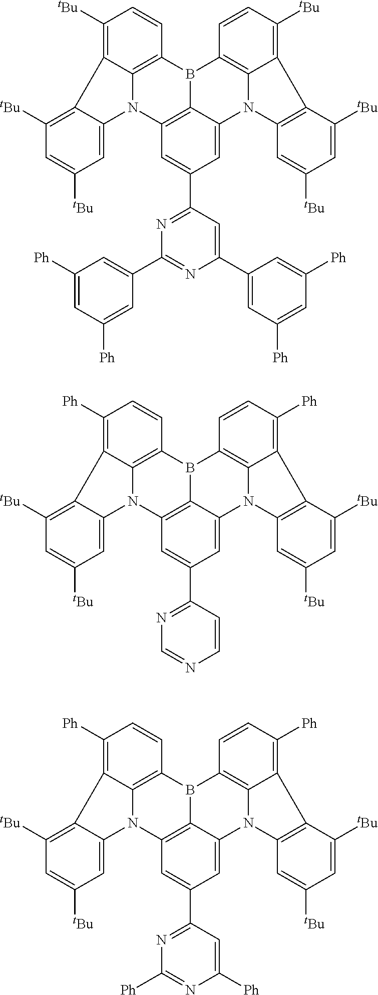 [SMILES: CC(C)(C)c1cc(C(C)(C)C)c2c3c(C(C)(C)C)ccc4c3n(c2c1)-c1cc(-c2cc(-c3cc(-c5ccccc5)cc(-c5ccccc5)c3)nc(-c3cc(-c5ccccc5)cc(-c5ccccc5)c3)n2)cc2c1B4c1ccc(C(C)(C)C)c3c4c(C(C)(C)C)cc(C(C)(C)C)cc4n-2c13 ; CC(C)(C)c1cc(C(C)(C)C)c2c3c(-c4ccccc4)ccc4c3n(c2c1)-c1cc(-c2ccncn2)cc2c1B4c1ccc(-c3ccccc3)c3c4c(C(C)(C)C)cc(C(C)(C)C)cc4n-2c13 ; CC(C)(C)c1cc(C(C)(C)C)c2c3c(-c4ccccc4)ccc4c3n(c2c1)-c1cc(-c2cc(-c3ccccc3)nc(-c3ccccc3)n2)cc2c1B4c1ccc(-c3ccccc3)c3c4c(C(C)(C)C)cc(C(C)(C)C)cc4n-2c13]

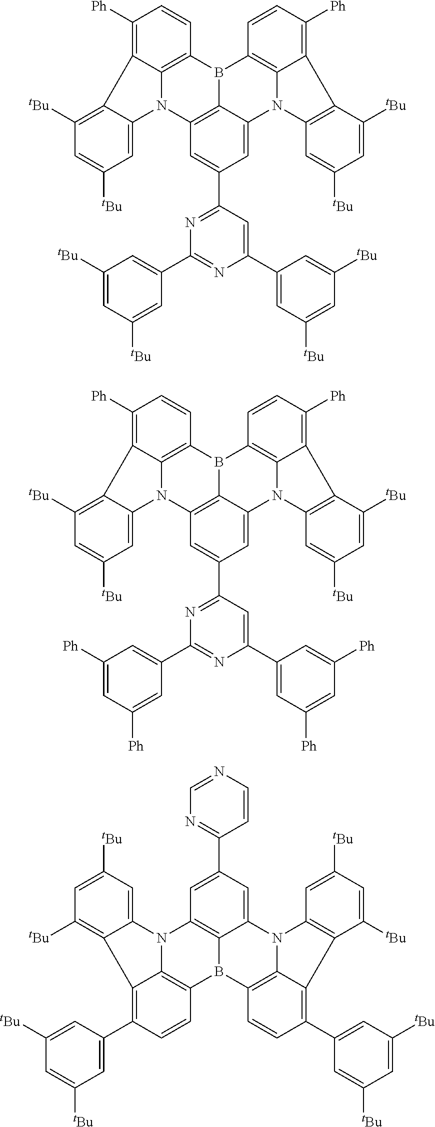

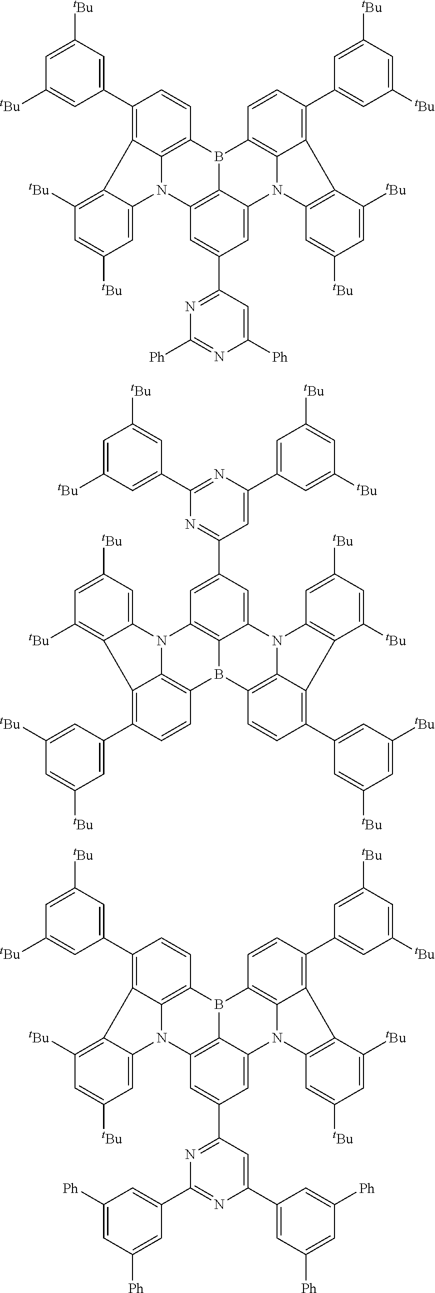

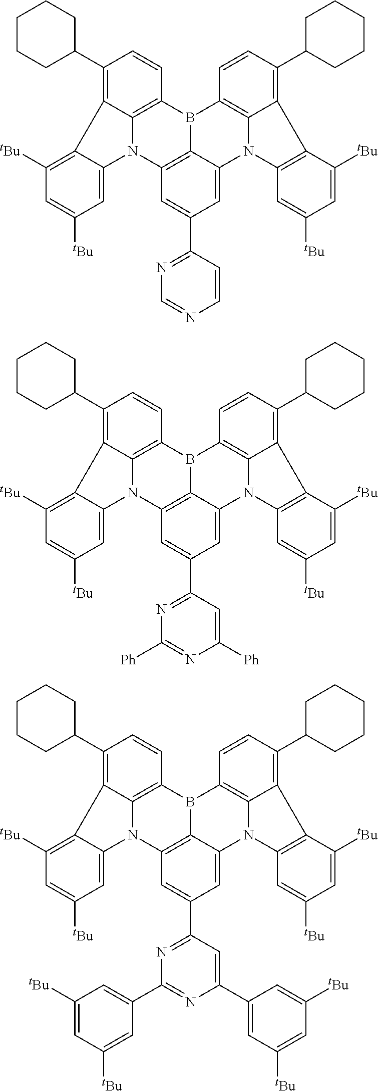 [SMILES: CC(C)(C)c1cc(C(C)(C)C)c2c3c(C4CCCCC4)ccc4c3n(c2c1)-c1cc(-c2ccncn2)cc2c1B4c1ccc(C3CCCCC3)c3c4c(C(C)(C)C)cc(C(C)(C)C)cc4n-2c13 ; CC(C)(C)c1cc(C(C)(C)C)c2c3c(C4CCCCC4)ccc4c3n(c2c1)-c1cc(-c2cc(-c3ccccc3)nc(-c3ccccc3)n2)cc2c1B4c1ccc(C3CCCCC3)c3c4c(C(C)(C)C)cc(C(C)(C)C)cc4n-2c13 ; CC(C)(C)c1cc(-c2cc(-c3cc4c5c(c3)-n3c6cc(C(C)(C)C)cc(C(C)(C)C)c6c6c(C7CCCCC7)ccc(c63)B5c3ccc(C5CCCCC5)c5c6c(C(C)(C)C)cc(C(C)(C)C)cc6n-4c35)nc(-c3cc(C(C)(C)C)cc(C(C)(C)C)c3)n2)cc(C(C)(C)C)c1]

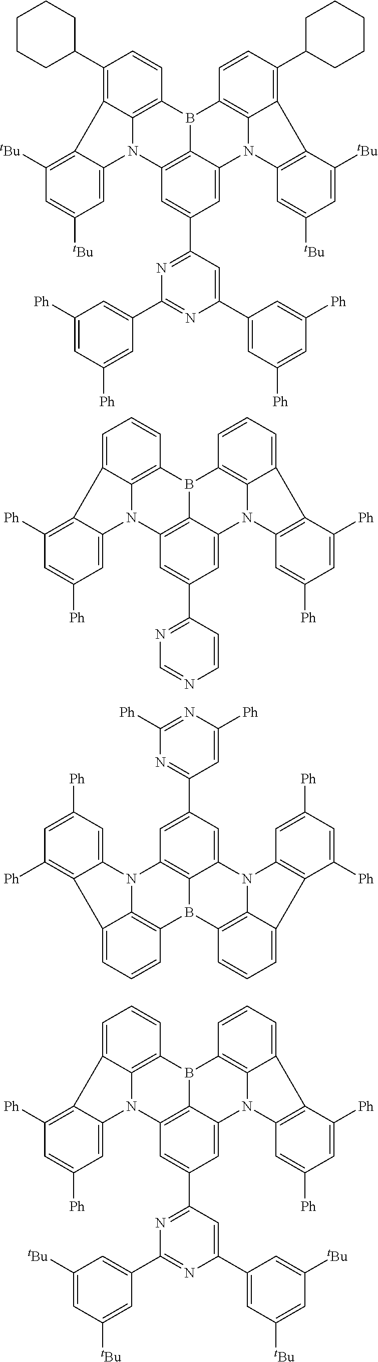

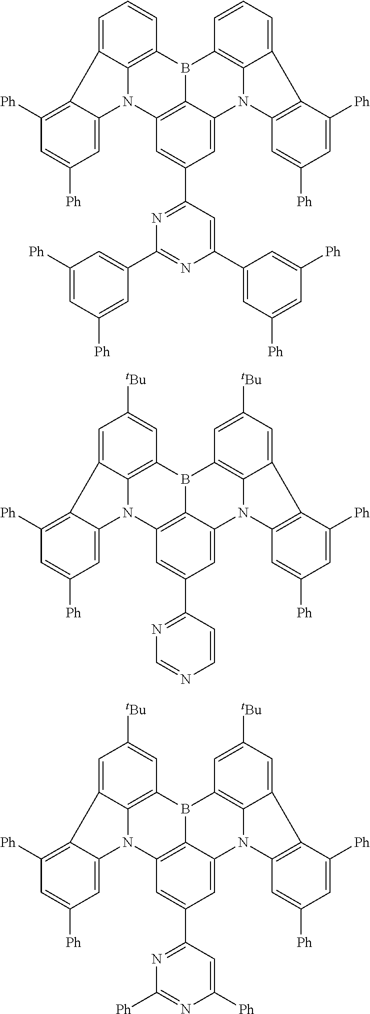

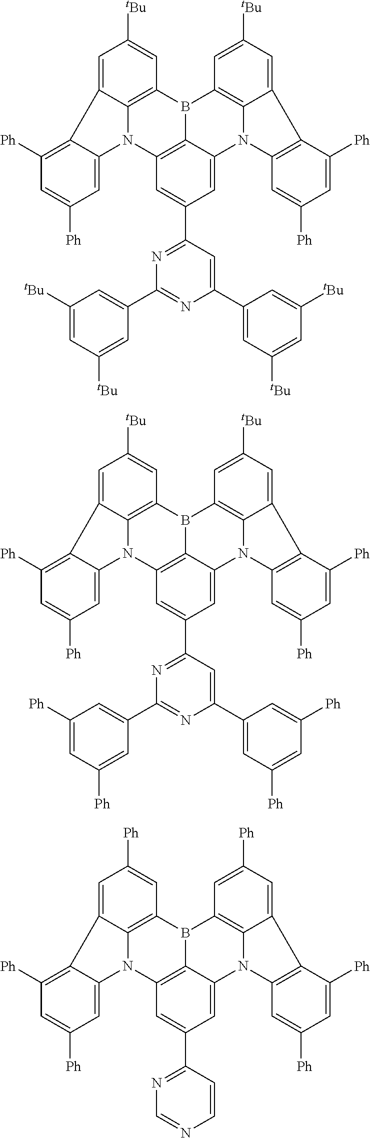

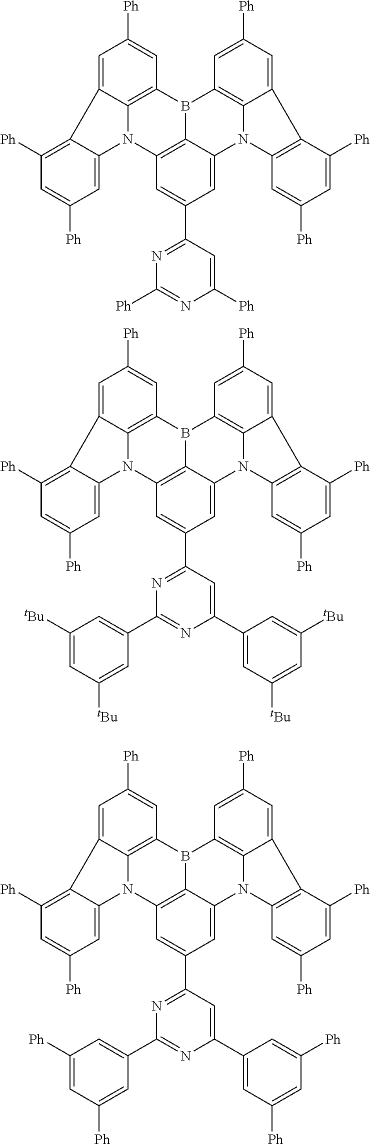

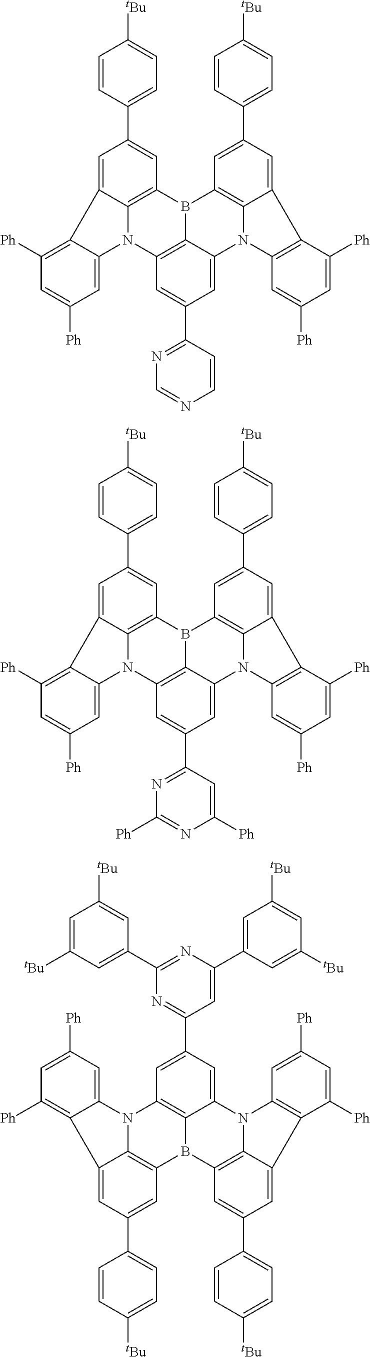

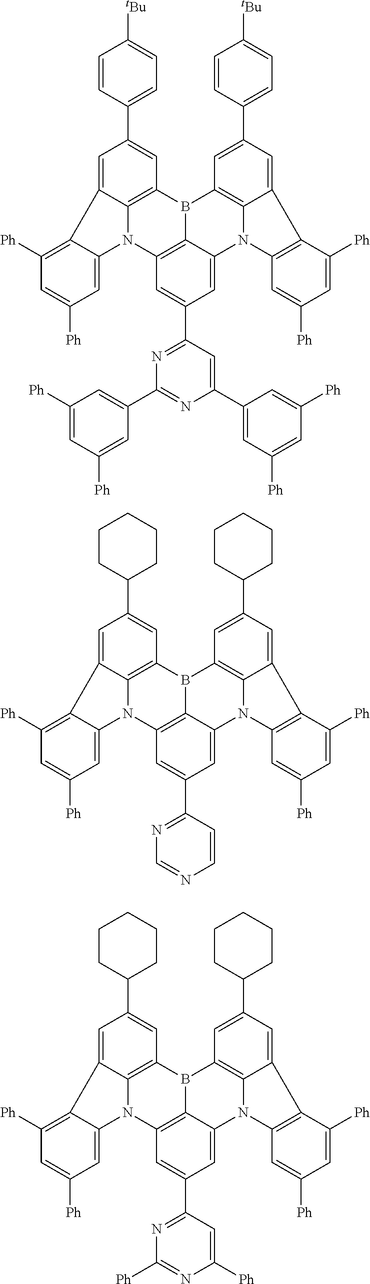

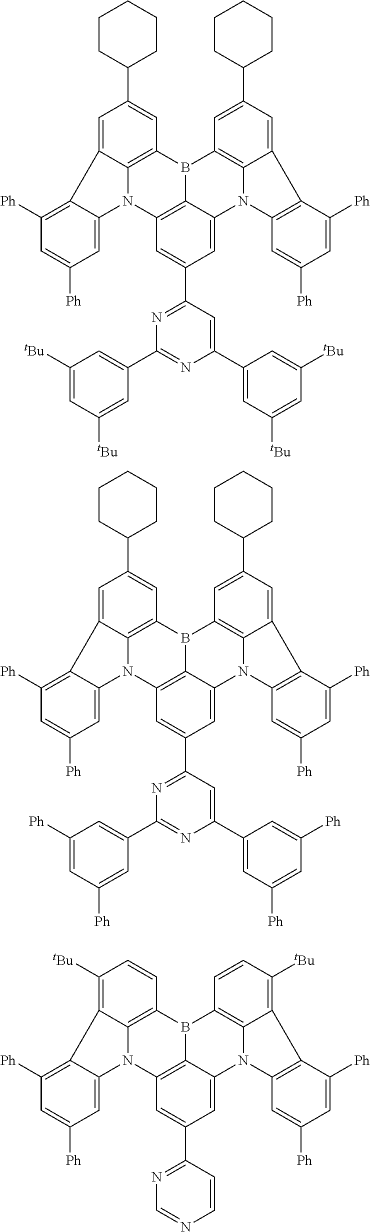

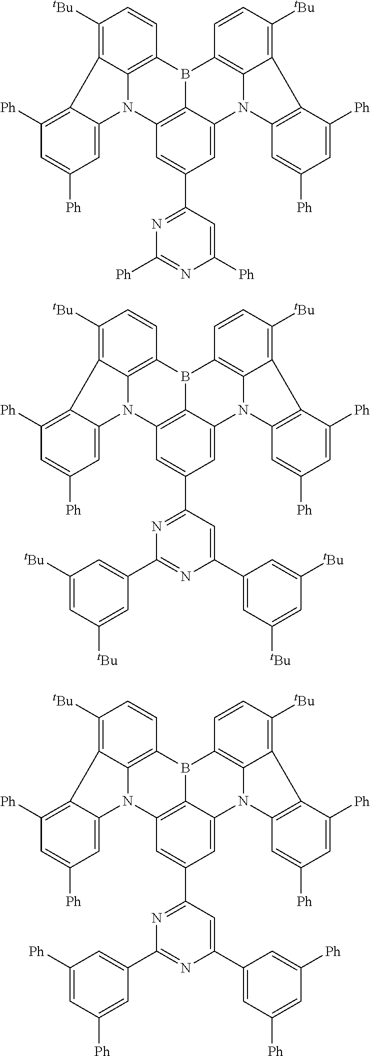

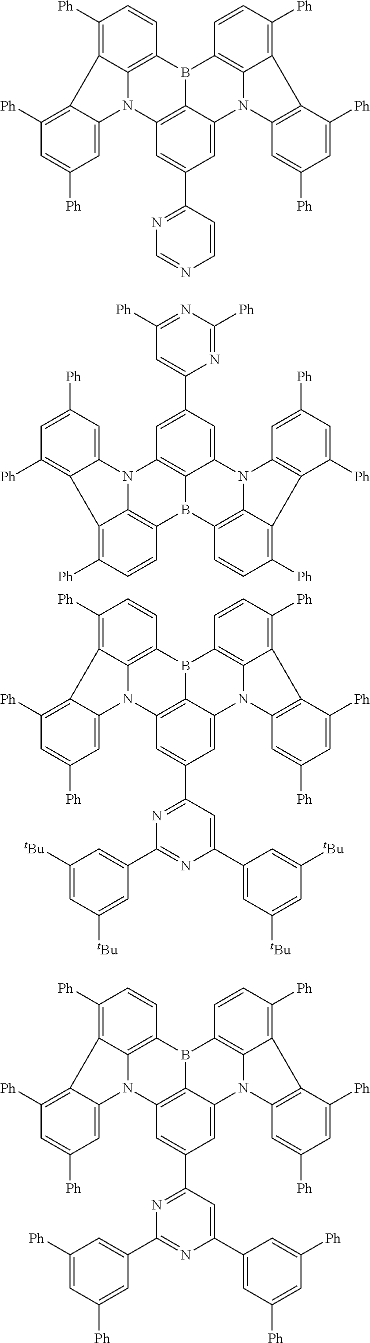

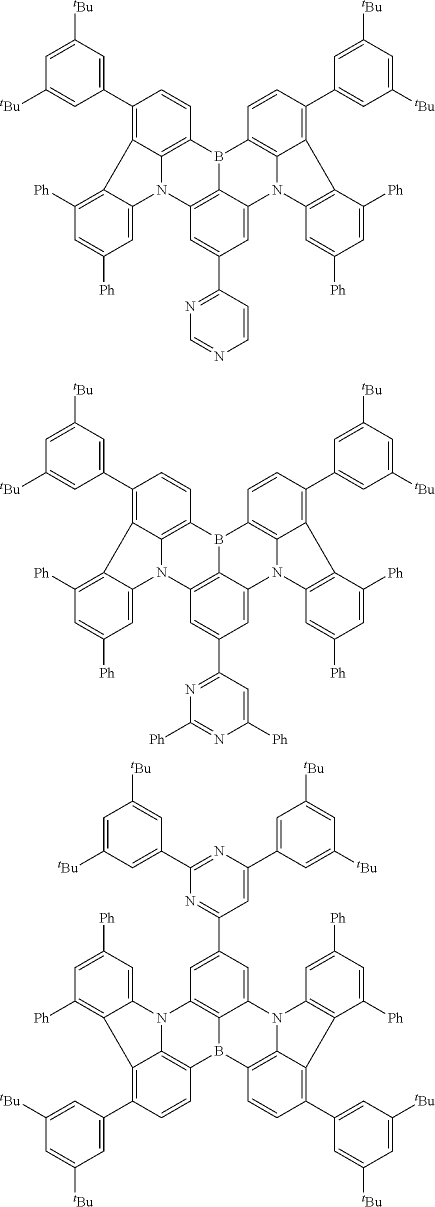

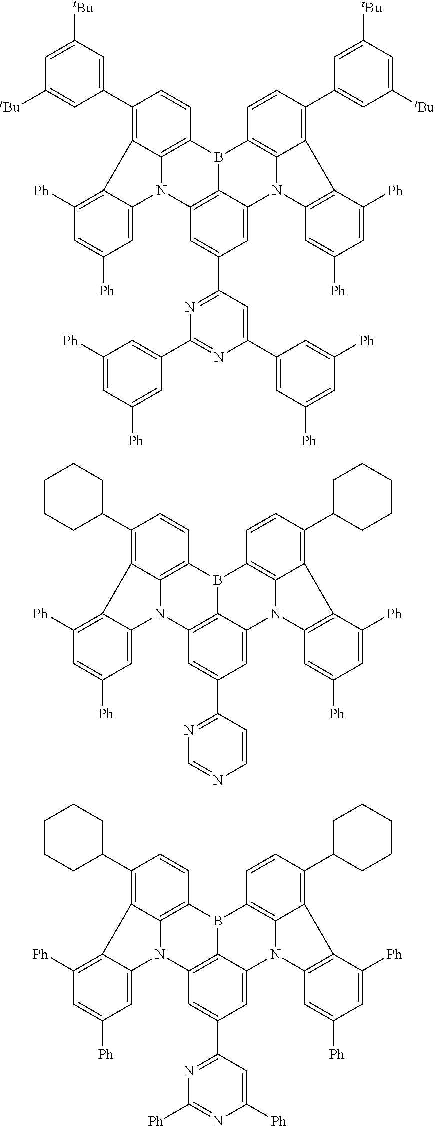

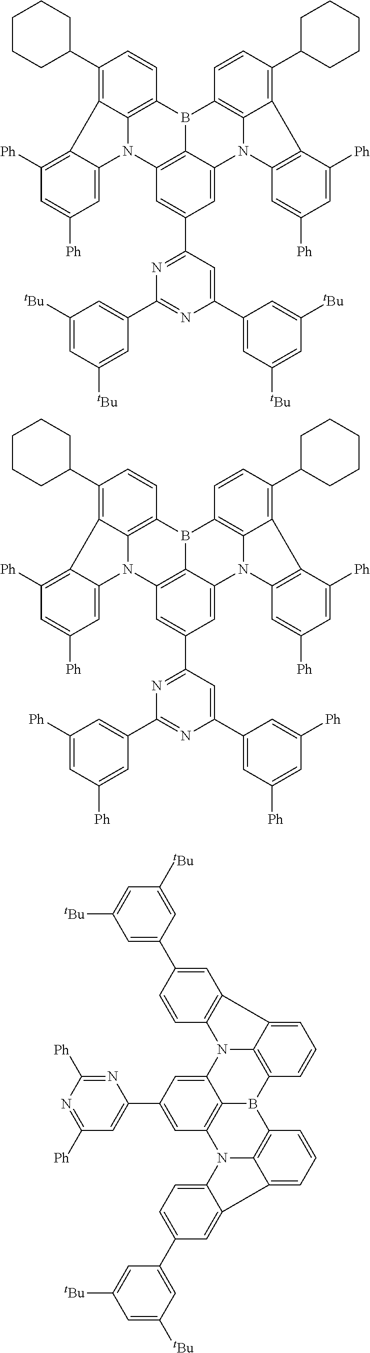

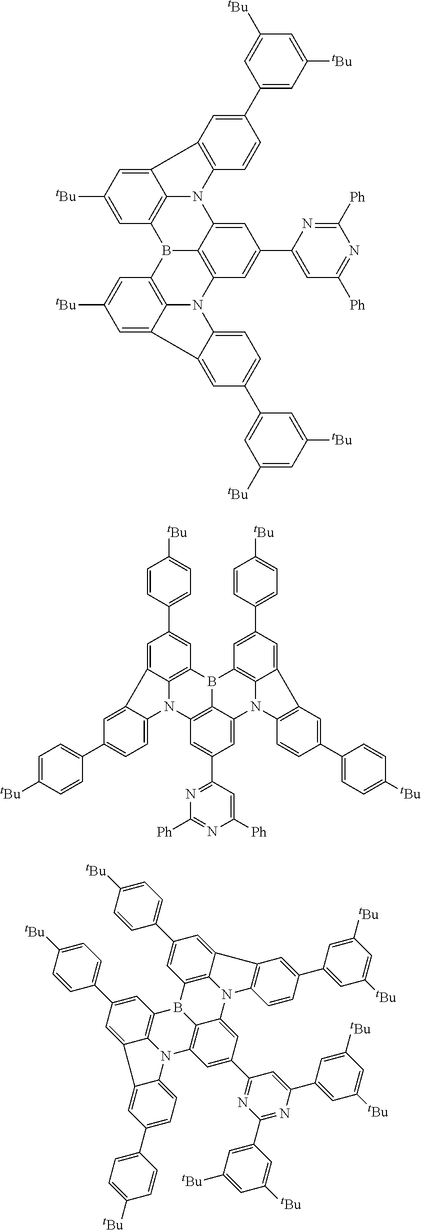

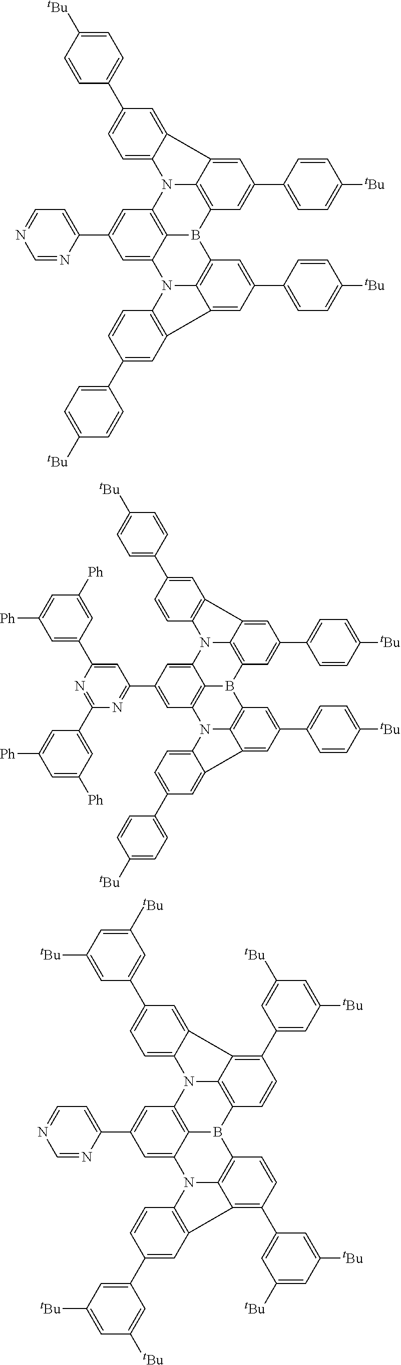

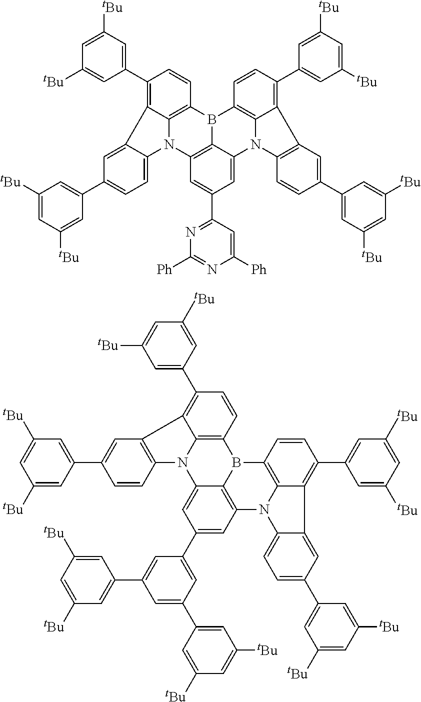

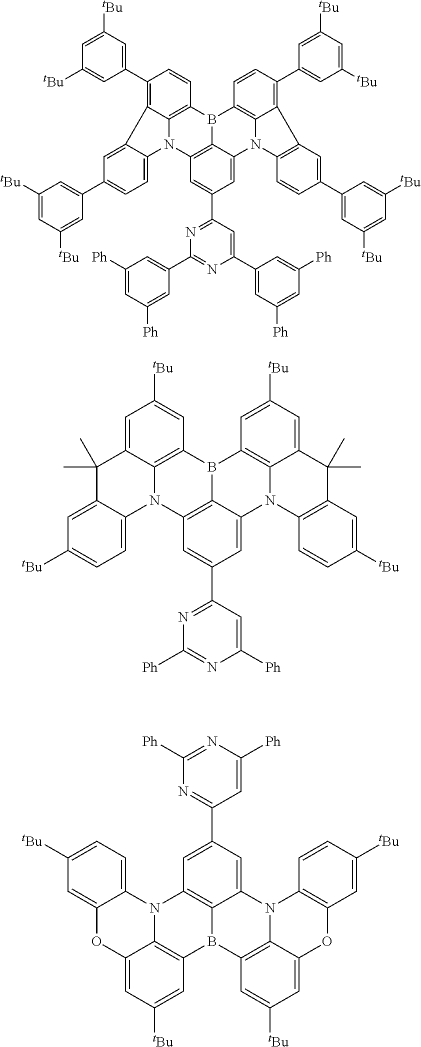

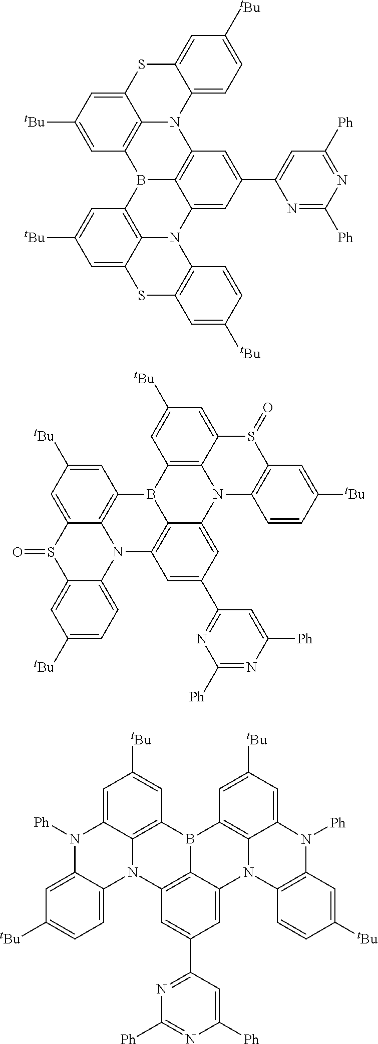 [SMILES: CC(C)(C)c1ccc2c(c1)Sc1cc(C(C)(C)C)cc3c1N2c1cc(-c2cc(-c4ccccc4)nc(-c4ccccc4)n2)cc2c1B3c1cc(C(C)(C)C)cc3c1N2c1ccc(C(C)(C)C)cc1S3 ; CC(C)(C)c1ccc2c(c1)S(=O)c1cc(C(C)(C)C)cc3c1N2c1cc(-c2cc(-c4ccccc4)nc(-c4ccccc4)n2)cc2c1B3c1cc(C(C)(C)C)cc3c1N2c1ccc(C(C)(C)C)cc1S3=O ; CC(C)(C)c1ccc2c(c1)N(c1ccccc1)c1cc(C(C)(C)C)cc3c1N2c1cc(-c2cc(-c4ccccc4)nc(-c4ccccc4)n2)cc2c1B3c1cc(C(C)(C)C)cc3c1N2c1ccc(C(C)(C)C)cc1N3c1ccccc1]

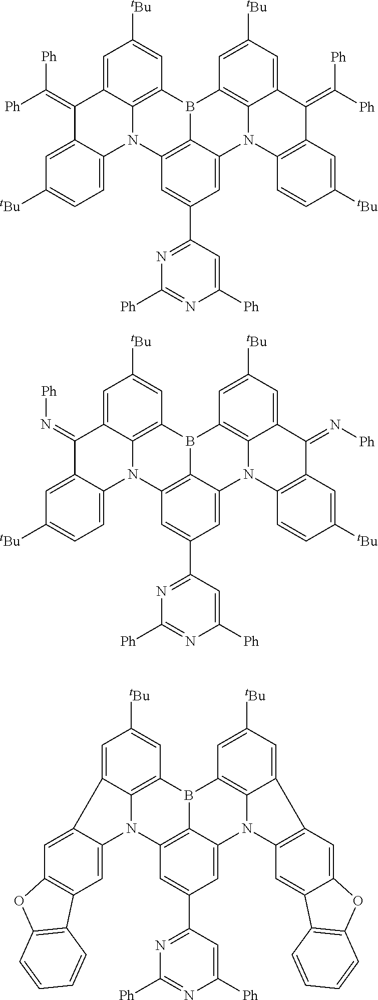

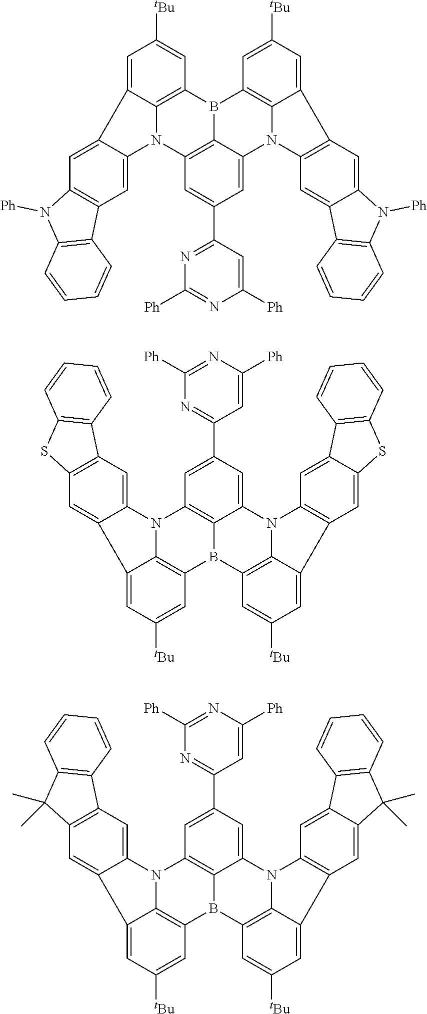

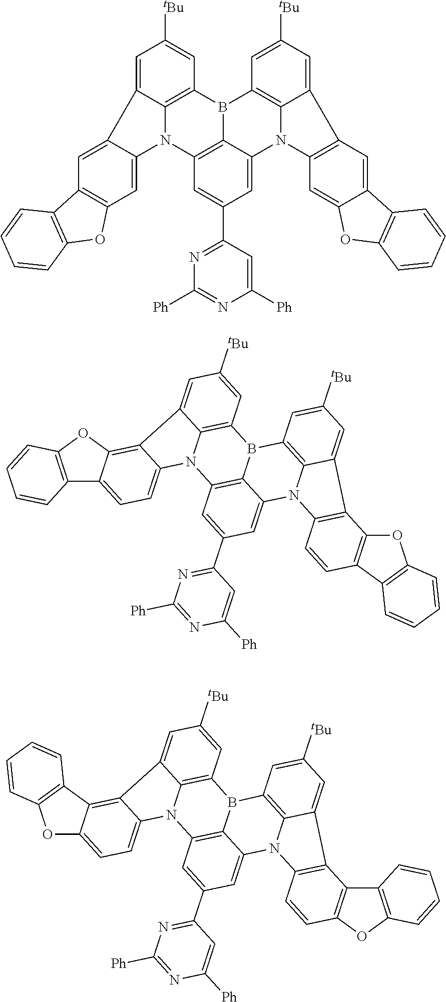

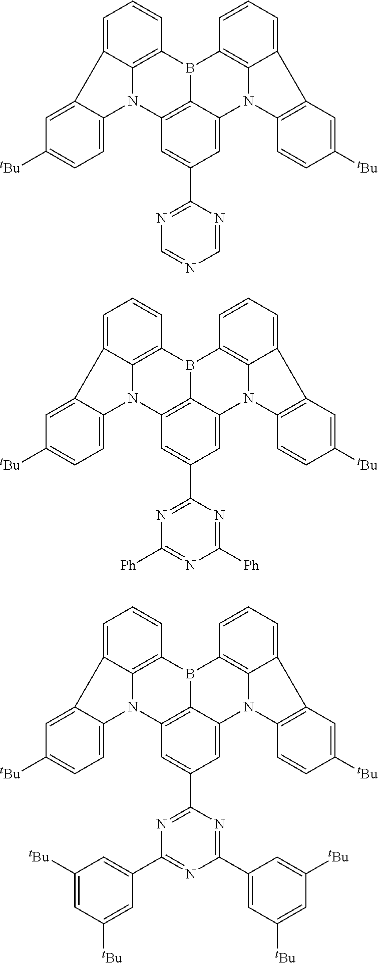

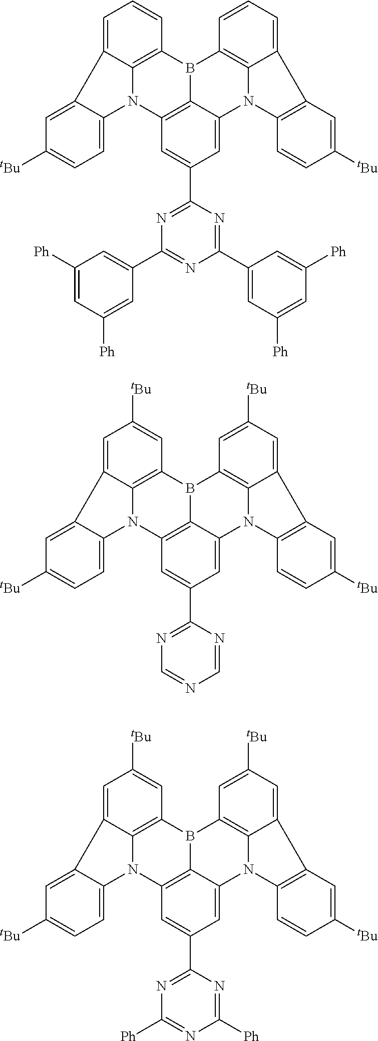 [SMILES: CC(C)(C)c1ccc2c(c1)c1cccc3c1n2-c1cc(-c2nc(-c4cc(-c5ccccc5)cc(-c5ccccc5)c4)nc(-c4cc(-c5ccccc5)cc(-c5ccccc5)c4)n2)cc2c1B3c1cccc3c4cc(C(C)(C)C)ccc4n-2c13 ; CC(C)(C)c1ccc2c(c1)c1cc(C(C)(C)C)cc3c1n2-c1cc(-c2ncncn2)cc2c1B3c1cc(C(C)(C)C)cc3c4cc(C(C)(C)C)ccc4n-2c13 ; CC(C)(C)c1ccc2c(c1)c1cc(C(C)(C)C)cc3c1n2-c1cc(-c2nc(-c4ccccc4)nc(-c4ccccc4)n2)cc2c1B3c1cc(C(C)(C)C)cc3c4cc(C(C)(C)C)ccc4n-2c13]

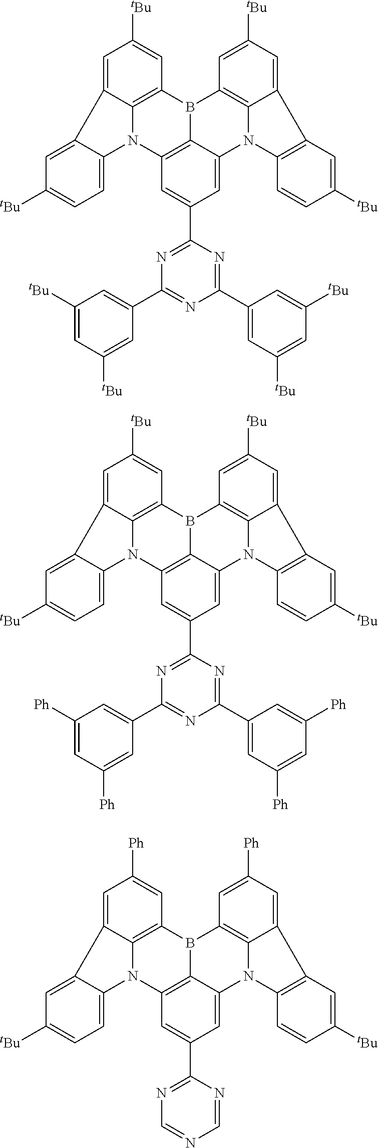

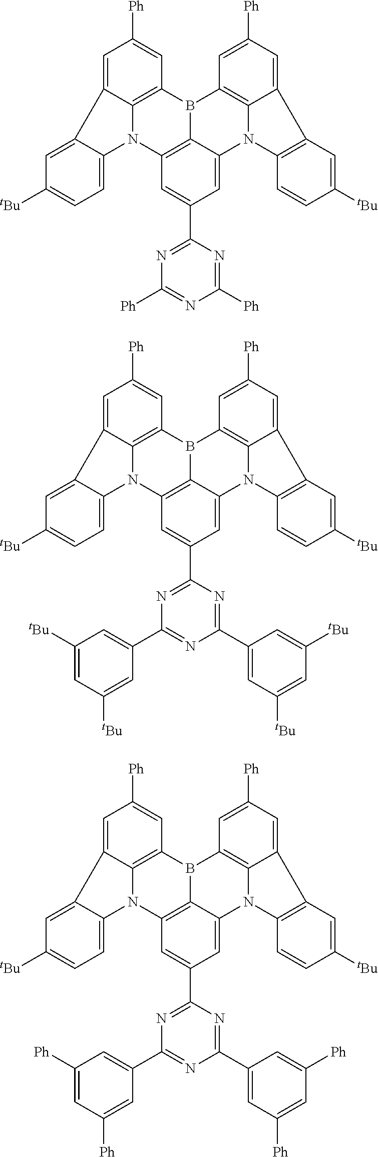

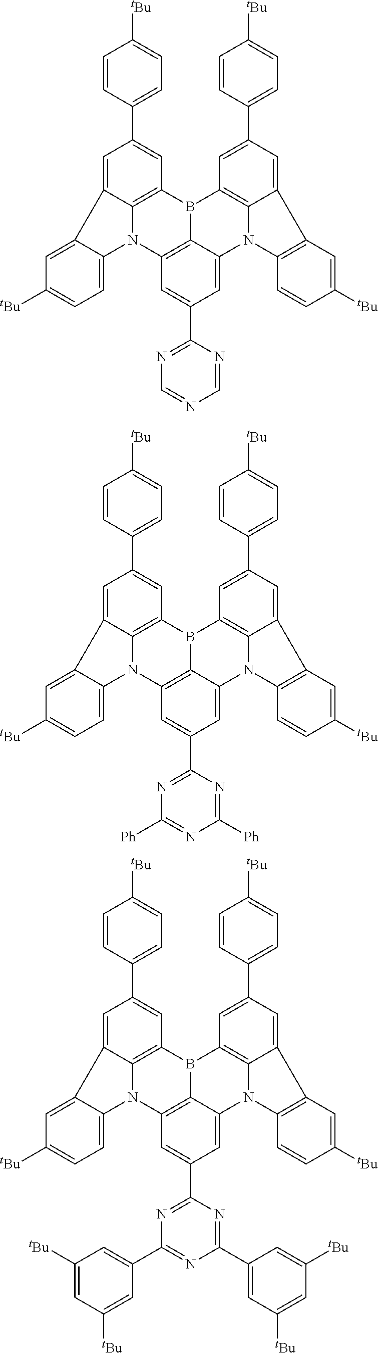

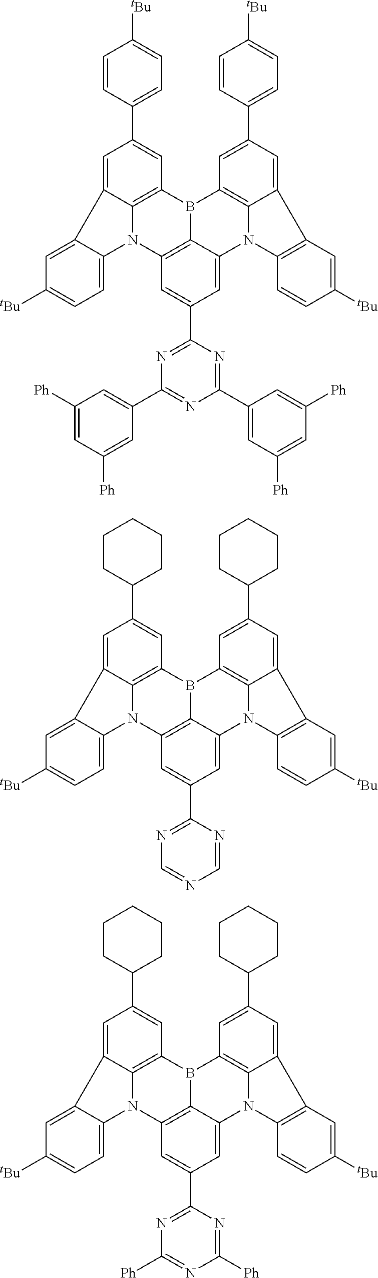

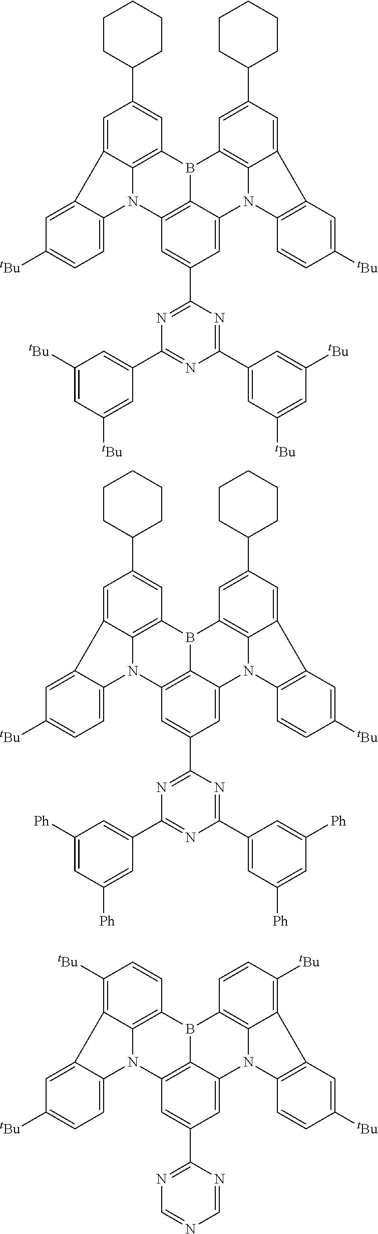

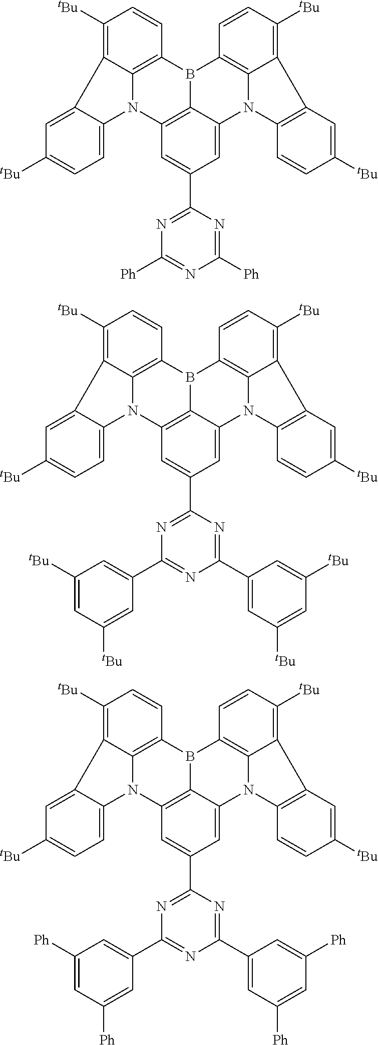

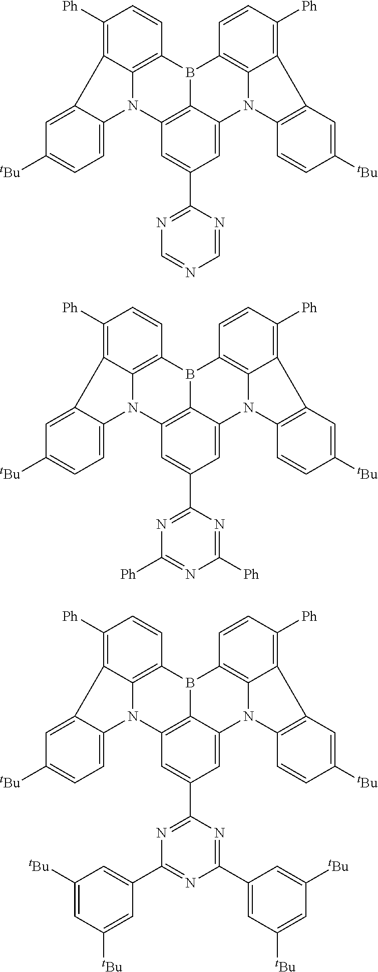

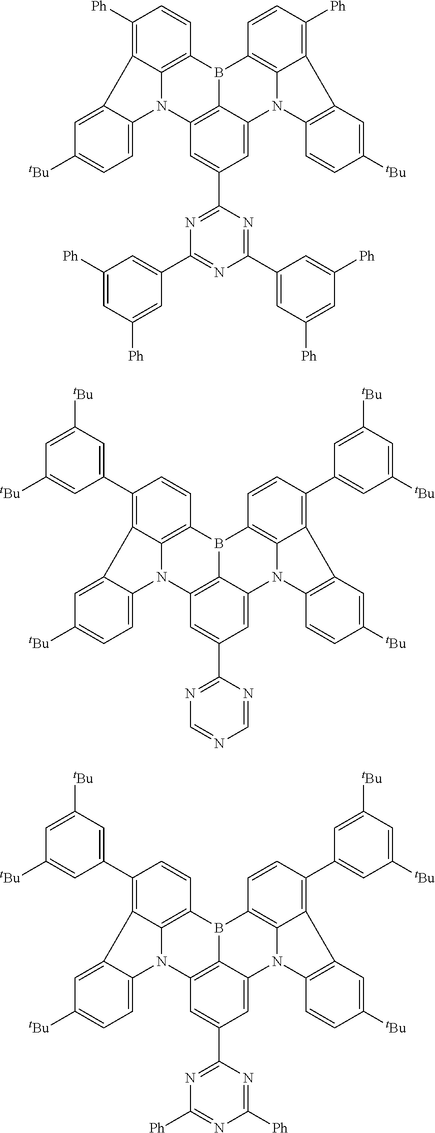 [SMILES: CC(C)(C)c1ccc2c(c1)c1c(-c3ccccc3)ccc3c1n2-c1cc(-c2nc(-c4cc(-c5ccccc5)cc(-c5ccccc5)c4)nc(-c4cc(-c5ccccc5)cc(-c5ccccc5)c4)n2)cc2c1B3c1ccc(-c3ccccc3)c3c4cc(C(C)(C)C)ccc4n-2c13 ; CC(C)(C)c1cc(-c2ccc3c4c2c2cc(C(C)(C)C)ccc2n4-c2cc(-c4ncncn4)cc4c2B3c2ccc(-c3cc(C(C)(C)C)cc(C(C)(C)C)c3)c3c5cc(C(C)(C)C)ccc5n-4c23)cc(C(C)(C)C)c1 ; CC(C)(C)c1cc(-c2ccc3c4c2c2cc(C(C)(C)C)ccc2n4-c2cc(-c4nc(-c5ccccc5)nc(-c5ccccc5)n4)cc4c2B3c2ccc(-c3cc(C(C)(C)C)cc(C(C)(C)C)c3)c3c5cc(C(C)(C)C)ccc5n-4c23)cc(C(C)(C)C)c1]

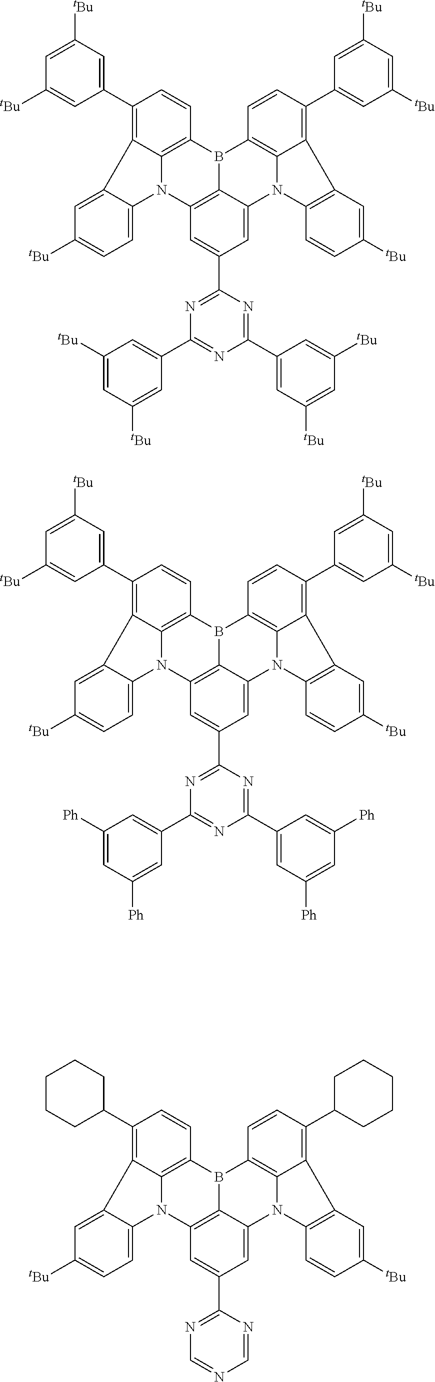

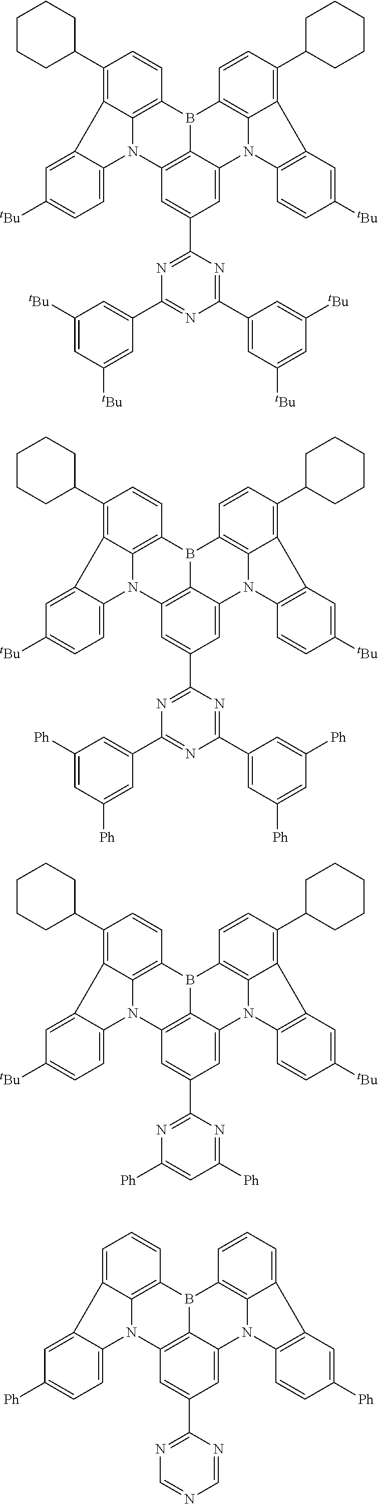

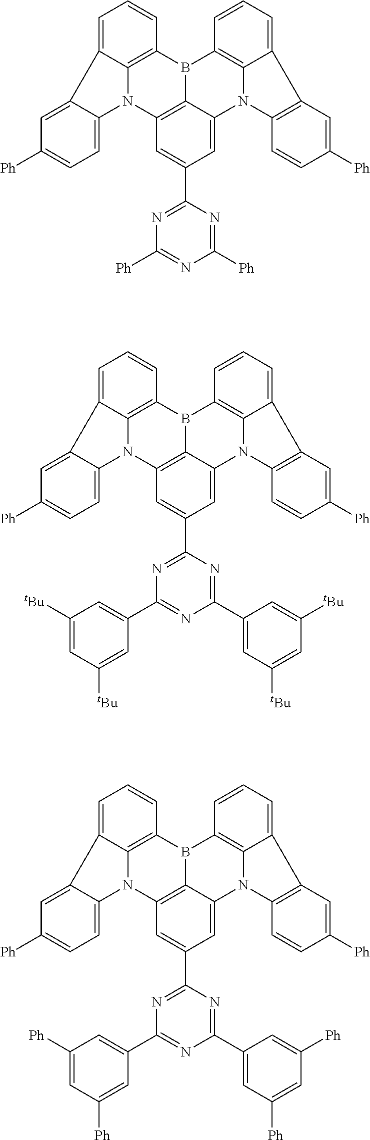 [SMILES: c1ccc(-c2ccc3c(c2)c2cccc4c2n3-c2cc(-c3nc(-c5ccccc5)nc(-c5ccccc5)n3)cc3c2B4c2cccc4c5cc(-c6ccccc6)ccc5n-3c24)cc1 ; CC(C)(C)c1cc(-c2nc(-c3cc(C(C)(C)C)cc(C(C)(C)C)c3)nc(-c3cc4c5c(c3)-n3c6ccc(-c7ccccc7)cc6c6cccc(c63)B5c3cccc5c6cc(-c7ccccc7)ccc6n-4c35)n2)cc(C(C)(C)C)c1 ; c1ccc(-c2cc(-c3ccccc3)cc(-c3nc(-c4cc(-c5ccccc5)cc(-c5ccccc5)c4)nc(-c4cc5c6c(c4)-n4c7ccc(-c8ccccc8)cc7c7cccc(c74)B6c4cccc6c7cc(-c8ccccc8)ccc7n-5c46)n3)c2)cc1]

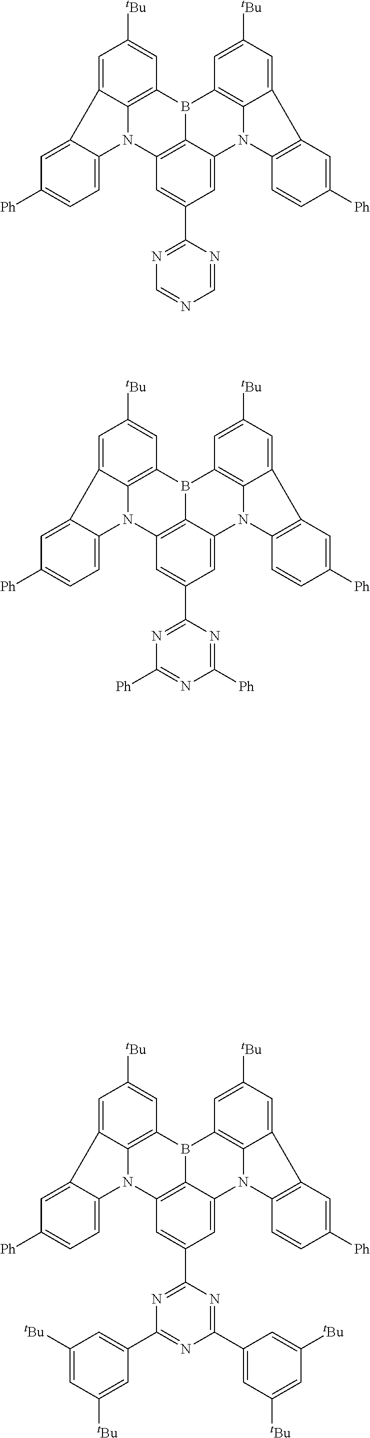 [SMILES: CC(C)(C)c1cc2c3c(c1)c1cc(-c4ccccc4)ccc1n3-c1cc(-c3ncncn3)cc3c1B2c1cc(C(C)(C)C)cc2c4cc(-c5ccccc5)ccc4n-3c12 ; CC(C)(C)c1cc2c3c(c1)c1cc(-c4ccccc4)ccc1n3-c1cc(-c3nc(-c4ccccc4)nc(-c4ccccc4)n3)cc3c1B2c1cc(C(C)(C)C)cc2c4cc(-c5ccccc5)ccc4n-3c12 ; CC(C)(C)c1cc(-c2nc(-c3cc(C(C)(C)C)cc(C(C)(C)C)c3)nc(-c3cc4c5c(c3)-n3c6ccc(-c7ccccc7)cc6c6cc(C(C)(C)C)cc(c63)B5c3cc(C(C)(C)C)cc5c6cc(-c7ccccc7)ccc6n-4c35)n2)cc(C(C)(C)C)c1]

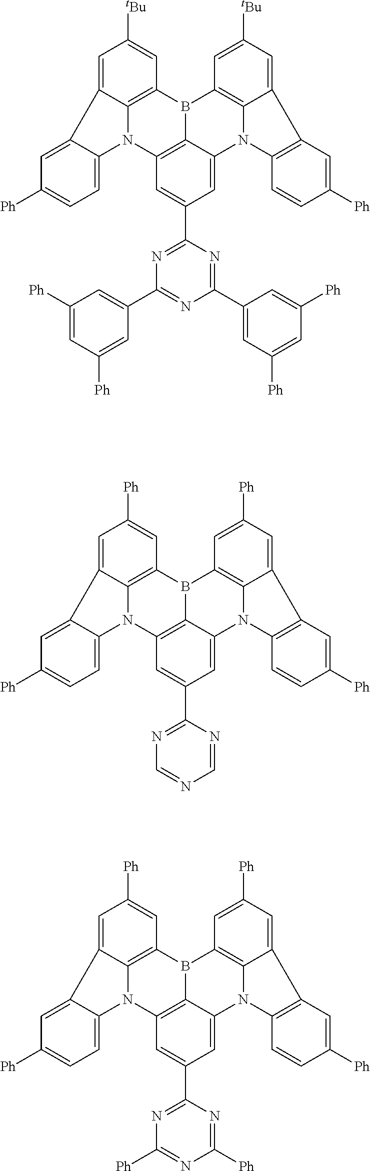 [SMILES: CC(C)(C)c1cc2c3c(c1)c1cc(-c4ccccc4)ccc1n3-c1cc(-c3nc(-c4cc(-c5ccccc5)cc(-c5ccccc5)c4)nc(-c4cc(-c5ccccc5)cc(-c5ccccc5)c4)n3)cc3c1B2c1cc(C(C)(C)C)cc2c4cc(-c5ccccc5)ccc4n-3c12 ; c1ccc(-c2ccc3c(c2)c2cc(-c4ccccc4)cc4c2n3-c2cc(-c3ncncn3)cc3c2B4c2cc(-c4ccccc4)cc4c5cc(-c6ccccc6)ccc5n-3c24)cc1 ; c1ccc(-c2ccc3c(c2)c2cc(-c4ccccc4)cc4c2n3-c2cc(-c3nc(-c5ccccc5)nc(-c5ccccc5)n3)cc3c2B4c2cc(-c4ccccc4)cc4c5cc(-c6ccccc6)ccc5n-3c24)cc1]

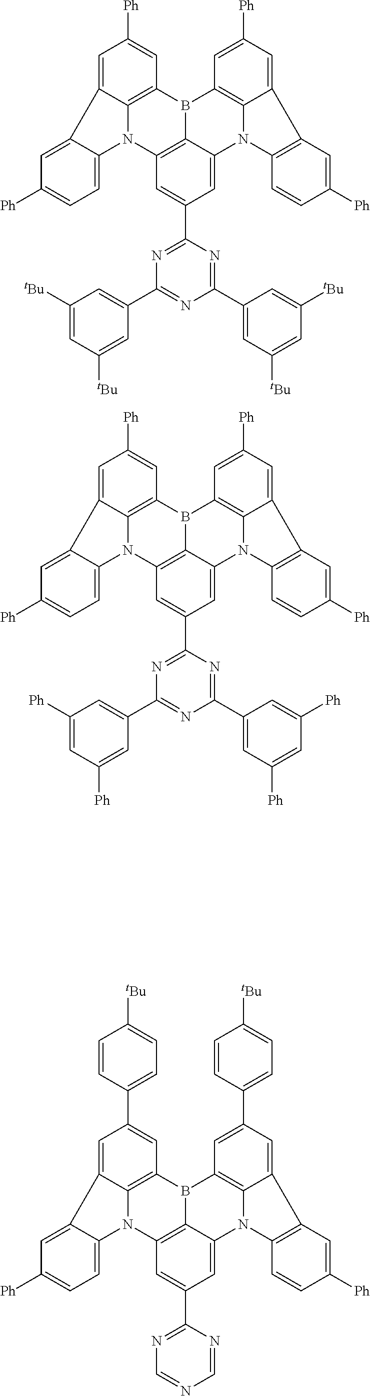

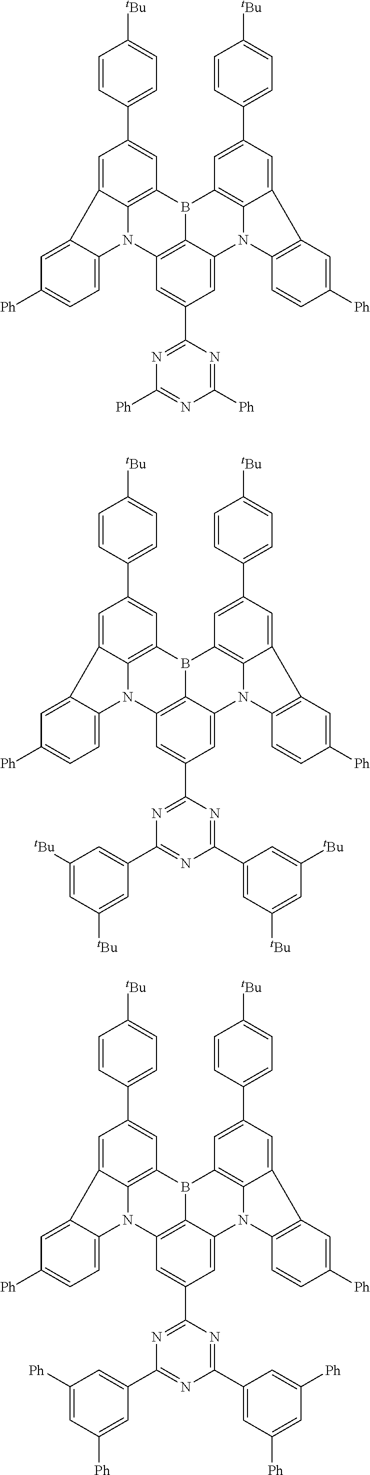

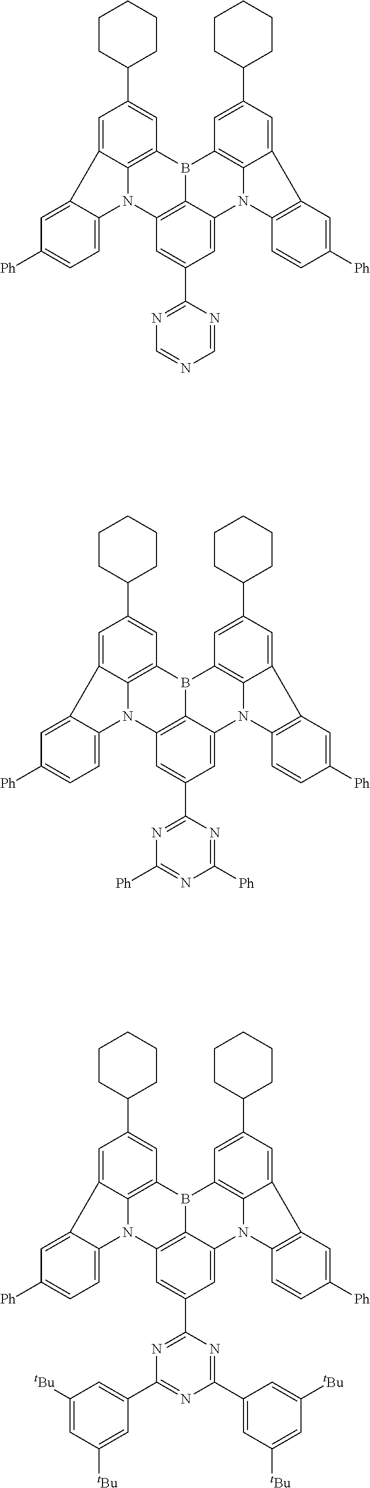 [SMILES: c1ccc(-c2ccc3c(c2)c2cc(C4CCCCC4)cc4c2n3-c2cc(-c3ncncn3)cc3c2B4c2cc(C4CCCCC4)cc4c5cc(-c6ccccc6)ccc5n-3c24)cc1 ; c1ccc(-c2ccc3c(c2)c2cc(C4CCCCC4)cc4c2n3-c2cc(-c3nc(-c5ccccc5)nc(-c5ccccc5)n3)cc3c2B4c2cc(C4CCCCC4)cc4c5cc(-c6ccccc6)ccc5n-3c24)cc1 ; CC(C)(C)c1cc(-c2nc(-c3cc(C(C)(C)C)cc(C(C)(C)C)c3)nc(-c3cc4c5c(c3)-n3c6ccc(-c7ccccc7)cc6c6cc(C7CCCCC7)cc(c63)B5c3cc(C5CCCCC5)cc5c6cc(-c7ccccc7)ccc6n-4c35)n2)cc(C(C)(C)C)c1]

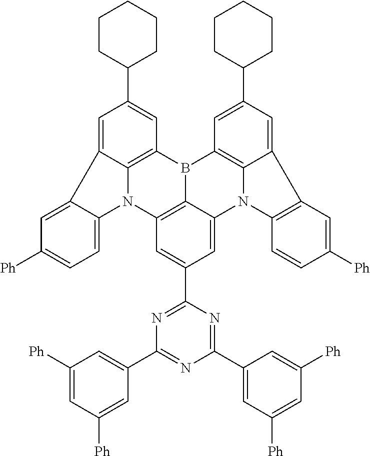 [SMILES: c1ccc(-c2cc(-c3ccccc3)cc(-c3nc(-c4cc(-c5ccccc5)cc(-c5ccccc5)c4)nc(-c4cc5c6c(c4)-n4c7ccc(-c8ccccc8)cc7c7cc(C8CCCCC8)cc(c74)B6c4cc(C6CCCCC6)cc6c7cc(-c8ccccc8)ccc7n-5c46)n3)c2)cc1]

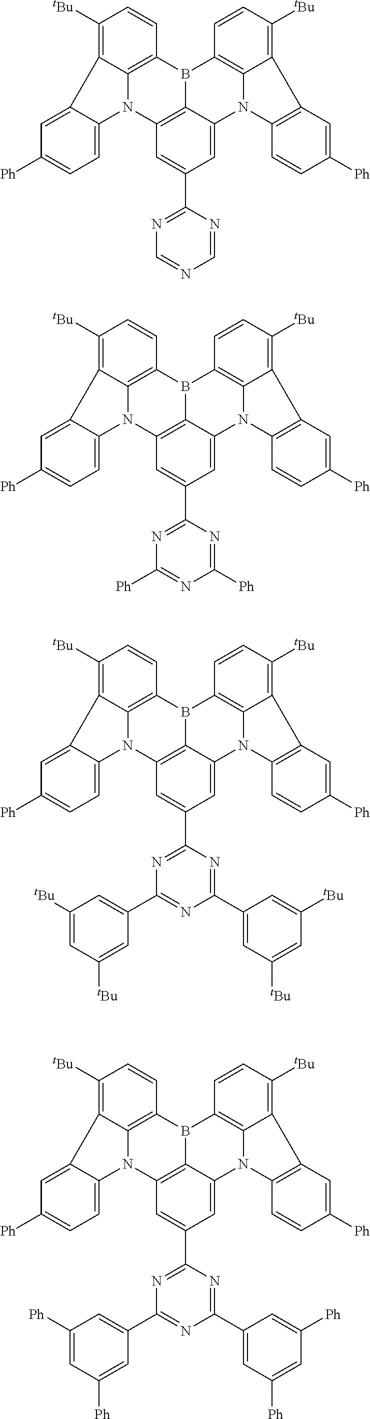

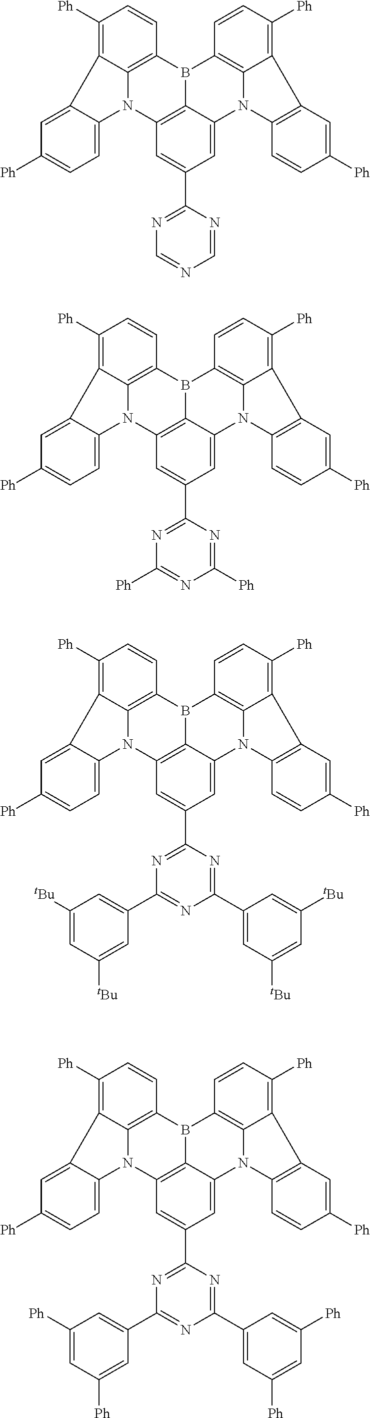

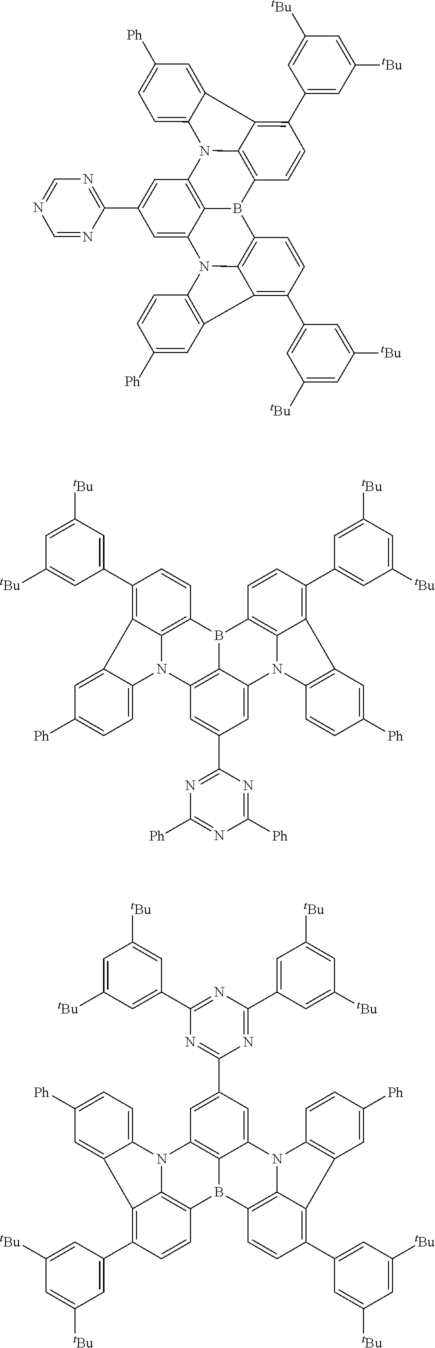

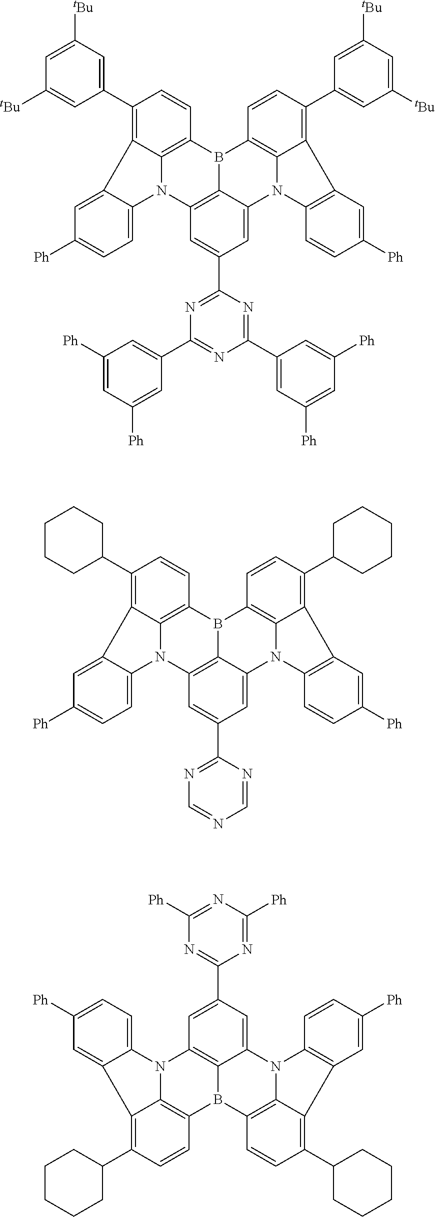 [SMILES: CC(C)(C)c1cc(-c2ccc3c4c2c2cc(-c5ccccc5)ccc2n4-c2cc(-c4nc(-c5cc(-c6ccccc6)cc(-c6ccccc6)c5)nc(-c5cc(-c6ccccc6)cc(-c6ccccc6)c5)n4)cc4c2B3c2ccc(-c3cc(C(C)(C)C)cc(C(C)(C)C)c3)c3c5cc(-c6ccccc6)ccc5n-4c23)cc(C(C)(C)C)c1 ; c1ccc(-c2ccc3c(c2)c2c(C4CCCCC4)ccc4c2n3-c2cc(-c3ncncn3)cc3c2B4c2ccc(C4CCCCC4)c4c5cc(-c6ccccc6)ccc5n-3c24)cc1 ; c1ccc(-c2ccc3c(c2)c2c(C4CCCCC4)ccc4c2n3-c2cc(-c3nc(-c5ccccc5)nc(-c5ccccc5)n3)cc3c2B4c2ccc(C4CCCCC4)c4c5cc(-c6ccccc6)ccc5n-3c24)cc1]

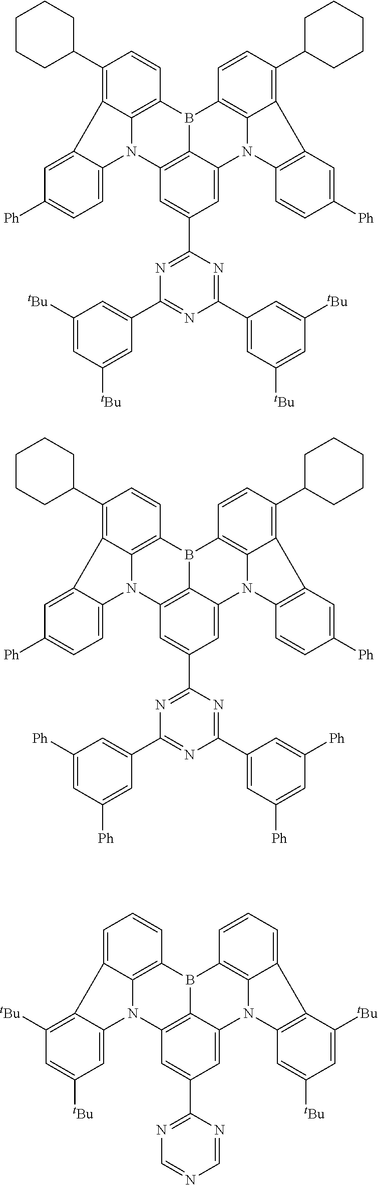 [SMILES: CC(C)(C)c1cc(-c2nc(-c3cc(C(C)(C)C)cc(C(C)(C)C)c3)nc(-c3cc4c5c(c3)-n3c6ccc(-c7ccccc7)cc6c6c(C7CCCCC7)ccc(c63)B5c3ccc(C5CCCCC5)c5c6cc(-c7ccccc7)ccc6n-4c35)n2)cc(C(C)(C)C)c1 ; c1ccc(-c2cc(-c3ccccc3)cc(-c3nc(-c4cc(-c5ccccc5)cc(-c5ccccc5)c4)nc(-c4cc5c6c(c4)-n4c7ccc(-c8ccccc8)cc7c7c(C8CCCCC8)ccc(c74)B6c4ccc(C6CCCCC6)c6c7cc(-c8ccccc8)ccc7n-5c46)n3)c2)cc1 ; CC(C)(C)c1cc(C(C)(C)C)c2c3cccc4c3n(c2c1)-c1cc(-c2ncncn2)cc2c1B4c1cccc3c4c(C(C)(C)C)cc(C(C)(C)C)cc4n-2c13]

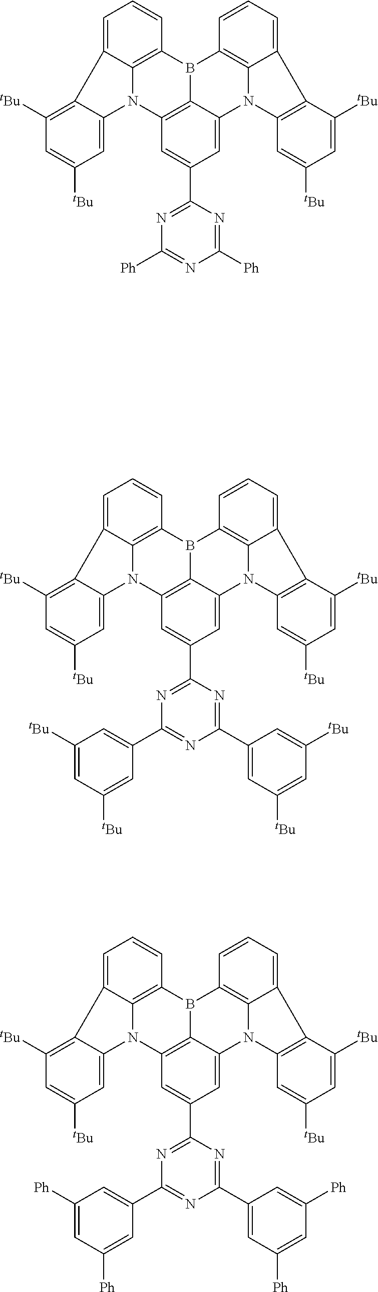 [SMILES: CC(C)(C)c1cc(C(C)(C)C)c2c3cccc4c3n(c2c1)-c1cc(-c2nc(-c3ccccc3)nc(-c3ccccc3)n2)cc2c1B4c1cccc3c4c(C(C)(C)C)cc(C(C)(C)C)cc4n-2c13 ; CC(C)(C)c1cc(-c2nc(-c3cc(C(C)(C)C)cc(C(C)(C)C)c3)nc(-c3cc4c5c(c3)-n3c6cc(C(C)(C)C)cc(C(C)(C)C)c6c6cccc(c63)B5c3cccc5c6c(C(C)(C)C)cc(C(C)(C)C)cc6n-4c35)n2)cc(C(C)(C)C)c1 ; CC(C)(C)c1cc(C(C)(C)C)c2c3cccc4c3n(c2c1)-c1cc(-c2nc(-c3cc(-c5ccccc5)cc(-c5ccccc5)c3)nc(-c3cc(-c5ccccc5)cc(-c5ccccc5)c3)n2)cc2c1B4c1cccc3c4c(C(C)(C)C)cc(C(C)(C)C)cc4n-2c13]

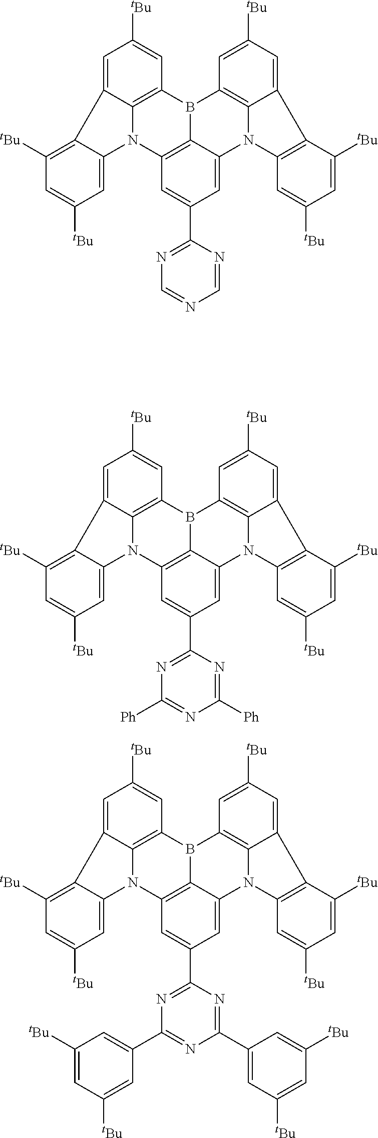

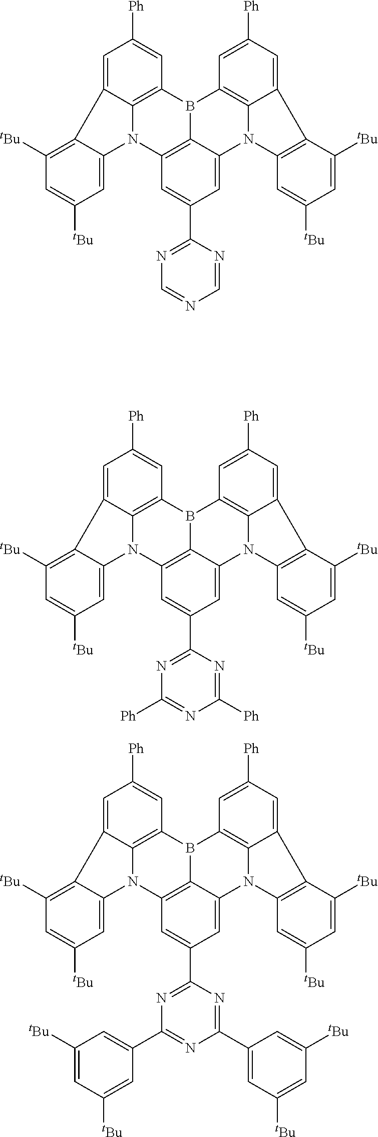

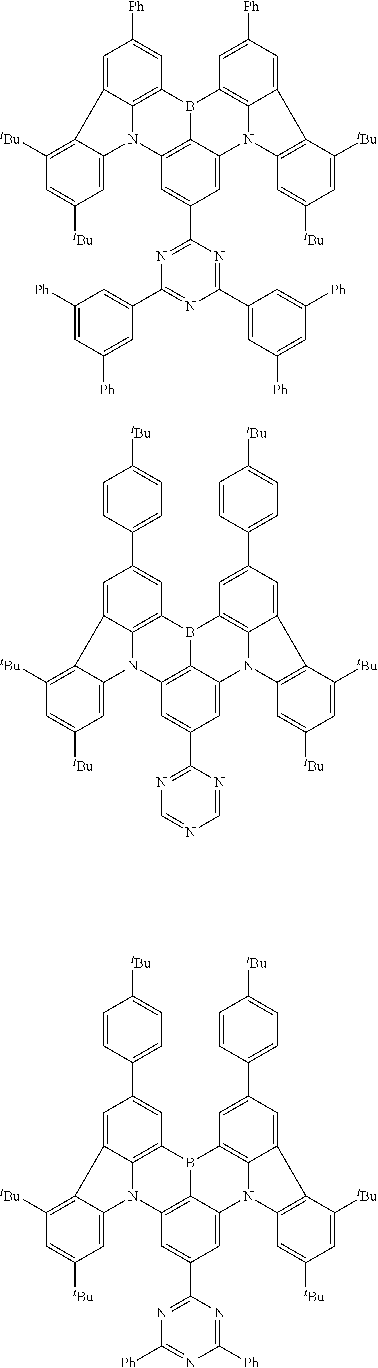

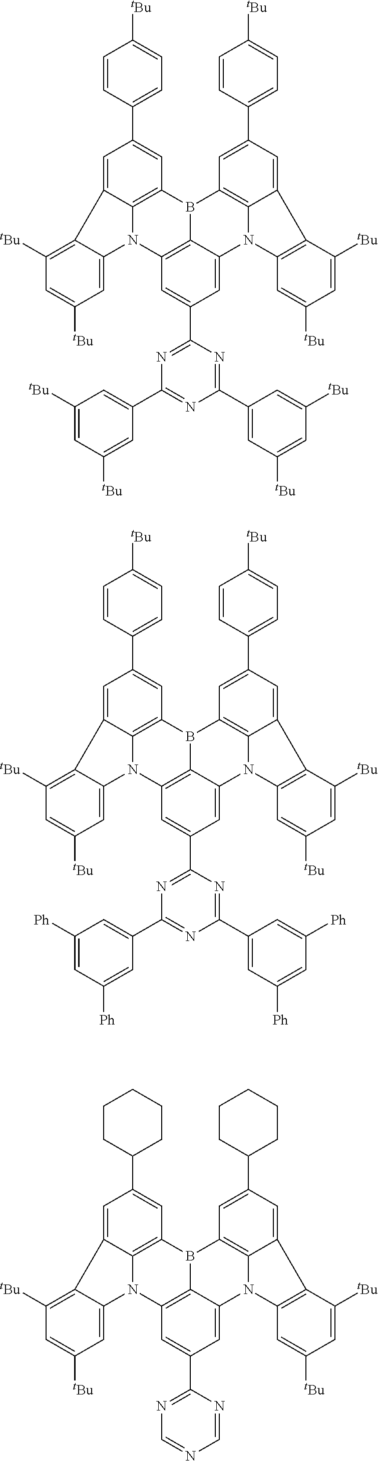

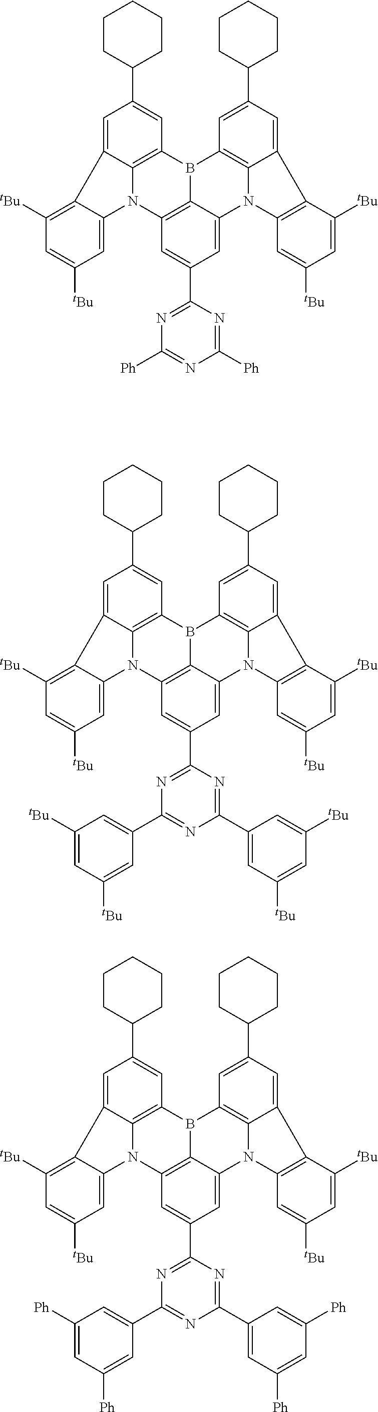

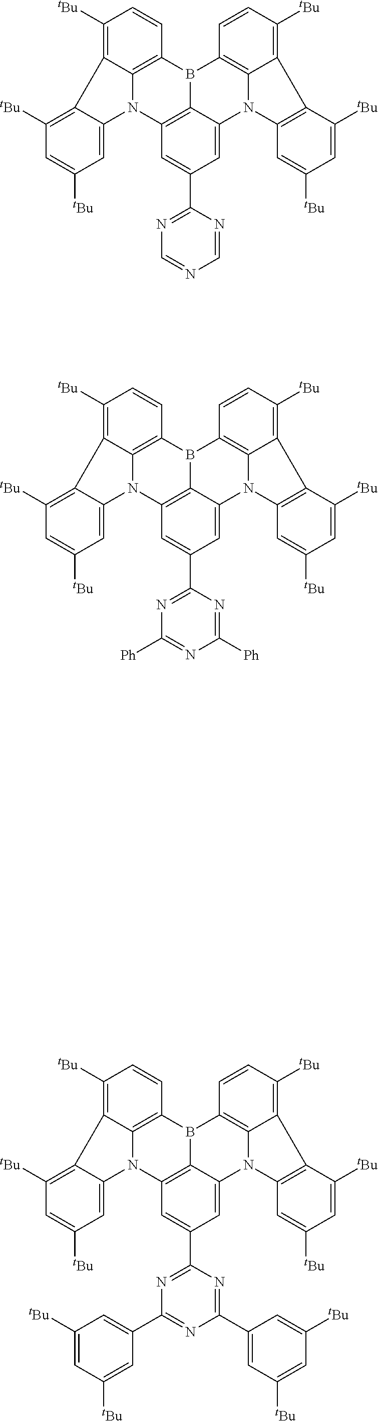 [SMILES: CC(C)(C)c1cc(C(C)(C)C)c2c3c(C(C)(C)C)ccc4c3n(c2c1)-c1cc(-c2ncncn2)cc2c1B4c1ccc(C(C)(C)C)c3c4c(C(C)(C)C)cc(C(C)(C)C)cc4n-2c13 ; CC(C)(C)c1cc(C(C)(C)C)c2c3c(C(C)(C)C)ccc4c3n(c2c1)-c1cc(-c2nc(-c3ccccc3)nc(-c3ccccc3)n2)cc2c1B4c1ccc(C(C)(C)C)c3c4c(C(C)(C)C)cc(C(C)(C)C)cc4n-2c13 ; CC(C)(C)c1cc(-c2nc(-c3cc(C(C)(C)C)cc(C(C)(C)C)c3)nc(-c3cc4c5c(c3)-n3c6cc(C(C)(C)C)cc(C(C)(C)C)c6c6c(C(C)(C)C)ccc(c63)B5c3ccc(C(C)(C)C)c5c6c(C(C)(C)C)cc(C(C)(C)C)cc6n-4c35)n2)cc(C(C)(C)C)c1]

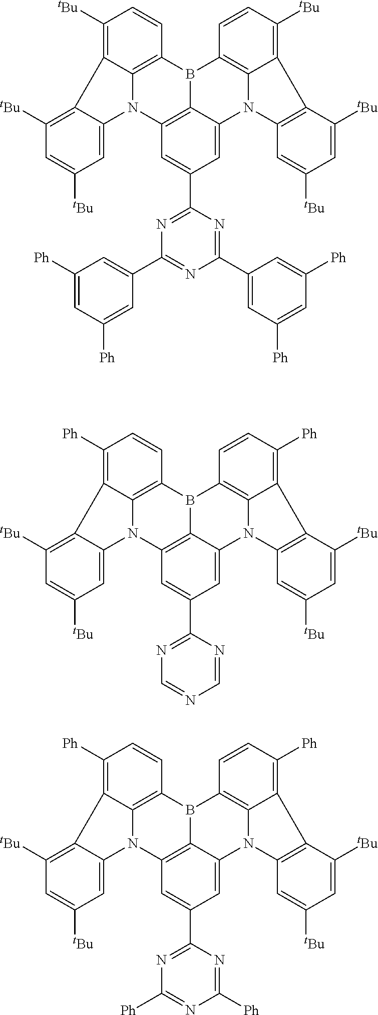 [SMILES: CC(C)(C)c1cc(C(C)(C)C)c2c3c(C(C)(C)C)ccc4c3n(c2c1)-c1cc(-c2nc(-c3cc(-c5ccccc5)cc(-c5ccccc5)c3)nc(-c3cc(-c5ccccc5)cc(-c5ccccc5)c3)n2)cc2c1B4c1ccc(C(C)(C)C)c3c4c(C(C)(C)C)cc(C(C)(C)C)cc4n-2c13 ; CC(C)(C)c1cc(C(C)(C)C)c2c3c(-c4ccccc4)ccc4c3n(c2c1)-c1cc(-c2ncncn2)cc2c1B4c1ccc(-c3ccccc3)c3c4c(C(C)(C)C)cc(C(C)(C)C)cc4n-2c13 ; CC(C)(C)c1cc(C(C)(C)C)c2c3c(-c4ccccc4)ccc4c3n(c2c1)-c1cc(-c2nc(-c3ccccc3)nc(-c3ccccc3)n2)cc2c1B4c1ccc(-c3ccccc3)c3c4c(C(C)(C)C)cc(C(C)(C)C)cc4n-2c13]

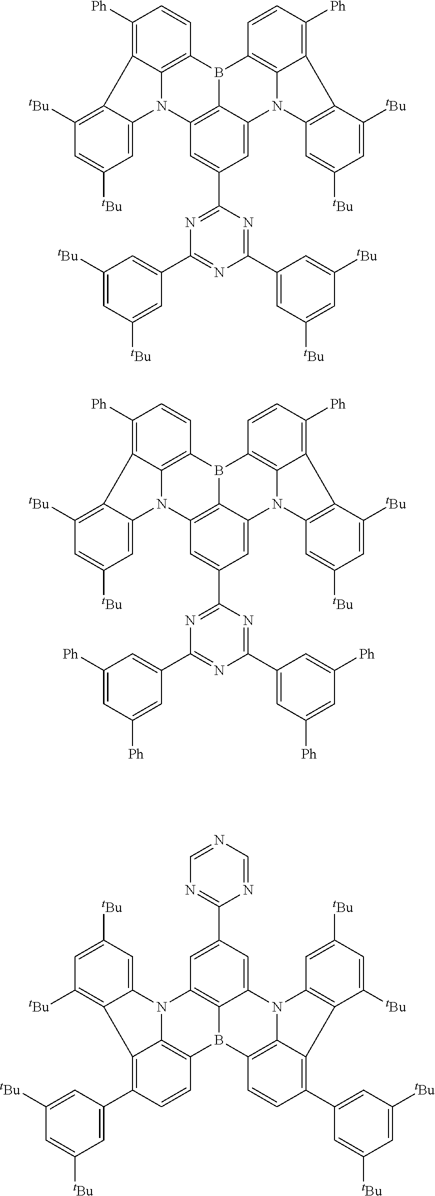

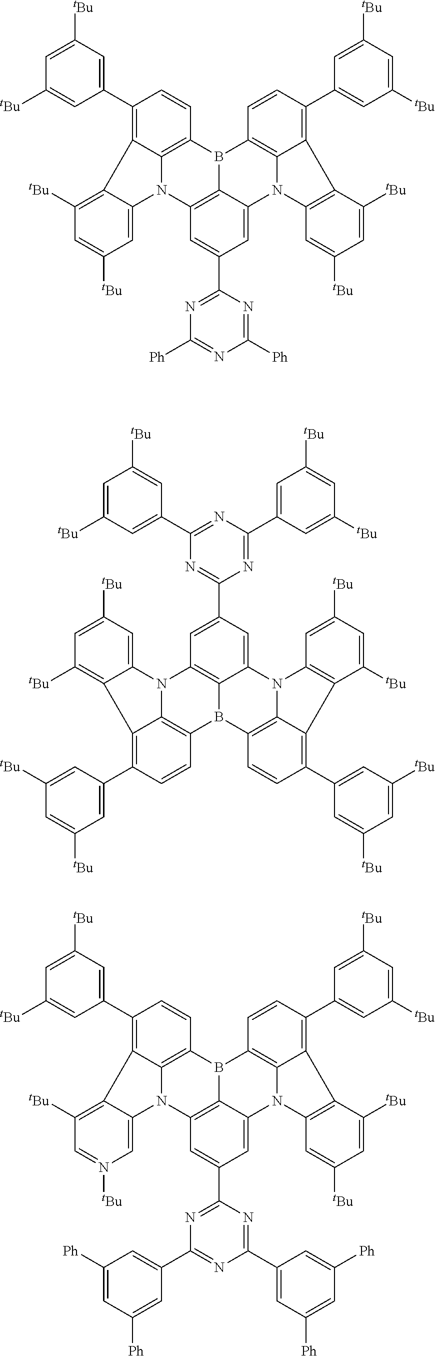

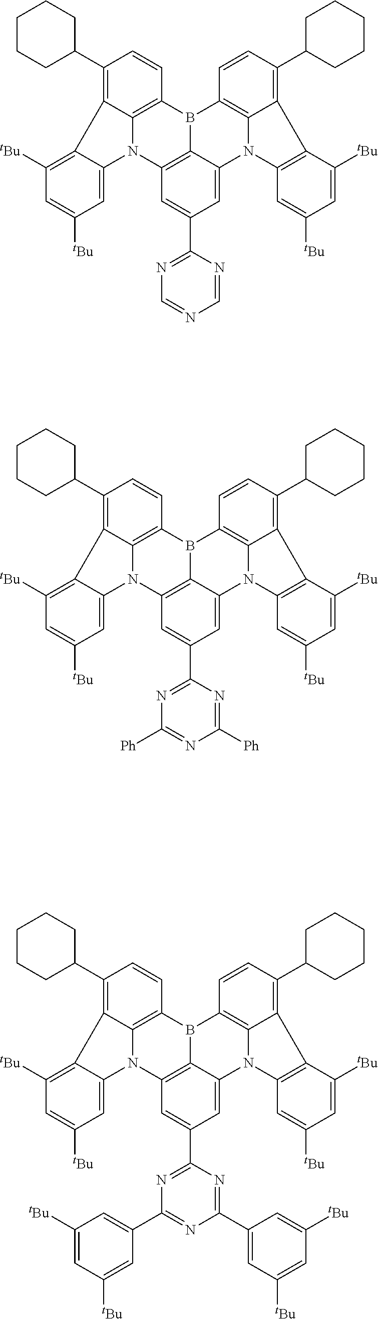 [SMILES: CC(C)(C)c1cc(C(C)(C)C)c2c3c(C4CCCCC4)ccc4c3n(c2c1)-c1cc(-c2ncncn2)cc2c1B4c1ccc(C3CCCCC3)c3c4c(C(C)(C)C)cc(C(C)(C)C)cc4n-2c13 ; CC(C)(C)c1cc(C(C)(C)C)c2c3c(C4CCCCC4)ccc4c3n(c2c1)-c1cc(-c2nc(-c3ccccc3)nc(-c3ccccc3)n2)cc2c1B4c1ccc(C3CCCCC3)c3c4c(C(C)(C)C)cc(C(C)(C)C)cc4n-2c13 ; CC(C)(C)c1cc(-c2nc(-c3cc(C(C)(C)C)cc(C(C)(C)C)c3)nc(-c3cc4c5c(c3)-n3c6cc(C(C)(C)C)cc(C(C)(C)C)c6c6c(C7CCCCC7)ccc(c63)B5c3ccc(C5CCCCC5)c5c6c(C(C)(C)C)cc(C(C)(C)C)cc6n-4c35)n2)cc(C(C)(C)C)c1]

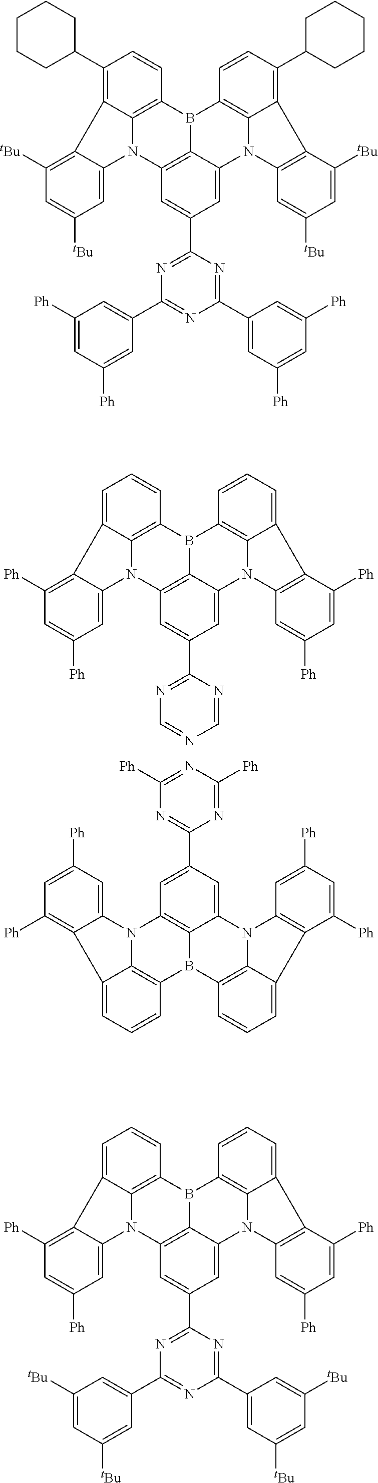

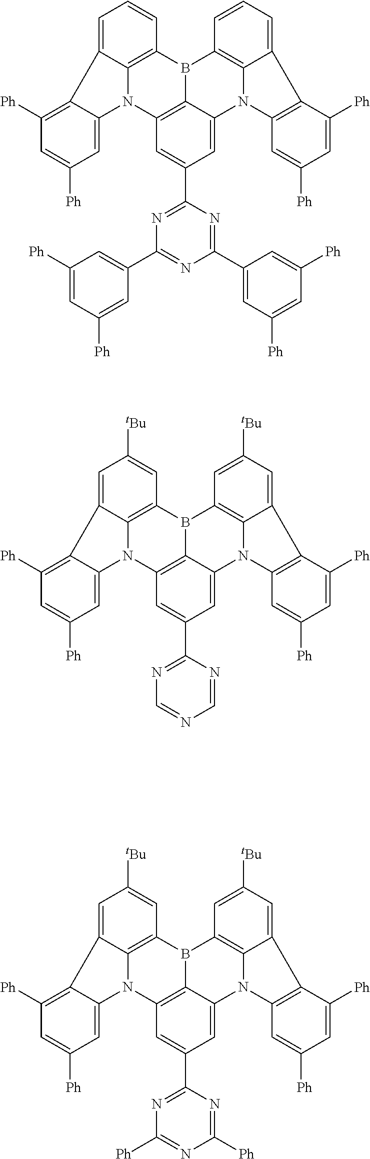 [SMILES: c1ccc(-c2cc(-c3ccccc3)cc(-c3nc(-c4cc(-c5ccccc5)cc(-c5ccccc5)c4)nc(-c4cc5c6c(c4)-n4c7cc(-c8ccccc8)cc(-c8ccccc8)c7c7cccc(c74)B6c4cccc6c7c(-c8ccccc8)cc(-c8ccccc8)cc7n-5c46)n3)c2)cc1 ; CC(C)(C)c1cc2c3c(c1)c1c(-c4ccccc4)cc(-c4ccccc4)cc1n3-c1cc(-c3ncncn3)cc3c1B2c1cc(C(C)(C)C)cc2c4c(-c5ccccc5)cc(-c5ccccc5)cc4n-3c12 ; CC(C)(C)c1cc2c3c(c1)c1c(-c4ccccc4)cc(-c4ccccc4)cc1n3-c1cc(-c3nc(-c4ccccc4)nc(-c4ccccc4)n3)cc3c1B2c1cc(C(C)(C)C)cc2c4c(-c5ccccc5)cc(-c5ccccc5)cc4n-3c12]

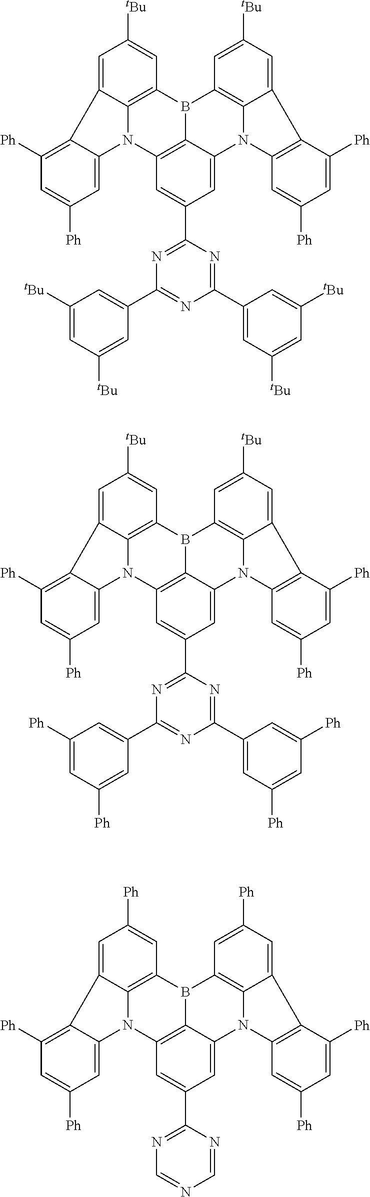

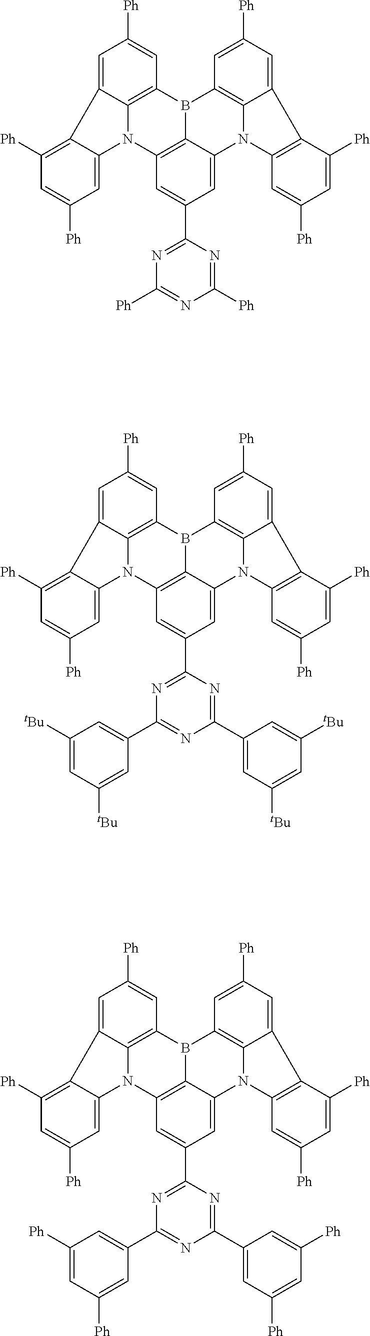

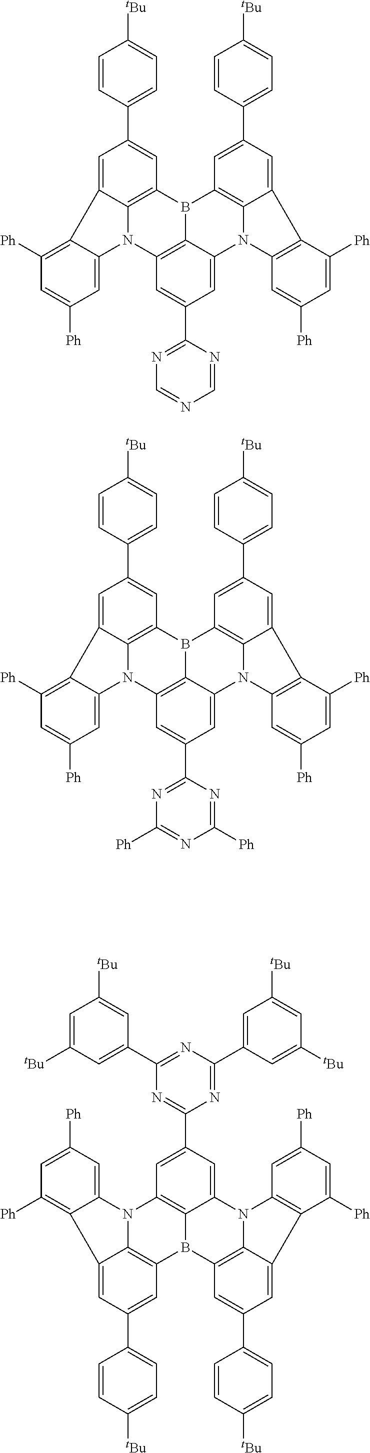

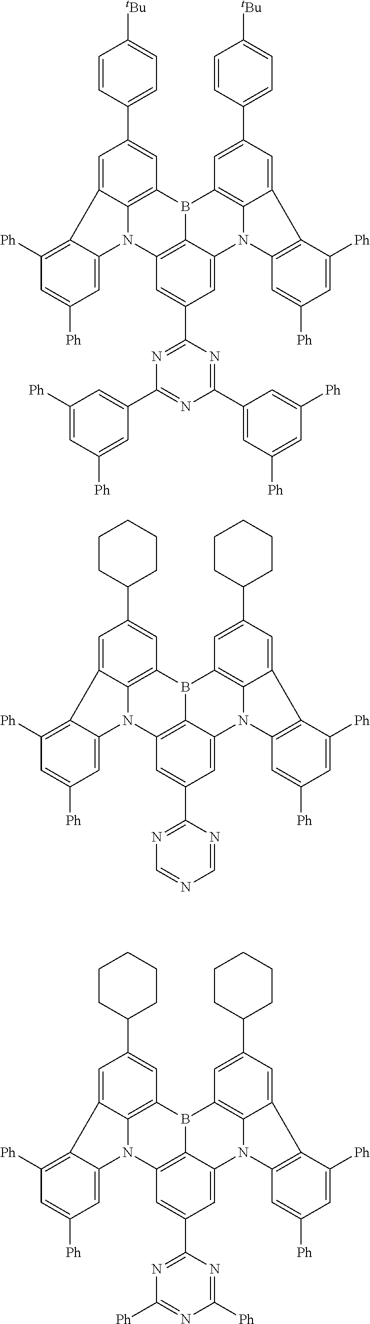

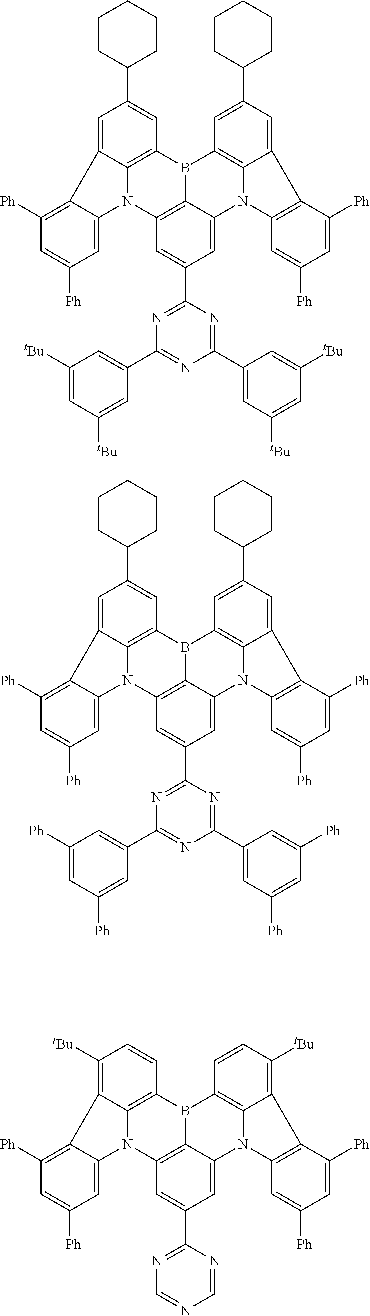

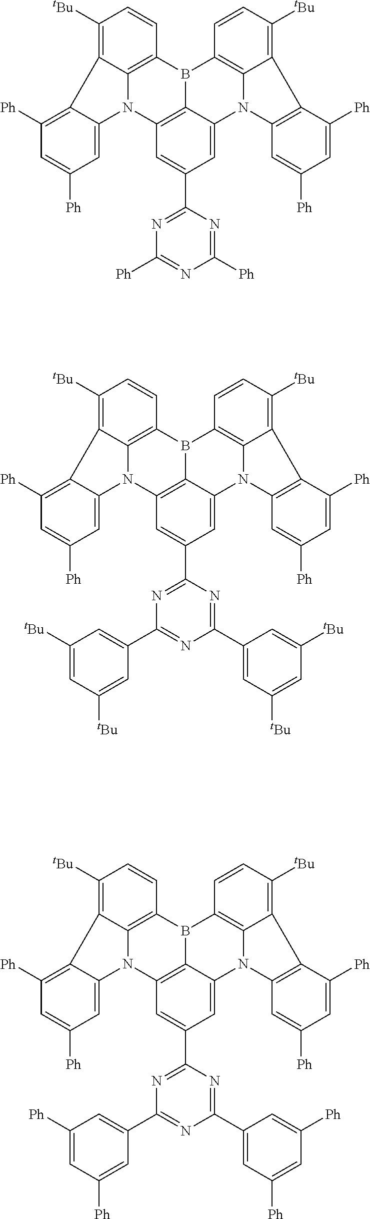

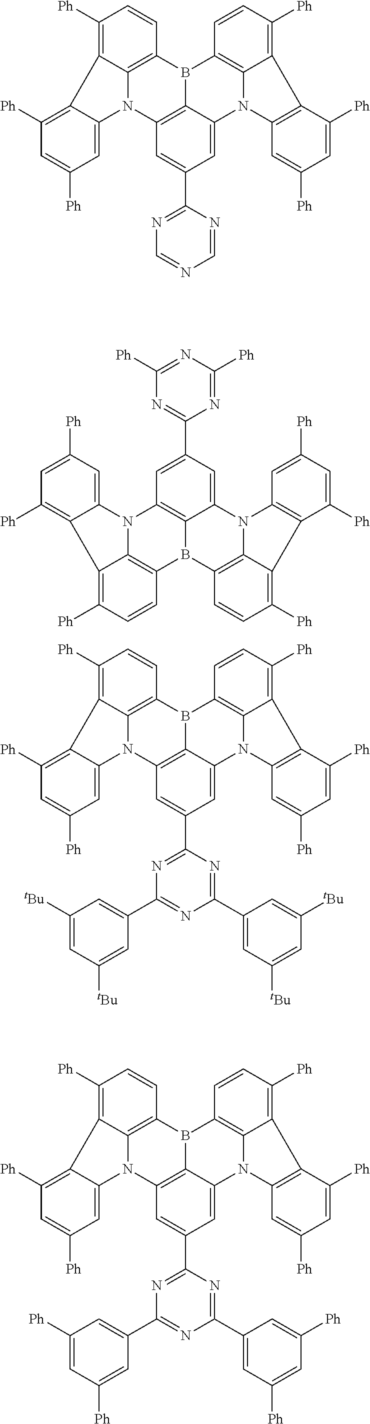

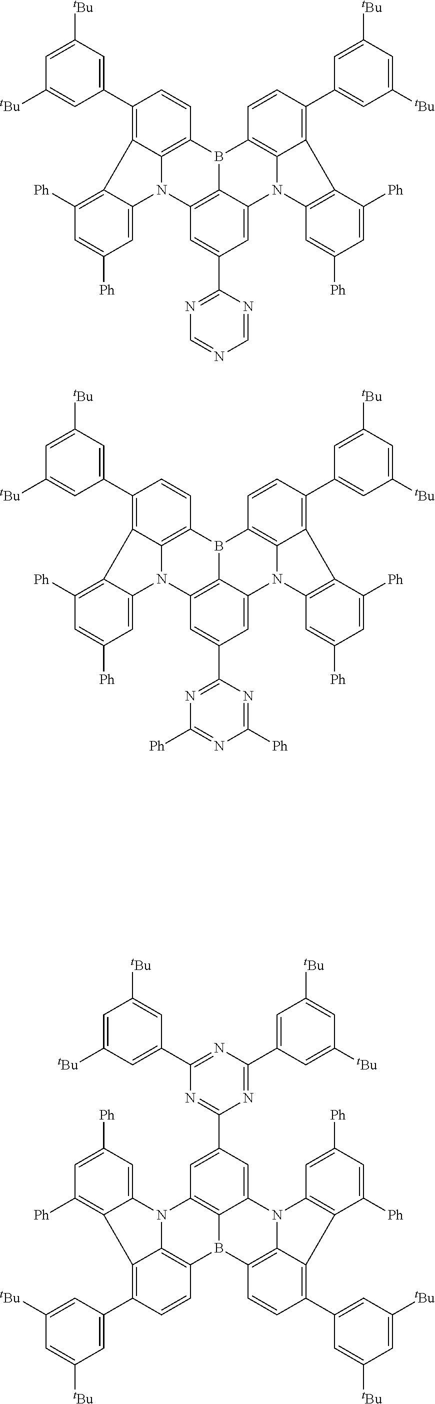

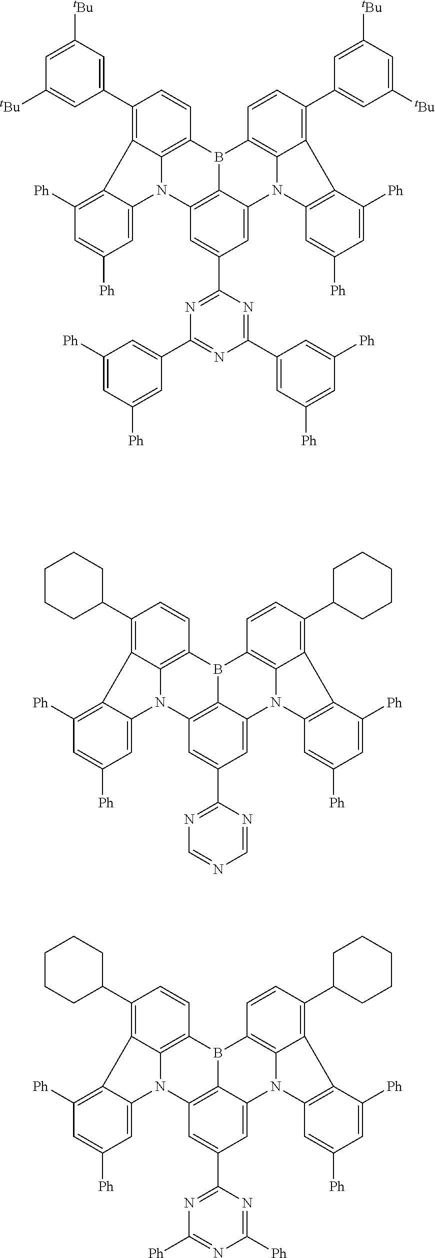

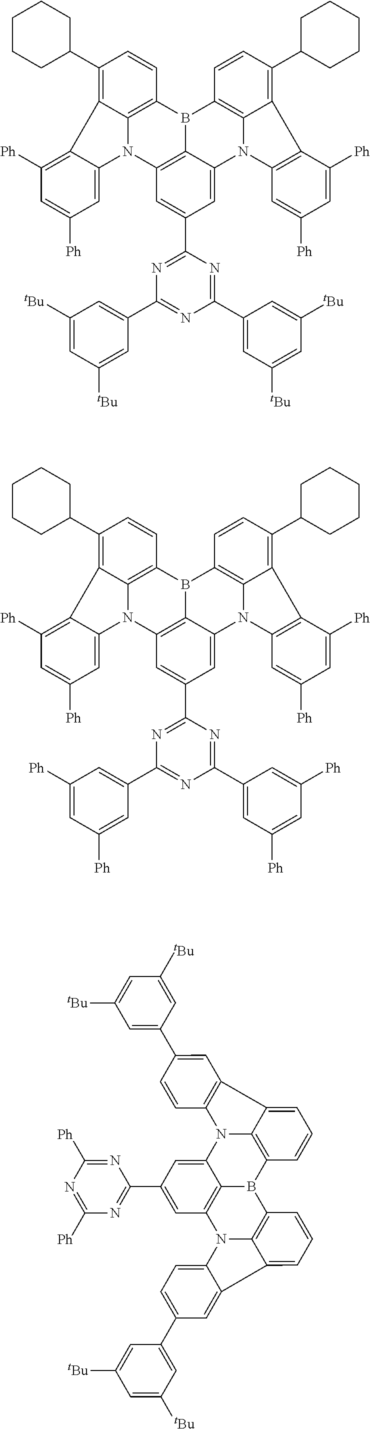

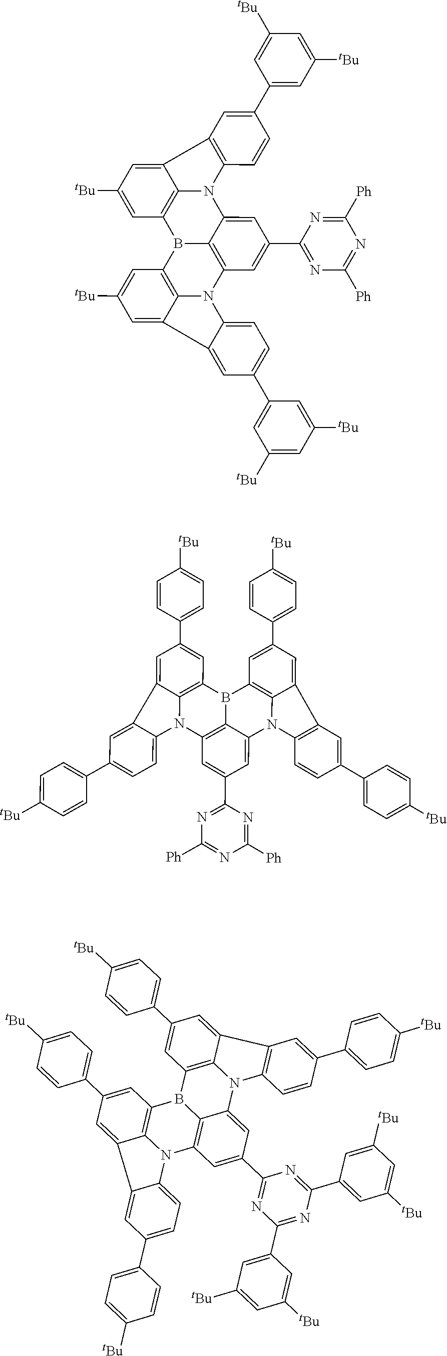

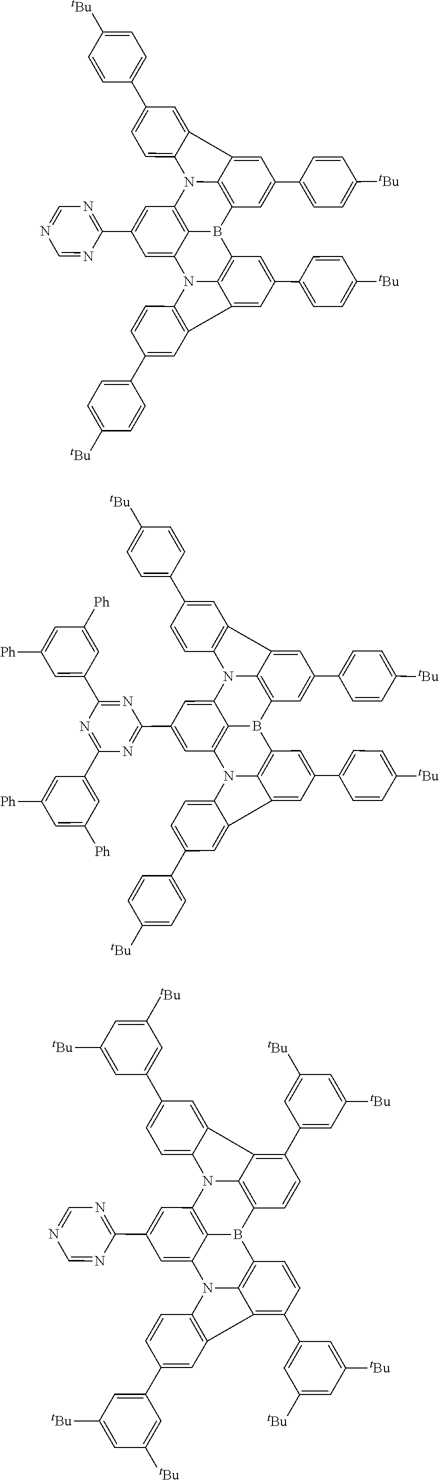

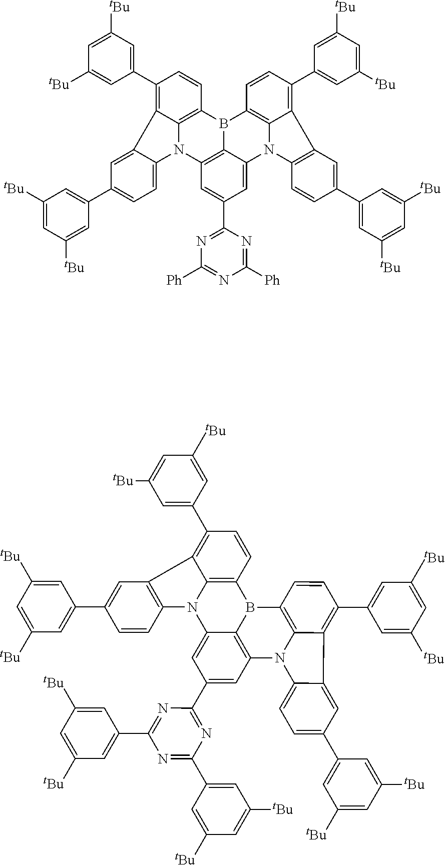 [SMILES: CC(C)(C)c1cc(-c2ccc3c(c2)c2c(-c4cc(C(C)(C)C)cc(C(C)(C)C)c4)ccc4c2n3-c2cc(-c3nc(-c5ccccc5)nc(-c5ccccc5)n3)cc3c2B4c2ccc(-c4cc(C(C)(C)C)cc(C(C)(C)C)c4)c4c5cc(-c6cc(C(C)(C)C)cc(C(C)(C)C)c6)ccc5n-3c24)cc(C(C)(C)C)c1 ; CC(C)(C)c1cc(-c2ccc3c(c2)c2c(-c4cc(C(C)(C)C)cc(C(C)(C)C)c4)ccc4c2n3-c2cc(-c3nc(-c5cc(C(C)(C)C)cc(C(C)(C)C)c5)nc(-c5cc(C(C)(C)C)cc(C(C)(C)C)c5)n3)cc3c2B4c2ccc(-c4cc(C(C)(C)C)cc(C(C)(C)C)c4)c4c5cc(-c6cc(C(C)(C)C)cc(C(C)(C)C)c6)ccc5n-3c24)cc(C(C)(C)C)c1]

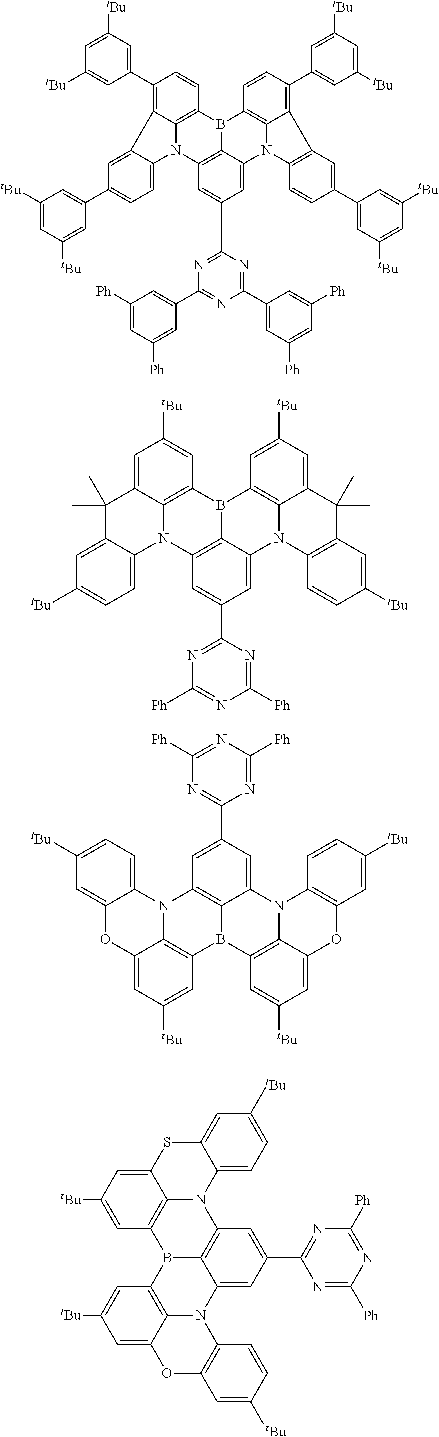

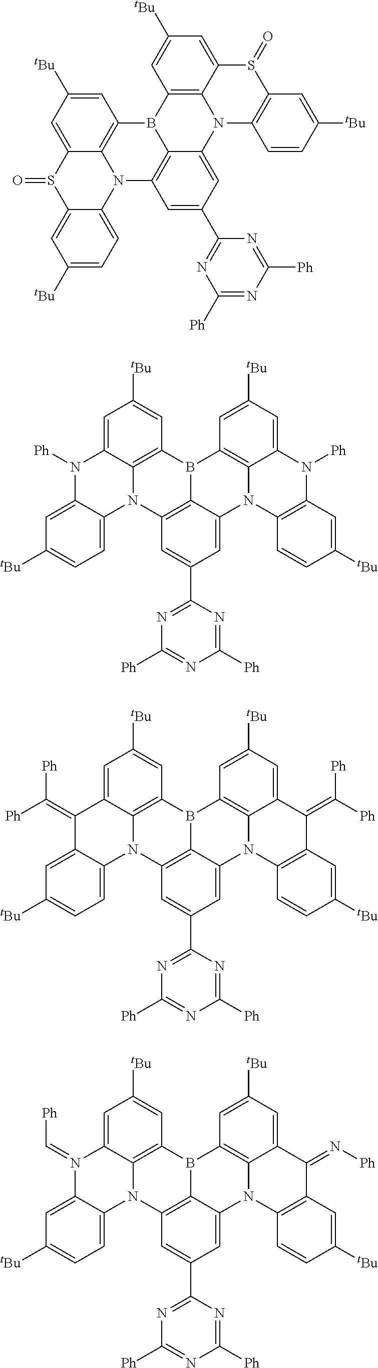

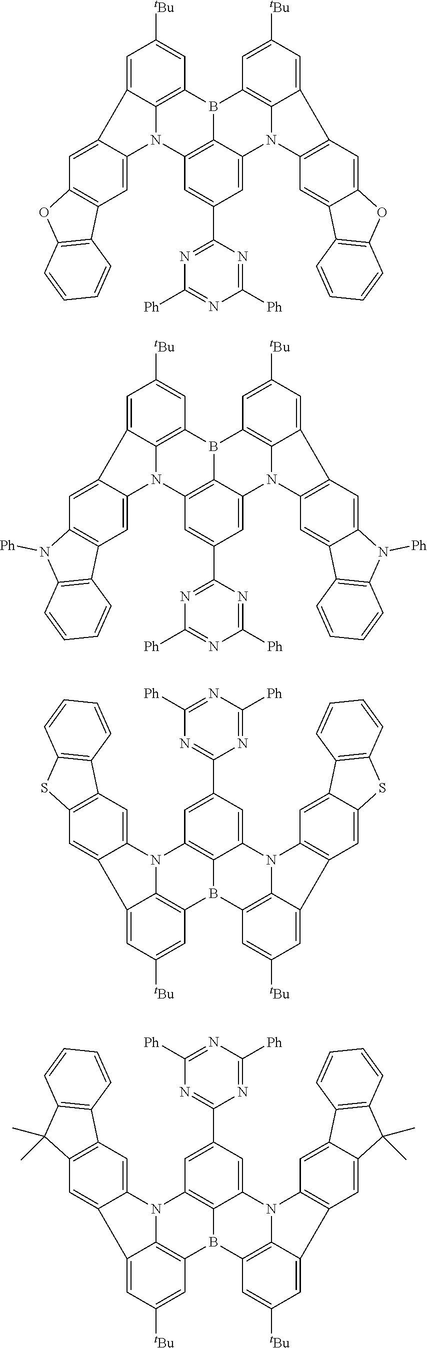

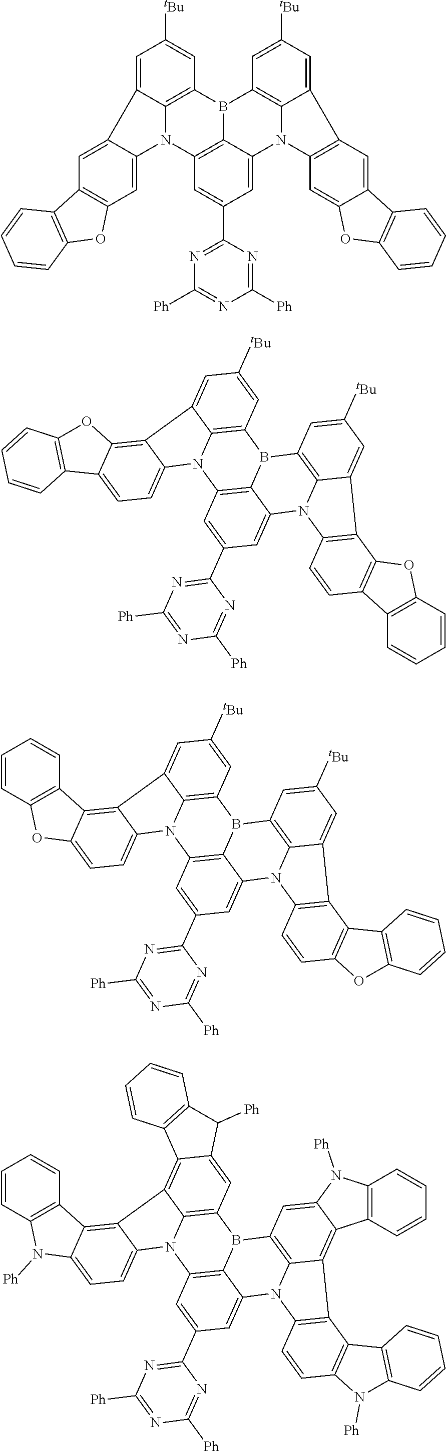

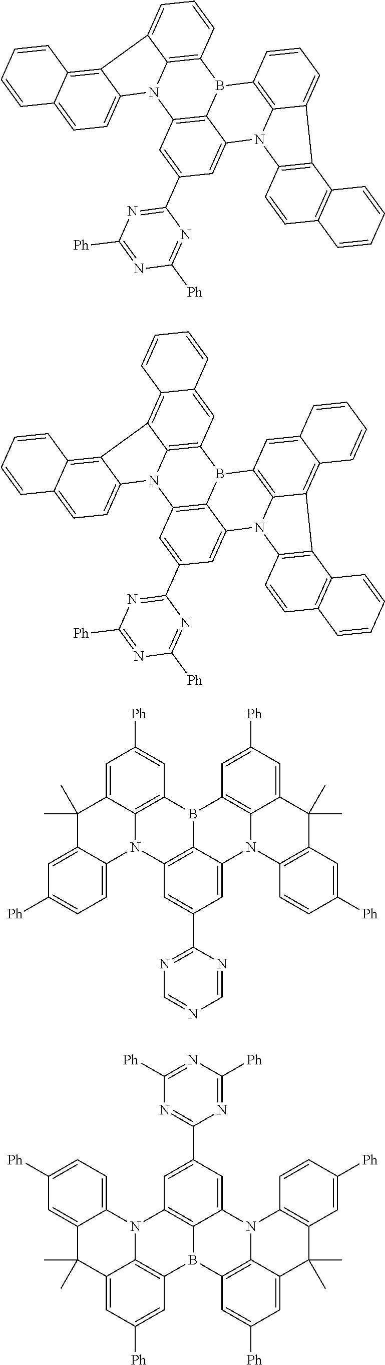

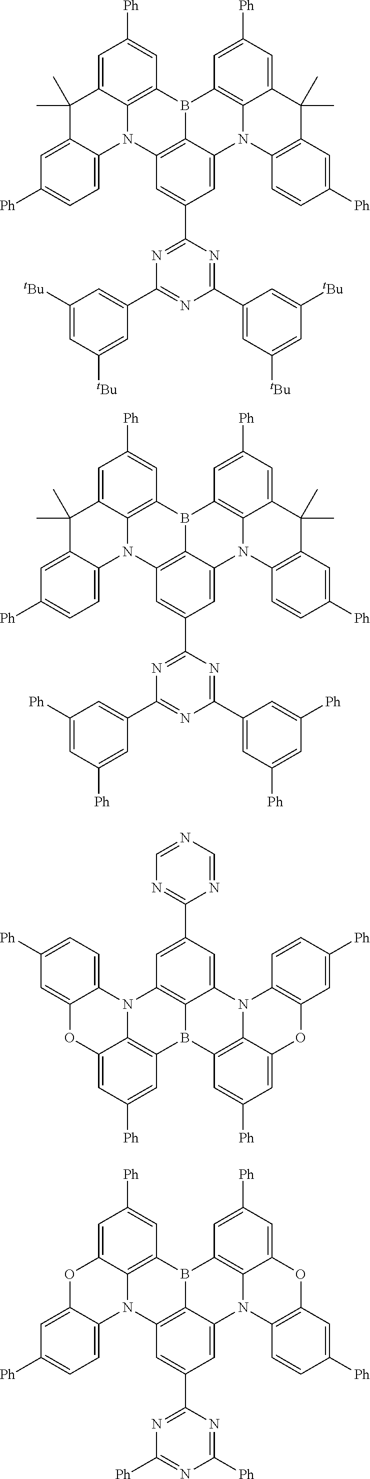

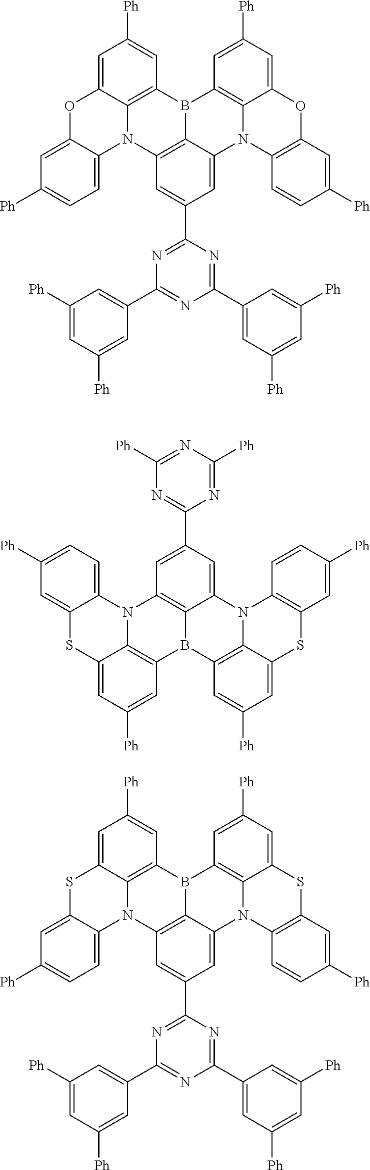

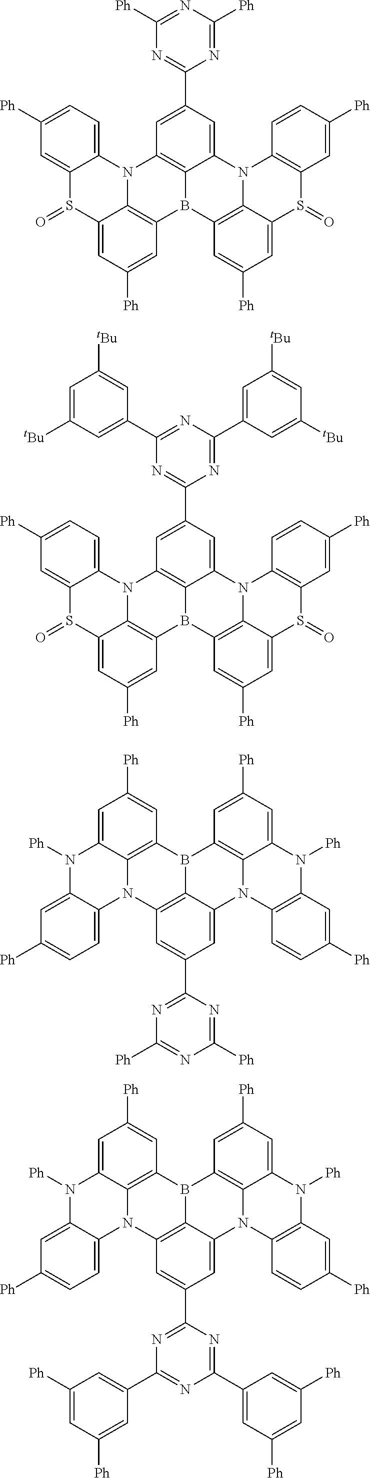

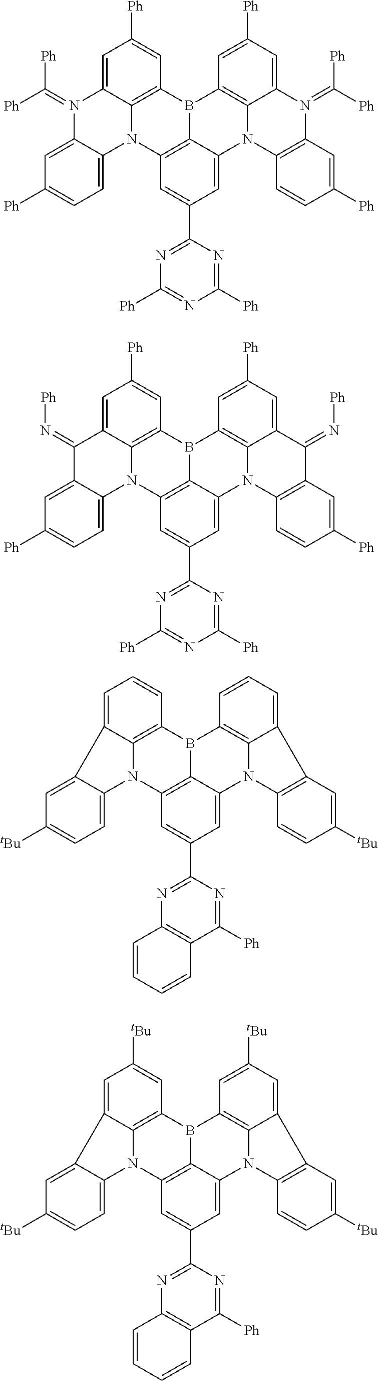

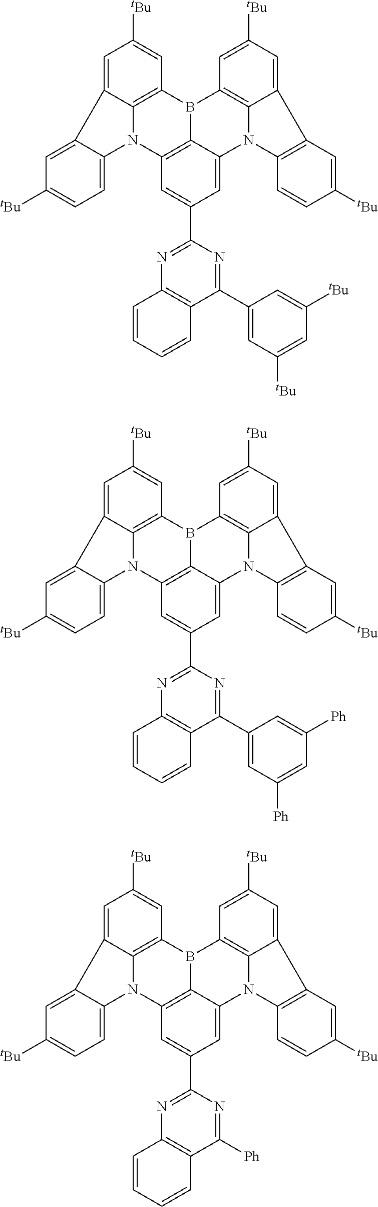 [SMILES: CC(C)(C)c1cc(-c2nc(-c3cc4c5c(c3)-n3c6ccc(C(C)(C)C)cc6c6cc(C(C)(C)C)cc(c63)B5c3cc(C(C)(C)C)cc5c6cc(C(C)(C)C)ccc6n-4c35)nc3ccccc23)cc(C(C)(C)C)c1 ; CC(C)(C)c1ccc2c(c1)c1cc(C(C)(C)C)cc3c1n2-c1cc(-c2nc(-c4cc(-c5ccccc5)cc(-c5ccccc5)c4)c4ccccc4n2)cc2c1B3c1cc(C(C)(C)C)cc3c4cc(C(C)(C)C)ccc4n-2c13 ; CC(C)(C)c1ccc2c(c1)c1cc(C(C)(C)C)cc3c1n2-c1cc(-c2nc(-c4ccccc4)c4ccccc4n2)cc2c1B3c1cc(C(C)(C)C)cc3c4cc(C(C)(C)C)ccc4n-2c13]

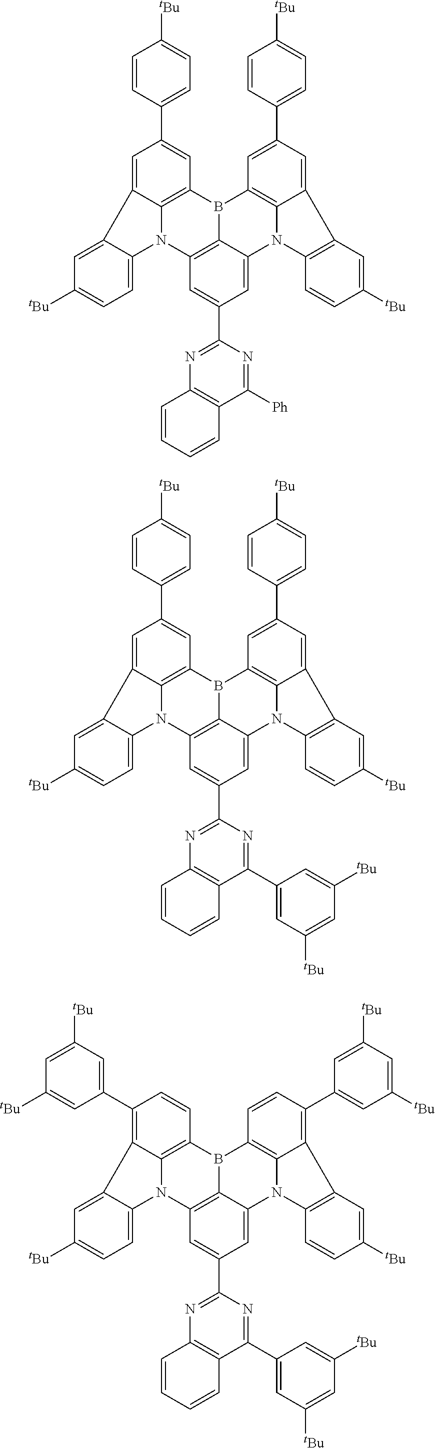

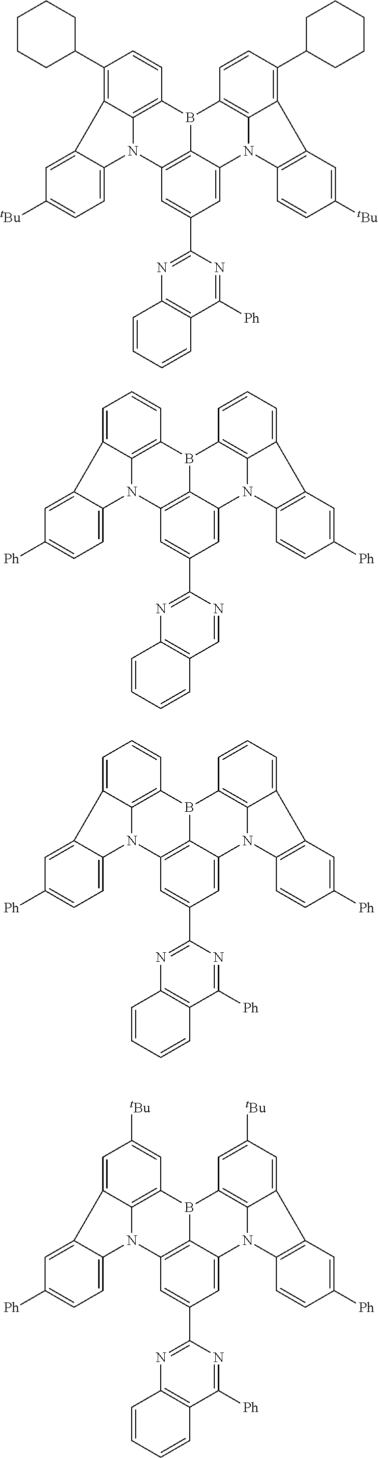

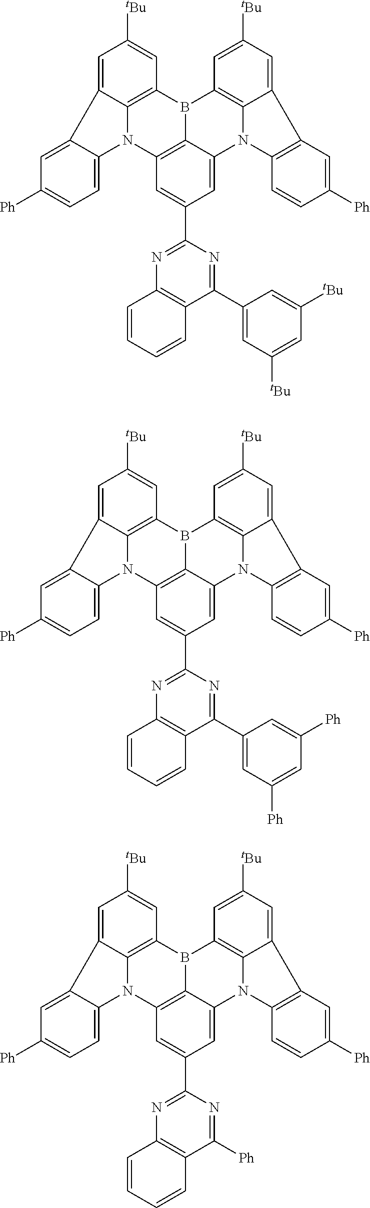 [SMILES: CC(C)(C)c1cc(-c2nc(-c3cc4c5c(c3)-n3c6ccc(-c7ccccc7)cc6c6cc(C(C)(C)C)cc(c63)B5c3cc(C(C)(C)C)cc5c6cc(-c7ccccc7)ccc6n-4c35)nc3ccccc23)cc(C(C)(C)C)c1 ; CC(C)(C)c1cc2c3c(c1)c1cc(-c4ccccc4)ccc1n3-c1cc(-c3nc(-c4cc(-c5ccccc5)cc(-c5ccccc5)c4)c4ccccc4n3)cc3c1B2c1cc(C(C)(C)C)cc2c4cc(-c5ccccc5)ccc4n-3c12 ; CC(C)(C)c1cc2c3c(c1)c1cc(-c4ccccc4)ccc1n3-c1cc(-c3nc(-c4ccccc4)c4ccccc4n3)cc3c1B2c1cc(C(C)(C)C)cc2c4cc(-c5ccccc5)ccc4n-3c12]

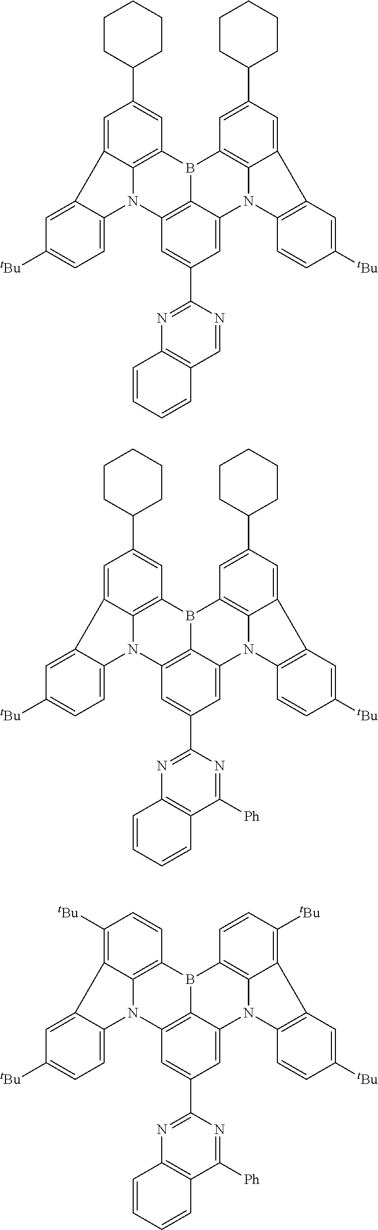

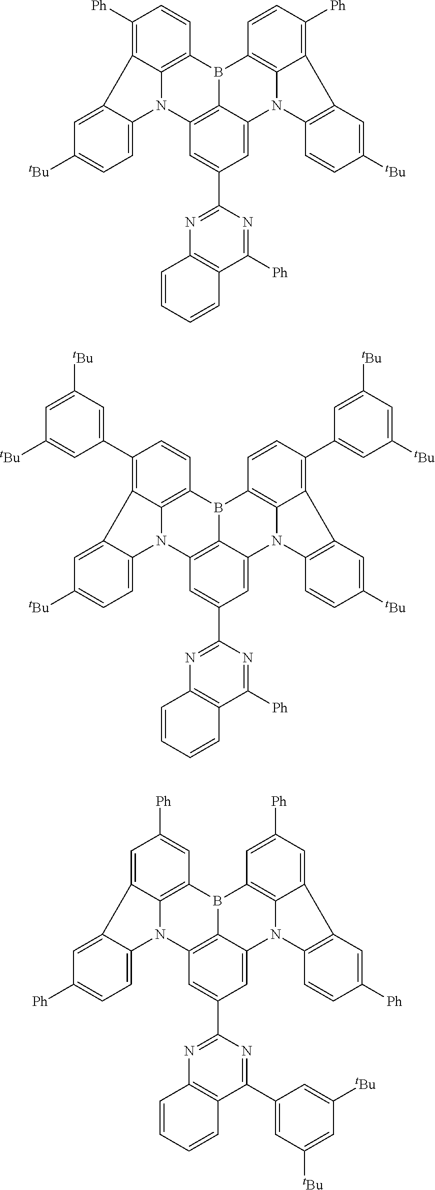 [SMILES: CC(C)(C)c1ccc2c(c1)c1c(-c3ccccc3)ccc3c1n2-c1cc(-c2nc(-c4ccccc4)c4ccccc4n2)cc2c1B3c1ccc(-c3ccccc3)c3c4cc(C(C)(C)C)ccc4n-2c13 ; CC(C)(C)c1cc(-c2ccc3c4c2c2cc(C(C)(C)C)ccc2n4-c2cc(-c4nc(-c5ccccc5)c5ccccc5n4)cc4c2B3c2ccc(-c3cc(C(C)(C)C)cc(C(C)(C)C)c3)c3c5cc(C(C)(C)C)ccc5n-4c23)cc(C(C)(C)C)c1 ; CC(C)(C)c1cc(-c2nc(-c3cc4c5c(c3)-n3c6ccc(-c7ccccc7)cc6c6cc(-c7ccccc7)cc(c63)B5c3cc(-c5ccccc5)cc5c6cc(-c7ccccc7)ccc6n-4c35)nc3ccccc23)cc(C(C)(C)C)c1]

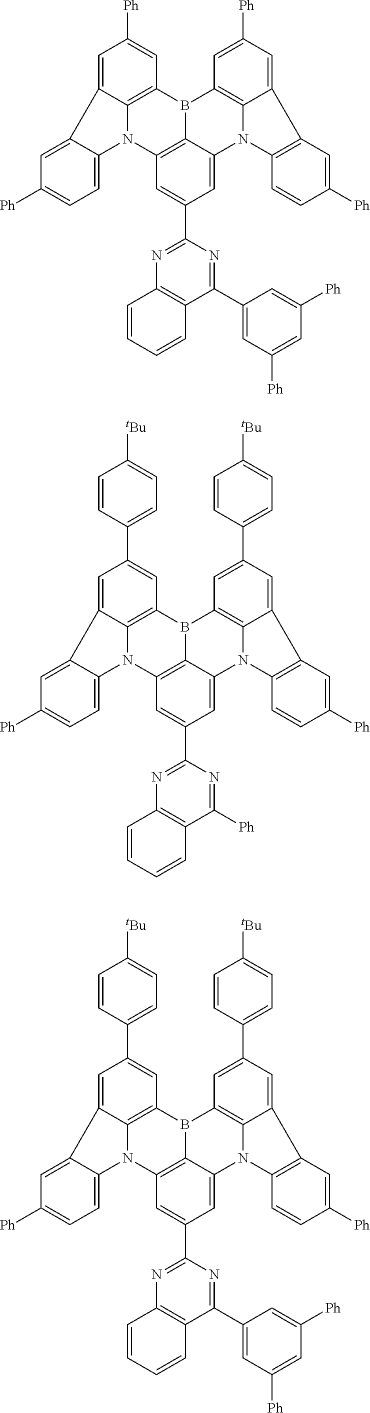 [SMILES: c1ccc(-c2cc(-c3ccccc3)cc(-c3nc(-c4cc5c6c(c4)-n4c7ccc(-c8ccccc8)cc7c7cc(-c8ccccc8)cc(c74)B6c4cc(-c6ccccc6)cc6c7cc(-c8ccccc8)ccc7n-5c46)nc4ccccc34)c2)cc1 ; CC(C)(C)c1ccc(-c2cc3c4c(c2)c2cc(-c5ccccc5)ccc2n4-c2cc(-c4nc(-c5ccccc5)c5ccccc5n4)cc4c2B3c2cc(-c3ccc(C(C)(C)C)cc3)cc3c5cc(-c6ccccc6)ccc5n-4c23)cc1 ; CC(C)(C)c1ccc(-c2cc3c4c(c2)c2cc(-c5ccccc5)ccc2n4-c2cc(-c4nc(-c5cc(-c6ccccc6)cc(-c6ccccc6)c5)c5ccccc5n4)cc4c2B3c2cc(-c3ccc(C(C)(C)C)cc3)cc3c5cc(-c6ccccc6)ccc5n-4c23)cc1]

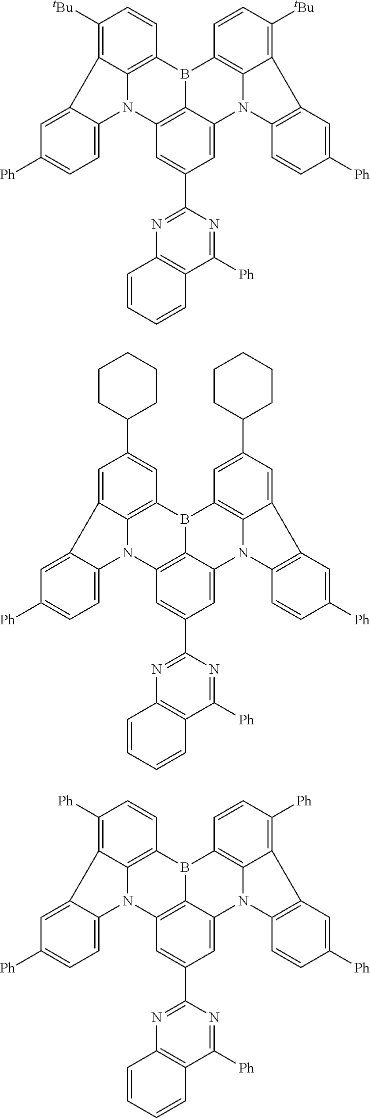

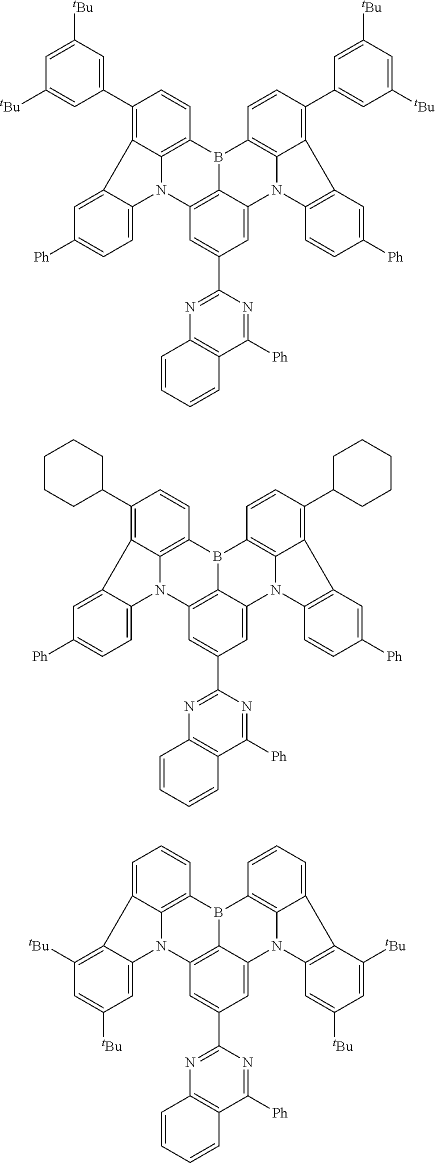 [SMILES: CC(C)(C)c1cc(-c2ccc3c4c2c2cc(-c5ccccc5)ccc2n4-c2cc(-c4nc(-c5ccccc5)c5ccccc5n4)cc4c2B3c2ccc(-c3cc(C(C)(C)C)cc(C(C)(C)C)c3)c3c5cc(-c6ccccc6)ccc5n-4c23)cc(C(C)(C)C)c1 ; c1ccc(-c2ccc3c(c2)c2c(C4CCCCC4)ccc4c2n3-c2cc(-c3nc(-c5ccccc5)c5ccccc5n3)cc3c2B4c2ccc(C4CCCCC4)c4c5cc(-c6ccccc6)ccc5n-3c24)cc1 ; CC(C)(C)c1cc(C(C)(C)C)c2c3cccc4c3n(c2c1)-c1cc(-c2nc(-c3ccccc3)c3ccccc3n2)cc2c1B4c1cccc3c4c(C(C)(C)C)cc(C(C)(C)C)cc4n-2c13]

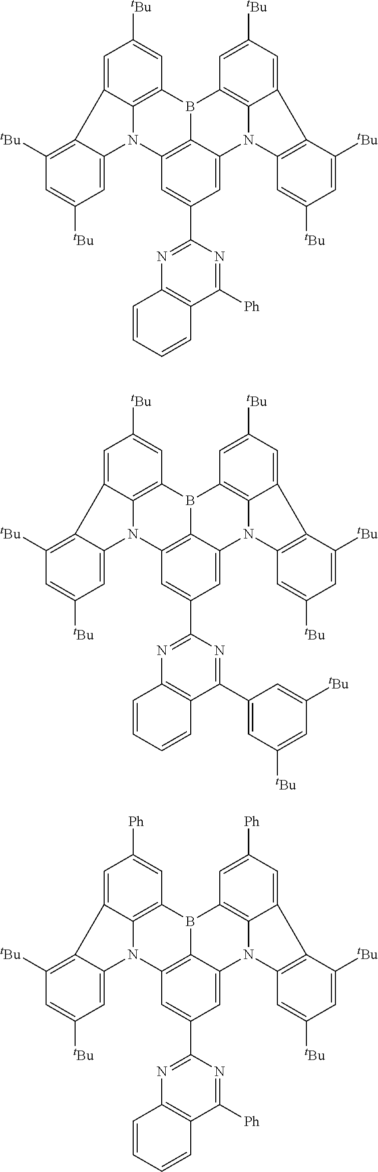 [SMILES: CC(C)(C)c1cc2c3c(c1)c1c(C(C)(C)C)cc(C(C)(C)C)cc1n3-c1cc(-c3nc(-c4ccccc4)c4ccccc4n3)cc3c1B2c1cc(C(C)(C)C)cc2c4c(C(C)(C)C)cc(C(C)(C)C)cc4n-3c12 ; CC(C)(C)c1cc(-c2nc(-c3cc4c5c(c3)-n3c6cc(C(C)(C)C)cc(C(C)(C)C)c6c6cc(C(C)(C)C)cc(c63)B5c3cc(C(C)(C)C)cc5c6c(C(C)(C)C)cc(C(C)(C)C)cc6n-4c35)nc3ccccc23)cc(C(C)(C)C)c1 ; CC(C)(C)c1cc(C(C)(C)C)c2c3cc(-c4ccccc4)cc4c3n(c2c1)-c1cc(-c2nc(-c3ccccc3)c3ccccc3n2)cc2c1B4c1cc(-c3ccccc3)cc3c4c(C(C)(C)C)cc(C(C)(C)C)cc4n-2c13]

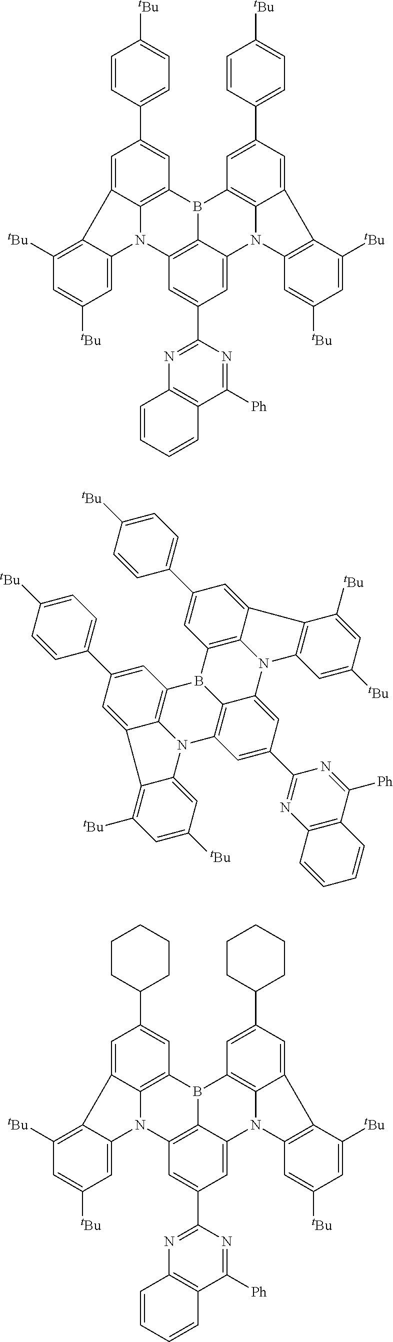 [SMILES: CC(C)(C)c1ccc(-c2cc3c4c(c2)c2c(C(C)(C)C)cc(C(C)(C)C)cc2n4-c2cc(-c4nc(-c5ccccc5)c5ccccc5n4)cc4c2B3c2cc(-c3ccc(C(C)(C)C)cc3)cc3c5c(C(C)(C)C)cc(C(C)(C)C)cc5n-4c23)cc1 ; CC(C)(C)c1ccc(-c2cc3c4c(c2)c2c(C(C)(C)C)cc(C(C)(C)C)cc2n4-c2cc(-c4nc(-c5ccccc5)c5ccccc5n4)cc4c2B3c2cc(-c3ccc(C(C)(C)C)cc3)cc3c5c(C(C)(C)C)cc(C(C)(C)C)cc5n-4c23)cc1 ; CC(C)(C)c1cc(C(C)(C)C)c2c3cc(C4CCCCC4)cc4c3n(c2c1)-c1cc(-c2nc(-c3ccccc3)c3ccccc3n2)cc2c1B4c1cc(C3CCCCC3)cc3c4c(C(C)(C)C)cc(C(C)(C)C)cc4n-2c13]

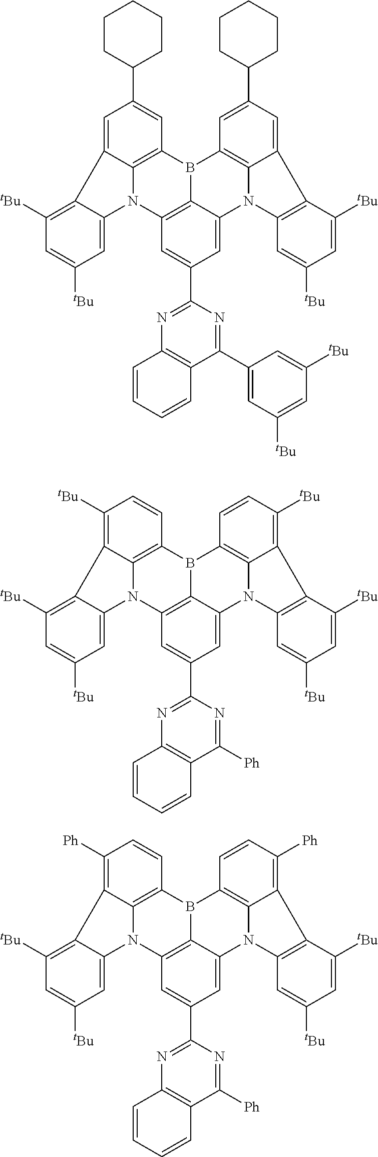

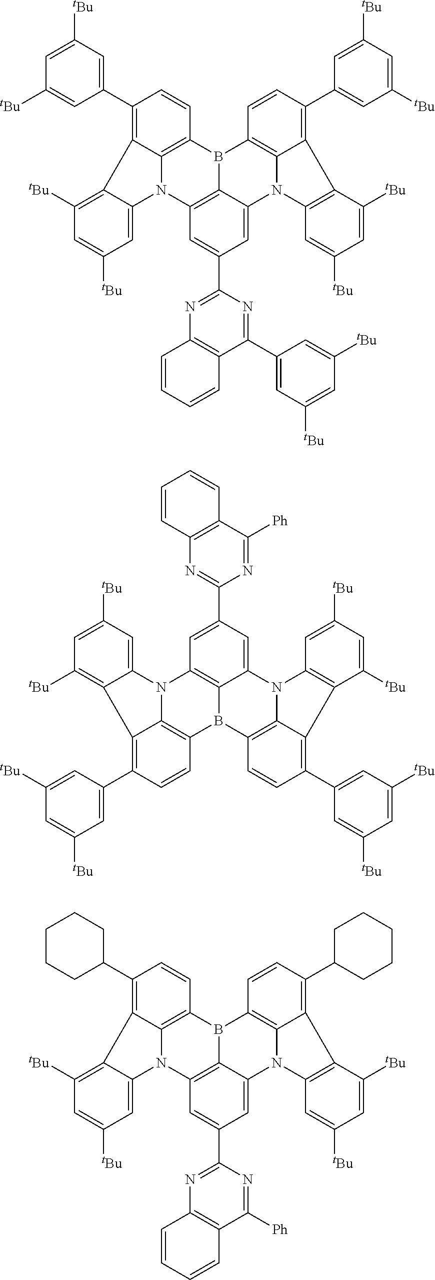

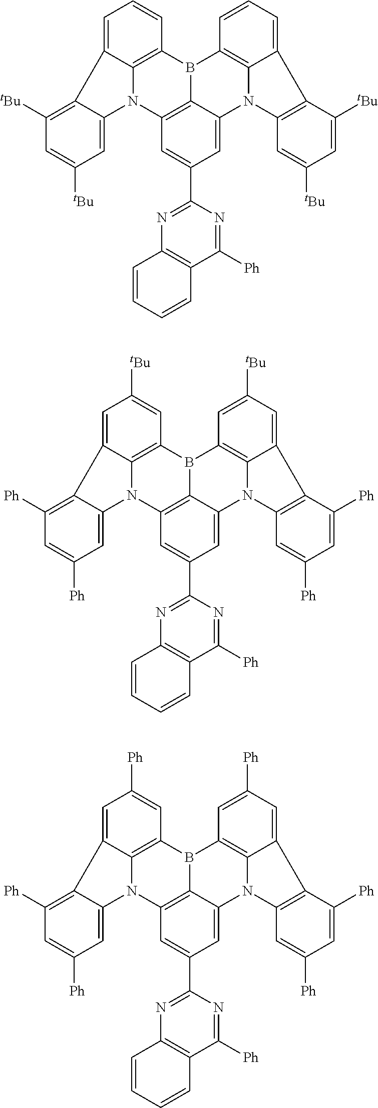 [SMILES: CC(C)(C)c1cc(C(C)(C)C)c2c3cccc4c3n(c2c1)-c1cc(-c2nc(-c3ccccc3)c3ccccc3n2)cc2c1B4c1cccc3c4c(C(C)(C)C)cc(C(C)(C)C)cc4n-2c13 ; CC(C)(C)c1cc2c3c(c1)c1c(-c4ccccc4)cc(-c4ccccc4)cc1n3-c1cc(-c3nc(-c4ccccc4)c4ccccc4n3)cc3c1B2c1cc(C(C)(C)C)cc2c4c(-c5ccccc5)cc(-c5ccccc5)cc4n-3c12 ; c1ccc(-c2cc3c4c(c2)c2c(-c5ccccc5)cc(-c5ccccc5)cc2n4-c2cc(-c4nc(-c5ccccc5)c5ccccc5n4)cc4c2B3c2cc(-c3ccccc3)cc3c5c(-c6ccccc6)cc(-c6ccccc6)cc5n-4c23)cc1]

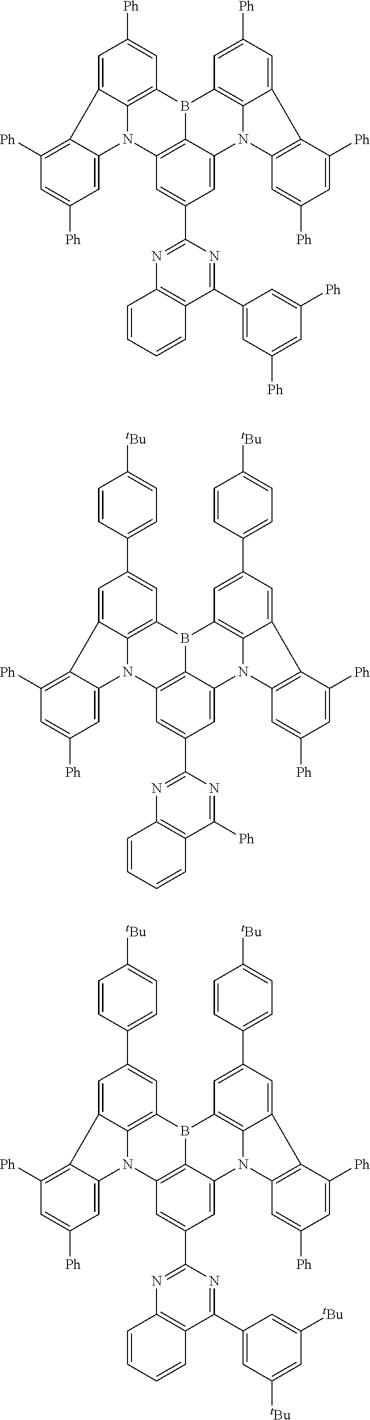

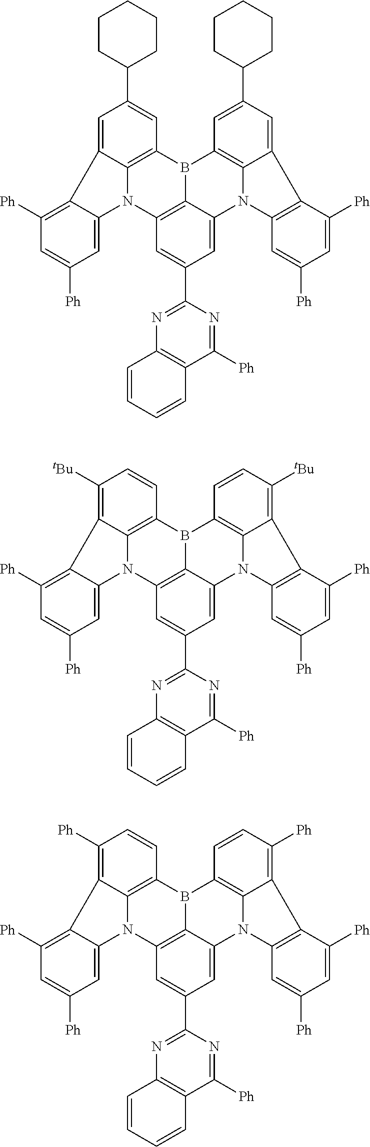 [SMILES: c1ccc(-c2cc(-c3ccccc3)c3c4cc(C5CCCCC5)cc5c4n(c3c2)-c2cc(-c3nc(-c4ccccc4)c4ccccc4n3)cc3c2B5c2cc(C4CCCCC4)cc4c5c(-c6ccccc6)cc(-c6ccccc6)cc5n-3c24)cc1 ; CC(C)(C)c1ccc2c3c1c1c(-c4ccccc4)cc(-c4ccccc4)cc1n3-c1cc(-c3nc(-c4ccccc4)c4ccccc4n3)cc3c1B2c1ccc(C(C)(C)C)c2c4c(-c5ccccc5)cc(-c5ccccc5)cc4n-3c12 ; c1ccc(-c2cc(-c3ccccc3)c3c4c(-c5ccccc5)ccc5c4n(c3c2)-c2cc(-c3nc(-c4ccccc4)c4ccccc4n3)cc3c2B5c2ccc(-c4ccccc4)c4c5c(-c6ccccc6)cc(-c6ccccc6)cc5n-3c24)cc1]

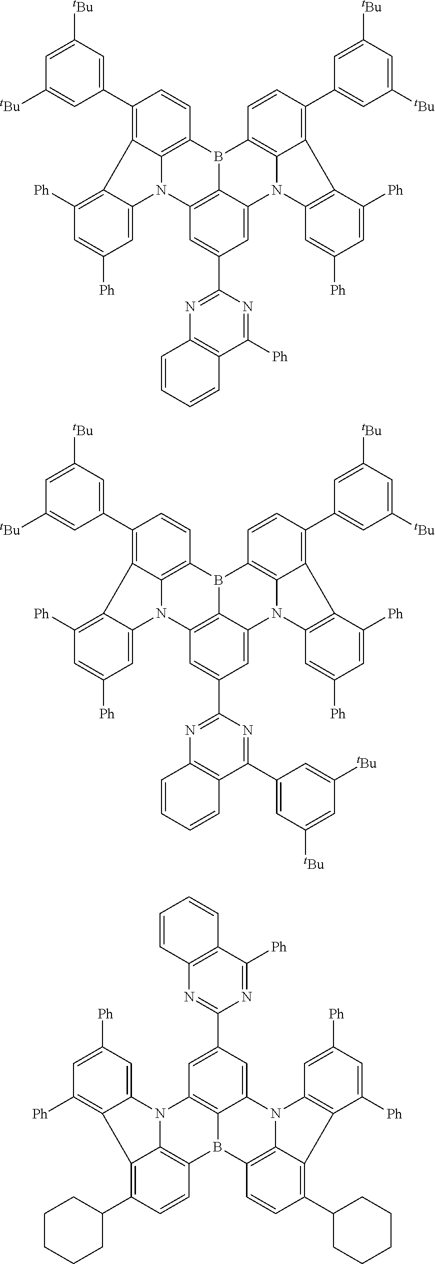

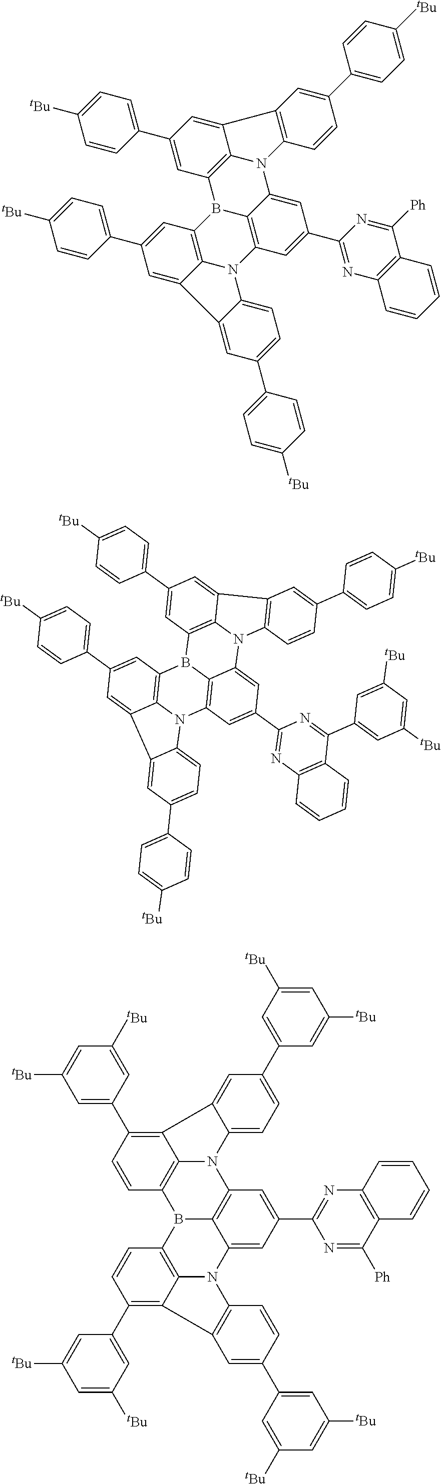

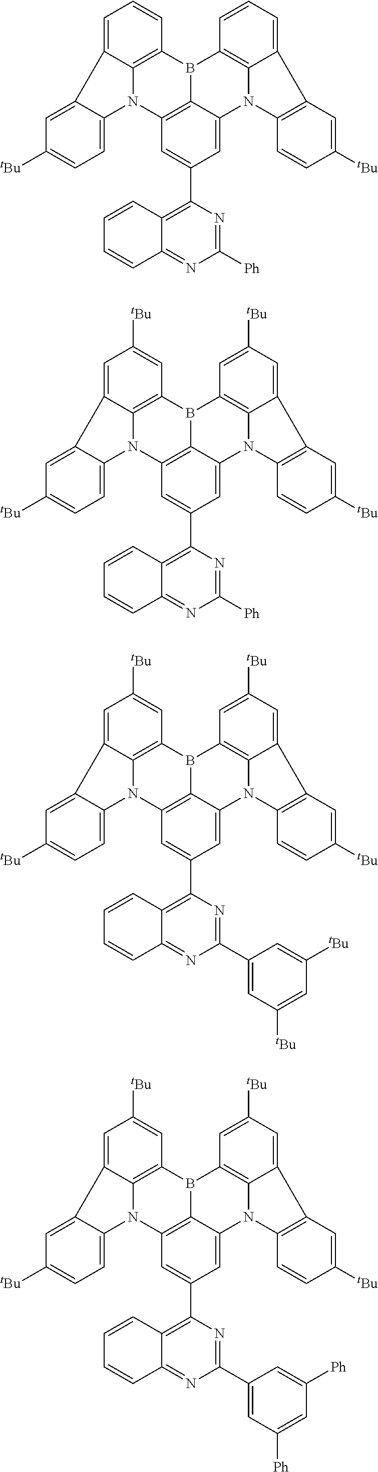

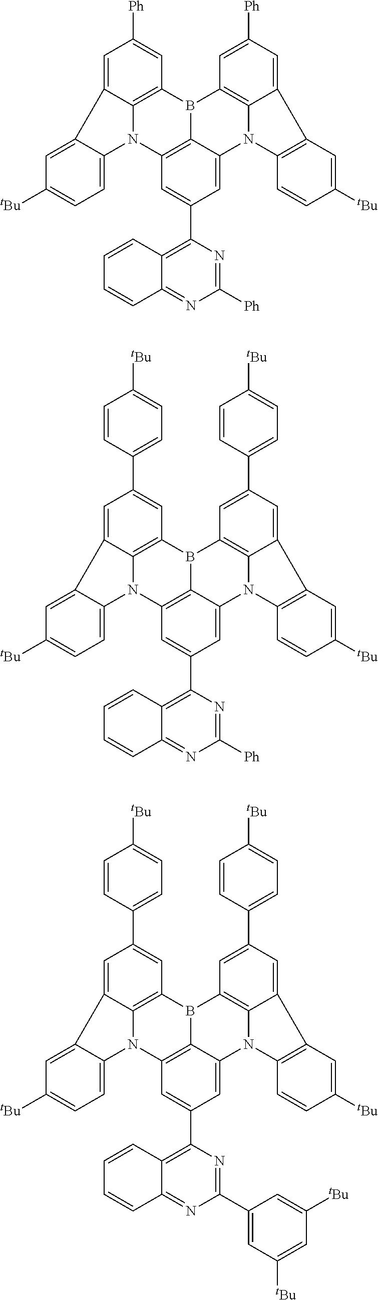 [SMILES: CC(C)(C)c1ccc2c(c1)c1cc(-c3ccccc3)cc3c1n2-c1cc(-c2nc(-c4ccccc4)nc4ccccc24)cc2c1B3c1cc(-c3ccccc3)cc3c4cc(C(C)(C)C)ccc4n-2c13 ; CC(C)(C)c1ccc(-c2cc3c4c(c2)c2cc(C(C)(C)C)ccc2n4-c2cc(-c4nc(-c5ccccc5)nc5ccccc45)cc4c2B3c2cc(-c3ccc(C(C)(C)C)cc3)cc3c5cc(C(C)(C)C)ccc5n-4c23)cc1 ; CC(C)(C)c1ccc(-c2cc3c4c(c2)c2cc(C(C)(C)C)ccc2n4-c2cc(-c4nc(-c5cc(C(C)(C)C)cc(C(C)(C)C)c5)nc5ccccc45)cc4c2B3c2cc(-c3ccc(C(C)(C)C)cc3)cc3c5cc(C(C)(C)C)ccc5n-4c23)cc1]

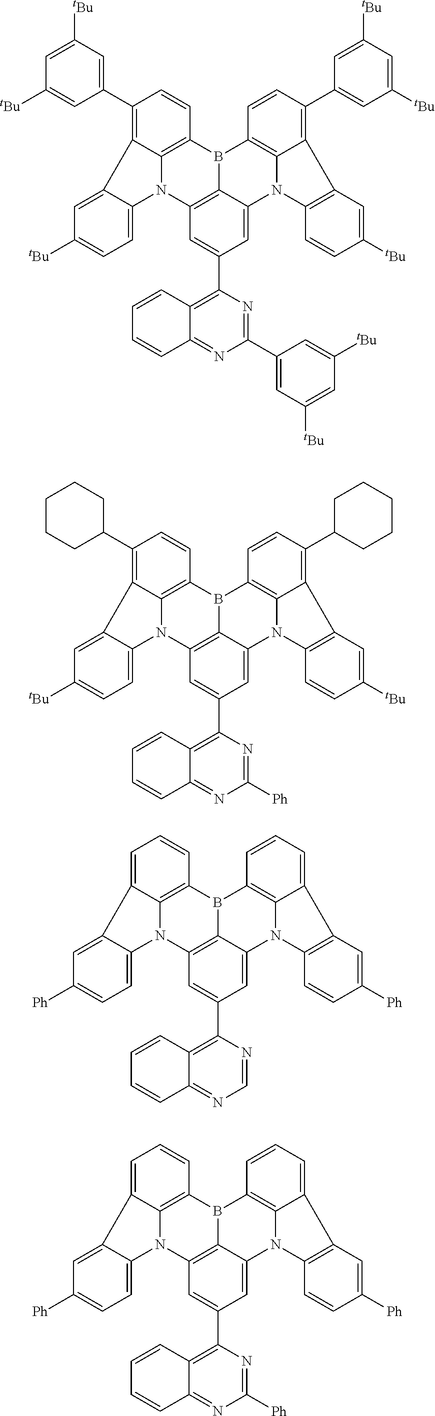

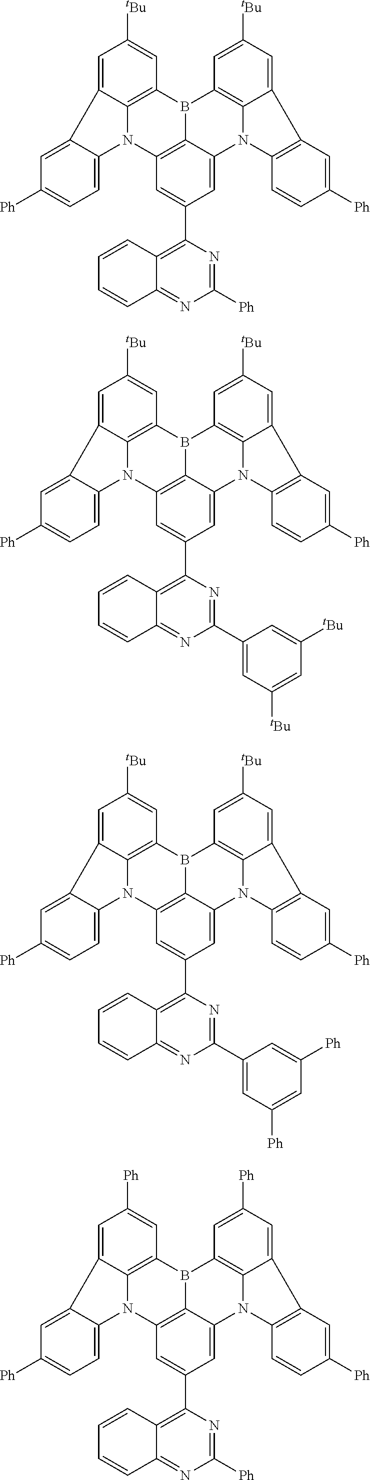

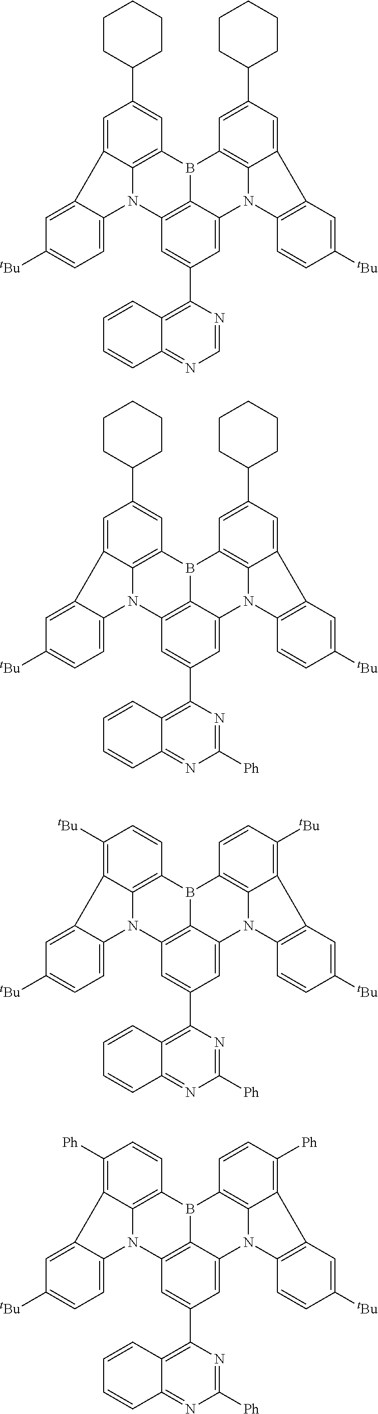

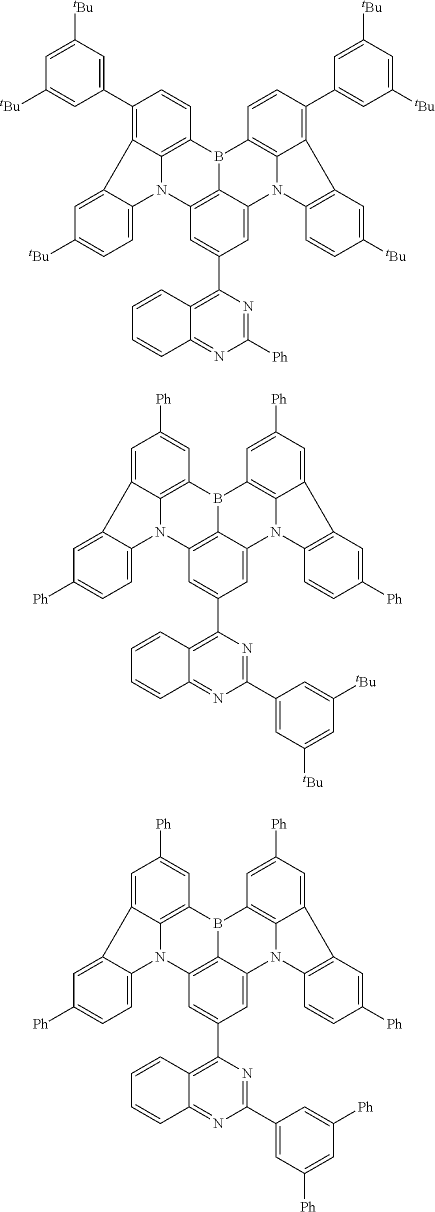

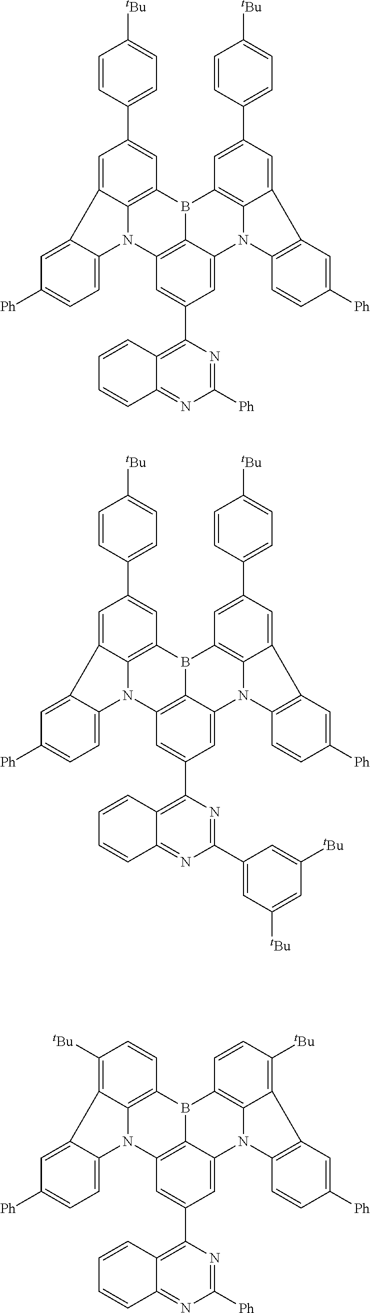 [SMILES: CC(C)(C)c1ccc(-c2cc3c4c(c2)c2cc(-c5ccccc5)ccc2n4-c2cc(-c4nc(-c5ccccc5)nc5ccccc45)cc4c2B3c2cc(-c3ccc(C(C)(C)C)cc3)cc3c5cc(-c6ccccc6)ccc5n-4c23)cc1 ; CC(C)(C)c1ccc(-c2cc3c4c(c2)c2cc(-c5ccccc5)ccc2n4-c2cc(-c4nc(-c5cc(C(C)(C)C)cc(C(C)(C)C)c5)nc5ccccc45)cc4c2B3c2cc(-c3ccc(C(C)(C)C)cc3)cc3c5cc(-c6ccccc6)ccc5n-4c23)cc1 ; CC(C)(C)c1ccc2c3c1c1cc(-c4ccccc4)ccc1n3-c1cc(-c3nc(-c4ccccc4)nc4ccccc34)cc3c1B2c1ccc(C(C)(C)C)c2c4cc(-c5ccccc5)ccc4n-3c12]

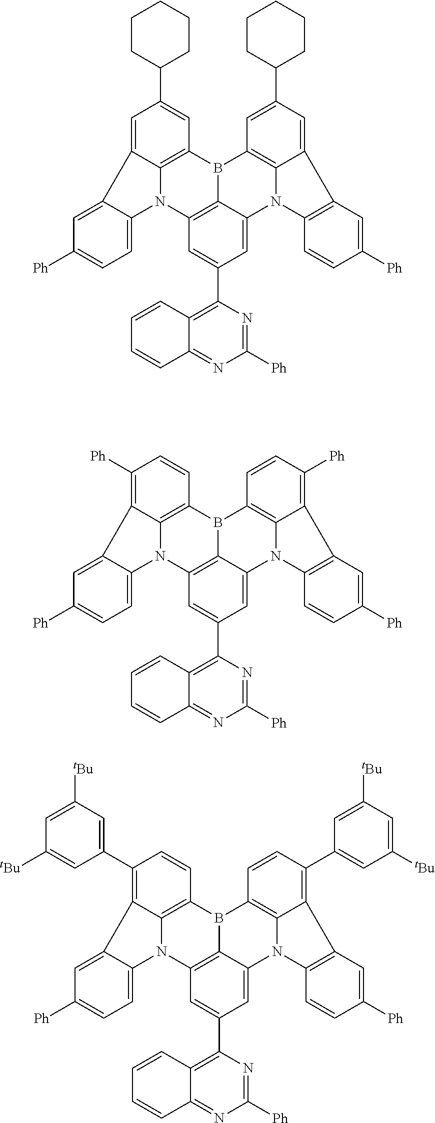 [SMILES: c1ccc(-c2ccc3c(c2)c2cc(C4CCCCC4)cc4c2n3-c2cc(-c3nc(-c5ccccc5)nc5ccccc35)cc3c2B4c2cc(C4CCCCC4)cc4c5cc(-c6ccccc6)ccc5n-3c24)cc1 ; c1ccc(-c2ccc3c(c2)c2c(-c4ccccc4)ccc4c2n3-c2cc(-c3nc(-c5ccccc5)nc5ccccc35)cc3c2B4c2ccc(-c4ccccc4)c4c5cc(-c6ccccc6)ccc5n-3c24)cc1 ; CC(C)(C)c1cc(-c2ccc3c4c2c2cc(-c5ccccc5)ccc2n4-c2cc(-c4nc(-c5ccccc5)nc5ccccc45)cc4c2B3c2ccc(-c3cc(C(C)(C)C)cc(C(C)(C)C)c3)c3c5cc(-c6ccccc6)ccc5n-4c23)cc(C(C)(C)C)c1]

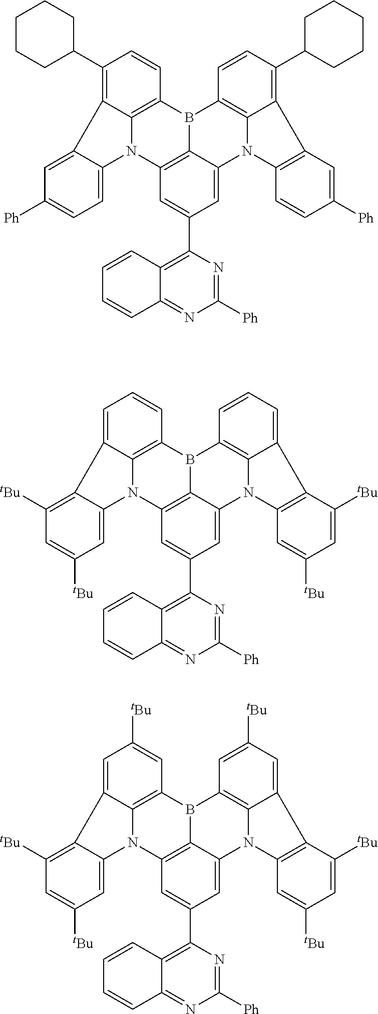 [SMILES: c1ccc(-c2ccc3c(c2)c2c(C4CCCCC4)ccc4c2n3-c2cc(-c3nc(-c5ccccc5)nc5ccccc35)cc3c2B4c2ccc(C4CCCCC4)c4c5cc(-c6ccccc6)ccc5n-3c24)cc1 ; CC(C)(C)c1cc(C(C)(C)C)c2c3cccc4c3n(c2c1)-c1cc(-c2nc(-c3ccccc3)nc3ccccc23)cc2c1B4c1cccc3c4c(C(C)(C)C)cc(C(C)(C)C)cc4n-2c13 ; CC(C)(C)c1cc2c3c(c1)c1c(C(C)(C)C)cc(C(C)(C)C)cc1n3-c1cc(-c3nc(-c4ccccc4)nc4ccccc34)cc3c1B2c1cc(C(C)(C)C)cc2c4c(C(C)(C)C)cc(C(C)(C)C)cc4n-3c12]

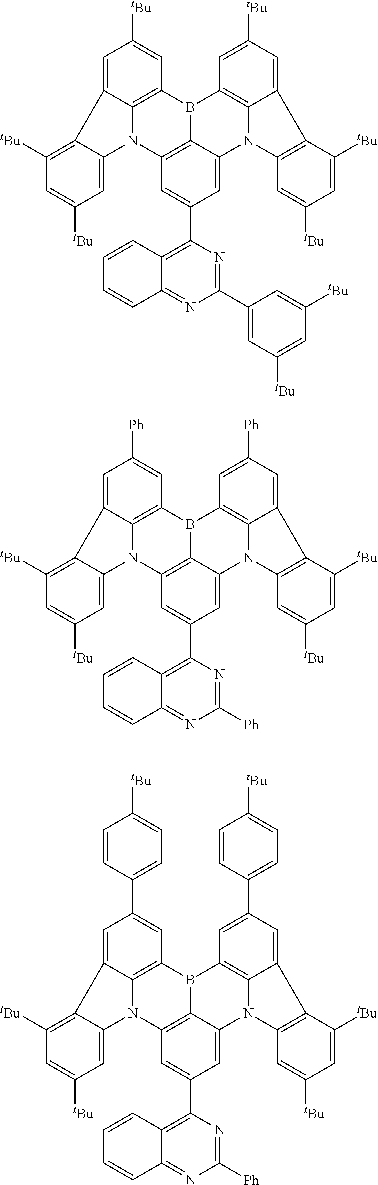

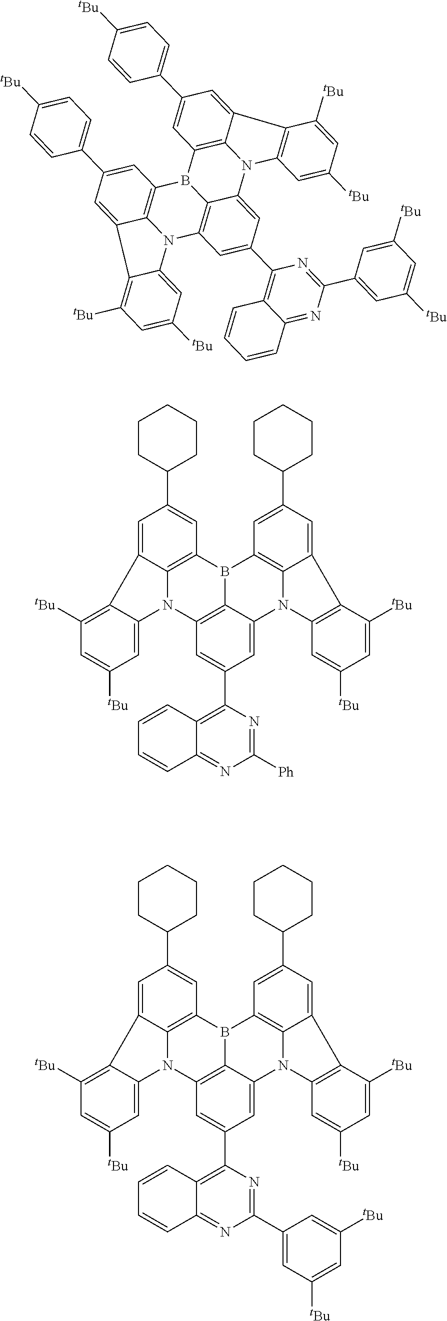 [SMILES: CC(C)(C)c1ccc(-c2cc3c4c(c2)c2c(C(C)(C)C)cc(C(C)(C)C)cc2n4-c2cc(-c4nc(-c5cc(C(C)(C)C)cc(C(C)(C)C)c5)nc5ccccc45)cc4c2B3c2cc(-c3ccc(C(C)(C)C)cc3)cc3c5c(C(C)(C)C)cc(C(C)(C)C)cc5n-4c23)cc1 ; CC(C)(C)c1cc(C(C)(C)C)c2c3cc(C4CCCCC4)cc4c3n(c2c1)-c1cc(-c2nc(-c3ccccc3)nc3ccccc23)cc2c1B4c1cc(C3CCCCC3)cc3c4c(C(C)(C)C)cc(C(C)(C)C)cc4n-2c13 ; CC(C)(C)c1cc(-c2nc(-c3cc4c5c(c3)-n3c6cc(C(C)(C)C)cc(C(C)(C)C)c6c6cc(C7CCCCC7)cc(c63)B5c3cc(C5CCCCC5)cc5c6c(C(C)(C)C)cc(C(C)(C)C)cc6n-4c35)c3ccccc3n2)cc(C(C)(C)C)c1]

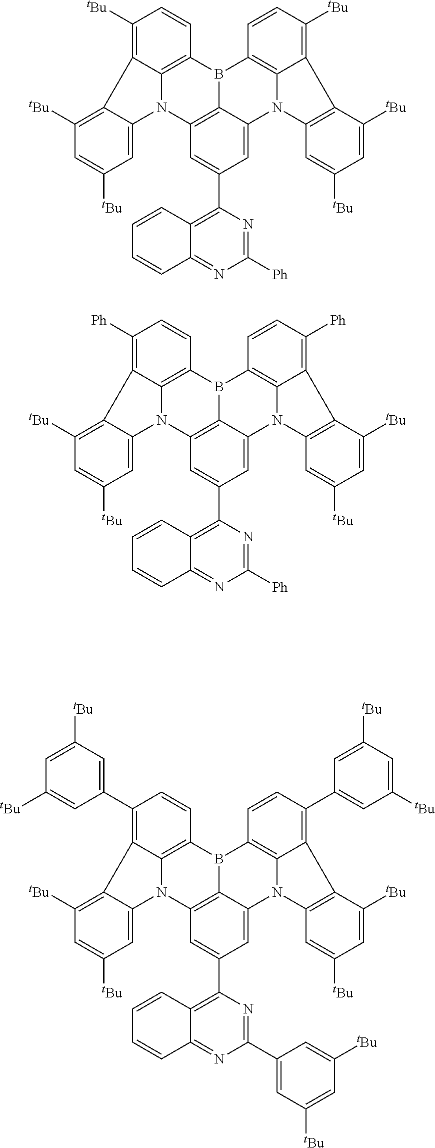

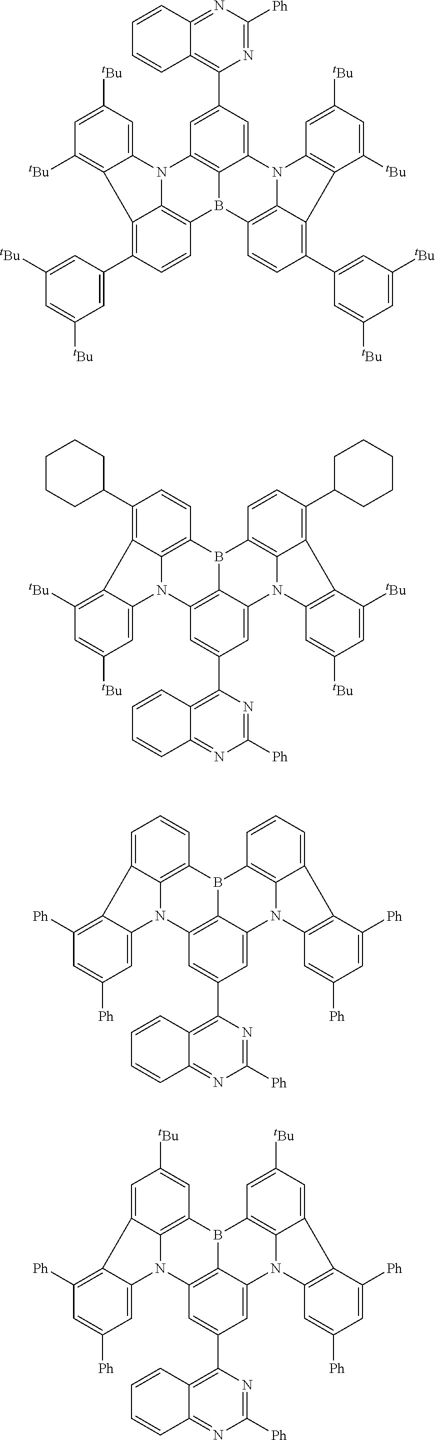

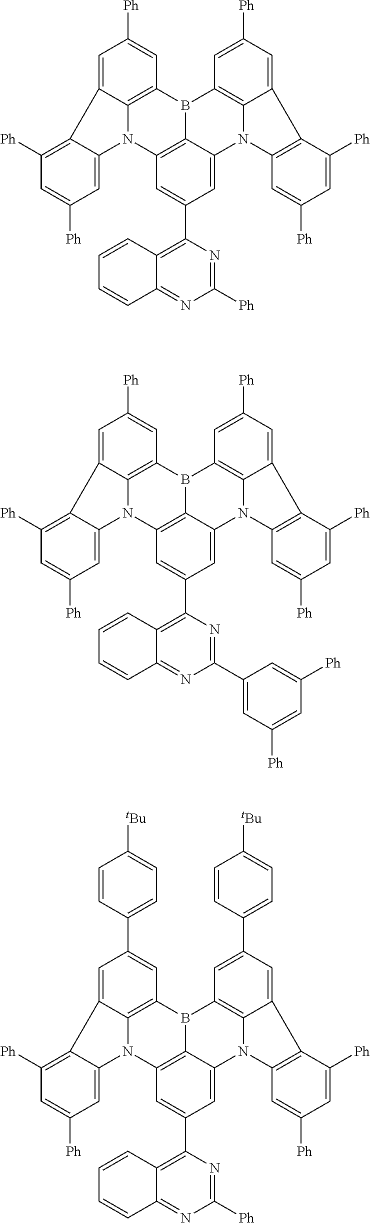 [SMILES: c1ccc(-c2cc3c4c(c2)c2c(-c5ccccc5)cc(-c5ccccc5)cc2n4-c2cc(-c4nc(-c5ccccc5)nc5ccccc45)cc4c2B3c2cc(-c3ccccc3)cc3c5c(-c6ccccc6)cc(-c6ccccc6)cc5n-4c23)cc1 ; c1ccc(-c2cc(-c3ccccc3)cc(-c3nc(-c4cc5c6c(c4)-n4c7cc(-c8ccccc8)cc(-c8ccccc8)c7c7cc(-c8ccccc8)cc(c74)B6c4cc(-c6ccccc6)cc6c7c(-c8ccccc8)cc(-c8ccccc8)cc7n-5c46)c4ccccc4n3)c2)cc1 ; CC(C)(C)c1ccc(-c2cc3c4c(c2)c2c(-c5ccccc5)cc(-c5ccccc5)cc2n4-c2cc(-c4nc(-c5ccccc5)nc5ccccc45)cc4c2B3c2cc(-c3ccc(C(C)(C)C)cc3)cc3c5c(-c6ccccc6)cc(-c6ccccc6)cc5n-4c23)cc1]

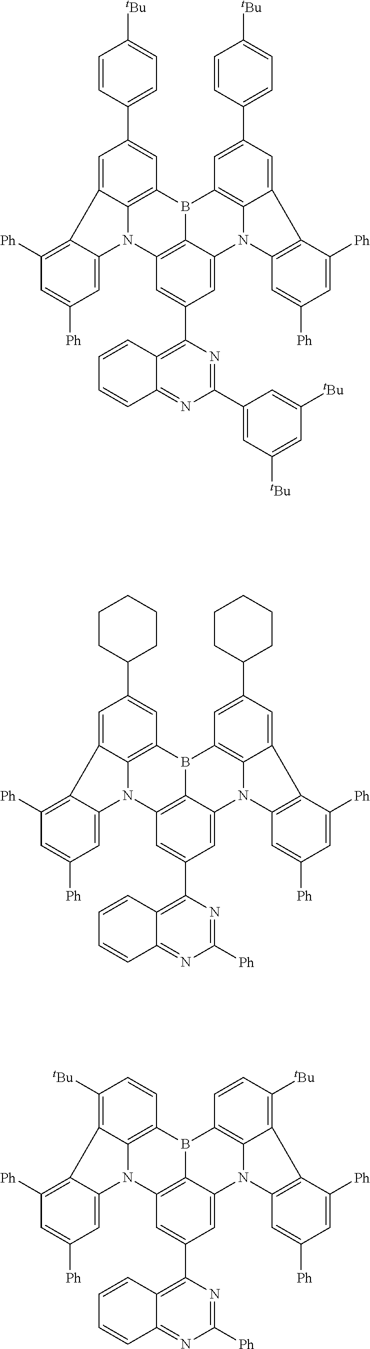 [SMILES: CC(C)(C)c1ccc(-c2cc3c4c(c2)c2c(-c5ccccc5)cc(-c5ccccc5)cc2n4-c2cc(-c4nc(-c5cc(C(C)(C)C)cc(C(C)(C)C)c5)nc5ccccc45)cc4c2B3c2cc(-c3ccc(C(C)(C)C)cc3)cc3c5c(-c6ccccc6)cc(-c6ccccc6)cc5n-4c23)cc1 ; c1ccc(-c2cc(-c3ccccc3)c3c4cc(C5CCCCC5)cc5c4n(c3c2)-c2cc(-c3nc(-c4ccccc4)nc4ccccc34)cc3c2B5c2cc(C4CCCCC4)cc4c5c(-c6ccccc6)cc(-c6ccccc6)cc5n-3c24)cc1 ; CC(C)(C)c1ccc2c3c1c1c(-c4ccccc4)cc(-c4ccccc4)cc1n3-c1cc(-c3nc(-c4ccccc4)nc4ccccc34)cc3c1B2c1ccc(C(C)(C)C)c2c4c(-c5ccccc5)cc(-c5ccccc5)cc4n-3c12]

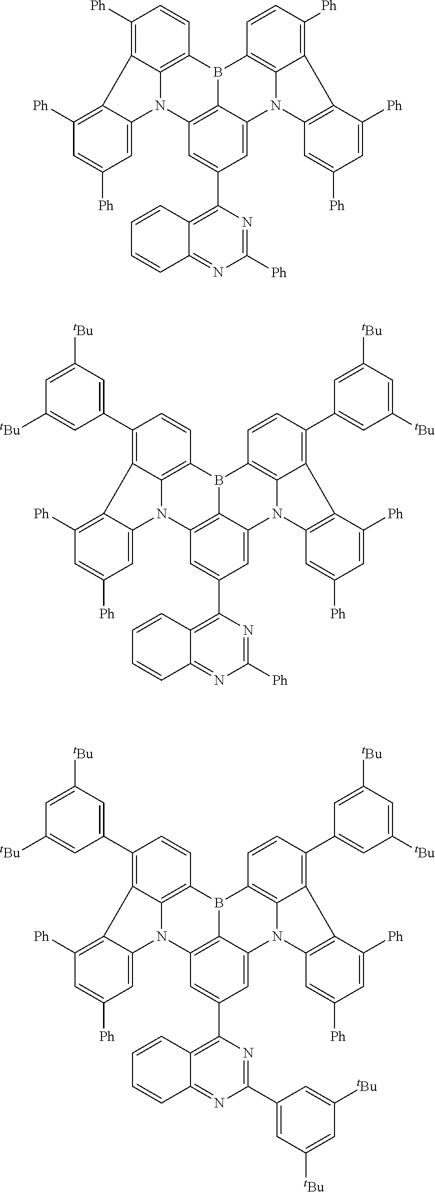

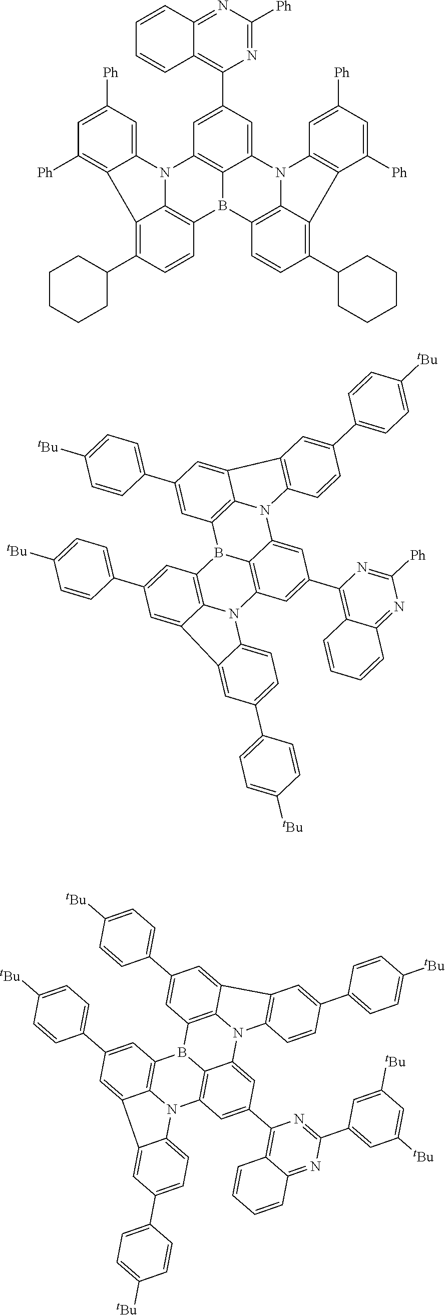

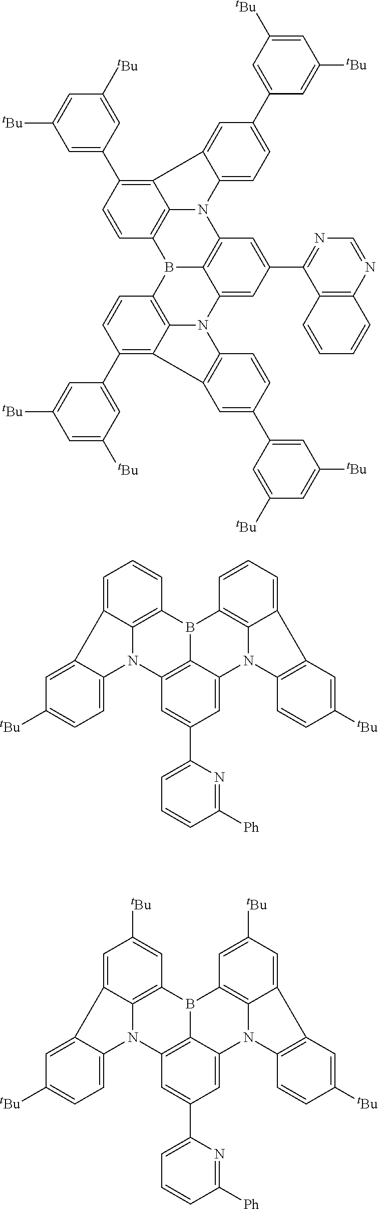

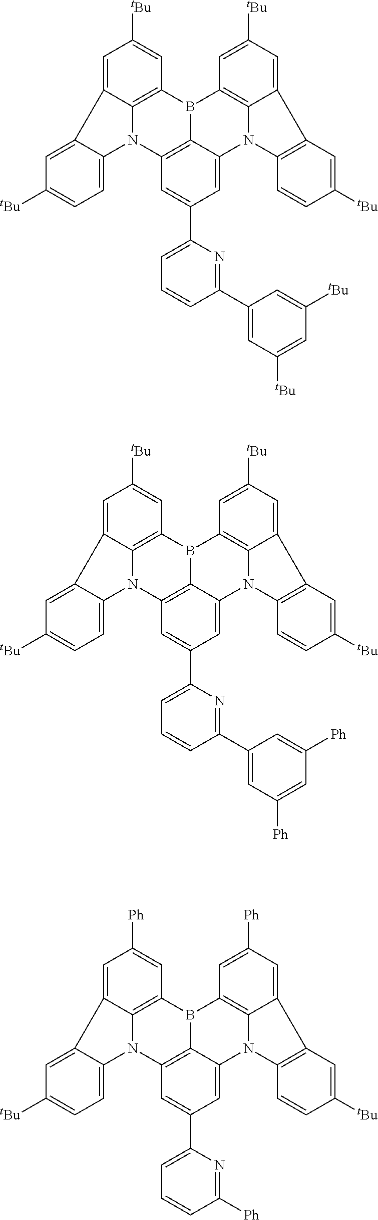 [SMILES: CC(C)(C)c1cc(-c2cccc(-c3cc4c5c(c3)-n3c6ccc(C(C)(C)C)cc6c6cc(C(C)(C)C)cc(c63)B5c3cc(C(C)(C)C)cc5c6cc(C(C)(C)C)ccc6n-4c35)n2)cc(C(C)(C)C)c1 ; CC(C)(C)c1ccc2c(c1)c1cc(C(C)(C)C)cc3c1n2-c1cc(-c2cccc(-c4cc(-c5ccccc5)cc(-c5ccccc5)c4)n2)cc2c1B3c1cc(C(C)(C)C)cc3c4cc(C(C)(C)C)ccc4n-2c13 ; CC(C)(C)c1ccc2c(c1)c1cc(-c3ccccc3)cc3c1n2-c1cc(-c2cccc(-c4ccccc4)n2)cc2c1B3c1cc(-c3ccccc3)cc3c4cc(C(C)(C)C)ccc4n-2c13]

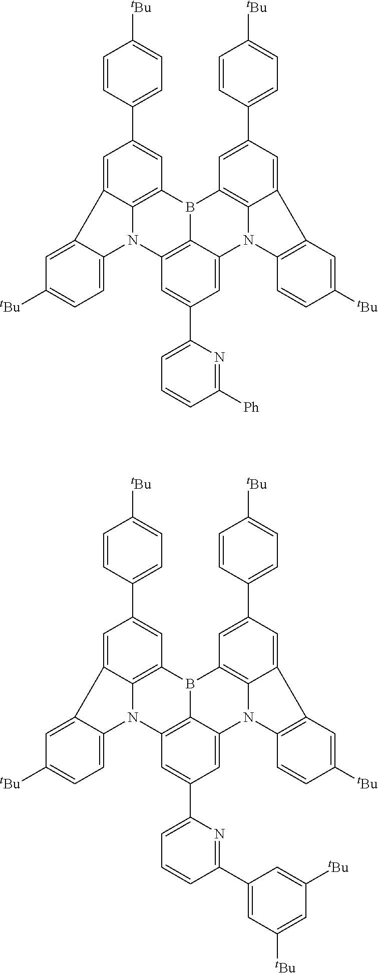 [SMILES: CC(C)(C)c1ccc(-c2cc3c4c(c2)c2cc(C(C)(C)C)ccc2n4-c2cc(-c4cccc(-c5ccccc5)n4)cc4c2B3c2cc(-c3ccc(C(C)(C)C)cc3)cc3c5cc(C(C)(C)C)ccc5n-4c23)cc1 ; CC(C)(C)c1ccc(-c2cc3c4c(c2)c2cc(C(C)(C)C)ccc2n4-c2cc(-c4cccc(-c5cc(C(C)(C)C)cc(C(C)(C)C)c5)n4)cc4c2B3c2cc(-c3ccc(C(C)(C)C)cc3)cc3c5cc(C(C)(C)C)ccc5n-4c23)cc1]

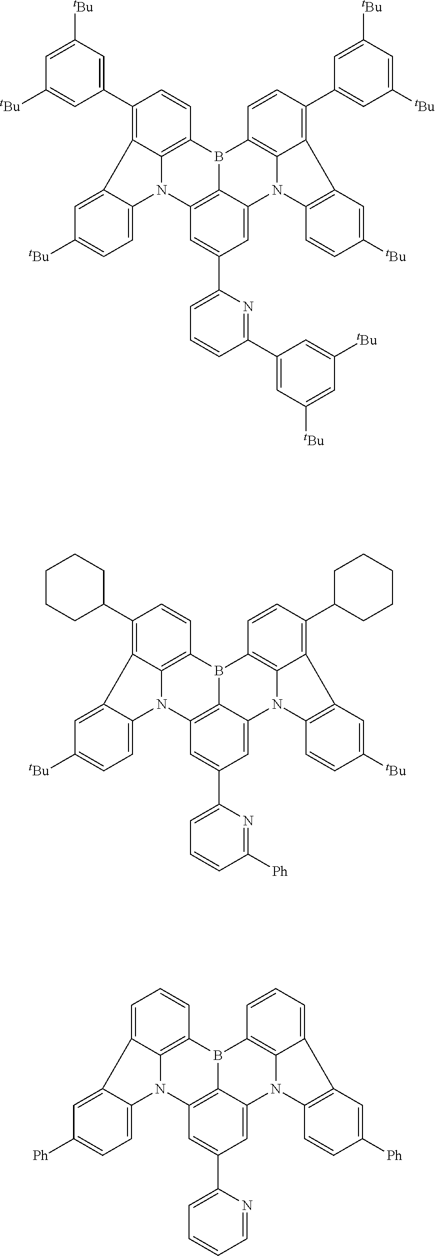 [SMILES: CC(C)(C)c1cc(-c2cccc(-c3cc4c5c(c3)-n3c6ccc(C(C)(C)C)cc6c6c(-c7cc(C(C)(C)C)cc(C(C)(C)C)c7)ccc(c63)B5c3ccc(-c5cc(C(C)(C)C)cc(C(C)(C)C)c5)c5c6cc(C(C)(C)C)ccc6n-4c35)n2)cc(C(C)(C)C)c1 ; CC(C)(C)c1ccc2c(c1)c1c(C3CCCCC3)ccc3c1n2-c1cc(-c2cccc(-c4ccccc4)n2)cc2c1B3c1ccc(C3CCCCC3)c3c4cc(C(C)(C)C)ccc4n-2c13 ; c1ccc(-c2ccc3c(c2)c2cccc4c2n3-c2cc(-c3ccccn3)cc3c2B4c2cccc4c5cc(-c6ccccc6)ccc5n-3c24)cc1]

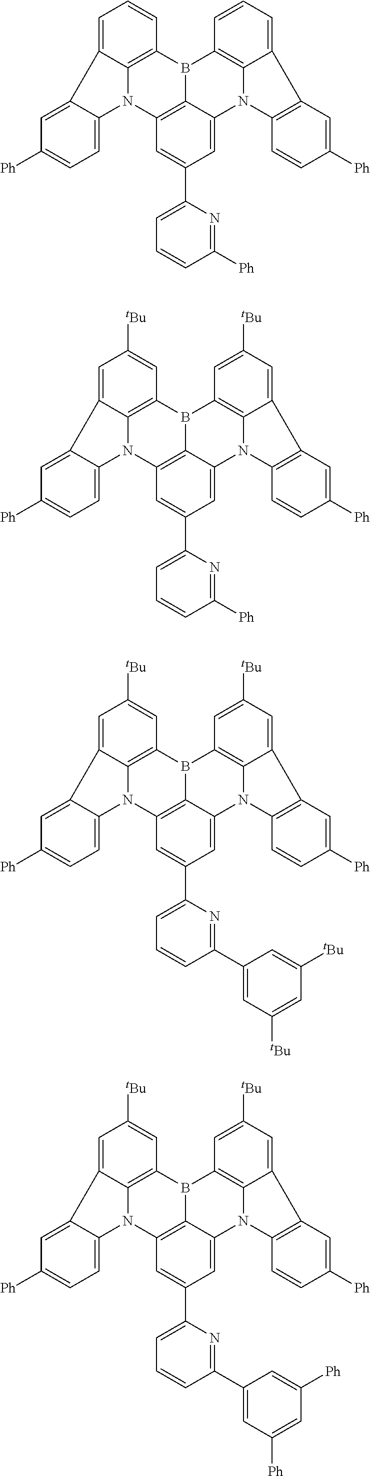

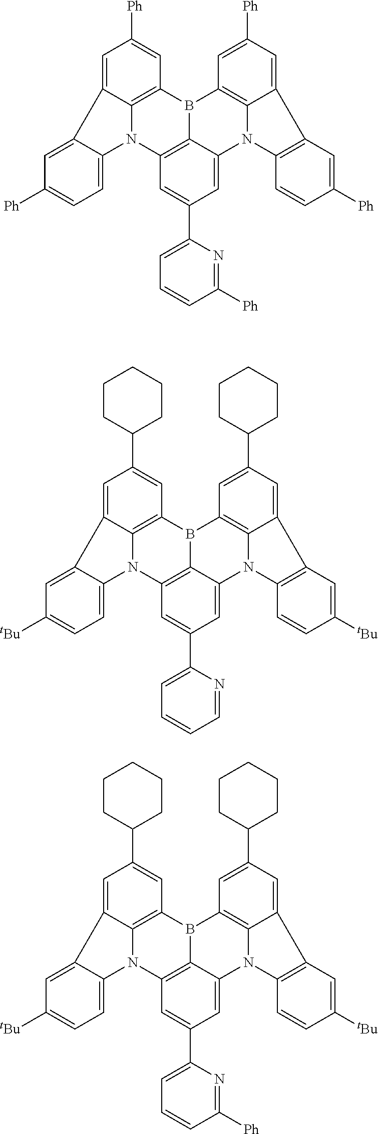 [SMILES: c1ccc(-c2ccc3c(c2)c2cc(-c4ccccc4)cc4c2n3-c2cc(-c3cccc(-c5ccccc5)n3)cc3c2B4c2cc(-c4ccccc4)cc4c5cc(-c6ccccc6)ccc5n-3c24)cc1 ; CC(C)(C)c1ccc2c(c1)c1cc(C3CCCCC3)cc3c1n2-c1cc(-c2ccccn2)cc2c1B3c1cc(C3CCCCC3)cc3c4cc(C(C)(C)C)ccc4n-2c13 ; CC(C)(C)c1ccc2c(c1)c1cc(C3CCCCC3)cc3c1n2-c1cc(-c2cccc(-c4ccccc4)n2)cc2c1B3c1cc(C3CCCCC3)cc3c4cc(C(C)(C)C)ccc4n-2c13]

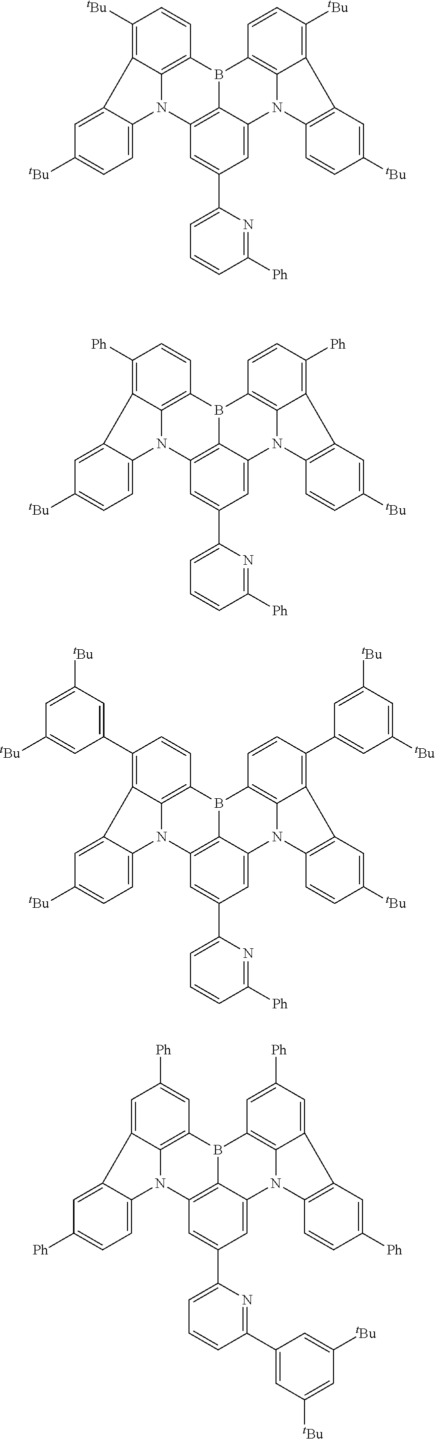

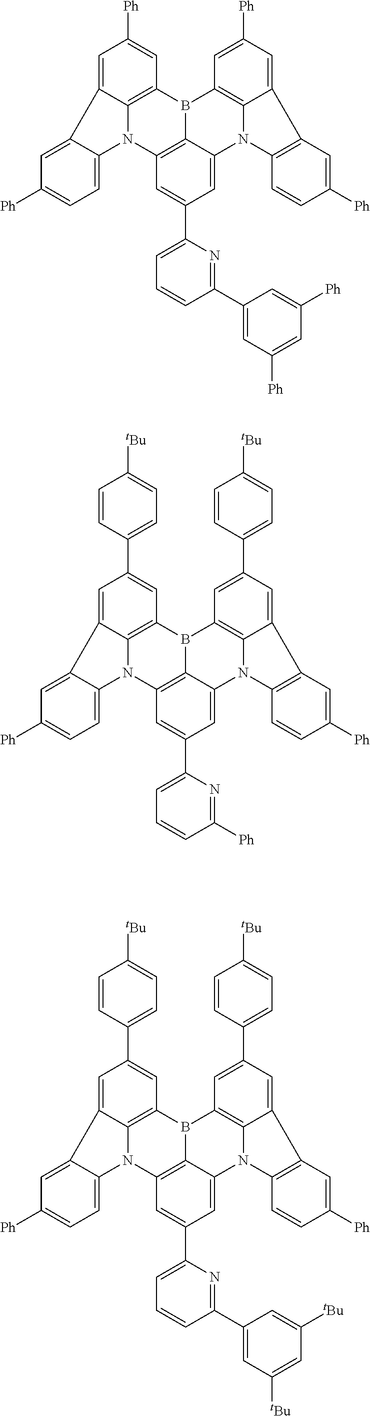 [SMILES: c1ccc(-c2cc(-c3ccccc3)cc(-c3cccc(-c4cc5c6c(c4)-n4c7ccc(-c8ccccc8)cc7c7cc(-c8ccccc8)cc(c74)B6c4cc(-c6ccccc6)cc6c7cc(-c8ccccc8)ccc7n-5c46)n3)c2)cc1 ; CC(C)(C)c1ccc(-c2cc3c4c(c2)c2cc(-c5ccccc5)ccc2n4-c2cc(-c4cccc(-c5ccccc5)n4)cc4c2B3c2cc(-c3ccc(C(C)(C)C)cc3)cc3c5cc(-c6ccccc6)ccc5n-4c23)cc1 ; CC(C)(C)c1ccc(-c2cc3c4c(c2)c2cc(-c5ccccc5)ccc2n4-c2cc(-c4cccc(-c5cc(C(C)(C)C)cc(C(C)(C)C)c5)n4)cc4c2B3c2cc(-c3ccc(C(C)(C)C)cc3)cc3c5cc(-c6ccccc6)ccc5n-4c23)cc1]

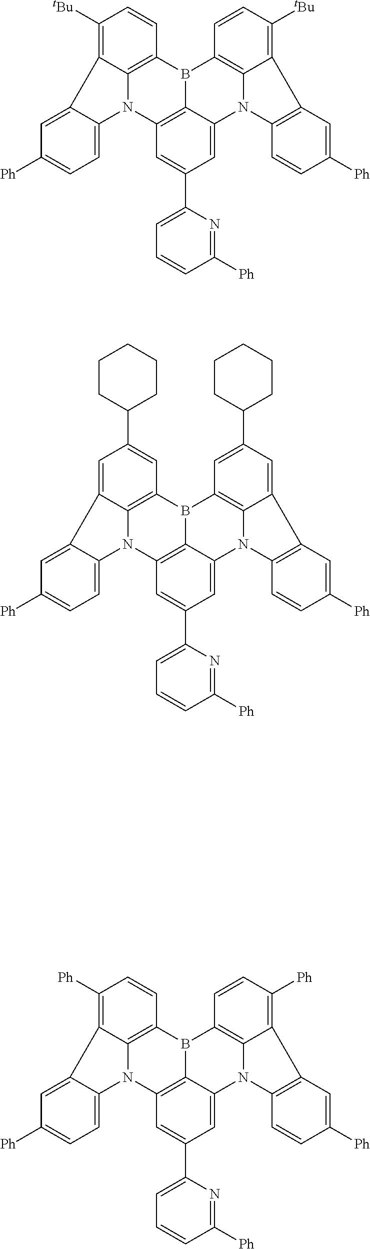 [SMILES: CC(C)(C)c1ccc2c3c1c1cc(-c4ccccc4)ccc1n3-c1cc(-c3cccc(-c4ccccc4)n3)cc3c1B2c1ccc(C(C)(C)C)c2c4cc(-c5ccccc5)ccc4n-3c12 ; c1ccc(-c2ccc3c(c2)c2cc(C4CCCCC4)cc4c2n3-c2cc(-c3cccc(-c5ccccc5)n3)cc3c2B4c2cc(C4CCCCC4)cc4c5cc(-c6ccccc6)ccc5n-3c24)cc1 ; c1ccc(-c2ccc3c(c2)c2c(-c4ccccc4)ccc4c2n3-c2cc(-c3cccc(-c5ccccc5)n3)cc3c2B4c2ccc(-c4ccccc4)c4c5cc(-c6ccccc6)ccc5n-3c24)cc1]

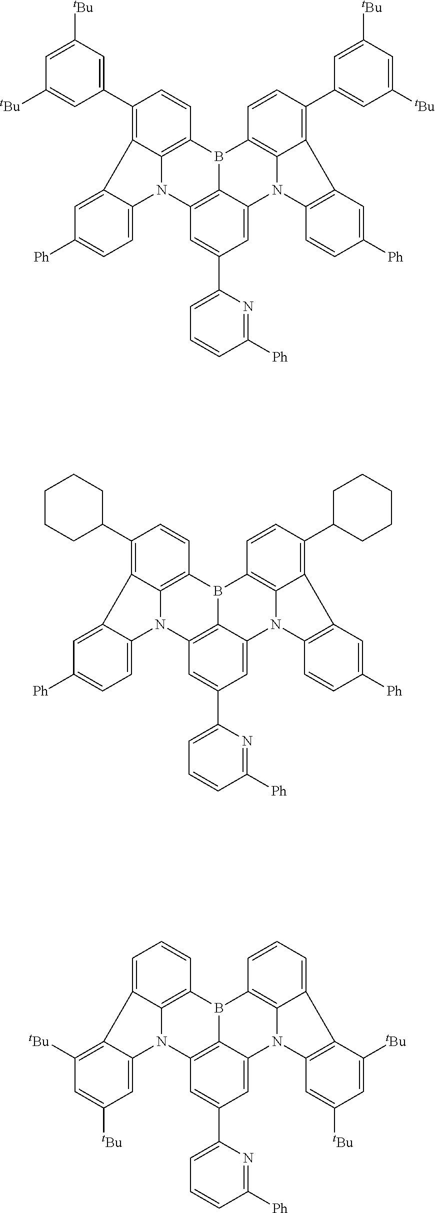 [SMILES: CC(C)(C)c1cc(-c2ccc3c4c2c2cc(-c5ccccc5)ccc2n4-c2cc(-c4cccc(-c5ccccc5)n4)cc4c2B3c2ccc(-c3cc(C(C)(C)C)cc(C(C)(C)C)c3)c3c5cc(-c6ccccc6)ccc5n-4c23)cc(C(C)(C)C)c1 ; c1ccc(-c2ccc3c(c2)c2c(C4CCCCC4)ccc4c2n3-c2cc(-c3cccc(-c5ccccc5)n3)cc3c2B4c2ccc(C4CCCCC4)c4c5cc(-c6ccccc6)ccc5n-3c24)cc1 ; CC(C)(C)c1cc(C(C)(C)C)c2c3cccc4c3n(c2c1)-c1cc(-c2cccc(-c3ccccc3)n2)cc2c1B4c1cccc3c4c(C(C)(C)C)cc(C(C)(C)C)cc4n-2c13]

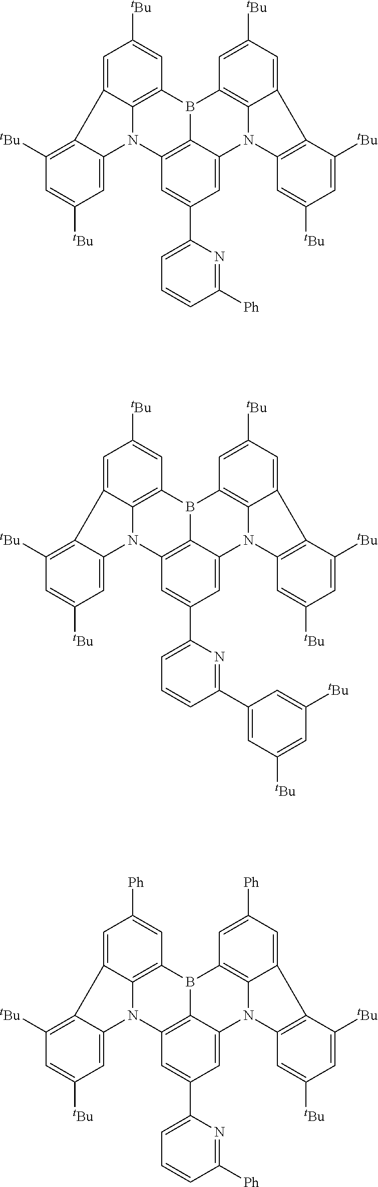 [SMILES: CC(C)(C)c1cc2c3c(c1)c1c(C(C)(C)C)cc(C(C)(C)C)cc1n3-c1cc(-c3cccc(-c4ccccc4)n3)cc3c1B2c1cc(C(C)(C)C)cc2c4c(C(C)(C)C)cc(C(C)(C)C)cc4n-3c12 ; CC(C)(C)c1cc(-c2cccc(-c3cc4c5c(c3)-n3c6cc(C(C)(C)C)cc(C(C)(C)C)c6c6cc(C(C)(C)C)cc(c63)B5c3cc(C(C)(C)C)cc5c6c(C(C)(C)C)cc(C(C)(C)C)cc6n-4c35)n2)cc(C(C)(C)C)c1 ; CC(C)(C)c1cc(C(C)(C)C)c2c3cc(-c4ccccc4)cc4c3n(c2c1)-c1cc(-c2cccc(-c3ccccc3)n2)cc2c1B4c1cc(-c3ccccc3)cc3c4c(C(C)(C)C)cc(C(C)(C)C)cc4n-2c13]

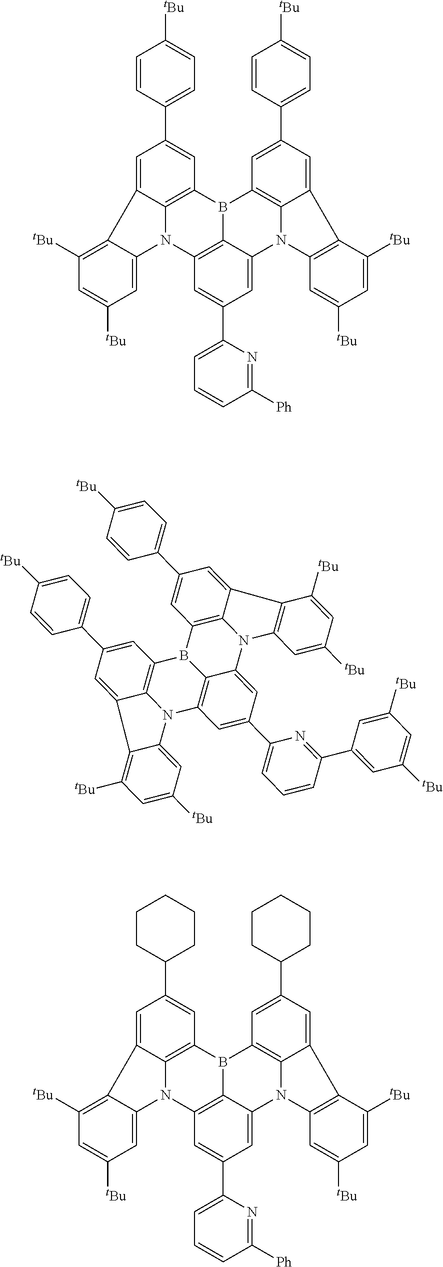 [SMILES: CC(C)(C)c1ccc(-c2cc3c4c(c2)c2c(C(C)(C)C)cc(C(C)(C)C)cc2n4-c2cc(-c4cccc(-c5ccccc5)n4)cc4c2B3c2cc(-c3ccc(C(C)(C)C)cc3)cc3c5c(C(C)(C)C)cc(C(C)(C)C)cc5n-4c23)cc1 ; CC(C)(C)c1ccc(-c2cc3c4c(c2)c2c(C(C)(C)C)cc(C(C)(C)C)cc2n4-c2cc(-c4cccc(-c5cc(C(C)(C)C)cc(C(C)(C)C)c5)n4)cc4c2B3c2cc(-c3ccc(C(C)(C)C)cc3)cc3c5c(C(C)(C)C)cc(C(C)(C)C)cc5n-4c23)cc1 ; CC(C)(C)c1cc(C(C)(C)C)c2c3cc(C4CCCCC4)cc4c3n(c2c1)-c1cc(-c2cccc(-c3ccccc3)n2)cc2c1B4c1cc(C3CCCCC3)cc3c4c(C(C)(C)C)cc(C(C)(C)C)cc4n-2c13]

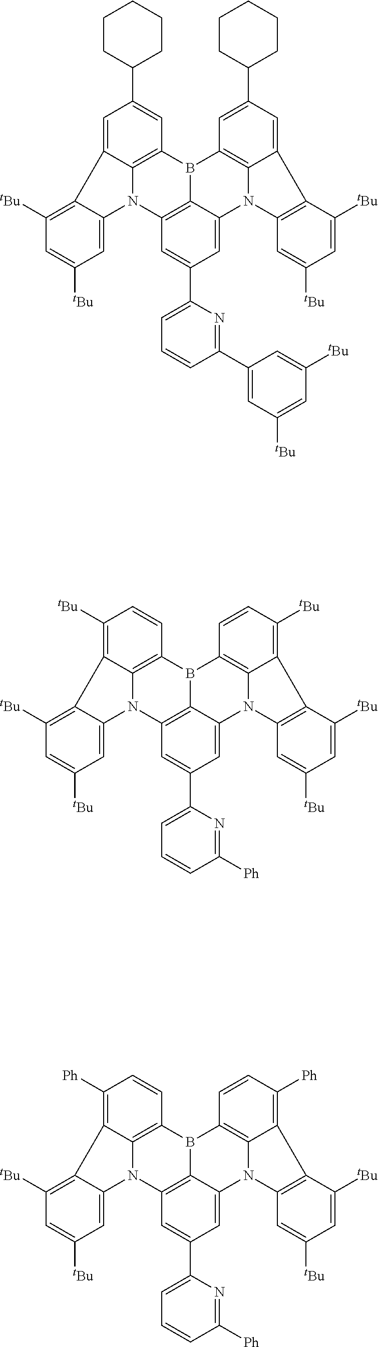 [SMILES: CC(C)(C)c1cc(-c2cccc(-c3cc4c5c(c3)-n3c6cc(C(C)(C)C)cc(C(C)(C)C)c6c6cc(C7CCCCC7)cc(c63)B5c3cc(C5CCCCC5)cc5c6c(C(C)(C)C)cc(C(C)(C)C)cc6n-4c35)n2)cc(C(C)(C)C)c1 ; CC(C)(C)c1cc(C(C)(C)C)c2c3c(C(C)(C)C)ccc4c3n(c2c1)-c1cc(-c2cccc(-c3ccccc3)n2)cc2c1B4c1ccc(C(C)(C)C)c3c4c(C(C)(C)C)cc(C(C)(C)C)cc4n-2c13 ; CC(C)(C)c1cc(C(C)(C)C)c2c3c(-c4ccccc4)ccc4c3n(c2c1)-c1cc(-c2cccc(-c3ccccc3)n2)cc2c1B4c1ccc(-c3ccccc3)c3c4c(C(C)(C)C)cc(C(C)(C)C)cc4n-2c13]

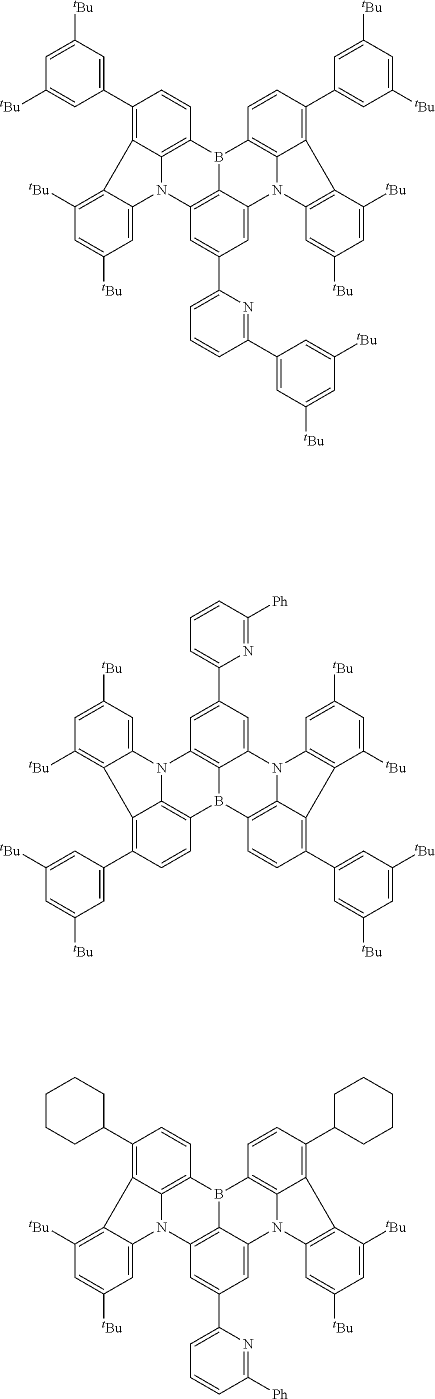

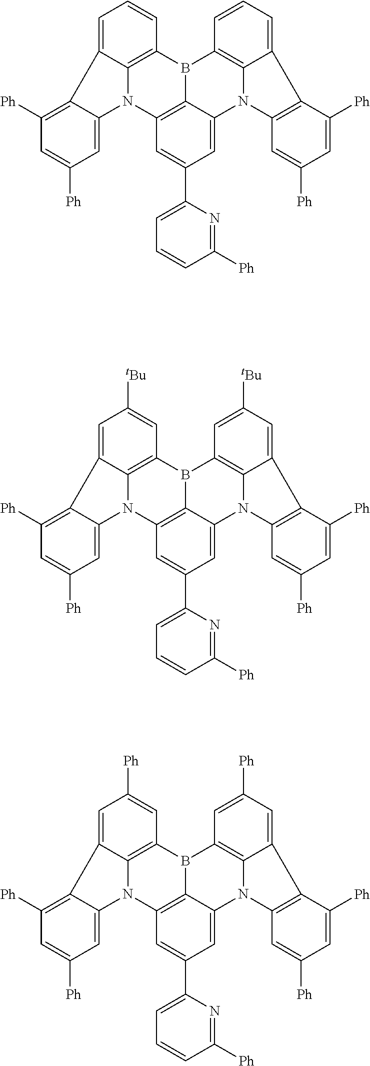 [SMILES: c1ccc(-c2cc(-c3ccccc3)c3c4cccc5c4n(c3c2)-c2cc(-c3cccc(-c4ccccc4)n3)cc3c2B5c2cccc4c5c(-c6ccccc6)cc(-c6ccccc6)cc5n-3c24)cc1 ; CC(C)(C)c1cc2c3c(c1)c1c(-c4ccccc4)cc(-c4ccccc4)cc1n3-c1cc(-c3cccc(-c4ccccc4)n3)cc3c1B2c1cc(C(C)(C)C)cc2c4c(-c5ccccc5)cc(-c5ccccc5)cc4n-3c12 ; c1ccc(-c2cc3c4c(c2)c2c(-c5ccccc5)cc(-c5ccccc5)cc2n4-c2cc(-c4cccc(-c5ccccc5)n4)cc4c2B3c2cc(-c3ccccc3)cc3c5c(-c6ccccc6)cc(-c6ccccc6)cc5n-4c23)cc1]

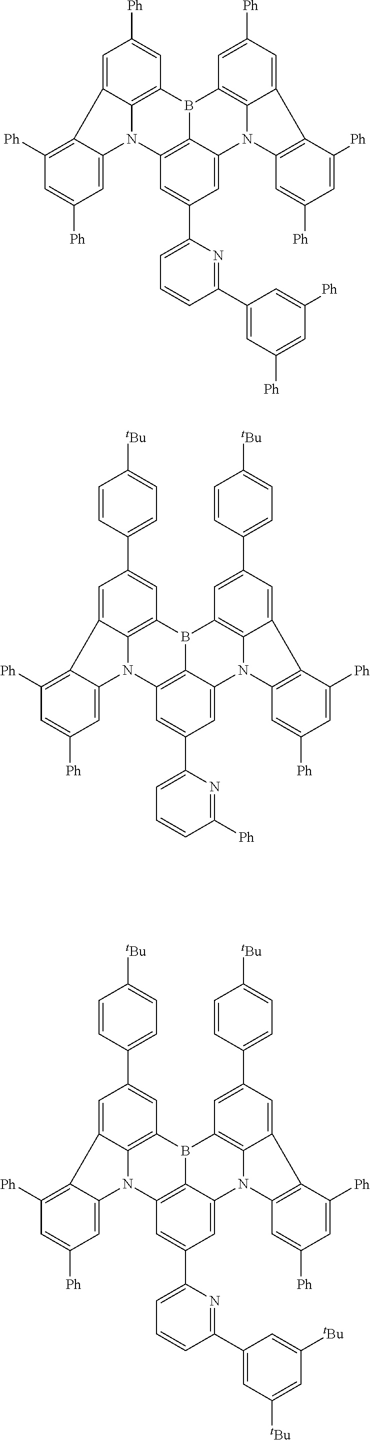

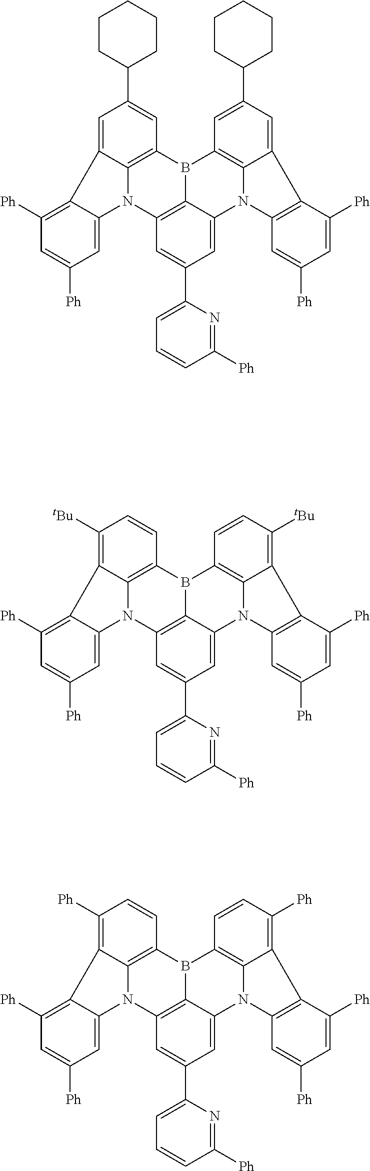 [SMILES: c1ccc(-c2cc(-c3ccccc3)c3c4cc(C5CCCCC5)cc5c4n(c3c2)-c2cc(-c3cccc(-c4ccccc4)n3)cc3c2B5c2cc(C4CCCCC4)cc4c5c(-c6ccccc6)cc(-c6ccccc6)cc5n-3c24)cc1 ; CC(C)(C)c1ccc2c3c1c1c(-c4ccccc4)cc(-c4ccccc4)cc1n3-c1cc(-c3cccc(-c4ccccc4)n3)cc3c1B2c1ccc(C(C)(C)C)c2c4c(-c5ccccc5)cc(-c5ccccc5)cc4n-3c12 ; c1ccc(-c2cc(-c3ccccc3)c3c4c(-c5ccccc5)ccc5c4n(c3c2)-c2cc(-c3cccc(-c4ccccc4)n3)cc3c2B5c2ccc(-c4ccccc4)c4c5c(-c6ccccc6)cc(-c6ccccc6)cc5n-3c24)cc1]

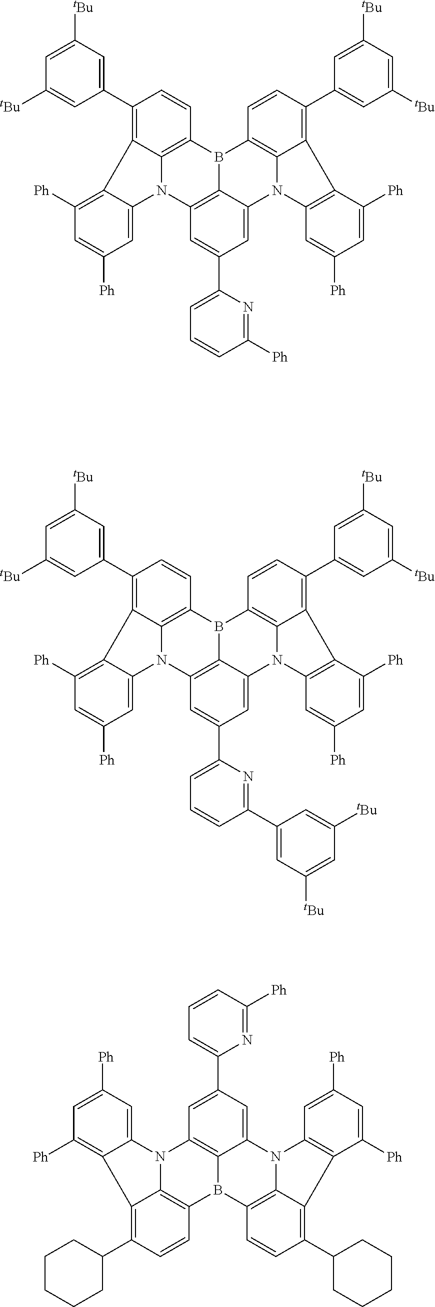

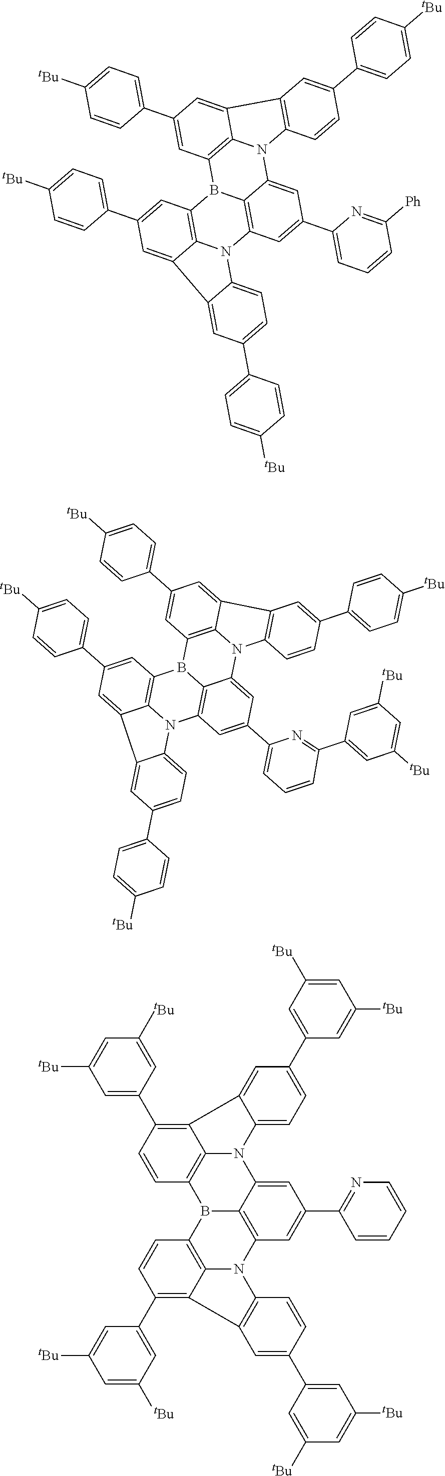

1.-15. (canceled)

16. An organic molecule, comprising a structure of Formula I: 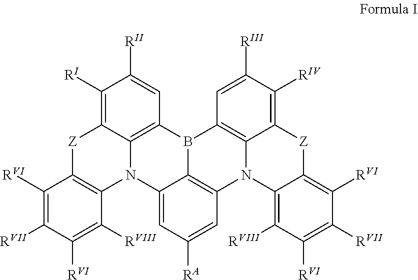
wherein
R^{A} is a moiety comprising a structure of Formula II, III, or IV: 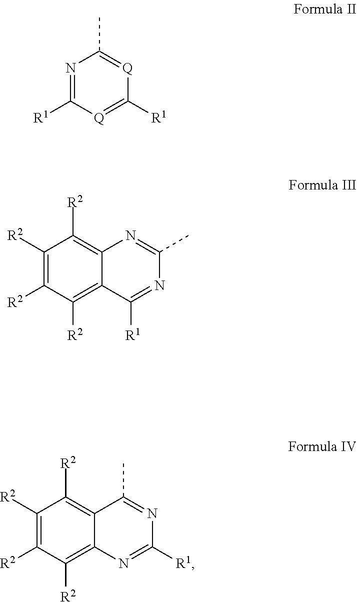
which is bonded to the structure of Formula I via a position marked by the dotted line;
Q is at each occurrence independently selected from the group consisting of N and CR³;
Z is at each occurrence independently from one another selected from the group consisting of a direct bond, CR⁴R⁵, C═CR⁴R⁵, C═O, C═NR⁴, NR⁴, O, SiR⁴R⁵, S, S(O) and S(O)₂;
R¹, R², and R³ are at each occurrence independently selected from the group consisting of:
hydrogen, deuterium, halogen, Me, ⁱPr, ^{t}Bu, CN, CF₃, SiMe₃, SiPh₃; and
C₆-C₁₆-aryl,
wherein optionally one or more hydrogen atoms are independently substituted by C₁-C₅-alkyl, CN, CF₃ and Ph;
R^{I}, R^{II}, R^{III}, R^{IV}, R^{VI}, R^{VII}, and R^{VIII} are at each occurrence independently selected from the group consisting of:
hydrogen;
deuterium;
N(R⁶)₂;
ORO;
SRO;
Si(R⁶)₃;
B(OR⁶)₂;
OSO₂R⁶;
CF₃;
CN;
halogen;
C₁-C₄₀-alkyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₁-C₄₀-alkoxy,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₁-C₄₀-thioalkoxy,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₂-C₄₀-alkenyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₂-C₄₀-alkynyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₆-C₆₀-aryl,
which is optionally substituted with one or more substituents R⁶; and
C₃-C₅₇-heteroaryl,
which is optionally substituted with one or more substituents R⁶;
wherein R^{I}, R^{II}, R^{III}, R^{IV}, R^{VI}, R^{VII}, and R^{VIII} independently from each other optionally form a mono- or polycyclic, aliphatic, aromatic and/or benzo-fused ring system with one or more adjacent substituents R^{I}, R^{II}, R^{III}, R^{IV}, R^{VI}, R^{VII} and/or R^{VIII},
R⁴, R⁵, and R⁶ are at each occurrence independently selected from the group consisting of:
hydrogen, deuterium, OPh, SPh, CF₃, CN, F, Si(C₁-C₅-alkyl)₃, Si(Ph)₃;
C₁-C₅-alkyl,
wherein optionally one or more hydrogen atoms are independently substituted by deuterium, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₆-aryl,
which is optionally substituted with one or more C₁-C₅-alkyl substituents;
C₃-C₁₇-heteroaryl,
which is optionally substituted with one or more C₁-C₅-alkyl substituents;
N(C₆-C₁₈-aryl)₂;
N(C₃-C₁₇-heteroaryl)₂; and
N(C₃-C₁₇-heteroaryl)(C₆-C₁₈-aryl).

17. The organic molecule according to claim 16, wherein the molecule comprises a structure f Formula Ia:

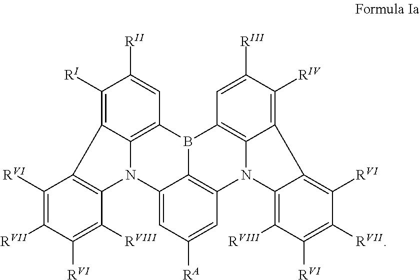

18. The organic molecule according to claim 16, wherein R^{A} is a moiety represented b one of Formulas IIa, IIb, IIc, IIIa, or IVa: 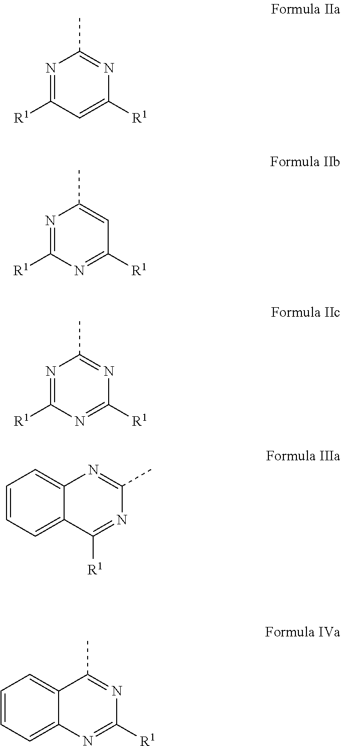
which is bonded to the structure of Formula I via the position marked by the dotted line.

19. The organic molecule according to claim 16, wherein the molecule comprises a structure of Formula Ib or Ic:

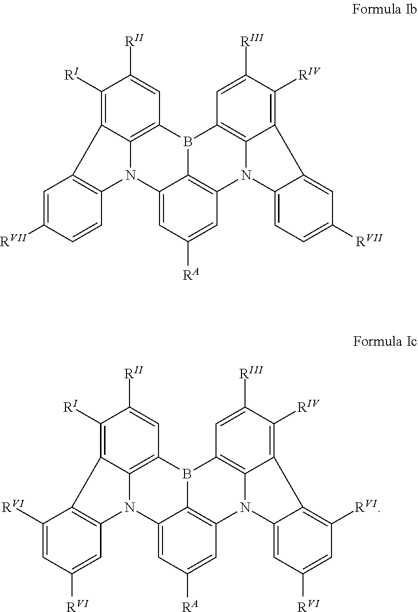

20. The organic molecule according to claim 16, wherein the molecule comprises a structure of Formula Ib-1, Ib-2 or Ib-3:

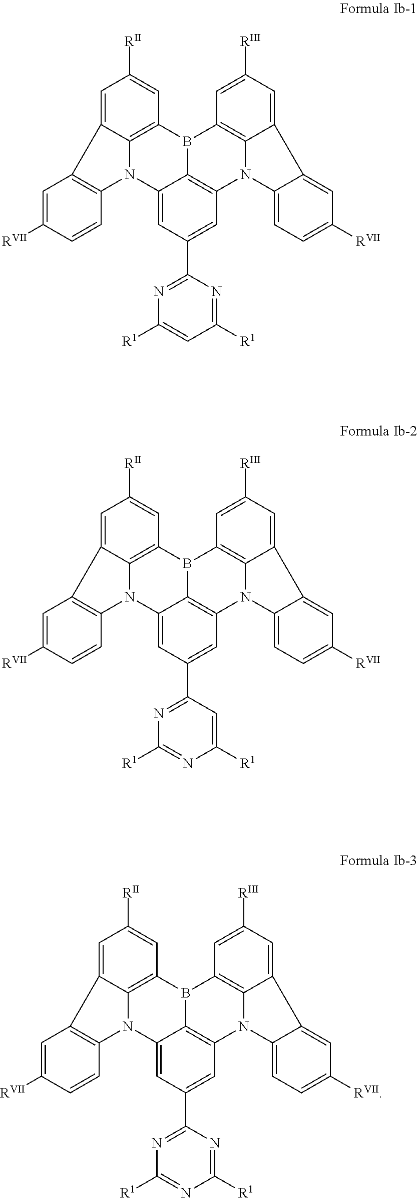

21. The organic molecule according to claim 16, wherein R^{I}, R^{II}, R^{III}, R^{IV}, R^{VI}, R^{VII}, and R^{VIII} are at each occurrence independently selected from the group consisting of:
hydrogen, deuterium, halogen, CN, CF₃, SiMe₃, SiPh₃;
C₁-C₅-alkyl,
wherein one or more hydrogen atoms are optionally substituted by deuterium;
C₆-C₁₈-aryl,
wherein optionally one or more hydrogen atoms are independently substituted by C₁-C₅-alkyl, C₆-C₁₈-aryl, C₃-C₁₇-heteroaryl, CN or CF₃;
C₃-C₁₅-heteroaryl,
wherein optionally one or more hydrogen atoms are independently substituted by C₁-C₅-alkyl, C₆-C₁₈-aryl, C₃-C₁₇-heteroaryl, CN or CF₃; and
N(Ph)₂.

22. The organic molecule according to claim 16, wherein R^{I}, R^{II}, R^{III}, R^{IV}, R^{VI}, R^{VII}, and R^{VIII} are at each occurrence independently selected from the group consisting of:
hydrogen, deuterium, halogen, Me, ⁱPr, ^{t}Bu, CN, CF₃, SiMe₃, SiPh₃,
Ph, which is optionally substituted with one or more substituents independently selected from the group consisting of Me, ⁱPr, ^{t}Bu, CN, CF₃, and Ph, and
N(Ph)₂.

23. The organic molecule according to claim 16, wherein R⁴, R⁵, and R⁶ are at each occurrence independently selected from the group consisting of:
hydrogen, deuterium, halogen, CN, CF₃, SiMe₃, SiPh₃;
C₁-C₅-alkyl,
wherein one or more hydrogen atoms are optionally substituted by deuterium;
C₆-C₁₈-aryl,
wherein optionally one or more hydrogen atoms are independently substituted by C₁-C₅-alkyl, C₆-C₁₈-aryl, C₃-C₁₇-heteroaryl, CN or CF₃;
C₃-C₁₅-heteroaryl,
wherein optionally one or more hydrogen atoms are independently substituted by C₁-C₅-alkyl, C₆-C₁₈-aryl, C₃-C₁₇-heteroaryl, CN or CF₃; and
N(Ph)₂.

24. An optoelectronic device comprising the organic molecule according to claim 16 as a luminescent emitter.

25. The optoelectronic device according to claim 24, wherein the optoelectronic device is at least one selected from the group consisting of organic light-emitting diodes (OLEDs), light-emitting electrochemical cells, OLED-sensors, organic diodes, organic solar cells, organic transistors, organic field-effect transistors, organic lasers, and down-conversion elements.

26. A composition comprising:
(a) the organic molecule according to claim 16, as an emitter and/or a host, and
(b) an emitter and/or a host material, which differs from the organic molecule, and
(c) optionally, a dye and/or a solvent.

27. An optoelectronic device, comprising the composition according to claim 26.

28. The optoelectronic device according to claim 27, wherein the device is at least one selected from the group consisting of organic light-emitting diodes (OLEDs), light-emitting electrochemical cells, OLED-sensors, organic diodes, organic solar cells, organic transistors, organic field-effect transistors, organic lasers, and down-conversion elements.

29. The optoelectronic device according to claim 24, comprising:
a substrate,
an anode, and
a cathode, wherein the anode or the cathode is disposed on the substrate, and
a light-emitting layer between the anode and the cathode and comprising the organic molecule.

30. A method for producing an optoelectronic device, the method comprising depositing the organic molecule according to claim 16 by a vacuum evaporation method or from a solution.

31. The optoelectronic device according to claim 27, comprising:
a substrate,
an anode, and
a cathode, wherein the anode or the cathode is on the substrate, and
a light-emitting layer between the anode and the cathode and comprising the composition.

32. A method for producing an optoelectronic device, the method comprising depositing the composition according to claim 26 by a vacuum evaporation method or from a solution.
